(19) United States
(12) Patent Application Publication
(10) Pub. No.: US 2024/0018165 A1
(43) Pub. Date: Jan. 18, 2024

(54) ORGANIC MOLECULES FOR OPTOELECTRONIC DEVICES

(71) Applicant: Samsung Display Co., Ltd., Yongin-si, Gyeonggi-do (KR)

(72) Inventors: Stefan SEIFERMANN, Bühl (DE); Daniel ZINK, Graben-Neudorf (DE); Damien THIRION, Karlsdorf-Neuthard (DE)

(21) Appl. No.: 18/248,675

(22) PCT Filed: Oct. 11, 2021
(86) PCT No.: PCT/EP2021/078055

§ 371 Date: Apr. 11, 2023

(30) Foreign Application Priority Data
Oct. 12, 2020 (EP) 20201411.4

(51) Int. Cl. C07F 5/02; H10K 50/11; C09K 11/06; H10K 71/16; H10K 85/60

(52) U.S. Cl. CPC C07F 5/02; H10K 50/11; C09K 11/06; C09K 2211/1055; H10K 85/658; C07B 2200/05; H10K 71/164

(57) ABSTRACT

The invention pertains to an organic molecule for use in optoelectronic devices. The organic molecule has
a first chemical moiety with a structure of Formula I

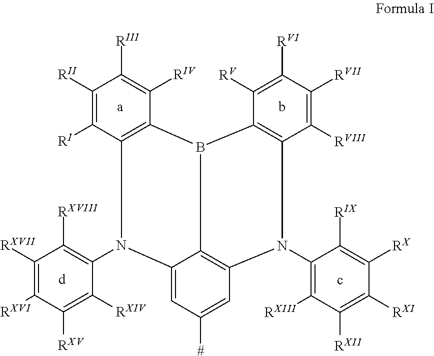

and
a second chemical moiety with a structure according to Formula II

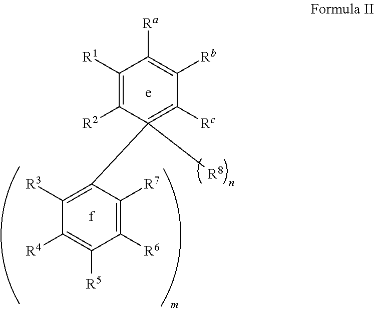

wherein the first chemical moiety is linked to the second chemical moiety via a single bond;
# is the binding site of the first chemical moiety to the second chemical moiety;
exactly one group selected from R^{a}, R^{b}, and R^{c} is the binding site of a single bond linking the second chemical moiety to the first chemical moiety;
m is 0 or 1, n is 0 or 1, and m+n=1; and
wherein at least one pair of adjacent groups R^{I} and R^{II}, R^{II} and R^{III}, R^{III} and R^{IV}, R^{V} and R^{VI}, R^{VI} and R^{VII}, R^{VII} and R^{VIII}, R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, or R^{XVII} and R^{XVIII} forms an aromatic ring system which is fused to the adjacent benzene ring a, b, c or d of Formula I and which is optionally substituted with one or more substituent R⁹.

### CROSS-REFERENCE TO RELATED APPLICATIONS

This application is a U.S. National Phase Patent Application of International Patent Application Number PCT/EP2021/078055, filed on Oct. 11, 2021, which claims priority to European Patent Application Number 20201411.4, filed on Oct. 12, 2020, the entire content of each of which is incorporated herein by reference.

The invention relates to light-emitting organic molecules and their use in organic light-emitting diodes (OLEDs) and in other optoelectronic devices.

### DESCRIPTION

The object of the present invention is to provide molecules which are suitable for use in optoelectronic devices.

This object is achieved by the invention which provides a new class of organic molecules.

Optoelectronic devices containing one or more light-emitting layers based on organics such as, e.g., organic light emitting diodes (OLEDs), light emitting electrochemical cells (LECs) and light-emitting transistors gain increasing importance. In particular, OLEDs are promising devices for electronic products such as screens, displays and illumination devices. In contrast to most optoelectronic devices essentially based on inorganics, optoelectronic devices based on organics are often rather flexible and producible in particularly thin layers. The OLED-based screens and displays already available today bear either good efficiencies and long lifetimes or good color purity and long lifetimes, but do not combine all three properties, i.e. good efficiency, long lifetime, and good color purity.

Thus, there is still an unmet technical need for optoelectronic devices which have a high quantum yield, a long lifetime, and a good color purity.

The color purity or color point of an OLED is typically provided by CIEx and CIEy coordinates, whereas the color gamut for the next display generation is provided by so-called BT-2020 and DCPI3 values. Generally, in order to achieve these color coordinates, top emitting devices are needed to adjust the color coordinates by changing the cavity. In order to achieve high efficiency in top emitting devices while targeting this color gamut, a narrow emission spectrum in bottom emitting devices is required.

The organic molecules according to the invention exhibit emission maxima in the deep blue, sky blue, green or yellow spectral range, preferably in the deep blue, sky blue, and green spectral range, and most preferably in the green spectral range. The organic molecules exhibit in particular emission maxima between 420 and 580 nm, more preferably between 440 and 560 nm, even more preferably between 470 and 550 nm, and particularly preferably between 500 and 540 nm. Additionally, the molecules of the invention exhibit in particular a narrow emission—expressed by a small full width at half maximum (FWHM). The emission spectra of the organic molecules preferably show a full width at half maximum (FWHM) of less than or equal to 0.25 eV (0.25 eV), typically measured with 2% by weight of the emitter in poly(methyl methacrylate) PMMA at room temperature (i.e. approximately 25° C.). The photoluminescence quantum yields of the organic molecules according to the invention are, in particular, 10% or more.

The use of the molecules according to the invention in an optoelectronic device, for example, an organic light-emitting diode (OLED), leads to a narrow emission and high efficiency of the device. Corresponding OLEDs have a higher stability than OLEDs with known emitter materials and comparable color and/or by employing the molecules according to the invention in an OLED display, a more accurate reproduction of visible colors in nature, i.e. a higher resolution in the displayed image, is achieved. In particular, the molecules can be used in combination with an energy pump to achieve hyper-fluorescence or hyper-phosphorescence. In these cases, another species included in an optoelectronic device transfers energy to the organic molecules of the invention which then emit light.

The organic molecules according to the invention include or consist of:
one first chemical moiety including or consisting of a structure of Formula I

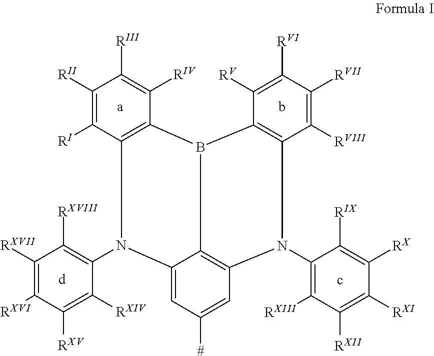

and
one second chemical moiety including or consisting of a structure according to Formula II

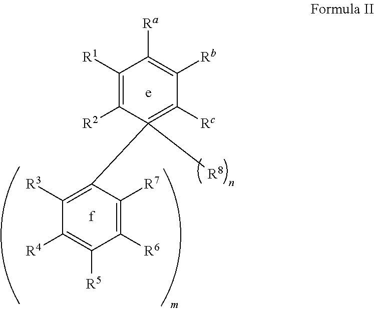

wherein the first chemical moiety is linked to the second chemical moiety via a single bond.

# is the binding site of the first chemical moiety to the second chemical moiety.

m is 0 or 1, n is 0 or 1.

R^{a} is the binding site of a single bond linking the second chemical moiety to the first chemical moiety, or is R^{A}.

R^{b} is the binding site of a single bond linking the second chemical moiety to the first chemical moiety, or is R^{B}.

R^{c} is the binding site of a single bond linking the second chemical moiety to the first chemical moiety, or is R^{X}.

R^{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, and R^{XVIII} are independently of each other selected from the group consisting of: hydrogen, deuterium, N(R⁹)₂, OR⁹, SR⁹, Si(R⁹)₃, B(OR⁹)₂, OSO₂R⁹, CF₃, CN, halogen (F, Cl, Br, I),
C₁-C₄O-alkyl,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₁-C₄₀-alkoxy,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₁-C₄₀-thioalkoxy,
which is optionally substituted with one or more substituents R⁹ and

wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₂-C₄₀-alkenyl,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₂-C₄₀-alkynyl,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₆-C₆₀-aryl,
which is optionally substituted with one or more substituents R⁹; and
C₃-C₅₇-heteroaryl,
which is optionally substituted with one or more substituents R⁹;
wherein at least one pair of adjacent groups R^{I} and R^{II}, R^{II} and R^{III}, R^{III} and R^{IV}, R^{V} and R^{VI}, R^{VI} and R^{VII}, R^{VII} and R^{VIII}, R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, or R^{XVII} and R^{XVIII} forms an aromatic ring system which is fused to the adjacent benzene ring a, b, c or d of Formula I and which is optionally substituted with one or more substituents R⁹; and
wherein each pair of R^{I} and R^{XVIII} as well as R^{VIII} and R^{IX} optionally forms a group Z¹, which is at each occurrence independently of each other selected from the group consisting of: direct bond, CR⁹R¹⁰, C═CR⁹R¹⁰, C═O, C═NR⁹, NR⁹, O, SiR⁹R¹⁰, S, S(O) and S(O)₂.

R^{A}, R^{B}, R^{X}, and R¹ to R⁸ are independently of each other selected from the group consisting of: hydrogen, deuterium, N(R¹¹)₂, OR, SR¹¹, Si(R¹¹)₃, B(OR¹¹)₂, R¹¹, CF₃, CN, halogen (F, Cl, Br, I),
C₁-C₄₀-alkyl,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₁-C₄₀-alkoxy,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₁-C₄₀-thioalkoxy,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₂-C₄₀-alkenyl,
which is optionally substituted with one or more substituents R¹¹ and
wherein one or more non-adjacent CH₂-groups are optionally substituted by R¹¹C═CR¹¹, C═C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₂-C₄₀-alkynyl,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₆-C₆₀-aryl,
which is optionally substituted with one or more substituents R¹¹; and
C₃-C₅₇-heteroaryl,
which is optionally substituted with one or more substituents R¹¹;
wherein each pair of R² and R³ as well as R^{X} and R⁷ optionally forms a group Z², which is at each occurrence independently of each other selected from the group consisting of: CR¹²R¹³, C═CR¹²R¹³, C═O, C═NR¹², NR¹², O, SiR¹²R¹³, S, S(O) and S(O)₂;
wherein, optionally, one or more pair of adjacent groups selected from R¹ and R², R³ and R⁴, R⁴ and R₅, R⁵ and R⁶, R⁶ and R⁷, R⁷ and R⁸, R⁸ and R^{X}, R^{X} and R^{B}, R^{B} and R^{A}, and R^{A} and R¹ form an aromatic or aliphatic, carbo- or heterocyclic ring system which is fused to the adjacent benzene ring e or f of Formula II, and which is optionally substituted with one or more substituents R¹¹.

R¹² and R¹³ are at each occurrence independently of each other selected from the group consisting of: hydrogen, deuterium, N(R¹⁴)₂, OR¹⁴, SR¹⁴, Si(R⁴)₃, B(OR¹⁴)₂, OSO₂R¹⁴, CF₃, CN, halogen (F, Cl, Br, I),
C₁-C₄₀-alkyl,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₁-C₄₀-alkoxy,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₁-C₄₀-thioalkoxy,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₂-C₄₀-alkenyl,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₂-C₄₀-alkynyl,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR⁴;
C₆-C₆₀-aryl,
which is optionally substituted with one or more substituents R¹⁴; and
C₃-C₅₇-heteroaryl,
which is optionally substituted with one or more substituents R¹⁴;
wherein, optionally, two or more substituents R¹² and/or R¹³ form an aliphatic or aromatic carbo- or heterocyclic ring system including 5 to 30 ring atoms, out of which 1 to 3 atoms may be a heteroatom independently selected from the group consisting of N, O, and S.
R⁹, R¹⁰, R¹¹, and R¹⁴ are at each occurrence independently of each other selected from the group consisting of: hydrogen, deuterium, OPh (Ph=phenyl), SPh, CF₃, CN, F, Si(C₁-C₅-alkyl)₃, Si(Ph)₃,
C₁-C₅-alkyl,
wherein optionally one or more hydrogen atoms are independently substituted by deuterium, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₃-C₁₇-aryl)₂,
N(C₃-C₁₇-heteroaryl)₂; and
N(C₃-C₁₇-heteroaryl)(C₆-C₁₈-aryl).

According to the invention, exactly one group selected from R^{e}, R^{b}, and R^{c} is the binding site of a single bond linking the second chemical moiety to the first chemical moiety;

Furthermore, according to the invention: m+n=1.

In one embodiment of the invention, R^{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, and R^{XVIII} are independently of each other selected from the group consisting of: hydrogen, deuterium, OPh, SPh, CF₃, CN, F, Si(C₁-C₅-alkyl)₃, Si(Ph)₃,
C₁-C₅-alkyl,
wherein optionally one or more hydrogen atoms are independently substituted by deuterium, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂,
N(C₃-C₁₇-heteroaryl)₂; and
N(C₃-C₁₇-heteroaryl)(C₆-C₁₈-aryl);
wherein at least one pair of adjacent groups R^{I} and R^{II}, R^{II} and R^{III}, R^{III} and R^{IV}, R^{V} and R^{VI}, R^{VI} and R^{VII}, or R^{VII} and R^{VIII} forms an aromatic ring system which is fused to the adjacent benzene ring a or b of Formula I, and which is optionally substituted with one or more substituents R⁹; wherein the optionally so-formed fused ring system or systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I; and
wherein each pair of R^{I} and R^{XVIII} as well as R^{VIII} and R^{IX} optionally forms a group Z¹, which is at each occurrence a direct bond.

In a preferred embodiment of the invention, R^{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, and R^{XVIII} are independently of each other selected from the group consisting of: hydrogen, deuterium, Me, ⁱPr, ^{t}Bu, CN, CF₃, SiMe₃, SiPh₃,
Ph, which is optionally substituted with one or more substituents independently selected from the group consisting of deuterium, Me, ⁱPr, ^{t}Bu, CN, CF₃, and Ph,
and N(Ph)₂;
wherein at least one pair of adjacent groups R^{I} and R^{II}, R^{II} and R^{III}, R^{III} and R^{IV}, R^{V} and R^{VI}, R^{VI} and R^{VII}, or R^{VII} and R^{VIII} forms an aromatic ring system which is fused to the adjacent benzene ring a or b of Formula I, and which is optionally substituted with one or more substituents independently of each other selected from the group consisting of: deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein the optionally so-formed fused ring system or systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I;
wherein each pair of R^{I} and R^{XVIII} as well as R^{VIII} and R^{IX} optionally forms a group Z¹, which is at each occurrence a direct bond.

In an even more preferred embodiment of the invention, R^{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, and R^{XVIII} are independently of each other selected from the group consisting of: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein at least one pair of adjacent groups R^{I} and R^{II}, R^{II} and R^{III}, R^{III} and R^{IV}, R^{V} and R^{VI}, R^{VI} and R^{VII}, or R^{VII} and R^{VIII} forms an aromatic ring system which is fused to the adjacent benzene ring a or b of Formula I, and which is optionally substituted with one or more substituents independently of each other selected from the group consisting of: deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein the optionally so-formed fused ring system or systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I;
wherein each pair of R^{I} and R^{XVIII} as well as R^{VIII} and R^{IX} optionally forms a group Z¹, which is at each occurrence a direct bond.

In a particularly preferred embodiment of the invention, R^{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, and R^{XVIII} are independently of each other selected from the group consisting of: hydrogen, deuterium, Me, ⁱPr, ^{t}Bu, and
Ph, which is optionally substituted with one or more substituents independently selected from the group consisting of deuterium, Me, ⁱPr, ^{t}Bu, and Ph;
wherein at least one pair of adjacent groups R^{I} and R^{II}, R^{II} and R^{III}, R^{III} and R^{IV}, R^{V} and R^{VI}, R^{VI} and R^{VII}, or R^{VII} and R^{VIII} forms an aromatic ring system which is fused to the adjacent benzene ring a or b of Formula I, and which is optionally substituted with one or more substituents independently of each other selected from the group consisting of: deuterium, Me, ⁱPr, ^{t}Bu, and
Ph, which is optionally substituted with one or more substituents independently selected from the group consisting of deuterium, Me, ⁱPr, ^{t}Bu, and Ph;
wherein the optionally so-formed fused ring system or systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I;
wherein each pair of R^{I} and R^{XVIII} as well as R^{VIII} and R^{IX} optionally forms a group Z¹, which is at each occurrence a direct bond;

In a preferred embodiment of the invention, at least one pair of adjacent groups R^{I} and R^{II}, R^{II} and R^{III}, or R^{III} and R^{IV} forms an aromatic ring system which is fused to the adjacent benzene ring a;
and at least one pair of adjacent groups R^{V} and R^{VI}, R^{VI} and R^{VII}, or R^{VII} and R^{VIII} forms an aromatic ring system which is fused to the adjacent benzene ring b of general Formula I;
wherein both of the so-formed fused ring systems are optionally substituted with one or more substituents independently of each other selected from the group consisting of: deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein the so-formed fused ring systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I; and
wherein each pair of R^{I} and R^{XVIII} as well as R^{VIII} and R^{IX} optionally forms a group Z¹, which is at each occurrence a direct bond.

In a still even more preferred embodiment of the invention, at least one pair of adjacent groups R^{I} and R^{II}, R^{II} and R^{III}, or R^{III} and R^{IV} forms an aromatic ring system which is fused to the adjacent benzene ring a;
and at least one pair of adjacent groups R^{V} and R^{VI}, R^{VI} and R^{VII}, or R^{VII} and R^{VIII} forms an aromatic ring system which is fused to the adjacent benzene ring b of general Formula I;
wherein the so-formed aromatic ring systems are identical and optionally substituted with one or more substituents independently of each other selected from the group consisting of: deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein the so-formed fused ring systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I; and
wherein each pair of R^{I} and R^{XVIII} as well as R^{VIII} and R^{IX} optionally forms a group Z¹, which is at each occurrence a direct bond.

In a still even more preferred embodiment of the invention, exactly one pair of adjacent groups R^{I} and R^{II}, R^{II} and R^{III}, or R^{III} and R^{IV} forms an aromatic ring system which is fused to the adjacent benzene ring a;
and exactly one pair of adjacent groups R^{V} and R^{VI}, R^{VI} and R^{VII}, or R^{VII} and R^{VIII} forms an aromatic ring system which is fused to the adjacent benzene ring b of general Formula I;
wherein both of the so-formed aromatic ring systems are identical (e.g. both naphthyl) and optionally substituted with one or more substituents independently of each other selected from the group consisting of: deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein the so-formed fused ring systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I; and
wherein R^{I} and R^{XVIII} as well as R^{VIII} and R^{IX} do not form a group Z¹.

In a particularly preferred embodiment of the invention, exactly one pair of adjacent groups R^{I} and R^{II}, R^{II} and R^{III}, or R^{III} and R^{IV} forms an aromatic ring system which is fused to the adjacent benzene ring a;
and exactly one pair of adjacent groups R^{V} and R^{VI}, R^{VI} and R^{VII}, or R^{VII} and R^{VIII} forms an aromatic ring system which is fused to the adjacent benzene ring b of general Formula I;
wherein both of the so-formed aromatic ring systems are identical (e.g. both naphthyl) and optionally substituted with one or more substituents independently of each other selected from the group consisting of: deuterium, Me, ⁱPr, ^{t}Bu, and
Ph, which is optionally substituted with one or more substituents independently selected from the group consisting of deuterium, Me, ⁱPr, ^{t}Bu, and Ph;
wherein the so-formed fused ring systems constructed from the respective benzene ring a or b and the additional ring or rings formed by adjacent substituents each include or consist of in total 9 to 30 ring atoms, which are all carbon atoms;
wherein no pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to the adjacent benzene ring c or d of Formula I; and
wherein R^{I} and R^{XVIII} as well as R^{VIII} and R^{IX} do not form a group Z¹.

In one embodiment of the invention, R^{A}, R^{B}, R^{X}, and R¹ to R⁸ are independently of each other selected from the group consisting of: hydrogen, deuterium, OPh, SPh, CF₃, CN, F, Si(C₁-C₅-alkyl)₃, Si(Ph)₃,
C₁-C₅-alkyl,
wherein optionally one or more hydrogen atoms are independently substituted by deuterium, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂,
N(C₃-C₁₇-heteroaryl)₂; and
N(C₃-C₁₇-heteroaryl)(C₆-C₁₈-aryl);
wherein one pair selected from R² and R³ as well as R^{X} and R⁷ optionally forms a group Z², which is at each occurrence independently of each other selected from the group consisting of: CR¹²R¹³, C═O, NR¹², O, SiR¹²R¹³, and S; and
wherein, optionally, one or more pair of adjacent groups selected from R¹ and R², R³ and R⁴, R⁴ and R⁵, R⁵ and R⁶, R⁶ and R⁷, R⁷ and R⁸, R⁸ and R^{X}, R^{X} and R^{B}, R^{B} and R^{A}, and R^{A} and R¹ form an aromatic or aliphatic, carbo- or heterocyclic ring system which is fused to the adjacent benzene ring e or f of Formula II and optionally substituted with one or more substituents independently of each other selected from the group consisting of: deuterium, Me, ⁱPr, ^{t}Bu, CN, CF₃, and
Ph, which is optionally substituted with one or more substituents independently of each other selected from deuterium, Me, ⁱPr, ^{t}Bu, CN, CF₃;
wherein the optionally so-formed fused ring system or systems constructed from the respective benzene ring e or f and the additional ring or rings formed by adjacent substituents each include or consist of in total 9 to 30 ring atoms, out of which 1 to 3 atoms may be heteroatoms independently of each other selected from N, O, and S.

In a preferred embodiment of the invention, R^{A}, R^{B}, R^{X}, and R¹ to R⁸ are independently of each other selected from the group consisting of: hydrogen, deuterium, Me, ⁱPr, ^{t}Bu, CN, CF₃, SiMe₃, SiPh₃,
Ph, which is optionally substituted with one or more substituents independently selected from the group consisting of deuterium, Me, ⁱPr, ^{t}Bu, CN, CF₃, and Ph,
and N(Ph)₂;
wherein one pair selected from R² and R³ as well as R^{X} and R⁷ optionally forms a group Z², which is at each occurrence independently of each other selected from the group consisting of: CR¹²R¹³, C═O, NR¹², O, SiR¹²R¹³, and S;
wherein, optionally, one or more pair of adjacent groups selected from R¹ and R², R³ and R⁴, R⁴ and R⁵, R⁵ and R⁶, R⁶ and R⁷, R⁷ and R⁸, R⁸ and R^{X}, R^{X} and R^{B}, R^{B} and R^{A}, and R^{A} and R¹ form an aliphatic or aromatic, carbo- or heterocyclic ring system which is fused to the adjacent benzene ring e or f of Formula II and optionally substituted with one or more substituents independently of each other selected from the group consisting of: deuterium, Me, ⁱPr, ^{t}Bu, CN, CF₃, and
Ph, which is optionally substituted with one or more substituents independently of each other selected from deuterium, Me, ⁱPr, ^{t}Bu, CN, CF₃, and Ph;
wherein the optionally so-formed fused ring system or systems constructed from the respective benzene ring e or f and the additional ring or rings formed by adjacent substituents each include or consist of in total 9 to 30 ring atoms, out of which 1 to 3 atoms may be heteroatoms independently of each other selected from N, O, and S.

In an even more preferred embodiment of the invention, R^{A}, R^{B}, R^{X}, and R¹ to R⁸ are independently of each other selected from the group consisting of: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph,
wherein one pair selected from R² and R³ as well as R^{X} and R⁷ optionally forms a group Z², which is at each occurrence independently of each other selected from the group consisting of: CR¹²R¹³, C═O, NR¹², O, SiR¹²R¹³, and S;
wherein, optionally, one or more pair of adjacent groups selected from R¹ and R², R³ and R⁴, R⁴ and R⁵, R⁵ and R⁶, R⁶ and R⁷, R⁷ and R⁸, R⁸ and R^{X}, R^{X} and R^{B}, R^{B} and R^{A}, and R^{A} and R¹ form an aliphatic or aromatic, carbocyclic or heterocyclic ring system which is fused to the adjacent benzene ring e or f of Formula II and optionally substituted with one or more substituents independently of each other selected from the group consisting of: deuterium, Me, ⁱPr, ^{t}Bu, CN, CF₃, and
Ph, which is optionally substituted with one or more substituents independently of each other selected from deuterium, Me, ⁱPr, ^{t}Bu, CN, CF₃;
wherein the optionally so-formed fused ring system or systems constructed from the respective benzene ring e or f and the additional ring or rings formed by adjacent substituents each include or consist of in total 9 to 30 ring atoms, out of which 1 to 3 atoms may be heteroatoms independently of each other selected from N, O, and S.

In a still even more preferred embodiment of the invention, R^{A}, R^{B}, R^{X}, and R¹ to R⁸ are independently of each other selected from the group consisting of: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph,
wherein one pair selected from R² and R³ as well as R^{X} and R⁷ optionally forms a group Z², which is at each occurrence independently of each other selected from the group consisting of: CR¹²R¹³, NR¹², O, and S;
wherein, optionally, one or more pair of adjacent groups selected from R¹ and R², R³ and R⁴, R⁴ and R⁵, R⁵ and R⁶, R⁶ and R⁷, R⁷ and R⁸, R⁸ and R^{X}, R^{X} and R^{B}, R^{B} and R^{A}, and R^{A} and R¹ form an aliphatic or aromatic, carbocyclic or heterocyclic ring system which is fused to the adjacent benzene ring e or f of Formula II and optionally substituted with one or more substituents independently of each other selected from the group consisting of: deuterium, Me, ⁱPr, ^{t}Bu, CN, CF₃,
and Ph, which is optionally substituted with one or more substituents independently of each other selected from deuterium, Me, ⁱPr, ^{t}Bu, CN, CF₃;
wherein the optionally so-formed fused ring system or systems constructed from the respective benzene ring e or f and the additional ring or rings formed by adjacent substituents each include or consist of in total 9 to 30 ring atoms, out of which 1 to 3 atoms may be heteroatoms independently of each other selected from N, O, and S.

In a still even more preferred embodiment of the invention, R^{A}, R^{B}, R^{X}, and R¹ to R⁸ are independently of each other selected from the group consisting of: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph,
wherein one pair selected from R² and R³ as well as R^{X} and R⁷ optionally forms a group Z², which is at each occurrence independently of each other selected from the group consisting of: CR¹²R¹³, NR¹², and O;
wherein, optionally, one or more pair of adjacent groups selected from R¹ and R², R³ and R⁴, R⁴ and R⁵, R⁵ and R⁶, R⁶ and R⁷, R⁷ and R⁸, R⁸ and R^{X}, R^{X} and R^{B}, R^{B} and R^{A}, and R^{A} and R¹ form an aliphatic or aromatic, carbocyclic or heterocyclic ring system which is fused to the adjacent benzene ring e or f of Formula II and optionally substituted with one or more substituents independently of each other selected from the group consisting of: deuterium, Me, ⁱPr, ^{t}Bu, CN, CF₃, and Ph;
wherein the optionally so-formed fused ring system or systems constructed from the respective benzene ring e or f and the additional ring or rings formed by adjacent substituents each include or consist of in total 9 to 30 ring atoms, out of which 1 to 3 atoms may be heteroatoms independently of each other selected from N, O, and S.

In a particularly preferred embodiment of the invention, R^{A}, R^{B}, R^{X}, and R¹ to R⁸ are independently of each other selected from the group consisting of: hydrogen, deuterium, Me, ⁱPr, ^{t}Bu, and
Ph, which is optionally substituted with one or more substituents independently selected from the group consisting of deuterium, Me, ⁱPr, ^{t}Bu, and Ph,
wherein one pair selected from R² and R³ as well as R^{X} and R⁷ optionally forms a group Z², which is at each occurrence independently of each other selected from the group consisting of: CR¹²R¹³, NR¹², and O;
wherein, optionally, one or more pair of adjacent groups selected from R¹ and R², R³ and R⁴, R⁴ and R⁵, R⁵ and R⁶, R⁶ and R⁷, R⁷ and R⁸, R⁸ and R^{X}, R^{X} and R^{B}, R^{B} and R^{A}, and R^{A} and R¹ form an aliphatic or aromatic, carbocyclic or heterocyclic ring system which is fused to the adjacent benzene ring e or f of Formula II and optionally substituted with one or more substituents independently of each other selected from the group consisting of: deuterium, Me, ⁱPr, ^{t}Bu, and Ph;
wherein the optionally so-formed fused ring system or systems constructed from the respective benzene ring e or f and the additional ring or rings formed by adjacent substituents each include or consist of in total 9 to 30 ring atoms, out of which 1 to 3 atoms may be heteroatoms independently of each other selected from N, O, and S.

In one embodiment of the invention, R¹² and R¹³ are at each occurrence independently of each other selected from the group consisting of: hydrogen, deuterium, OPh, SPh, CF₃, CN, F, Si(C₁-C₅-alkyl)₃, Si(Ph)₃,
C₁-C₅-alkyl,
wherein optionally one or more hydrogen atoms are independently substituted by deuterium, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂,
N(C₃-C₁₇-heteroaryl)₂; and
N(C₃-C₁₇-heteroaryl)(C₆-C₁₈-aryl);

wherein, optionally, two substituents selected from R¹² and R¹³ form an aliphatic or aromatic carbo- or heterocyclic ring system including up 5 to 30 ring atoms, out of which 1 to 3 atoms may be heteroatoms independently of each other selected from N, O, and S.

In a preferred embodiment of the invention, R¹² and R¹³ are at each occurrence independently of each other selected from the group consisting of: hydrogen, deuterium, Me, ⁱPr, ^{t}Bu, CN, CF₃, SiMe₃, SiPh₃,
Ph, which is optionally substituted with one or more substituents independently selected from the group consisting of deuterium, Me, ⁱPr, ^{t}Bu, CN, CF₃, and Ph,
and N(Ph)₂;
wherein, optionally, two substituents selected from R¹² and R¹³ form an aliphatic or aromatic carbo- or heterocyclic ring system including up 5 to 30 ring atoms, out of which 1 to 3 atoms may be heteroatoms independently of each other selected from N, O, and S.

In an even more preferred embodiment of the invention, R¹² and R¹³ are at each occurrence independently of each other selected from the group consisting of: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph,
wherein, optionally, two substituents selected from R¹² and R¹³ form an aliphatic or aromatic carbocyclic ring system including up 5 to 30 ring atoms.

In a still even more preferred embodiment of the invention, R¹² and R¹³ are at each occurrence independently of each other selected from the group consisting of: hydrogen, deuterium, Me, ⁱPr, ^{t}Bu, and
Ph, which is optionally substituted with one or more substituents independently selected from the group consisting of deuterium, Me, ⁱPr, ^{t}Bu, and Ph,
wherein, optionally, two substituents selected from R¹² and R¹³ form an aliphatic or aromatic carbocyclic ring system including up 5 to 30 ring atoms.

In a particularly preferred embodiment of the invention, R¹² and R¹³ are at each occurrence independently of each other selected from the group consisting of: hydrogen, deuterium, Me, ⁱPr, ^{t}Bu, and Ph,
wherein, optionally, two substituents selected from R¹² and R¹³ form an aliphatic or aromatic carbocyclic ring system including up 5 to 30 ring atoms.

In one embodiment of the invention, the first chemical moiety includes or consists of a structure according to Formula I-a, I-b, I-c, I-d, I-e, I-f, I-g, I-h, I-i, I-j, I-k, I-m, I-n, I-o, I-p, I-q, I-r, I-s, I-t, I-u, I-v, I-w, I-x or I-y:

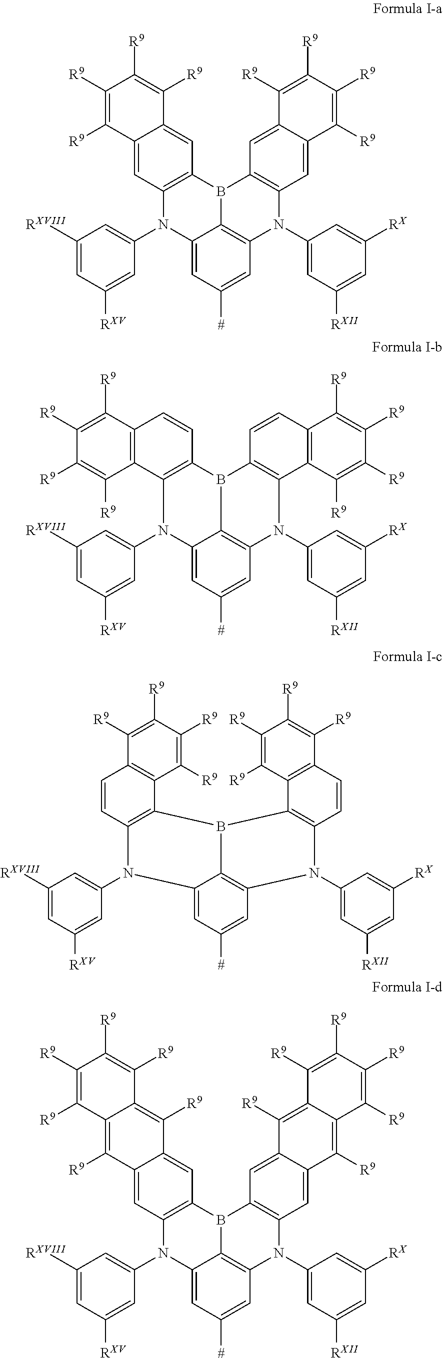

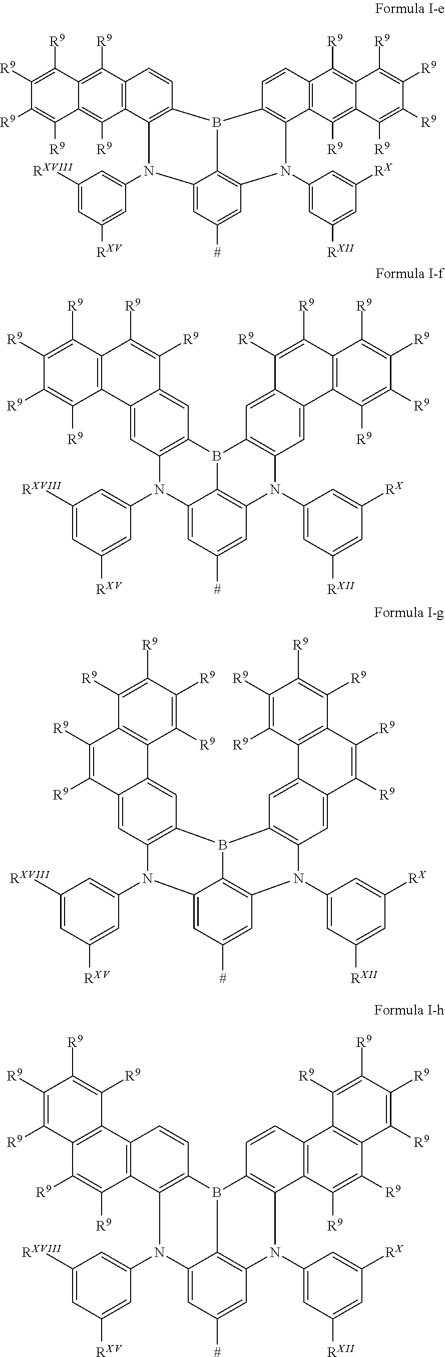

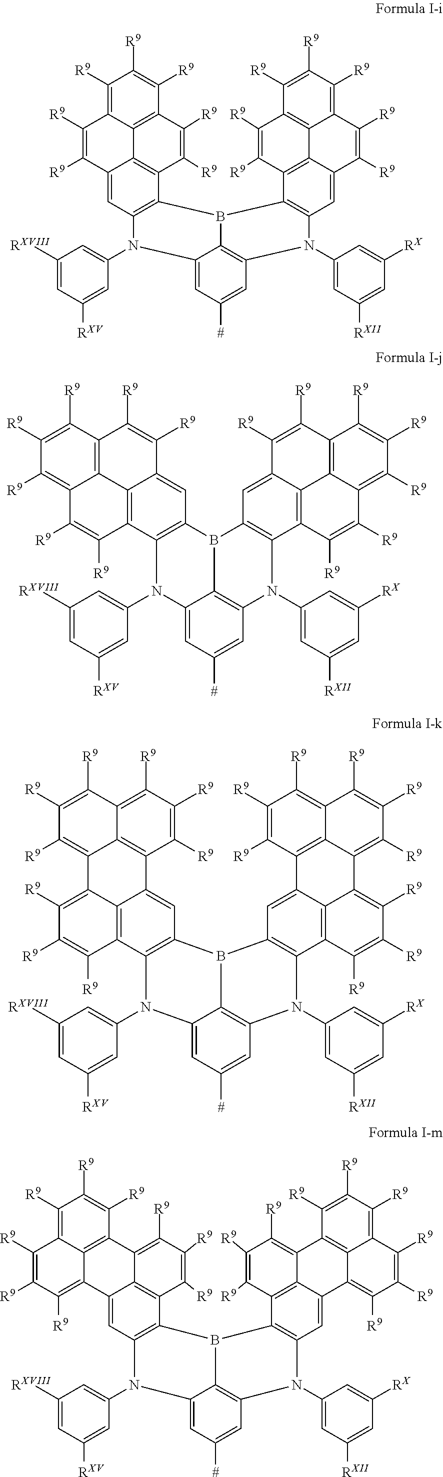

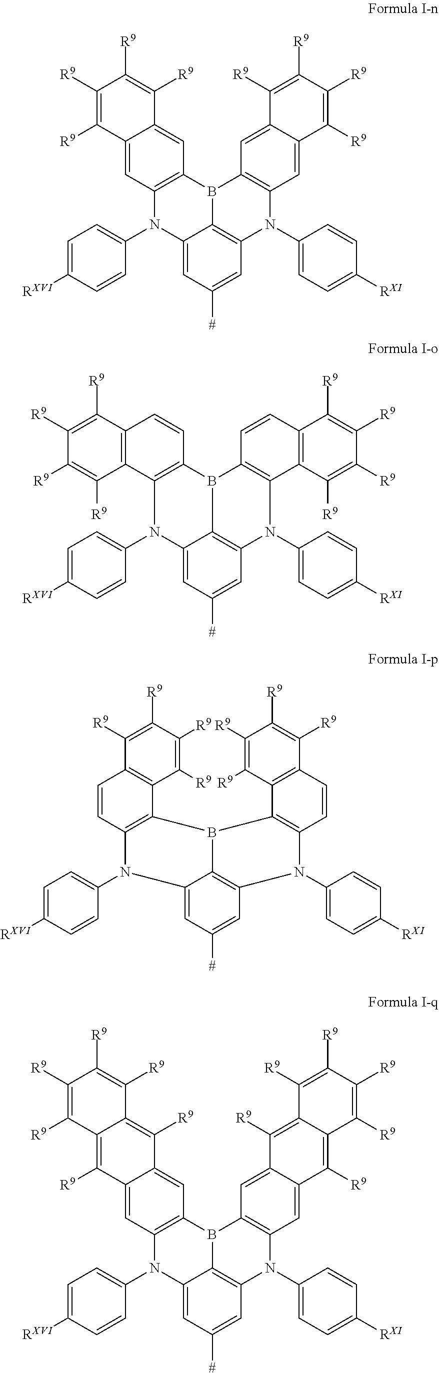

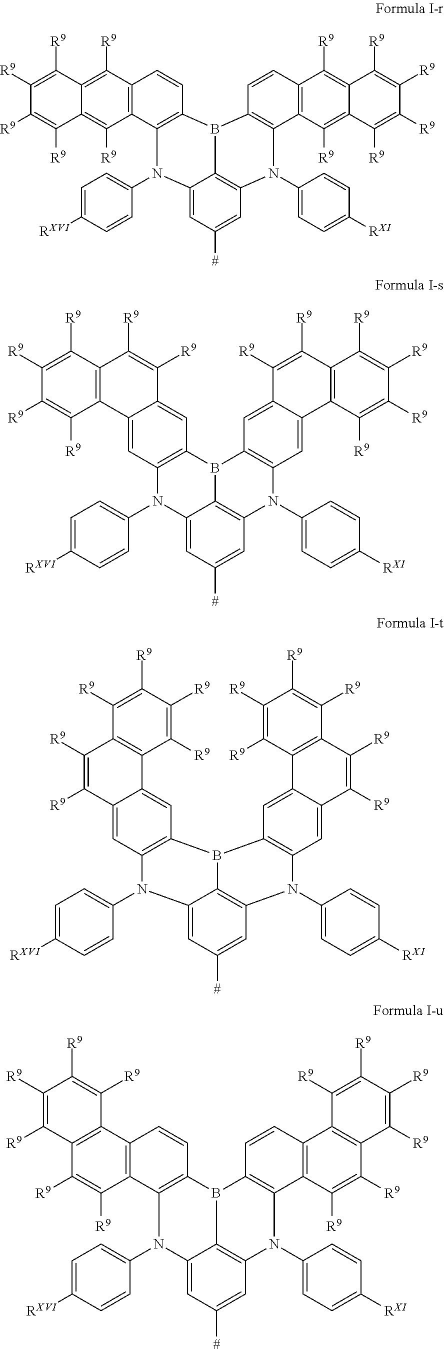

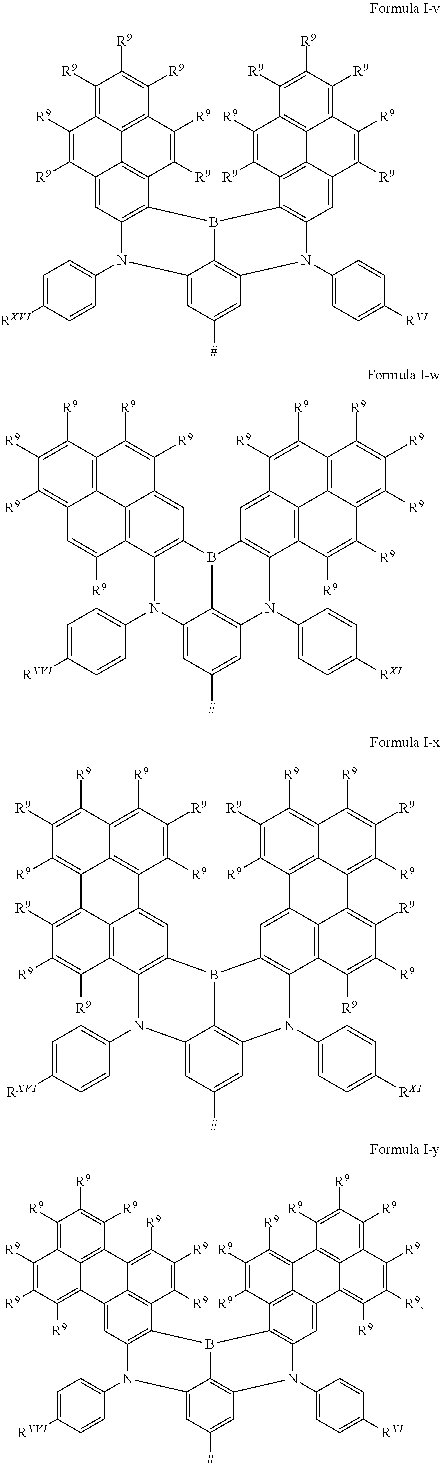

wherein R⁹ is at each occurrence independently selected from the group consisting of: deuterium, Me, ⁱPr, ^{t}Bu, CN, CF₃, and

Ph, which is optionally substituted with one or more substituents independently selected from the group consisting of deuterium, Me, ⁱPr, ^{t}Bu, CN, CF₃, and Ph.

In a preferred embodiment of the invention, the first chemical moiety includes or consists of a structure according to Formula I-a, I-b, I-c, I-d, I-e, I-f, I-g, I-h, I-i, I-j, I-k, I-m, I-n, I-o, I-p, I-q, I-r, I-s, I-t, I-u, I-v, I-w, I-x or I-y, wherein R⁹ is at each occurrence hydrogen or deuterium.

In one embodiment of the invention, the first chemical moiety includes or consists of a structure according to Formula I-a, I-b, I-d, I-e, I-f, I-i, I-j, I-k, I-m, I-n, I-o, I-q, I-r, I-s, I-v, I-w, I-x or I-y.

In a preferred embodiment of the invention, the first chemical moiety includes or consists of a structure according to Formula I-a, I-b, I-d, I-e, I-f, I-i, I-j, I-k, I-m, I-n, I-o, I-q, I-r, I-s, I-v, I-w, I-x or I-y, wherein R⁹ is at each occurrence hydrogen or deuterium.

In an even more preferred embodiment of the invention, the first chemical moiety includes or consists of a structure according to Formula I-a, I-d, I-f, I-n, I-q or I-s.

In a still even more preferred embodiment of the invention, the first chemical moiety includes or consists of a structure according to Formula I-a, I-d, I-f, I-n, I-q or I-s, wherein R⁹ is at each occurrence hydrogen or deuterium.

In a still even more preferred embodiment of the invention, the first chemical moiety includes or consists of a structure according to Formula I-a or I-n.

In a particularly preferred embodiment of the invention, the first chemical moiety includes or consists of a structure according to Formula I-a or I-n, wherein R⁹ is at each occurrence hydrogen or deuterium.

In one embodiment of the invention, the second chemical moiety includes or consists of a structure according to Formula II-a or II-b:

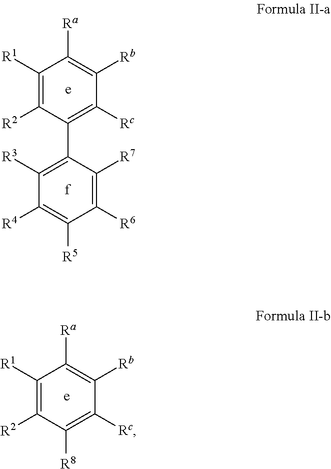

wherein the aforementioned definitions apply.

In one embodiment of the invention, the second chemical moiety includes or consists of a structure according to Formula II-a, wherein the aforementioned definitions apply.

In one embodiment of the invention, the second chemical moiety includes or consists of a structure according to Formula II-b, wherein the aforementioned definitions apply.

In a preferred embodiment of the invention, the second chemical moiety includes or consists of a structure according to any of Formulas II-a-1, II-a-2, II-a-3, II-a-4, II-a-5, II-a-6, II-a-7, II-b-1, II-b-2, II-b-3, II-b-4, II-b-5, II-b-6, II-b-7, II-b-8, II-b-9, II-b-10, II-b-11, II-b-12, and II-b-13,

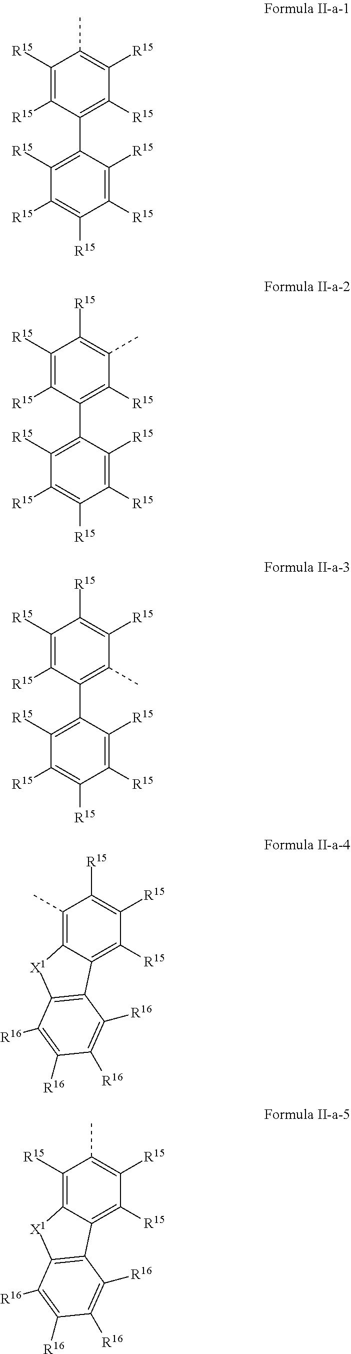

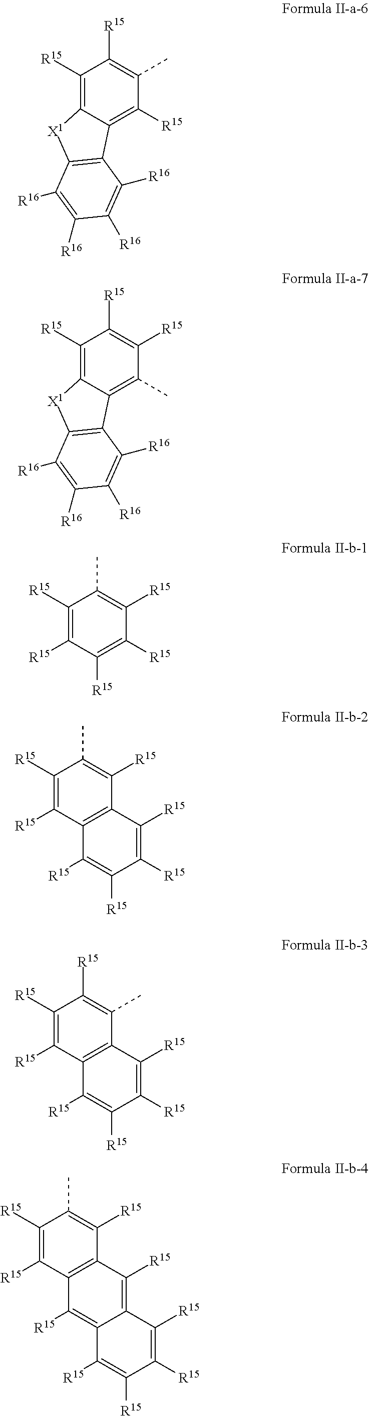

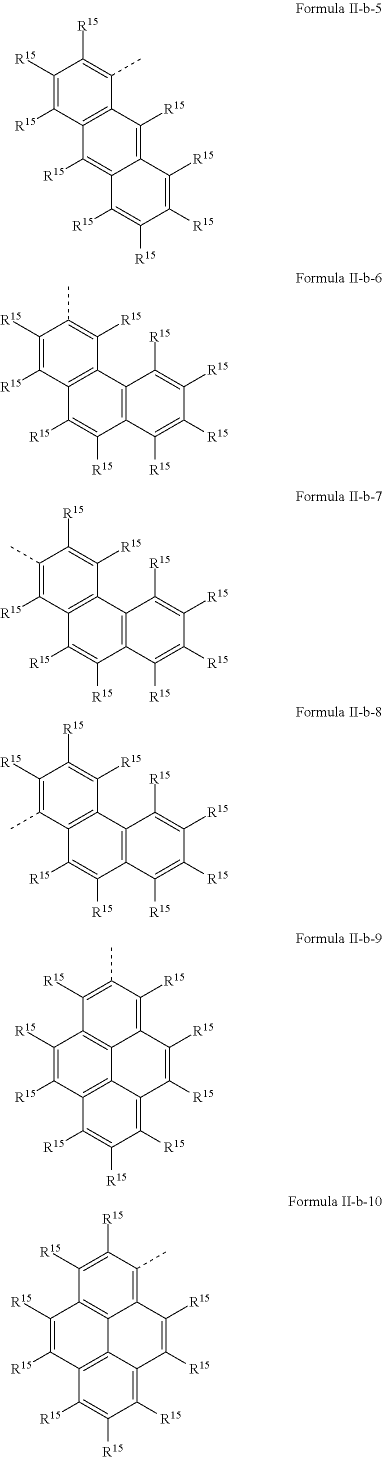

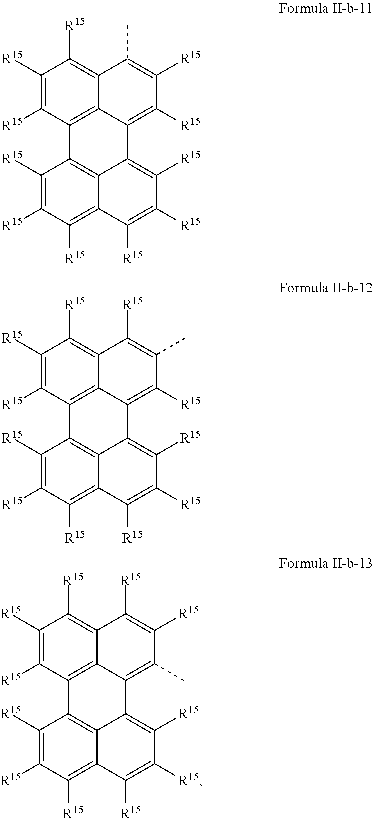

wherein,
the dashed line indicates a single bond linking the second chemical moiety to the first chemical moiety;
X¹ is selected from the group consisting of C(R¹⁷)₂, NR¹⁵, O, and S;
R¹⁵, R¹⁶, and R¹⁷ are at each occurrence independently of each other selected from the group consisting of: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein two or more adjacent groups R¹⁶ may optionally form an aliphatic or aromatic, carbocyclic or heterocyclic ring system which is fused to the structure according to Formula II-a-4, II-a-5, II-a-6 or II-a-7; wherein, in this case, the whole second chemical moiety according to Formula II-a-4, II-a-5, II-a-6 or II-a-7 including the additional ring or rings formed by adjacent substituents includes 16 to 30 ring atoms, out of which 1 to 3 atoms may be heteroatoms independently of each other selected from N, O, and S;
wherein the optionally so formed additional rings may be substituted with one or more substituents independently of each other selected from: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph; and
wherein, optionally, two substituents R¹⁷ form an aliphatic or aromatic carbocyclic ring system including 5 to 30 carbon atoms, which may optionally be substituted with one or more substituents independently of each other selected from: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph.

In an even more preferred embodiment of the invention, the second chemical moiety includes or consists of a structure according to any of Formulas II-a-1, II-a-2, II-a-3, II-a-4, II-a-5, II-a-6, II-a-7, II-b-1, II-b-2, II-b-3, II-b-4, II-b-5, II-b-6, II-b-7, II-b-8, II-b-9, II-b-10, II-b-11, II-b-12, and II-b-13, wherein
X¹ is selected from the group consisting of C(R¹⁷)₂, NR¹⁵, O, and S;
R¹⁵, R¹⁶, and R¹⁷ are at each occurrence independently of each other selected from the group consisting of: hydrogen, deuterium, Me, ⁱPr, ^{t}Bu, CN, CF₃, and
Ph, which is optionally substituted with one or more substituents independently selected from the group consisting of deuterium, Me, ⁱPr, ^{t}Bu, CN, CF₃, and Ph;
wherein two or more adjacent groups R¹⁶ may optionally form an aliphatic or aromatic, carbocyclic or heterocyclic ring system which is fused to the structure according to Formula II-a-4, II-a-5, II-a-6 or II-a-7; wherein, in this case, the whole second chemical moiety according to Formula II-a-4, II-a-5, II-a-6 or II-a-7 including the additional ring or rings formed by adjacent substituents includes 16 to 30 ring atoms, out of which 1 to 3 atoms may be heteroatoms independently of each other selected from N, O, and S;
wherein, optionally, two substituents R¹⁷ form an aliphatic or aromatic carbocyclic ring system including 5 to 30 carbon atoms.

In one embodiment of the invention, the second chemical moiety includes or consists of a structure according to any of Formulas II-a-1, II-a-2, II-a-3, II-a-4, II-a-5, II-a-6, II-a-7, II-b-1, II-b-2, II-b-3, II-b-4, II-b-5, II-b-9, and II-b-10, wherein the aforementioned definitions apply.

In a preferred embodiment of the invention, the first chemical moiety includes or consists of a structure according to Formula I-a, I-b, I-c, I-d, I-e, I-f, I-g, I-h, I-i, I-j, I-k, I-m, I-n, I-o, I-p, I-q, I-r, I-s, I-t, I-u, I-v, I-w, I-x or I-y, for which the aforementioned definitions apply, and the second chemical moiety includes or consists of a structure according to Formula II-a-1, II-a-2, II-a-3, II-a-4, II-a-5, II-a-6, II-a-7, II-b-1, II-b-2, II-b-3, II-b-4, II-b-5, II-b-6, II-b-7, II-b-8, II-b-9, II-b-10, l-b-11, II-b-12 or II-b-13, for which the aforementioned definitions apply.

In an even more preferred embodiment of the invention, the first chemical moiety includes or consists of a structure according to Formula I-a, I-b, I-c, I-d, I-e, I-f, I-i, I-j, I-k, I-m, I-n, I-o, I-q, I-r, I-s, I-v, I-w, I-x or I-y, for which the aforementioned definitions apply, and the second chemical moiety includes or consists of a structure according to Formula II-a-1, II-a-2, II-a-3, II-a-4, II-a-5, II-a-6, II-a-7, II-b-1, II-b-2, II-b-3, II-b-4, II-b-5, II-b-6, II-b-7, II-b-8, II-b-9, II-b-10, II-b-11, II-b-12 or II-b-13, for which the aforementioned definitions apply.

In a still even more preferred embodiment of the invention, the first chemical moiety includes or consists of a structure according to Formula I-a, I-d, I-f, I-n, I-q or I-s, for which the aforementioned definitions apply, and the second chemical moiety includes or consists of a structure according to Formula II-a-1, II-a-2, II-a-3, II-a-4, II-a-5, II-a-6, II-a-7, II-b-1, II-b-2, II-b-3, II-b-4, II-b-5, II-b-6, I-b-7, II-b-8, II-b-9, II-b-10, II-b-11, I-b-12 or II-b-13, for which the aforementioned definitions apply.

In a still even more preferred embodiment of the invention, the first chemical moiety includes or consists of a structure according to Formula I-a, I-d, I-f, I-n, I-q or I-s, for which the aforementioned definitions apply, and the second chemical moiety includes or consists of a structure according to Formula II-a-1, II-a-2, II-a-3, II-a-4, II-a-5, II-a-6, II-a-7, II-b-1, II-b-2, II-b-3, II-b-4, II-b-5, II-b-9, or II-b-10, for which the aforementioned definitions apply.

In a particularly preferred embodiment of the invention, the first chemical moiety includes or consists of a structure according to Formula I-a or I-n, for which the aforementioned definitions apply, and the second chemical moiety includes or consists of a structure according to Formula II-a-1, II-a-2, II-a-3, II-a-4, II-a-5, II-a-6, II-a-7, II-b-1, II-b-2, II-b-3, II-b-4, II-b-5, II-b-9, or |I-b-10, for which the aforementioned definitions apply.

As used throughout the present application, the term “cyclic group” may be understood in the broadest sense as any mono-, bi- or polycyclic moieties.

As used throughout the present application, the terms “ring” and “ring system” may be understood in the broadest sense as any mono-, bi- or polycyclic moieties.

The term “ring atom” refers to any atom which is part of the cyclic core of a ring or a ring structure, and not part of a substituent optionally attached to the cyclic core.

As used throughout the present application, the term “carbocycle” may be understood in the broadest sense as any cyclic group in which the cyclic core structure includes only carbon atoms that may of course be substituted with hydrogen or any other substituents defined in the specific embodiments of the invention. It is understood that the term “carbocyclic” as adjective refers to cyclic groups in which the cyclic core structure includes only carbon atoms that may of course be substituted with hydrogen or any other substituents defined in the specific embodiments of the invention.

As used throughout the present application, the term “heterocycle” may be understood in the broadest sense as any cyclic group in which the cyclic core structure includes not just carbon atoms, but also at least one heteroatom. It is understood that the term “heterocyclic” as adjective refers to cyclic groups in which the cyclic core structure includes not just carbon atoms, but also at least one heteroatom. The heteroatoms may, unless stated otherwise in specific embodiments, at each occurrence be the same or different and be individually selected from the group consisting of N, O, and S. All carbon atoms or heteroatoms included in a heterocycle in the context of the invention may of course be substituted with hydrogen or any other substituents defined in the specific embodiments of the invention.

As used throughout the present application, the term “aromatic ring system” may be understood in the broadest sense as any bi- or polycyclic aromatic moiety.

As used throughout the present application, the term “heteroaromatic ring system” may be understood in the broadest sense as any bi- or polycyclic heteroaromatic moiety.

As used throughout the present application, the term “fused” when referring to aromatic or heteroaromatic ring systems means that the aromatic or hetroaromatic rings that are “fused” share at least one bond that is part of both ring systems. For example naphthalene (or naphthyl when referred to as substituent) or benzothiophene (or benzothiphenyl when referred to as substituent) are considered fused aromatic ring systems in the context of the present invention, in which two benzene rings (for naphthalene) or a thiophene and a benzene (for benzothiophene) share one bond. It is also understood that sharing a bond in this context includes sharing the two atoms that build up the respective bond and that fused aromatic or heteroaromatic ring systems can be understood as one aromatic or heteroaromatic system. Additionally, it is understood, that more than one bond may be shared by the aromatic or heteroaromatic rings building up a fused aromatic or heteroaromatic ring system (e.g. in pyrene). Furthermore, it will be understood that aliphatic ring systems may also be fused and that this has the same meaning as for aromatic or heteroaromatic ring systems, with the exception of course, that fused aliphatic ring systems are not aromatic.

As used throughout the present application, the terms “aryl” and “aromatic” may be understood in the broadest sense as any mono-, bi- or polycyclic aromatic moieties. Accordingly, unless specified differently in specific embodiments of the invention, an aryl group contains 6 to 60 aromatic ring atoms, and a heteroaryl group contains 5 to 60 aromatic ring atoms, of which at least one is a heteroatom. Notwithstanding, throughout the application the number of aromatic ring carbon atoms may be given as subscripted number in the definition of certain substituents. In particular, the heteroaromatic ring includes one to three heteroatoms. Again, the terms “heteroaryl” and “heteroaromatic” may be understood in the broadest sense as any mono-, bi- or polycyclic hetero-aromatic moieties that include at least one heteroatom. The heteroatoms may, unless stated otherwise in specific embodiments, at each occurrence be the same or different and be individually selected from the group consisting of N, O, and S. Accordingly, the term “arylene” refers to a divalent substituent that bears two binding sites to other molecular structures and thereby serving as a linker structure. In case, a group in the exemplary embodiments is defined differently from the definitions given here, for example, the number of aromatic ring atoms or number of heteroatoms differs from the given definition, the definition in the exemplary embodiments is to be applied. According to the invention, a condensed (annulated) aromatic or heteroaromatic polycycle is built of two or more single aromatic or heteroaromatic cycles, which formed the polycycle via a condensation reaction.

In particular, as used throughout the present application the term “aryl group” or “heteroaryl group” includes groups which can be bound via any position of the aromatic or heteroaromatic group, derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene; pyrrole, indole, isoindole, carbazole, indolocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazole, phenanthroxazole, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine and benzothiadiazole or combinations of the abovementioned groups.

As used throughout the present application, the terms “adjacent substituents” or “adjacent groups” refer to substituents or groups that may bond to either the same or to neighbouring atoms.

As used throughout the present application, the term “aliphatic” when referring to ring systems may be understood in the broadest sense and means that none of the rings that build up the ring system is an aromatic or heteroaromatic ring. It is understood that such an aliphatic ring system may be fused to one or more aromatic rings so that some (but not all) carbon- or heteroatoms included in the core structure of the aliphatic ring system are part of an attached aromatic ring.

As used above and herein, the term “alkyl group” may be understood in the broadest sense as any linear, branched, or cyclic alkyl substituent. In particular, the term alkyl includes the substituents methyl (Me), ethyl (Et), n-propyl (ⁿPr), i-propyl (ⁱPr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl and 1-(n-decyl)-cyclohex-1-yl.

As used above and herein, the term “alkenyl” includes linear, branched, and cyclic alkenyl substituents. The term alkenyl group exemplarily includes the substituents ethenyl, propenyl, butenyl, pentenyl, cyclopentenyl, hexenyl, cyclohexenyl, heptenyl, cycloheptenyl, octenyl, cyclooctenyl or cyclooctadienyl.

As used above and herein, the term “alkynyl” includes linear, branched, and cyclic alkynyl substituents. The term alkynyl group exemplarily includes ethynyl, propynyl, butynyl, pentynyl, hexynyl, heptynyl or octynyl.

As used above and herein, the term “alkoxy” includes linear, branched, and cyclic alkoxy substituents. The term alkoxy group exemplarily includes methoxy, ethoxy, n-propoxy, i-propoxy, n-butoxy, i-butoxy, s-butoxy, t-butoxy and 2-methylbutoxy.

As used above and herein, the term “thioalkoxy” includes linear, branched, and cyclic thioalkoxy substituents, in which the O of the exemplarily alkoxy groups is replaced by S.

As used above and herein, the terms “halogen” and “halo” may be understood in the broadest sense as being preferably fluorine, chlorine, bromine or iodine.

It is understood that when a molecular fragment is described as being a substituent or otherwise attached to another moiety, its name may be written as if it were a fragment (e.g. naphthyl, dibenzofuryl) or as if it were the whole molecule (e.g. naphthalene, dibenzofuran). As used herein, these different ways of designating a substituent or attached fragment are considered to be equivalent.

All hydrogen atoms (H) included in any structure referred to herein may at each occurrence independently of each other, and without this being indicated specifically, be replaced by deuterium (D). The replacement of hydrogen by deuterium is common practice and obvious for the person skilled in the art.

In one embodiment, the organic molecules according to the invention have an excited state lifetime of not more than 250 μs, of not more than 150 μs, in particular of not more than 100 μs, more preferably of not more than 80 μs or not more than 60 μs, even more preferably of not more than 40 μs in a film of poly(methyl methacrylate) (PMMA) with 2% by weight of the organic molecule at room temperature (i.e. approximately 25° C.).

In one embodiment of the invention, the organic molecules according to the invention represent thermally-activated delayed fluorescence (TADF) emitters, which exhibit a ΔE_{ST} value, which corresponds to the energy difference between the first excited singlet state (S1) and the first excited triplet state (T1), of less than 5000 cm⁻¹, preferably less than 3000 cm⁻¹, more preferably less than 1500 cm⁻¹, even more preferably less than 1000 cm⁻¹ or even less than 500 cm⁻¹.

In a further embodiment of the invention, the organic molecules according to the invention have an emission peak in the visible or nearest ultraviolet range, i.e., in the range of a wavelength of from 420 to 580 nm, with a full width at half maximum of less than 0.30 eV, preferably less than 0.28 eV, more preferably less than 0.25 eV, even more preferably less than 0.23 eV or even less than 0.20 eV in a film of poly(methyl methacrylate) (PMMA) with 2% by weight of the organic molecule at room temperature (i.e. approximately 25° C.).

Orbital and excited state energies can be determined either by means of experimental methods or by calculations employing quantum-chemical methods, in particular density functional theory calculations. The energy of the highest occupied molecular orbital E^{HOMO} is determined by methods known to the person skilled in the art from cyclic voltammetry measurements with an accuracy of 0.1 eV. The energy of the lowest unoccupied molecular orbital E^{LUMO} is determined as the onset of the absorption spectrum.

The onset of an absorption spectrum is determined by computing the intersection of the tangent to the absorption spectrum with the x-axis. The tangent to the absorption spectrum is set at the low-energy side of the absorption band and at the point at half maximum of the maximum intensity of the absorption spectrum.

Unless stated otherwise, the energy of the first excited triplet state T1 is determined from the onset the phosphorescence spectrum at 77K (steady-state spectrum; film of 2% by weight of the emitter in PMMA).

Unless stated otherwise, the energy of the first excited singlet state S1 is determined from the onset the fluorescence spectrum at room temperature (i.e. approx. 25° C.; steady-state spectrum; film of 2% by weight of the emitter in PMMA).

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

The ΔE_{ST} value, which corresponds to the energy difference between the first excited singlet state (S1) and the first excited triplet state (T1), was determined based on the first excited singlet state energy and the first excited triplet state energy, which were determined as stated above.

A further aspect of the invention relates to the use of an organic molecule according to the invention as a luminescent emitter or as an absorber, and/or as a host material and/or as an electron transport material, and/or as a hole injection material, and/or as a hole blocking material in an optoelectronic device.

The optoelectronic device may be understood in the broadest sense as any device based on organic materials that is suitable for emitting light in the visible or nearest ultraviolet (UV) range, i.e., in the wavelength range from 380 nm to 800 nm. More preferably, the optoelectronic device may be able to emit light in the visible range, i.e., of from 400 nm to 800 nm.

In the context of such use, the optoelectronic device is more particularly selected from the group consisting of:
organic light-emitting diodes (OLEDs),
light-emitting electrochemical cells,
OLED sensors, in particular in gas and vapor sensors not hermetically shielded to the outside,
organic diodes,
organic solar cells,
organic transistors,
organic field-effect transistors,
organic lasers, and
down-conversion elements.

A light-emitting electrochemical cell includes three layers, namely a cathode, an anode, and an active layer, which contains the organic molecule according to the invention.

In a preferred embodiment in the context of such use, the optoelectronic device is a device selected from the group consisting of an organic light emitting diode (OLED), a light emitting electrochemical cell (LEC), an organic laser, and a light-emitting transistor.

In one embodiment, the light-emitting layer of an organic light-emitting diode includes the organic molecules according to the invention.

In one embodiment, the light-emitting layer of an organic light-emitting diode includes not only the organic molecules according to the invention but also a host material whose triplet (T1) and singlet (S1) energy levels are energetically higher than the triplet (T1) and singlet (S1) energy levels of the organic molecule.

A further aspect of the invention relates to a composition including or consisting of:
(a) the organic molecule of the invention, in particular in the form of an emitter and/or a host, and
(b) one or more emitter and/or host materials, which differ from the organic molecule of the invention, and
(c) optionally, one or more dyes and/or one or more solvents.

In one embodiment, the light-emitting layer includes (or essentially consists of) a composition including or consisting of:
(a) at least one organic molecule according to the invention, in particular in the form of an emitter and/or a host, and
(b) one or more emitter and/or host materials, which differ from the organic molecule according to the invention and
(c) optional one or more dyes and/or one or more solvents.

In a further embodiment of the invention, the composition has a photoluminescence quantum yield (PLQY) of more than 10%, preferably more than 20%, more preferably more than 40%, even more preferably more than 60% or even more than 70% at room temperature.

In a particular embodiment, the light-emitting layer EML includes (or essentially consists of) a composition including or consisting of:
(i) 0.1-10% by weight, preferably 0.5-5% by weight, in particular 1-3% by weight, of one or more organic molecules according to the invention;
(ii) 5-99% by weight, preferably 15-85% by weight, in particular 20-75% by weight, of at least one host compound H; and
(iii) 0.9-94.9% by weight, preferably 14.5-80% by weight, in particular 24-77% by weight, of at least one further host compound D with a structure differing from the structure of the molecules according to the invention; and
(iv) optionally 0-94% by weight, preferably 0-65% by weight, in particular 0-50% by weight, of a solvent; and
(v) optionally 0-30% by weight, in particular 0-20% by weight, preferably 0-5% by weight, of at least one further emitter molecule F with a structure differing from the structure of the molecules according to the invention.

Preferably, energy can be transferred from the host compound H to the one or more organic molecules of the invention, in particular transferred from the first excited triplet state T1(H) of the host compound H to the first excited triplet state T1(E) of the one or more organic molecules according to the invention and/or from the first excited singlet state S1(H) of the host compound H to the first excited singlet state S1(E) of the one or more organic molecules according to the invention.

In one embodiment, the host compound H has a highest occupied molecular orbital HOMO(H) having an energy E^{HOMO}(H) in the range of from −5 eV to −6.5 eV and one organic molecule according to the invention E has a highest occupied molecular orbital HOMO(E) having an energy E^{HOMO}(E), wherein E^{HOMO}(H)>E^{HOMO}(E).

In a further embodiment, the host compound H has a lowest unoccupied molecular orbital LUMO(H) having an energy E^{LUMO}(H) and the one organic molecule according to the invention E has a lowest unoccupied molecular orbital LUMO(E) having an energy E^{LUMO}(E), wherein E^{LUMO}(H)>E^{LUMO}(E).

In one embodiment of the organic light-emitting diode of the invention, the host compound H has a highest occupied molecular orbital HOMO(H) having an energy E^{HOMO}(H) in the range of from −5 eV to −6.5 eV and the at least one further host compound D has a highest occupied molecular orbital HOMO(D) having an energy E^{HOMO}(D), wherein E^{HOMO}(H)>E^{HOMO}(D). The relation E^{HOMO}(H)>E^{HOMO}(D) favors an efficient hole transport.

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D), wherein E^{LUMO}(H)>E^{LUMO}(D). The relation E^{LUMO}(H)>E^{LUMO}(D) favors an efficient electron transport.

In one embodiment of the organic light-emitting diode of the invention, the host compound H has a highest occupied molecular orbital HOMO(H) having an energy E^{HOMO}(H) and a lowest unoccupied molecular orbital LUMO(H) having an energy E^{LUMO}(H), and
the at least one further host compound D has a highest occupied molecular orbital HOMO(D) having an energy E^{HOMO}(D) and a lowest unoccupied molecular orbital LUMO(D) having an energy E^{LUMO}(D),
the organic molecule E of the invention has a highest occupied molecular orbital HOMO(E) having an energy E^{HOMO}(E) and a lowest unoccupied molecular orbital LUMO(E) having an energy E^{LUMO}(E),
wherein
E^{HOMO}(H)>E^{HOMO}(D) and the difference between the energy level of the highest occupied molecular orbital HOMO(E) of organic molecule according to the invention (E^{HOMO}(E)) and the energy level of the highest occupied molecular orbital HOMO(H) of the host compound H (E^{HOMO}(H)) is between 0.5 eV and 0.5 eV, more preferably between −0.3 eV and 0.3 eV, even more preferably between −0.2 eV and 0.2 eV or even between −0.1 eV and 0.1 eV; and
E^{LUMO}(H)>E^{LUMO}(D) and the difference between the energy level of the lowest unoccupied molecular orbital LUMO(E) of organic molecule according to the invention (E^{LUMO}(E)) and the lowest unoccupied molecular orbital LUMO(D) of the at least one further host compound D (E^{LUMO}(D)) is between −0.5 eV and 0.5 eV, more preferably between −0.3 eV and 0.3 eV, even more preferably between −0.2 eV and 0.2 eV or even between −0.1 eV and 0.1 eV.

In one embodiment of the invention the host compound D and/or the host compound H is a thermally-activated delayed fluorescence (TADF)-material. TADF materials exhibit a ΔE_{ST} value, which corresponds to the energy difference between the first excited singlet state (S1) and the first excited triplet state (T1), of less than 2500 cm⁻¹. Preferably the TADF material exhibits a ΔE_{ST} value of less than 3000 cm⁻¹, more preferably less than 1500 cm⁻¹, even more preferably less than 1000 cm⁻¹ or even less than 500 cm⁻¹.

In one embodiment, the host compound D is a TADF material and the host compound H exhibits a ΔE_{ST} value of more than 2500 cm⁻¹. In a particular embodiment, the host compound D is a TADF material and the host compound H is selected from group consisting of CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole.

In one embodiment, the host compound H is a TADF material and the host compound D exhibits a ΔE_{ST} value of more than 2500 cm⁻¹. In a particular embodiment, the host compound H is a TADF material and the host compound D is selected from group consisting of T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine).

### Optoelectronic Devices

In a further aspect, the invention relates to an optoelectronic device including an organic molecule or a composition as described herein, more particularly in the form of a device selected from the group consisting of organic light-emitting diode (OLED), light-emitting electrochemical cell, OLED sensor (particularly gas and vapor sensors not hermetically externally shielded), organic diode, organic solar cell, organic transistor, organic field-effect transistor, organic laser and down-conversion element.

In a preferred embodiment, the optoelectronic device is a device selected from the group consisting of an organic light emitting diode (OLED), a light emitting electrochemical cell (LEC), and a light-emitting transistor.

In one embodiment of the optoelectronic device of the invention, the organic molecule according to the invention is used as emission material in a light-emitting layer EML.

In one embodiment of the optoelectronic device of the invention, the light-emitting layer EML consists of the composition according to the invention described herein.

When the optoelectronic device is an OLED, it may, for example, exhibit the following layer structure:
1. substrate
2. anode layer, A
3. hole injection layer, HIL
4. hole transport layer, HTL
5. electron blocking layer, EBL
6. emitting layer, EML
7. hole blocking layer, HBL
8. electron transport layer, ETL
9. electron injection layer, EIL
10. cathode layer, C
wherein the OLED includes each layer only optionally, different layers may be merged and the OLED may include more than one layer of each layer type defined above.

Furthermore, the optoelectronic device may optionally include one or more protective layers protecting the device from damaging exposure to harmful species in the environment including, exemplarily moisture, vapor and/or gases.

In one embodiment of the invention, the optoelectronic device is an OLED, which exhibits the following inverted layer structure:
1. substrate
2. cathode layer, C
3. electron injection layer, EIL
4. electron transport layer, ETL
5. hole blocking layer, HBL
6. emitting layer, EML
7. electron blocking layer, EBL
8. hole transport layer, HTL
9. hole injection layer, HIL
10. anode layer, A,
wherein the OLED with an inverted layer structure includes each layer only optionally, different layers may be merged and the OLED may include more than one layer of each layer types defined above.

In one embodiment of the invention, the optoelectronic device is an OLED, which may exhibit stacked architecture. In this architecture, contrary to the typical arrangement, where the OLEDs are placed side by side, the individual units are stacked on top of each other. Blended light may be generated with OLEDs exhibiting a stacked architecture, in particular white light may be generated by stacking blue, green and red OLEDs. Furthermore, the OLED exhibiting a stacked architecture may optionally include a charge generation layer (CGL), which is typically located between two OLED subunits and typically consists of an n-doped layer and a p-doped layer with the n-doped layer of one CGL being typically located closer to the anode layer.

In one embodiment of the invention, the optoelectronic device is an OLED, which includes two or more emission layers between anode and cathode. In particular, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

The substrate may be formed by any material or composition of materials. Most frequently, glass slides are used as substrates. Alternatively, thin metal layers (e.g., copper, gold, silver or aluminum films) or plastic films or slides may be used. This may allow a higher degree of flexibility. The anode layer A is mostly composed of materials allowing to obtain an (essentially) transparent film. As at least one of the two electrodes should be (essentially) transparent in order to allow light emission from the OLED, either the anode layer A or the cathode layer C is transparent. Preferably, the anode layer A includes a large content or even consists of transparent conductive oxides (TCOs). Such anode layer A may exemplarily include indium tin oxide, aluminum zinc oxide, fluorine doped tin oxide, indium zinc oxide, PbO, SnO, zirconium oxide, molybdenum oxide, vanadium oxide, tungsten oxide, graphite, doped Si, doped Ge, doped GaAs, doped polyaniline, doped polypyrrole and/or doped polythiophene.

Preferably, the anode layer A (essentially) consists of indium tin oxide (ITO) (e.g., (InO₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (i.e., holes) in that the transport of the quasi charge carriers from the TCO to the hole transport layer (HTL) is facilitated. The hole injection layer (HIL) may include poly-3,4-ethylenedioxy thiophene (PEDOT), polystyrene sulfonate (PSS), MoO₂, V₂O₅, CuPC or CuI, in particular a mixture of PEDOT and PSS. The hole injection layer (HIL) may also prevent the diffusion of metals from the anode layer A into the hole transport layer (HTL). The HIL may exemplarily include PEDOT:PSS (poly-3,4-ethylenedioxy thiophene:polystyrene sulfonate), PEDOT (poly-3,4-ethylenedioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N,N′-nis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,11-hexaazatriphenylen-hexacarbonitrile) and/or Spiro-NPD (N,N′-diphenyl-N,N′-bis-(1-naphthyl)-9,9′-spirobifluorene-2,7-diamine).

Adjacent to the anode layer A or hole injection layer (HIL) typically a hole transport layer (HTL) is located. Herein, any hole transport compound may be used. Exemplarily, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). Preferably, hole transport compounds bear comparably high energy levels of their triplet states T1. Exemplarily the hole transport layer (HTL) may include a star-shaped heterocycle such as tris(4-carbazoyl-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN and/or TrisPcz (9,9′-diphenyl-6-(9-phenyl-9H-carbazol-3-yl)-9H,9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide or tungsten oxide may exemplarily be used as the inorganic dopant. Tetrafluorotetracyanoquinodimethane (F4-TCNQ), copper-pentafluorobenzoate (Cu(I)pFBz) or transition metal complexes may exemplarily be used as the organic dopant.

The EBL may exemplarily include mCP (1,3-bis(carbazol-9-yl)benzene), TCTA, 2-TNATA, mCBP (3,3-di(9H-carbazol-9-yl)biphenyl), tris-Pcz, CzSi (9-(4-tert-butylphenyl)-3,6-bis(triphenylsilyl)-9H-carbazole), and/or DCB (N,N′-dicarbazolyl-1,4-dimethylbenzene).

Adjacent to the hole transport layer (HTL), typically, the light-emitting layer EML is located. The light-emitting layer EML includes at least one light emitting molecule. Particular, the EML includes at least one light emitting molecule according to the invention. Typically, the EML additionally includes one or more host material. Exemplarily, the host material is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl]ether oxide), 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). The host material typically should be selected to exhibit first triplet (T1) and first singlet (S1) energy levels, which are energetically higher than the first triplet (T1) and first singlet (S1) energy levels of the organic molecule.

In one embodiment of the invention, the EML includes a so-called mixed-host system with at least one hole-dominant host and one electron-dominant host. In a particular embodiment, the EML includes exactly one light emitting molecule species according to the invention and a mixed-host system including T2T as electron-dominant host and a host selected from CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as the hole-dominant host. In a further embodiment the EML includes 50-80% by weight, preferably 60-75% by weight of a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole; 10-45% by weight, preferably 15-30% by weight of T2T and 5-40% by weight, preferably 10-30% by weight of light emitting molecule according to the invention.

Adjacent to the light-emitting layer EML an electron transport layer (ETL) may be located. Herein, any electron transporter may be used. Exemplarily, compounds poor of electrons such as, e.g., benzimidazoles, pyridines, triazoles, oxadiazoles (e.g., 1,3,4-oxadiazole), phosphinoxides and sulfone, may be used. An electron transporter may also be a star-shaped heterocycle such as 1,3,5-tri(1-phenyl-1H-benzo[d]imidazol-2-yl)phenyl (TPBi). The ETL may include NBphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), BPyTP2 (2,7-di(2,2′-bipyridin-5-yl)triphenyle), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a hole blocking layer (HBL) is introduced.

The HBL may, for example, include BCP (2,9-dimethyl-4,7-diphenyl-1,10-phenanthroline=Bathocuproine), BAlq (bis(8-hydroxy-2-methylquinoline)-(4-phenylphenoxy)aluminum), NBphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/1,3,5-tris(carbazol)-9-yl)benzene).

A cathode layer C may be located adjacent to the electron transport layer (ETL). For example, the cathode layer C may include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) non-transparent metals such as Mg, Ca or Al. Alternatively or additionally, the cathode layer C may also include graphite and or carbon nanotubes (CNTs). Alternatively, the cathode layer C may also consist of nanoscalic silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO and/or NaF.

Optionally, also the electron transport layer (ETL) and/or a hole blocking layer (HBL) may include one or more host compounds.

In order to modify the emission spectrum and/or the absorption spectrum of the light-emitting layer EML further, the light-emitting layer EML may further include one or more further emitter molecule F. Such an emitter molecule F may be any emitter molecule known in the art. Preferably such an emitter molecule F is a molecule with a structure differing from the structure of the molecules according to the invention. The emitter molecule F may optionally be a TADF emitter. Alternatively, the emitter molecule F may optionally be a fluorescent and/or phosphorescent emitter molecule which is able to shift the emission spectrum and/or the absorption spectrum of the light-emitting layer EML. For example, the triplet and/or singlet excitons may be transferred from the emitter molecule according to the invention to the emitter molecule F before relaxing to the ground state S0 by emitting light typically red-shifted in comparison to the light emitted by emitter molecule E. Optionally, the emitter molecule F may also provoke two-photon effects (i.e., the absorption of two photons of half the energy of the absorption maximum).

Optionally, an optoelectronic device (e.g., an OLED) may, for example, be an essentially white optoelectronic device. Exemplarily such white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:
violet: wavelength range of >380-420 nm;
deep blue: wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to emitter molecules, such colors refer to the emission maximum. Therefore, exemplarily, a deep blue emitter has an emission maximum in the range of from >420 to 480 nm, a sky-blue emitter has an emission maximum in the range of from >480 to 500 nm, a green emitter has an emission maximum in a range of from >500 to 560 nm, and a red emitter has an emission maximum in a range of from >620 to 800 nm.

A further aspect of the present invention relates to an OLED, which emits light with CIEx and CIEy color coordinates close to the CIEx (=0.131) and CIEy (=0.046) color coordinates of the primary color blue (CIEx=0.131 and CIEy=0.046) as defined by ITU-R Recommendation BT.2020 (Rec. 2020) and thus is suited for the use in Ultra High Definition (UHD) displays, e.g. UHD-TVs. Accordingly, a further aspect of the present invention relates to an OLED, whose emission exhibits a CIEx color coordinate of between 0.02 and 0.30, preferably between 0.03 and 0.25, more preferably between 0.05 and 0.20 or even more preferably between 0.08 and 0.18 or even between 0.10 and 0.15 and/or a CIEy color coordinate of between 0.00 and 0.45, preferably between 0.01 and 0.30, more preferably between 0.02 and 0.20 or even more preferably between 0.03 and 0.15 or even between 0.04 and 0.10.

A further embodiment of the present invention relates to an OLED, which emits light with CIEx and CIEy color coordinates close to the CIEx (=0.170) and CIEy (=0.797) color coordinates of the primary color green (CIEx=0.170 and CIEy=0.797) as defined by ITU-R Recommendation BT.2020 (Rec. 2020) and thus is suited for the use in Ultra High Definition (UHD) displays, e.g. UHD-TVs. In this context, the term “close to” refers to the ranges of CIEx and CIEy coordinates provided at the end of this paragraph. In commercial applications, typically top-emitting (top-electrode is transparent) devices are used, whereas test devices as used throughout the present application represent bottom-emitting devices (bottom-electrode and substrate are transparent). Accordingly, a further aspect of the present invention relates to an OLED, whose emission exhibits a CIEx color coordinate of between 0.15 and 0.45 preferably between 0.15 and 0.35, more preferably between 0.15 and 0.30 or even more preferably between 0.15 and 0.25 or even between 0.15 and 0.20 and/or a CIEy color coordinate of between 0.60 and 0.92, preferably between 0.65 and 0.90, more preferably between 0.70 and 0.88 or even more preferably between 0.75 and 0.86 or even between 0.79 and 0.84.

A further embodiment of the present invention relates to an OLED, which emits light with CIEx and CIEy color coordinates close to the CIEx (=0.708) and CIEy (=0.292) color coordinates of the primary color red (CIEx=0.708 and CIEy=0.292) as defined by ITU-R Recommendation BT.2020 (Rec. 2020) and thus is suited for the use in Ultra High Definition (UHD) displays, e.g. UHD-TVs. In this context, the term “close to” refers to the ranges of CIEx and CIEy coordinates provided at the end of this paragraph. In commercial applications, typically top-emitting (top-electrode is transparent) devices are used, whereas test devices as used throughout the present application represent bottom-emitting devices (bottom-electrode and substrate are transparent). Accordingly, a further aspect of the present invention relates to an OLED, whose emission exhibits a CIEx color coordinate of between 0.60 and 0.88, preferably between 0.61 and 0.83, more preferably between 0.63 and 0.78 or even more preferably between 0.66 and 0.76 or even between 0.68 and 0.73 and/or a CIEy color coordinate of between 0.25 and 0.70, preferably between 0.26 and 0.55, more preferably between 0.27 and 0.45 or even more preferably between 0.28 and 0.40 or even between 0.29 and 0.35.

A further aspect of the present invention relates to an OLED, which exhibits an external quantum efficiency at 14500 cd/m² of more than 10%, more preferably of more than 13%, more preferably of more than 15%, even more preferably of more than 17% or even more than 20% and/or exhibits an emission maximum between 420 and 580 nm, more preferably between 440 and 560 nm, even more preferably between 470 and 550 nm, and particularly preferably between 500 and 540 nm and/or exhibits a LT97 value at 14500 cd/m² of more than 100 h, preferably more than 250 h, more preferably more than 500 h, even more preferably more than 750 h or even more than 1000 h.

The optoelectronic device, in particular the OLED according to the present invention can be manufactured by any means of vapor deposition and/or liquid processing. Accordingly, at least one layer is
prepared by means of a sublimation process,
prepared by means of an organic vapor phase deposition process,
prepared by means of a carrier gas sublimation process,
solution processed or
printed.

The methods used to manufacture the optoelectronic device, in particular the OLED according to the present invention are known in the art. The different layers are individually and successively deposited on a suitable substrate by means of subsequent deposition processes. The individual layers may be deposited using the same or differing deposition methods.

Vapor deposition processes exemplarily include thermal (co)evaporation, chemical vapor deposition and physical vapor deposition. For active matrix OLED display, an AMOLED backplane is used as substrate. The individual layer may be processed from solutions or dispersions employing adequate solvents. Solution deposition process exemplarily include spin coating, dip coating and jet printing. Liquid processing may optionally be carried out in an inert atmosphere (e.g., in a nitrogen atmosphere) and the solvent may optionally be completely or partially removed by means known in the state of the art.

### EXAMPLES

### General Synthesis Scheme

The general synthesis scheme provides a synthesis scheme for organic molecules according to the invention.

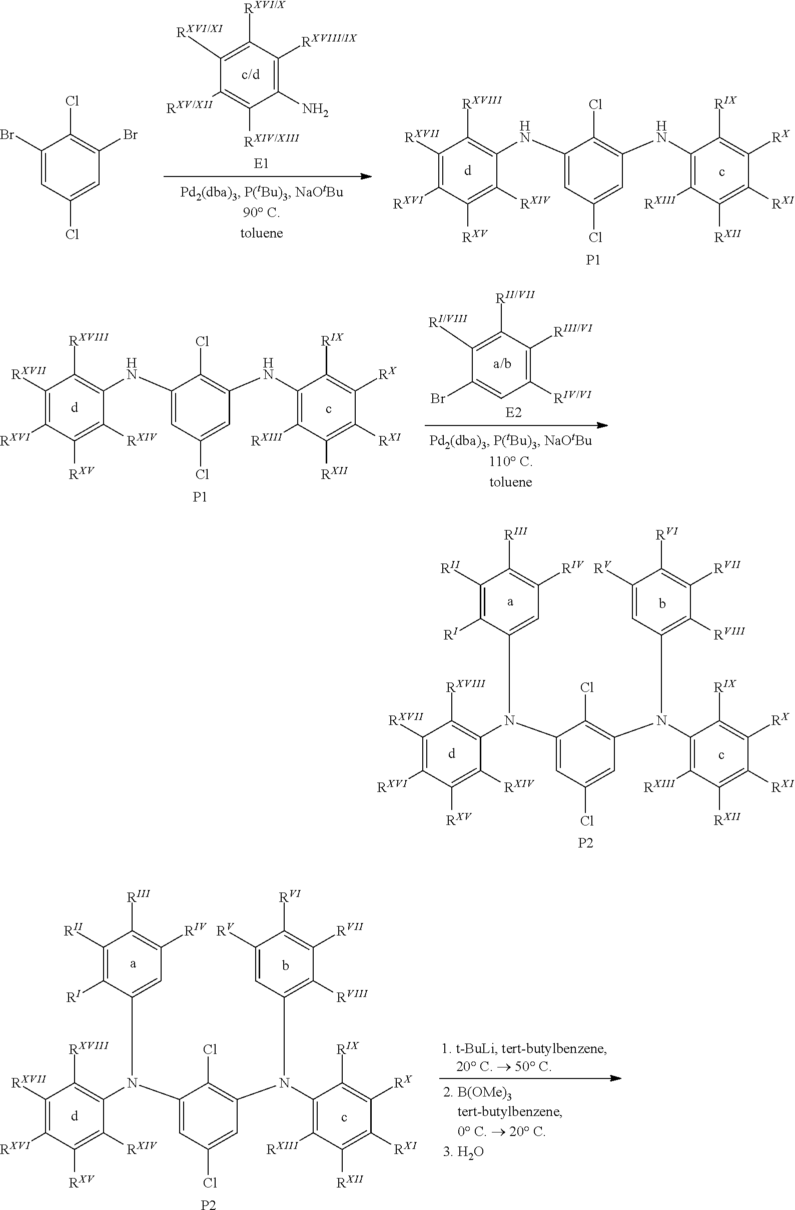

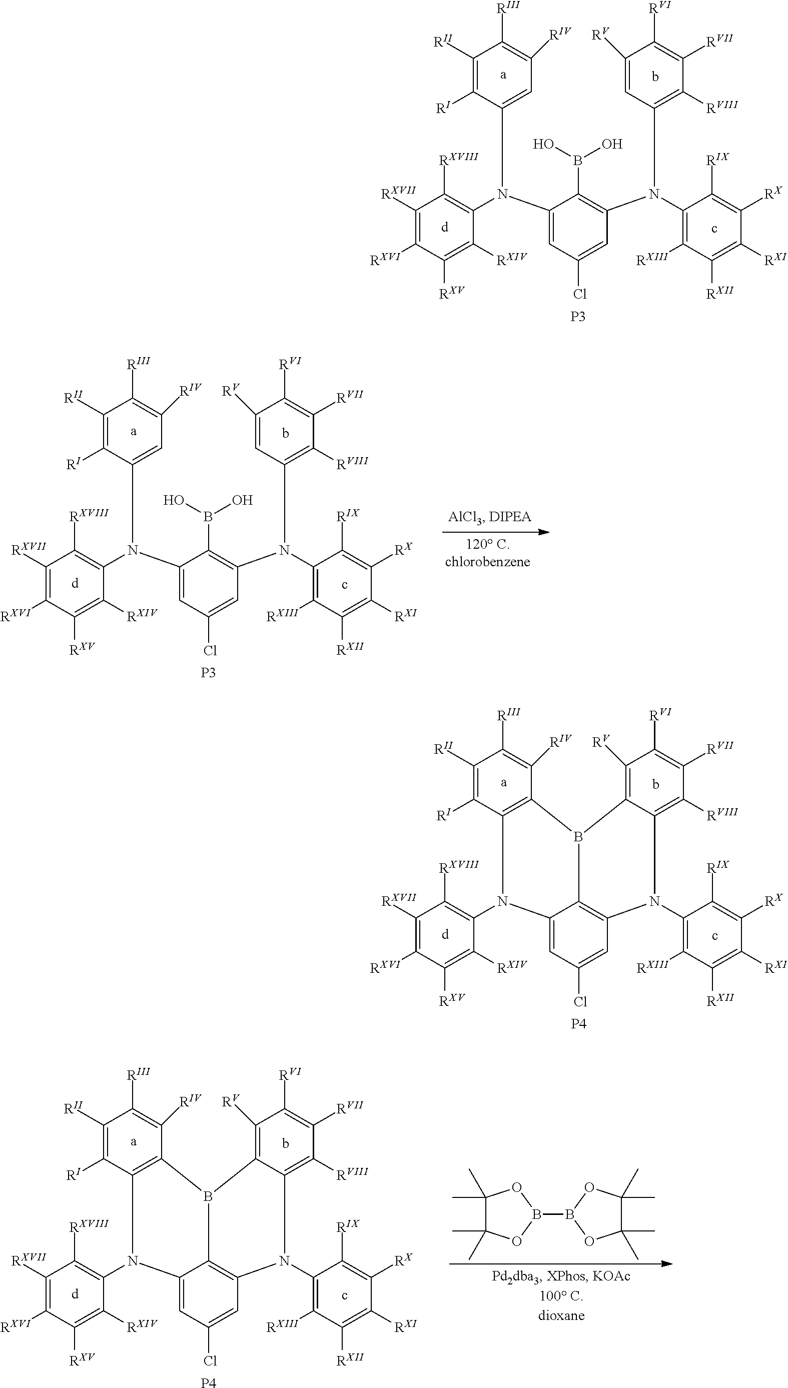

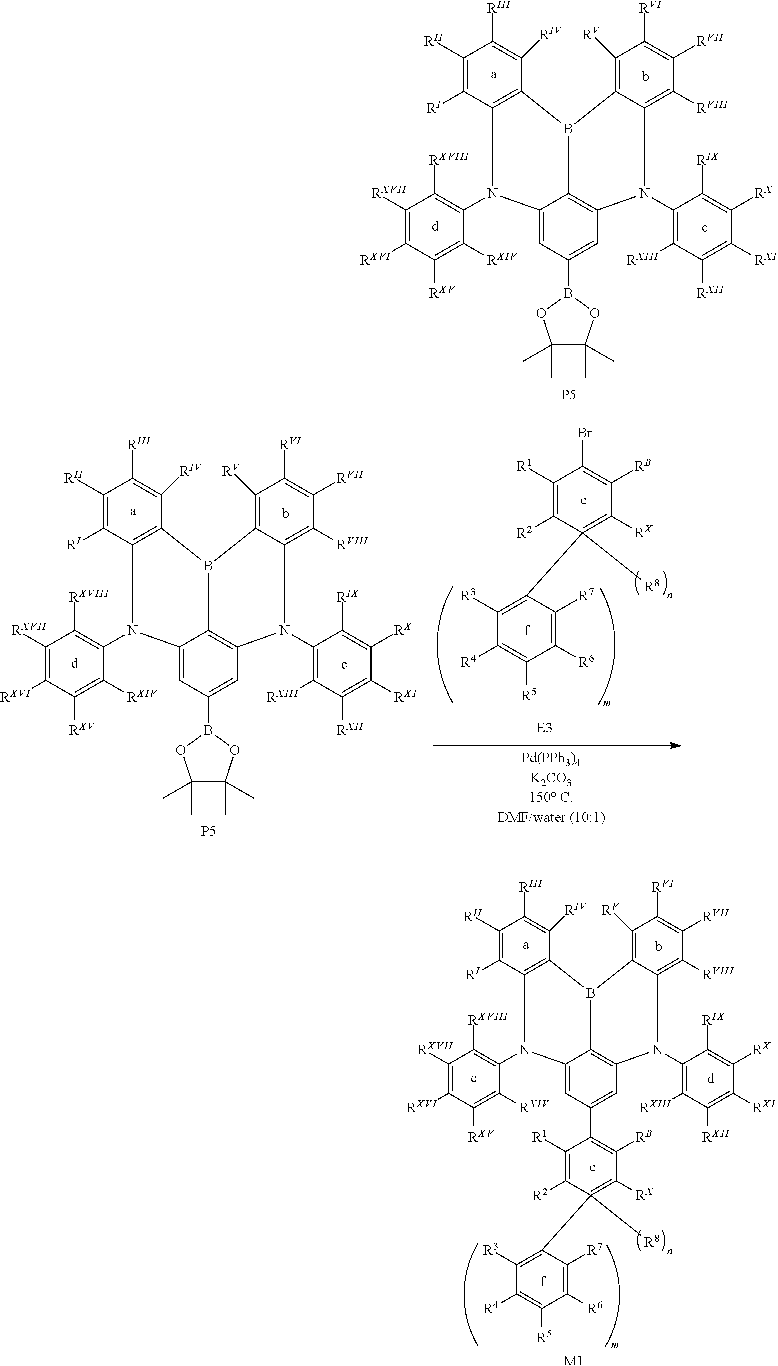

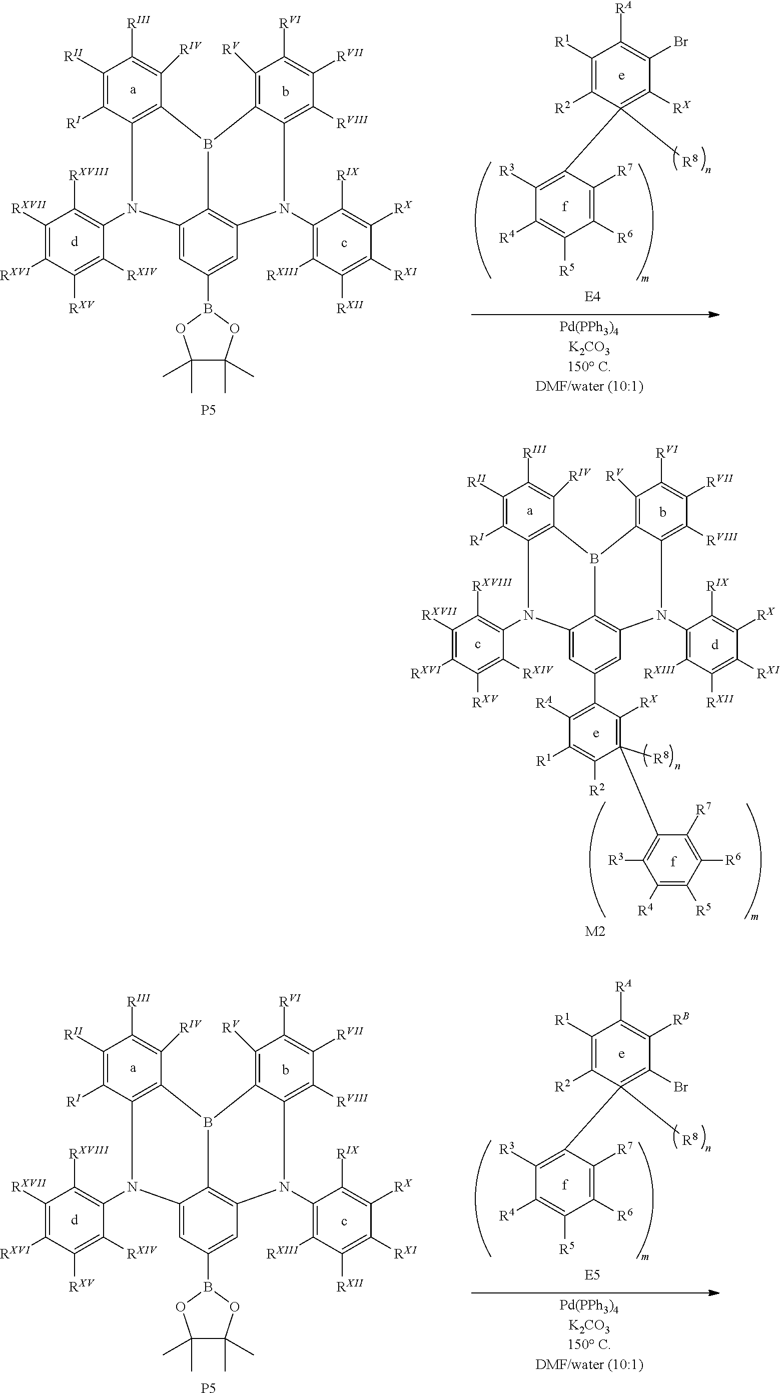

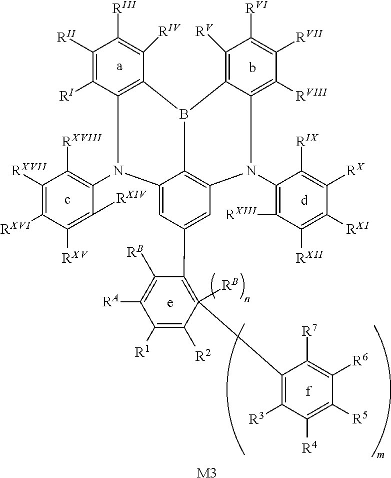

### General Procedure for Synthesis:

### Procedure 1

Under N₂ atmosphere, a two-necked flask is charged with 1,3-dibromo-5-chlorobenzene [81067-41-6] (1.0 equiv.), an arylamine E1 (2.2 equiv.), Pd₂(dba)₃ [51364-51-3] (0.01 equiv.), and sodium tert-butoxide [865-48-5] (4.0 equiv.). Dry toluene (5 mL/mmol of 1,3-dibromo-5-chlorobenzene) and tri-tert-butylphosphine [13716-12-6] (0.08 equiv.) are added and the resulting suspension is degassed for 10 min (nitrogen sparging). Subsequently, the mixture is heated at 90° C. until completion (usually 10-16 h). After cooling down to room temperature (rt), water is added, the phases separated, the aqueous layer extracted with ethyl acetate and the combined organic layers dried over MgSO₄, filtered and concentrated. The crude product is purified with column chromatography or recrystallization to obtain the corresponding product P1 as a solid.

### Procedure 2

Under N2 atmosphere, a two-necked flask is charged with P1 (1.0 equiv.), an aryl bromide E2 (2.2 equiv.), Pd₂(dba)₃ [51364-51-3] (0.02 equiv.), and sodium tert-butoxide [865-48-5] (2.3 equiv.). Dry toluene (16 mL/mmol of P1) and tri-tert-butylphosphine [131274-22-1] (0.08 equiv.) are added and the resulting suspension degassed for 10 min (nitrogen sparging). Subsequently, the mixture is heated at 110° C. until completion (usually 10-24 h). After cooling down to room temperature (rt), water is added, the phases separated, the aqueous layer extracted with ethyl acetate and the combined organic layers dried over MgSO₄, filtered and concentrated. The crude product is purified with column chromatography or recrystallization to obtain the corresponding product P2 as a solid.

### Procedure 3

Under nitrogen atmosphere, in a flame-dried two-necked flask, aryl chloride P2 (1.0 equiv.) is dissolved in degassed tert-butylbenzene. At 20° C., a solution of ted-butyllithium (1.9 M in pentane [594-19-4] (3.3 equiv.) is added dropwise. Subsequently, the mixture is stirred at 40° C. until completion of the lithiation (2-3 h). At 0° C., trimethyl borate [121-43-7] (6.0 equiv.) is injected slowly and stirring is continued at 20° C. until completion of the borylation (1-2 h). Subsequently, water is added and the resulting biphasic mixture stirred at 20° C. for 15 min. Ethyl acetate is added, the phases separated, and the combined organic layers dried over MgSO₄, filtered and concentrated. The crude product is purified by recrystallization to obtain the corresponding boronic acid P3 as a solid.

### Procedure 4

Under N₂ atmosphere, a two-necked flask is charged with the boronic acid P3 (1.0 equiv.). Dry chlorobenzene is added, followed by aluminum chloride [7446-70-0] (10 equiv.) and N,N-diisopropylethylamine (DIPEA) [7087-68-5] (10 equiv.). The resulting mixture is heated at 120° C. until completion of the reaction (1-2 h). After cooling down to rt, the reaction is quenched with ice water. Subsequently, the phases are separated, and the aqueous layer extracted with dichloromethane. The combined organic layers are dried over MgSO₄, filtered and concentrated. The residue is purified by filtration over a plug of silica, followed by precipitation from dichloromethane solution through addition of acetonitrile. The desired material P4, was obtained as a solid.

### Procedure 5

Under N₂ atmosphere, a two-necked flask is charged with P4 (1.0 equiv.), bis(pinacolato)diboron [73183-34-3] (5.0 equiv.), Pd₂(dba)₃ [51364-51-3] (0.02 equiv.), X-Phos [564483-18-7] (0.08 equiv.), and potassium acetate [127-08-2] (7.5 equiv.). Dry dioxane (20 mL/mmol of P4) is added and the resulting mixture degassed for 10 min (nitrogen sparging). Subsequently, the mixture is heated at 100° C. for 24 h. After cooling down to room temperature (rt), dichloromethane and water are added, the phases separated, the aqueous layer extracted with dichloromethane. The combined organic layers are stirred at rt with MgSO₄/Celite (kieselgur)/charcoal for 10 min, filtered and concentrated. The crude product is used for further conversion without purification. The desired boronic ester P5 is obtained as a solid.

### Procedure 6

Under N₂ atmosphere, a two-necked flask is charged with P5 (1.0 equiv.), a heteroaryl bromide E3, E4 or E5 (4.0 equiv.), Pd(PPha)₄ [14221-01-3] (0.1 equiv.) and potassium carbonate [584-08-7] (3.0 equiv.). A mixture of DMF and water (10:1 by volume, 60 mL/mmol of P5) is added and the resulting mixture degassed for 15 min (nitrogen sparging). Subsequently, the mixture is heated at 150° C. for 4-6 h. After cooling down to room temperature (rt), the mixture is poured into water. The precipitated solid was filtered off and rinsed with ethanol. The crude product is purified by recrystallization to obtain the corresponding product M1, M2 or M3 as a solid.

### Cyclic Voltammetry

Cyclic voltammograms are measured from solutions having concentration of 10⁻³ mol/L of the organic molecules in dichloromethane or a suitable solvent and a suitable supporting electrolyte (e.g. 0.1 mol/L of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

### Density Functional Theory Calculation

Molecular structures are optimized employing the BP86 functional and the resolution of identity approach (RI). Excitation energies are calculated using the (BP86) optimized structures employing Time-Dependent DFT (TD-DFT) methods. Orbital and excited state energies are calculated with the B3LYP functional. Def2-SVP basis sets (and an m4-grid for numerical integration were used. The Turbomole program package was used for all calculations.

### Photophysical Measurements

### Sample Pretreatment: Spin-Coating

Apparatus: Spin150, SPS euro.

The sample concentration is 0.2 mg/ml, dissolved in Toluene/DCM as suitable solvent.

Program: 7-30 sec. at 2000 U/min. After coating, the films are tried at 70° C. for 1 min.

### Absorption Measurements

A Thermo Scientific Evolution 201 UV-Visible Spectrophotometer is used to determine wavelength of the absorption maximum of the sample in the wavelength region above 270 nm. This wavelength is used as excitation wavelength for photoluminescence spectral and quantum yield measurements.

Photoluminescence Spectroscopy and Phosphorescence Spectroscopy For the analysis of Phosphorescence and Photoluminescence spectroscopy a fluorescence spectrometer “Fluoromax 4P” from Horiba is used.

Time-Resolved PL Spectroscopy in the μs-Range and ns-Range (FS5)

Time-resolved PL measurements were performed on a FS5 fluorescence spectrometer from Edinburgh Instruments. Compared to measurements on the HORIBA setup, better light gathering allows for an optimized signal to noise ratio, which favors the FS5 system especially for transient PL measurements of delayed fluorescence characteristics. As continuous light source, the spectrometer includes a 150 W xenon arc lamp and specific wavelengths may be selected by a Czemy-Turner monochromator. However, the standard measurements were instead performed using an external VPLED variable pulsed LED with an emission wavelength of 310 nm. The sample emission is directed towards a sensitive R928P photomultiplier tube (PMT), allowing the detection of single photons with a peak quantum efficiency of up to 25% in the spectral range between 200 nm to 870 nm. The detector is a temperature stabilized PMT, providing dark counts below 300 cps (counts per second). Finally, to determine the transient decay lifetime of the delayed fluorescence, a tail fit using three exponential functions is applied. By weighting the specific lifetimes τᵢ with their corresponding amplitudes Aᵢ,

$${τ}_{DF} = {\sum }_{i = 1}^{3} \frac{{A}_{i} {τ}_{i}}{{A}_{i}}$$

the delayed fluorescence lifetime T_{DF} is determined.

### Photoluminescence Quantum Yield Measurements

For photoluminescence quantum yield (PLQY) measurements an Absolute PL Quantum Yield Measurement C9920-03G system (Hamamatsu Photonics) is used. Quantum yields and CIE coordinates are determined using the software U6039-05 version 3.6.0.

Emission maxima are given in nm, quantum yields m in % and CIE coordinates as x,y values.

PLQY is determined using the following protocol:

Quality assurance: Anthracene in ethanol (known concentration) is used as reference

Excitation wavelength: the absorption maximum of the organic molecule is determined and the molecule is excited using this wavelength

### Measurement

Quantum yields are measured for sample of films (2% by weight of the emitter in PMMA) under nitrogen atmosphere. The yield is calculated using the equation:

$${Φ}_{PL} = \frac{{n}_{photon} , emitted}{{n}_{photon} , absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ}$$

wherein nₚₕₒₜₒₙ denotes the photon count and Int. denotes the intensity. For quality assurance, anthracene in ethanol (known concentration) is used as reference.

### Time-Correlated Single-Photon Counting (TCSPC)

Excited state population dynamics are determined employing Edinburgh Instruments FS5 Spectrofluoremeters, equipped with an emission monochromator, a temperature stabilized photomultiplier as detector unit and a pulsed LED (310 nm central wavelength, 910 μs pulse width) as excitation source. The samples are placed in a cuvette and flushed with nitrogen during the measurements.

### Full Decay Dynamics

The full excited state population decay dynamics over several orders of magnitude in time and signal intensity is achieved by carrying out TCSPC measurements in 4 time windows: 200 ns, 1 μs, and 20 μs, and a longer measurement spanning >80 μs. The measured time curves are then processed in the following way:

A background correction is applied by determining the average signal level before excitation and subtracting.

The time axes are aligned by taking the initial rise of the main signal as reference.

The curves are scaled onto each other using overlapping measurement time regions.

The processed curves are merged to one curve.

### Data Analysis

Data analysis was done using monoexponential and bi-exponential fitting of prompt fluorescence (PF) and delayed fluorescence (DF) decays separately. The ratio of delayed and prompt fluorescence (n-value) is calculated by the integration of respective photoluminescence decays in time.

$$\frac{\int {I}_{DF} ( t ) dt}{\int {I}_{PF} ( t ) dt} = n$$

The average excited state life time is calculated by taking the average of prompt and delayed fluorescence decay time, weighted with the respective contributions of PF and DF.

### Production and Characterization of Optoelectronic Devices

Via vacuum-deposition methods, optoelectronic devices, such as OLED devices including organic molecules according to the invention can be produced. If a layer contains more than one compound, the weight-percentage of one or more compounds is given in %. The total weight-percentage values amount to 100%, thus if a value is not given, the fraction of this compound equals to the difference between the given values and 100%.

The not fully optimized OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, and LT97 to the time point, at which the measured luminance decreased to 97% of the initial luminance etc.

Accelerated lifetime measurements are performed (e.g. applying increased current densities). Exemplarily LT80 values at 500 cd/m² are determined using the following equation:

$$LT 80 ( 500 \frac{{cd}^{2}}{{m}^{2}} ) = LT 80 ( {L}_{0} ) {( \frac{{L}_{0}}{500 \frac{{cd}^{2}}{{m}^{2}}} )}^{1.6}$$

wherein L₀ denotes the initial luminance at the applied current density.

The values correspond to the average of several pixels (typically two to eight), the standard deviation between these pixels is given. FIGS. 1-2 show the data series for one OLED pixel.

### HPLC-MS

This analysis is performed on an HPLC-MS by Agilent (HPLC1260 Infinity) with MS-detector

### (Single Quadrupole).

For example, a typical HPLC method is as follows: a reverse phase column 3.0 mm×100 mm, particle size 2.7 μm from Agilent (Poroshell 120EC-C18, 3.0×100 mm, 2.7 μm HPLC column) is used in the HPLC. The HPLC-MS measurements are performed at 45° C. and a typical gradient is as follows:

| Flow rate [ml/min] | Time [min] | A[%] | B[%] | C[%] |
|---|---|---|---|---|
| 2.1 | 0.0 | 40 | 50 | 10 |
| 2.1 | 1.00 | 40 | 50 | 10 |
| 2.1 | 3.50 | 10 | 65 | 25 |
| 2.1 | 6.00 | 10 | 40 | 50 |
| 2.1 | 8.00 | 10 | 10 | 80 |
| 2.1 | 11.50 | 10 | 10 | 80 |
| 2.1 | 11.51 | 40 | 50 | 10 |
| 2.1 | 12.50 | 40 | 50 | 10 |

using the following solvent mixtures (all solvents contain 0.1% (V/V) of formic acid:

| | | |
|---|---|---|
| Solvent A: | H₂O (10%) | MeCN (90%) |
| Solvent B: | H₂O (90%) | MeCN (10%) |
| Solvent C: | THF (50%) | MeCN (50%) |

An injection volume of 2 μL of a solution with a concentration of 0.5 mg/mL of the analyte is used for the measurements.

Ionization of the probe is performed using an atmospheric pressure chemical ionization (APCI) source either in positive (APCI +) or negative (APCI −) ionization mode or an atmospheric pressure photoionization (APPI) source.

### Example 1

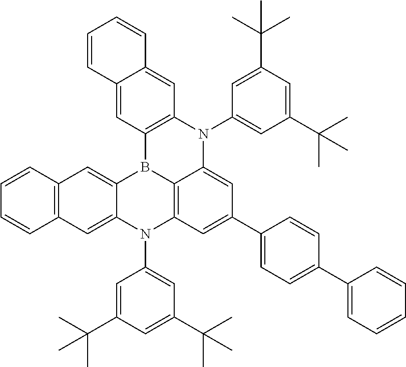

Example 1 was synthesized according to
Procedure 1 (78% yield), wherein 3,5-di-tert-butylaniline [2380-36-1] was used as compound E1;
Procedure 2 (59% yield);
Procedure 3 (27% yield);
Procedure 4 (59% yield);
Procedure 5 (quant. yield);
Procedure 6 (30% yield), wherein 2-bromobiphenyl [92-66-0] was used as compound E3.

MS (HPLC-MS): m/z (retention time)=898.0 (8.42 min).

The emission maximum of example 1 (2% by weight in PMMA) is at 474 nm, the full width at half maximum (FWHM) is 0.13 eV (23 nm), the CIE_{X} and CIE_{Y} coordinates are 0.12, and 0.22, respectively, and the PLQY is 64%.

### Example 2

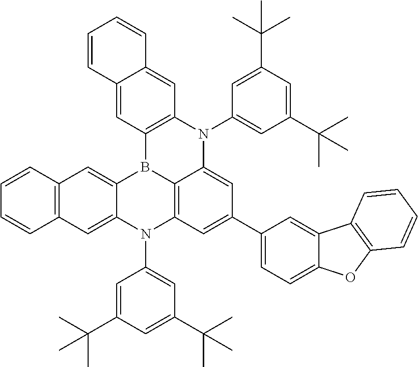

Example 2 was synthesized according to
Procedure 1 (78% yield), wherein 3,5-di-tert-butylaniline [2380-36-1] was used as compound E1;
Procedure 2 (59% yield);
Procedure 3 (27% yield);
Procedure 4 (59% yield);
Procedure 5 (quant. yield);
Procedure 6 (28% yield), wherein 2-bromodibenzofuran [86-76-0] was used as compound E3.

MS (HPLC-MS): m/z (retention time)=912.1 (8.51 min).

The emission maximum of example 1 (2% by weight in PMMA) is at 471 nm, the full width at half maximum (FWHM) is 0.13 eV (24 nm), the CIE_{X} and CIE_{Y} coordinates are 0.12, and 0.19, respectively, and the PLQY is 59%.

### Additional Examples of Organic Molecules of the Invention

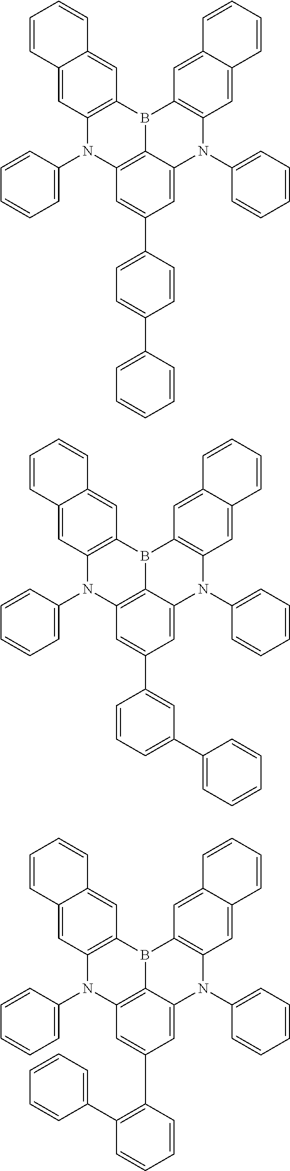

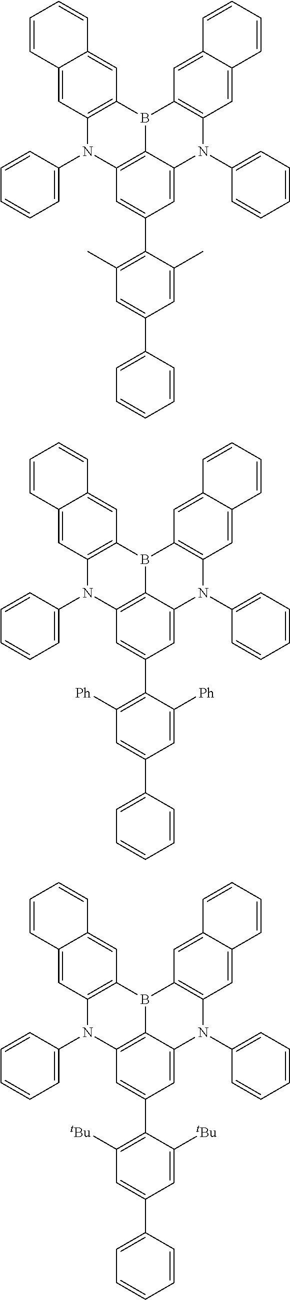 [SMILES: Cc1cc(-c2ccccc2)cc(C)c1-c1cc2c3c(c1)N(c1ccccc1)c1cc4ccccc4cc1B3c1cc3ccccc3cc1N2c1ccccc1 ; c1ccc(-c2cc(-c3ccccc3)c(-c3cc4c5c(c3)N(c3ccccc3)c3cc6ccccc6cc3B5c3cc5ccccc5cc3N4c3ccccc3)c(-c3ccccc3)c2)cc1 ; CC(C)(C)c1cc(-c2ccccc2)cc(C(C)(C)C)c1-c1cc2c3c(c1)N(c1ccccc1)c1cc4ccccc4cc1B3c1cc3ccccc3cc1N2c1ccccc1]

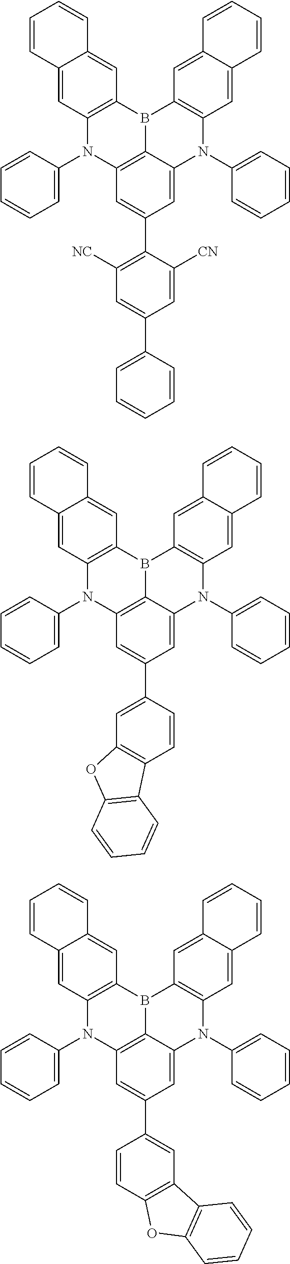 [SMILES: N#Cc1cc(-c2ccccc2)cc(C#N)c1-c1cc2c3c(c1)N(c1ccccc1)c1cc4ccccc4cc1B3c1cc3ccccc3cc1N2c1ccccc1 ; c1ccc(N2c3cc4ccccc4cc3B3c4cc5ccccc5cc4N(c4ccccc4)c4cc(-c5ccc6c(c5)oc5ccccc56)cc2c43)cc1 ; c1ccc(N2c3cc4ccccc4cc3B3c4cc5ccccc5cc4N(c4ccccc4)c4cc(-c5ccc6oc7ccccc7c6c5)cc2c43)cc1]

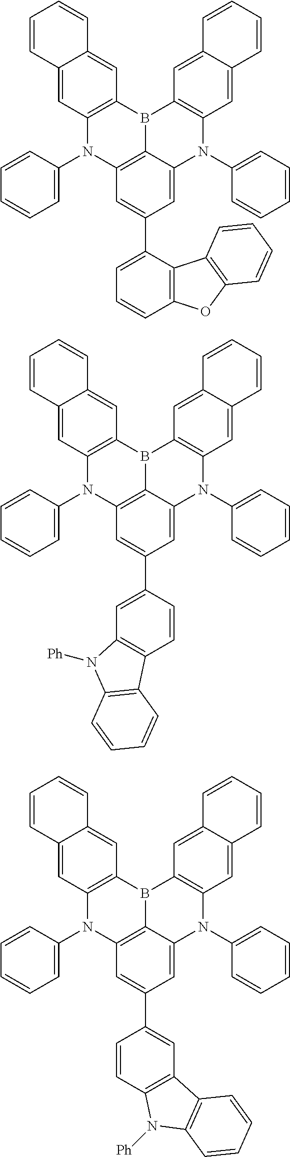

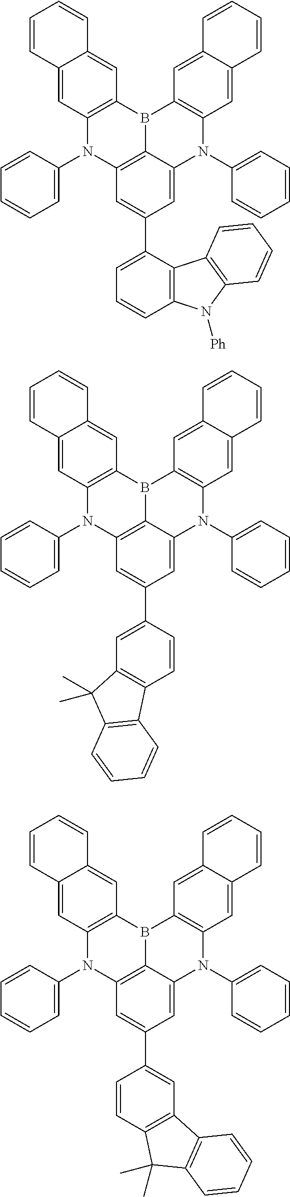

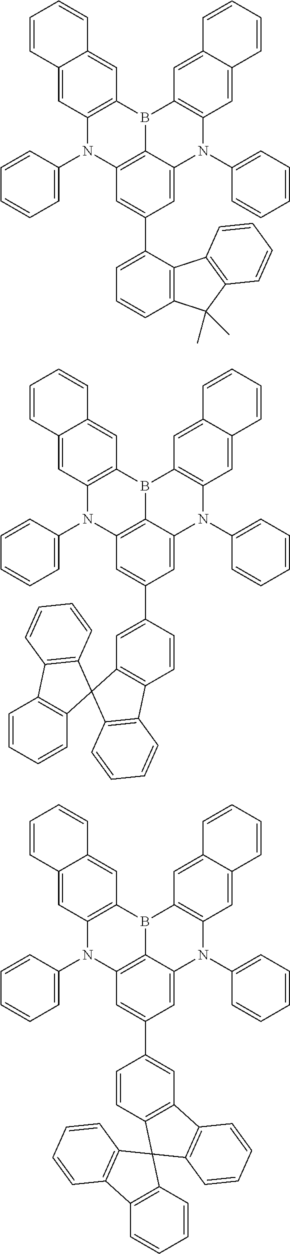

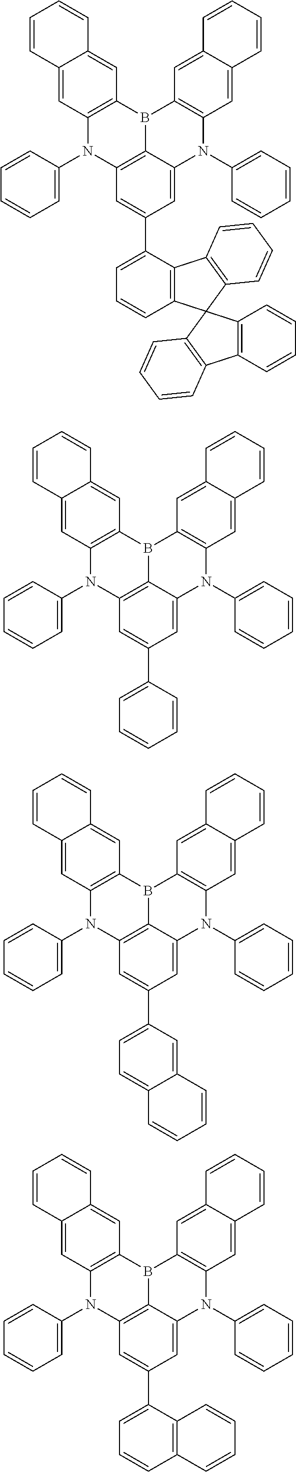

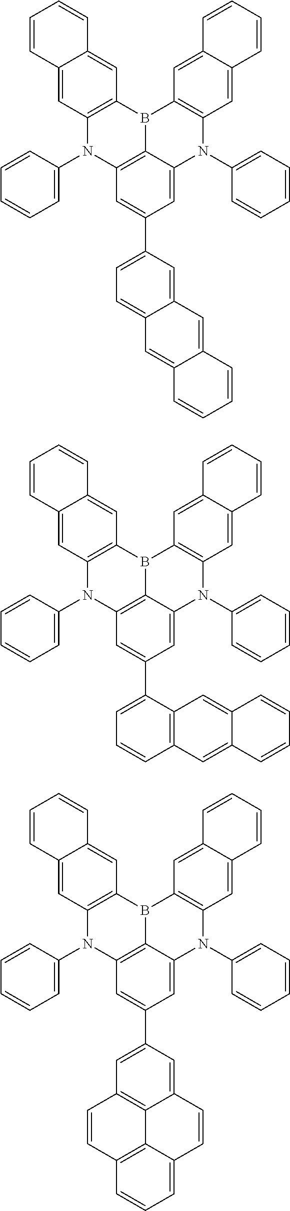

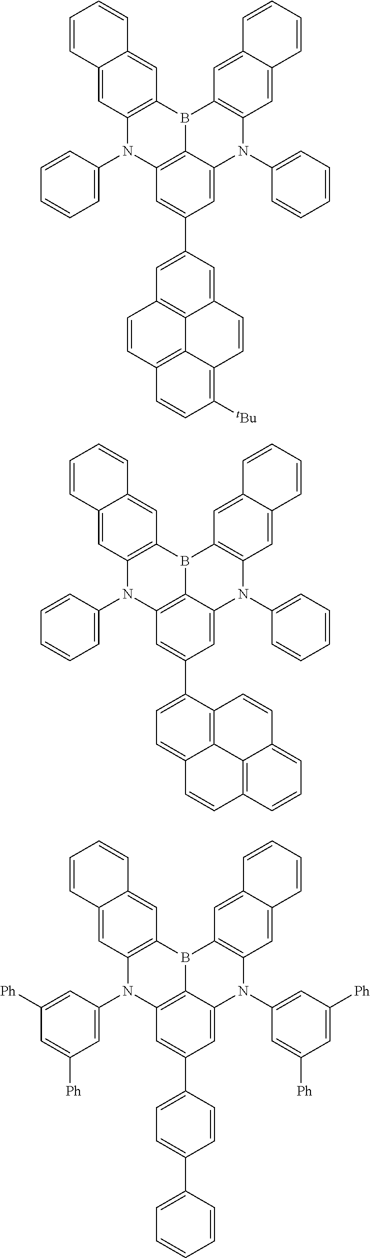

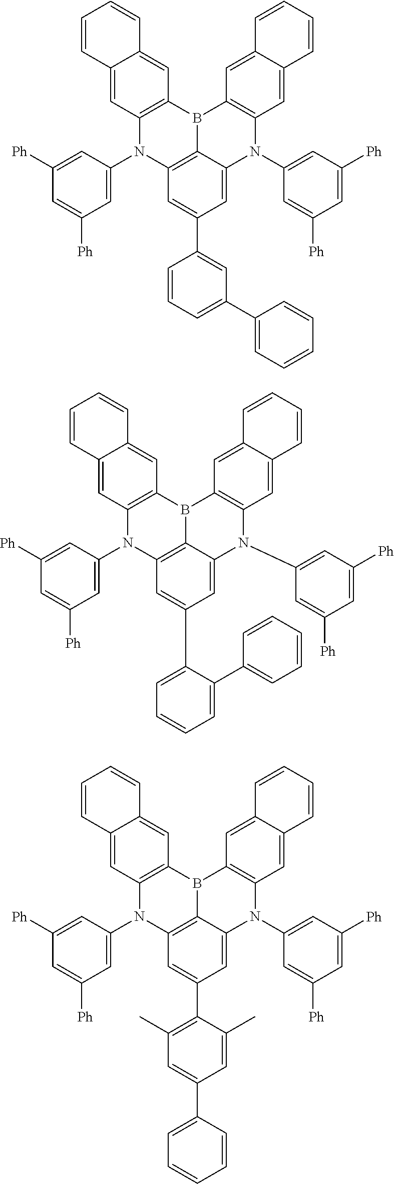

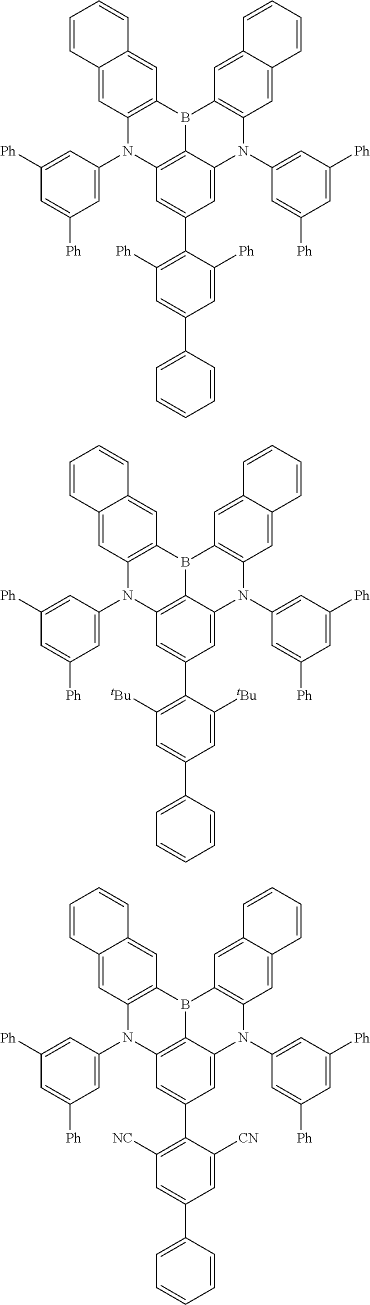 [SMILES: c1ccc(-c2cc(-c3ccccc3)cc(N3c4cc5ccccc5cc4B4c5cc6ccccc6cc5N(c5cc(-c6ccccc6)cc(-c6ccccc6)c5)c5cc(-c6c(-c7ccccc7)cc(-c7ccccc7)cc6-c6ccccc6)cc3c54)c2)cc1 ; CC(C)(C)c1cc(-c2ccccc2)cc(C(C)(C)C)c1-c1cc2c3c(c1)N(c1cc(-c4ccccc4)cc(-c4ccccc4)c1)c1cc4ccccc4cc1B3c1cc3ccccc3cc1N2c1cc(-c2ccccc2)cc(-c2ccccc2)c1 ; N#Cc1cc(-c2ccccc2)cc(C#N)c1-c1cc2c3c(c1)N(c1cc(-c4ccccc4)cc(-c4ccccc4)c1)c1cc4ccccc4cc1B3c1cc3ccccc3cc1N2c1cc(-c2ccccc2)cc(-c2ccccc2)c1]

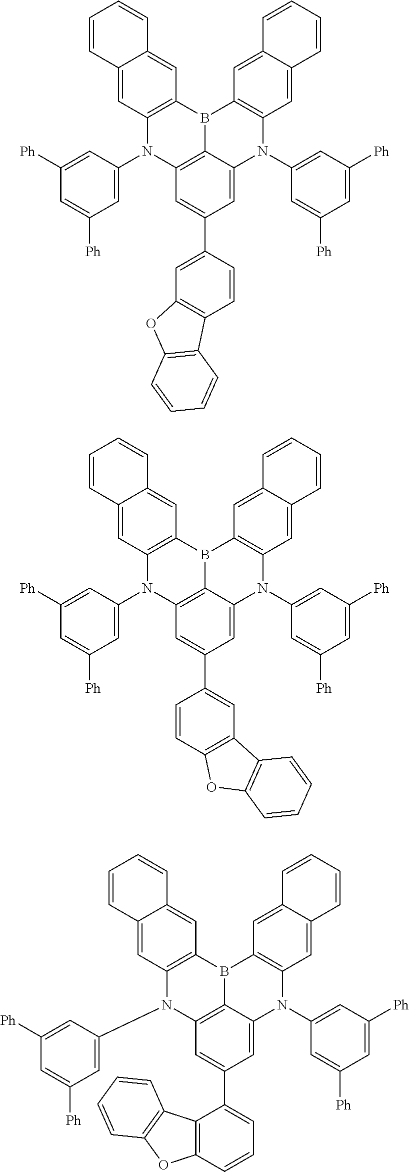

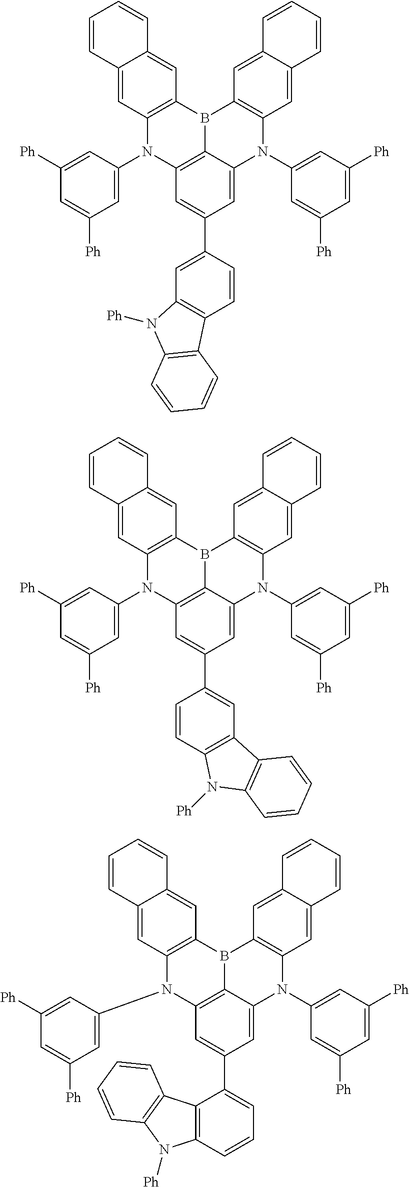

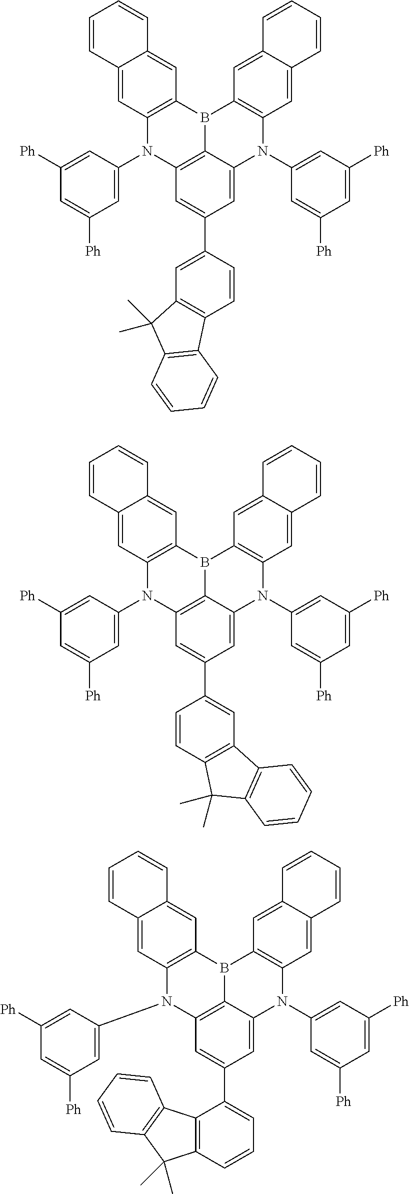

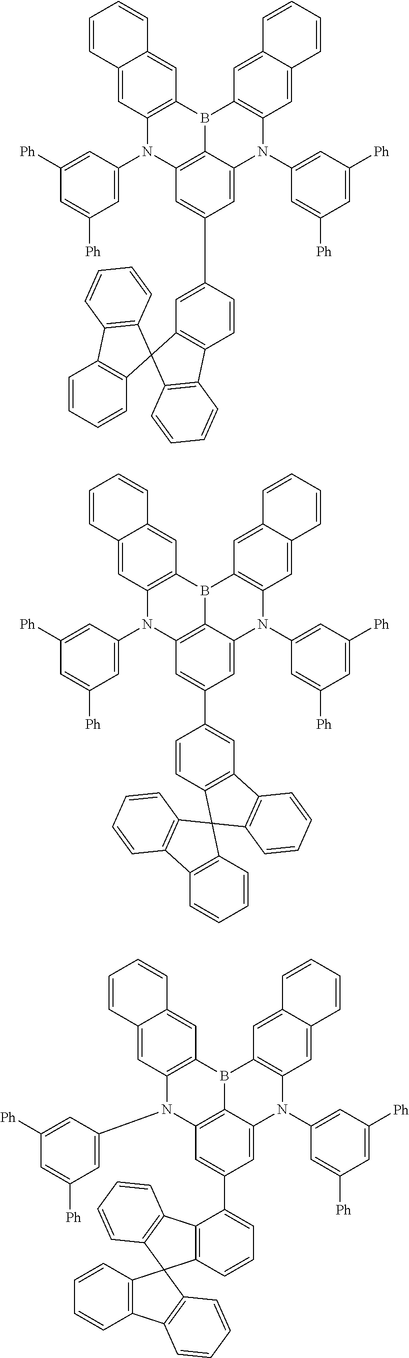 [SMILES: c1ccc(-c2cc(-c3ccccc3)cc(N3c4cc5ccccc5cc4B4c5cc6ccccc6cc5N(c5cc(-c6ccccc6)cc(-c6ccccc6)c5)c5cc(-c6ccc7c(c6)C6(c8ccccc8-c8ccccc86)c6ccccc6-7)cc3c54)c2)cc1 ; c1ccc(-c2cc(-c3ccccc3)cc(N3c4cc5ccccc5cc4B4c5cc6ccccc6cc5N(c5cc(-c6ccccc6)cc(-c6ccccc6)c5)c5cc(-c6ccc7c(c6)-c6ccccc6C76c7ccccc7-c7ccccc76)cc3c54)c2)cc1 ; c1ccc(-c2cc(-c3ccccc3)cc(N3c4cc5ccccc5cc4B4c5cc6ccccc6cc5N(c5cc(-c6ccccc6)cc(-c6ccccc6)c5)c5cc(-c6cccc7c6-c6ccccc6C76c7ccccc7-c7ccccc76)cc3c54)c2)cc1]

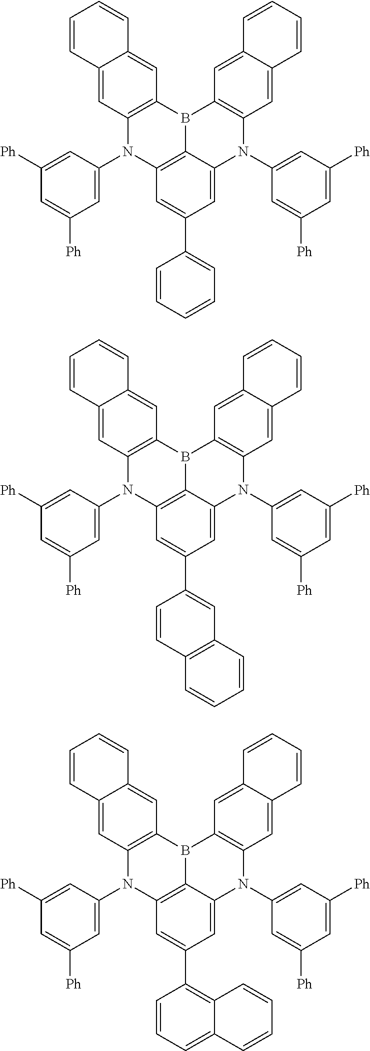 [SMILES: c1ccc(-c2cc(-c3ccccc3)cc(N3c4cc5ccccc5cc4B4c5cc6ccccc6cc5N(c5cc(-c6ccccc6)cc(-c6ccccc6)c5)c5cc(-c6ccccc6)cc3c54)c2)cc1 ; c1ccc(-c2cc(-c3ccccc3)cc(N3c4cc5ccccc5cc4B4c5cc6ccccc6cc5N(c5cc(-c6ccccc6)cc(-c6ccccc6)c5)c5cc(-c6ccc7ccccc7c6)cc3c54)c2)cc1 ; c1ccc(-c2cc(-c3ccccc3)cc(N3c4cc5ccccc5cc4B4c5cc6ccccc6cc5N(c5cc(-c6ccccc6)cc(-c6ccccc6)c5)c5cc(-c6cccc7ccccc67)cc3c54)c2)cc1]

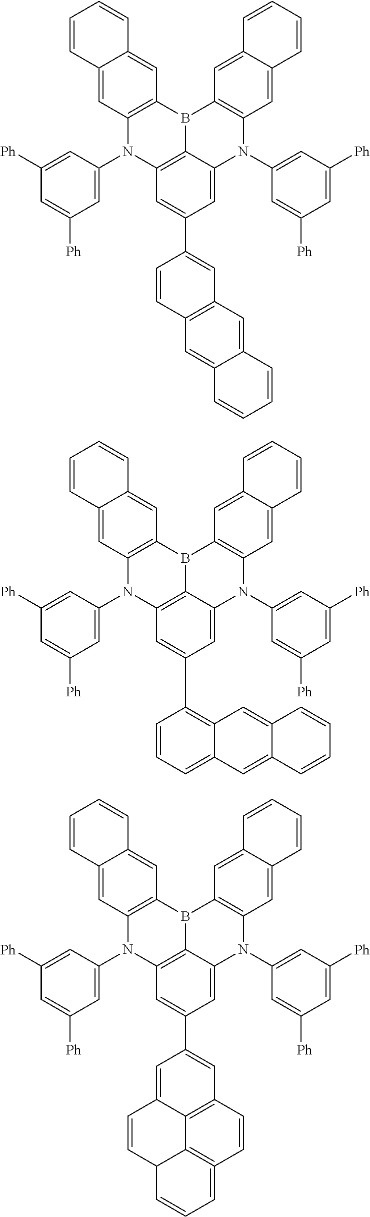

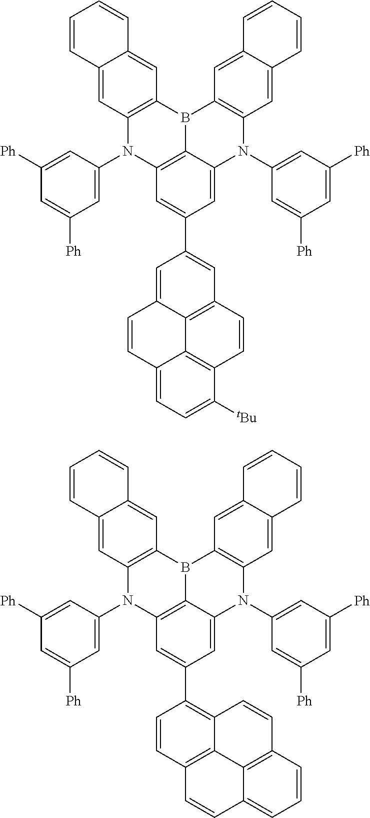

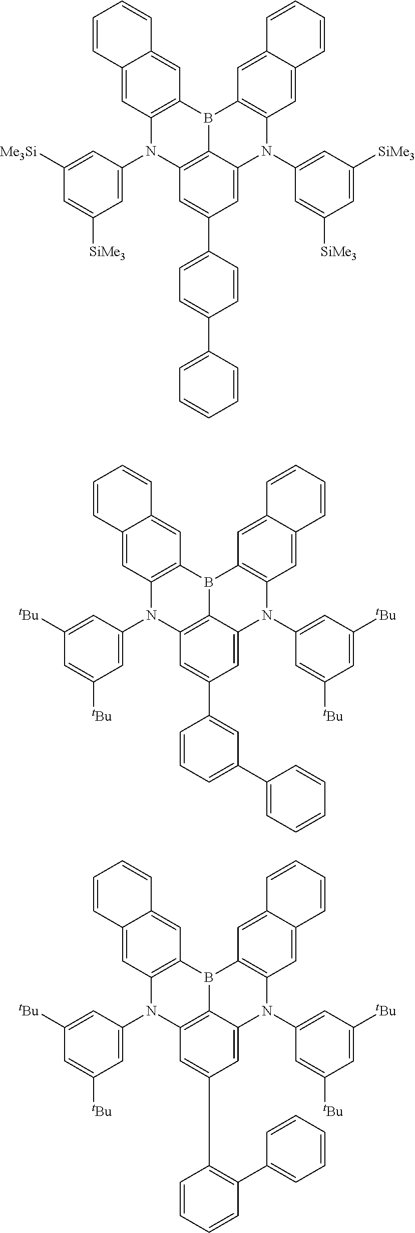

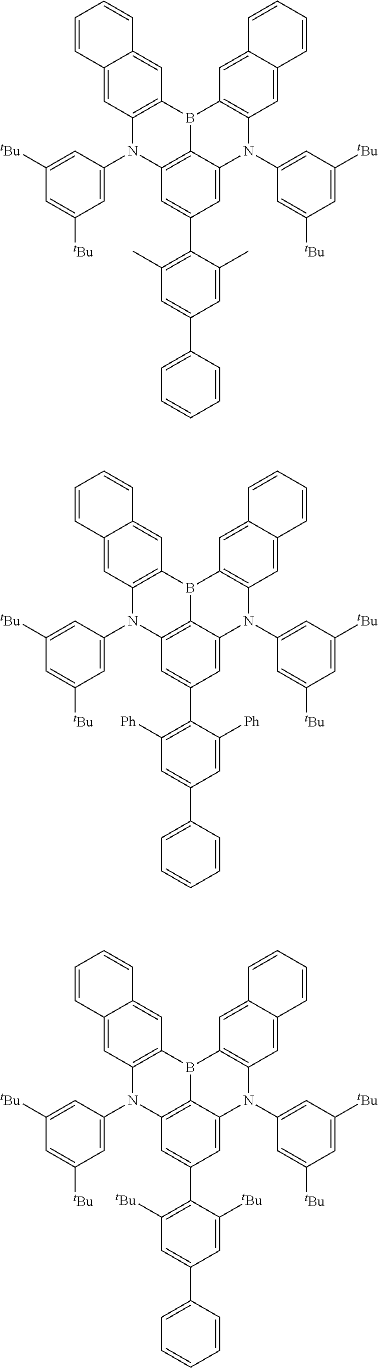 [SMILES: Cc1cc(-c2ccccc2)cc(C)c1-c1cc2c3c(c1)N(c1cc(C(C)(C)C)cc(C(C)(C)C)c1)c1cc4ccccc4cc1B3c1cc3ccccc3cc1N2c1cc(C(C)(C)C)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5c(-c6ccccc6)cc(-c6ccccc6)cc5-c5ccccc5)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5c(C(C)(C)C)cc(-c6ccccc6)cc5C(C)(C)C)cc2c43)cc(C(C)(C)C)c1]

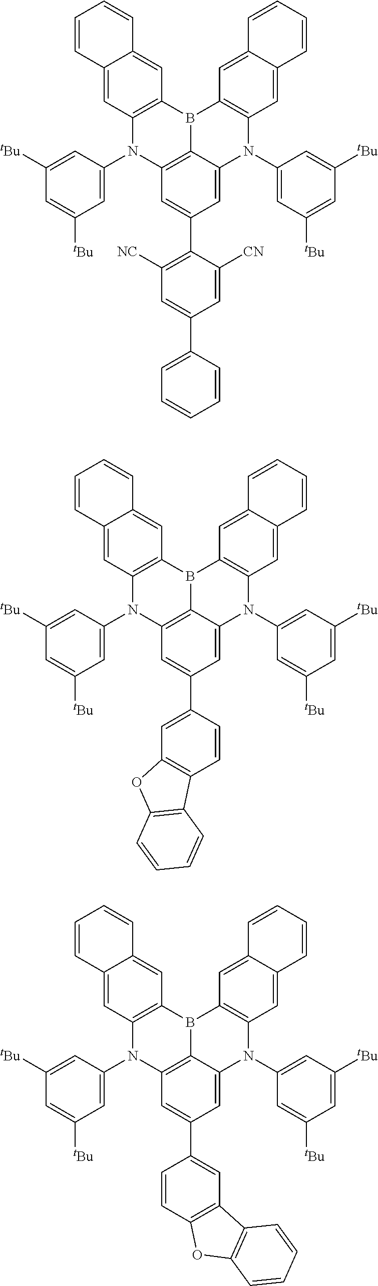 [SMILES: CC(C)(C)c1cc(N2c3cc4ccccc4cc3B3c4cc5ccccc5cc4N(c4cc(C(C)(C)C)cc(C(C)(C)C)c4)c4cc(-c5c(C#N)cc(-c6ccccc6)cc5C#N)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)oc5ccccc56)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6oc7ccccc7c6c5)cc2c43)cc(C(C)(C)C)c1]

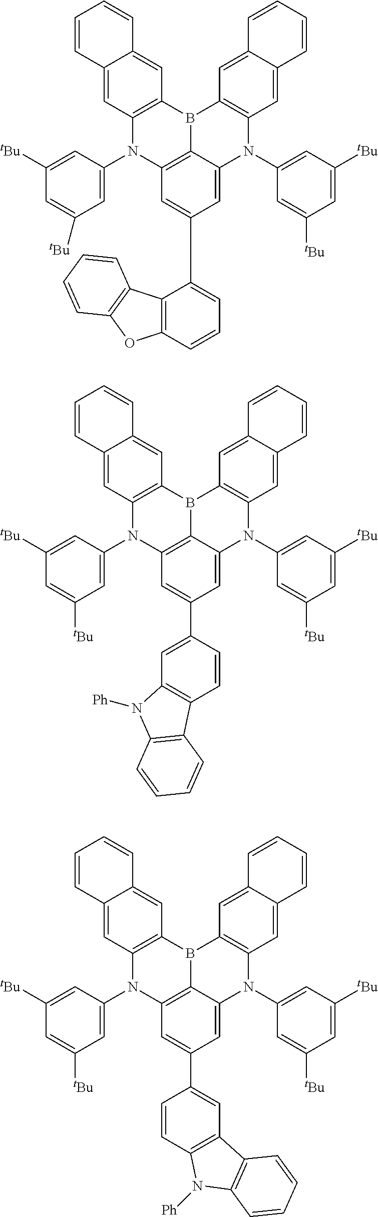 [SMILES: CC(C)(C)c1cc(N2c3cc4ccccc4cc3B3c4cc5ccccc5cc4N(c4cc(C(C)(C)C)cc(C(C)(C)C)c4)c4cc(-c5cccc6oc7ccccc7c56)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c7ccccc7n(-c7ccccc7)c6c5)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)c5ccccc5n6-c5ccccc5)cc2c43)cc(C(C)(C)C)c1]

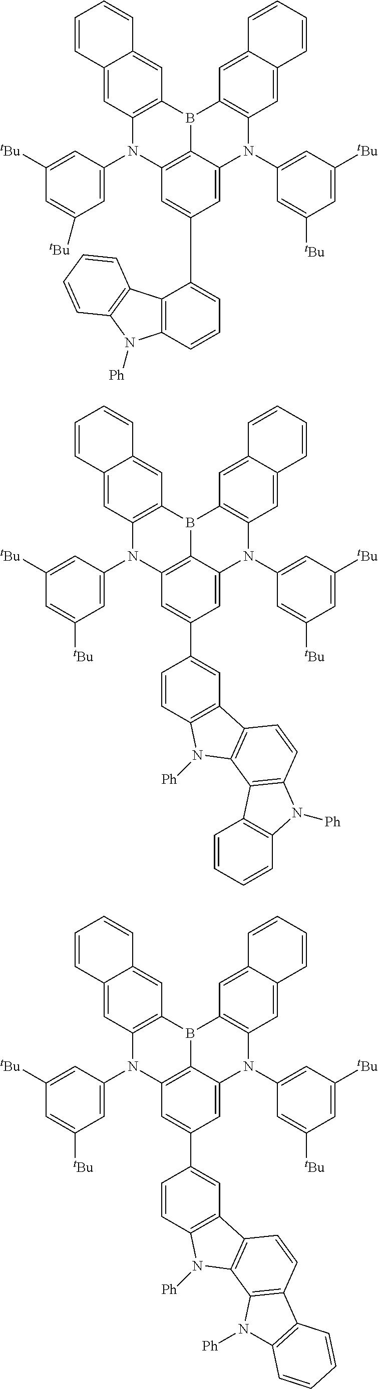

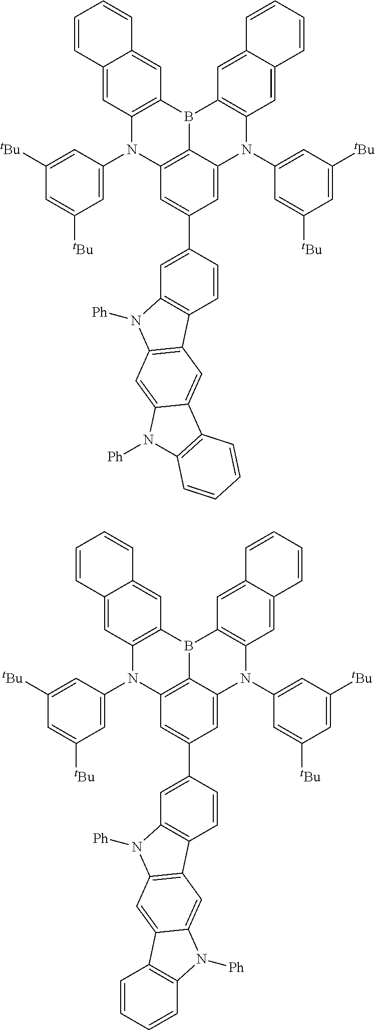 [SMILES: CC(C)(C)c1cc(N2c3cc4ccccc4cc3B3c4cc5ccccc5cc4N(c4cc(C(C)(C)C)cc(C(C)(C)C)c4)c4cc(-c5ccc6c7cc8c9ccccc9n(-c9ccccc9)c8cc7n(-c7ccccc7)c6c5)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c7cc8c(cc7n(-c7ccccc7)c6c5)c5ccccc5n8-c5ccccc5)cc2c43)cc(C(C)(C)C)c1]

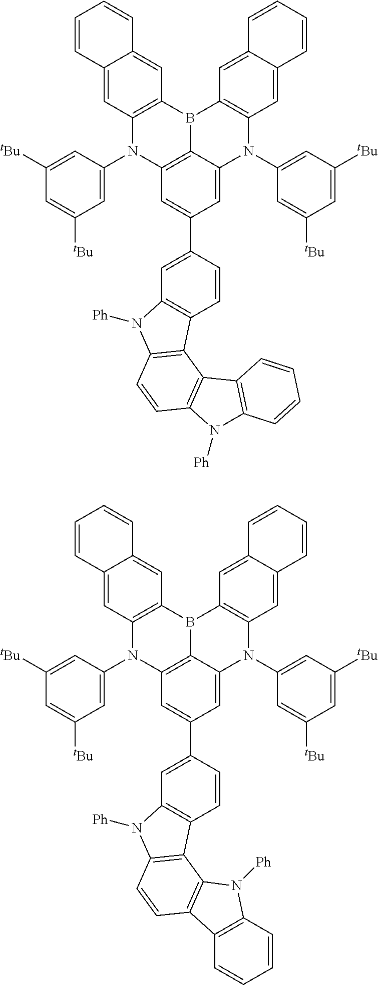 [SMILES: CC(C)(C)c1cc(N2c3cc4ccccc4cc3B3c4cc5ccccc5cc4N(c4cc(C(C)(C)C)cc(C(C)(C)C)c4)c4cc(-c5ccc6c7c8c9ccccc9n(-c9ccccc9)c8ccc7n(-c7ccccc7)c6c5)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c7c(ccc8c9ccccc9n(-c9ccccc9)c87)n(-c7ccccc7)c6c5)cc2c43)cc(C(C)(C)C)c1]

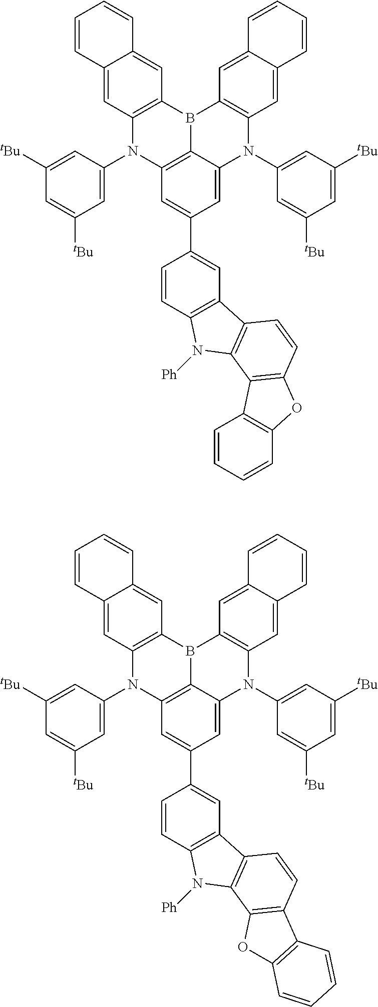 [SMILES: CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)c5ccc7oc8ccccc8c7c5n6-c5ccccc5)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)c5ccc7c8ccccc8oc7c5n6-c5ccccc5)cc2c43)cc(C(C)(C)C)c1]

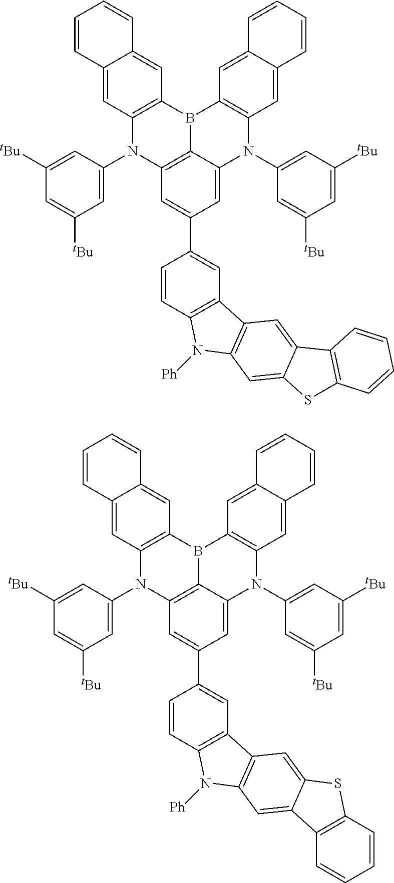

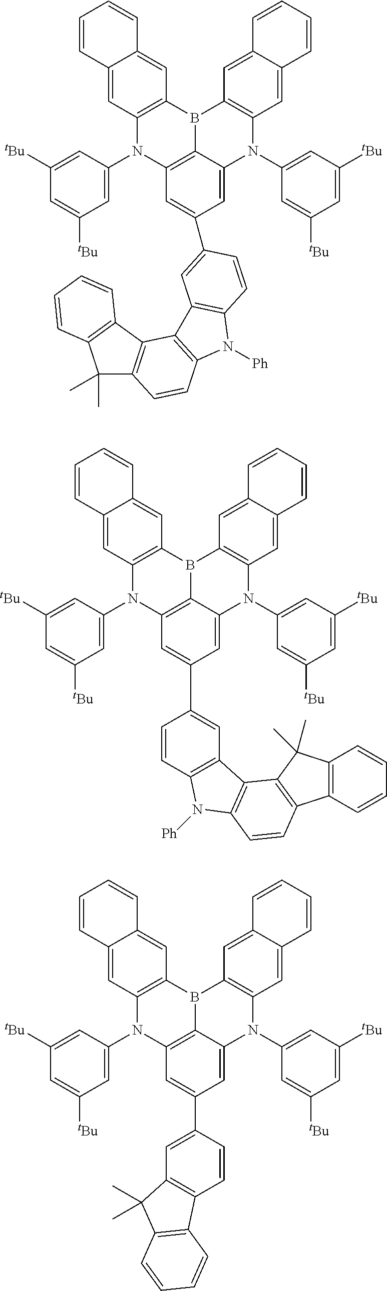

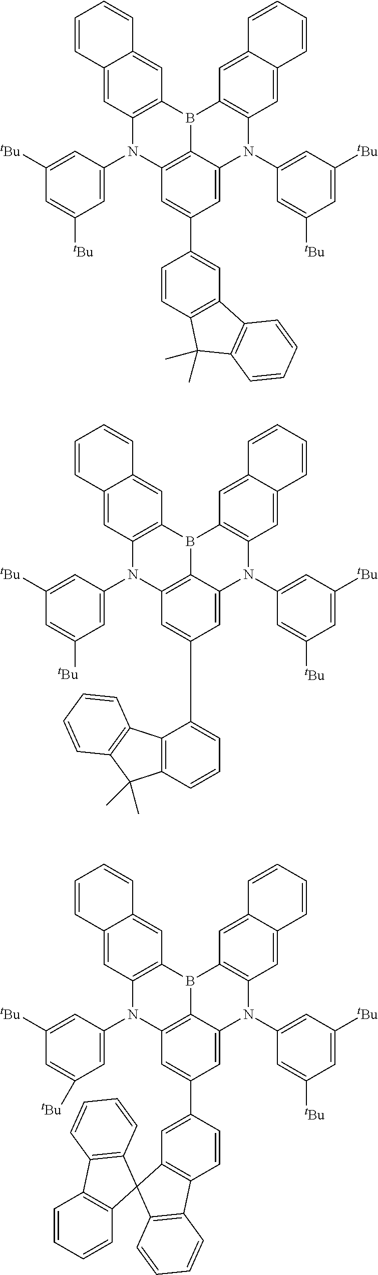 [SMILES: CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)-c5ccccc5C6(C)C)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5cccc6c5-c5ccccc5C6(C)C)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)C5(c7ccccc7-c7ccccc75)c5ccccc5-6)cc2c43)cc(C(C)(C)C)c1]

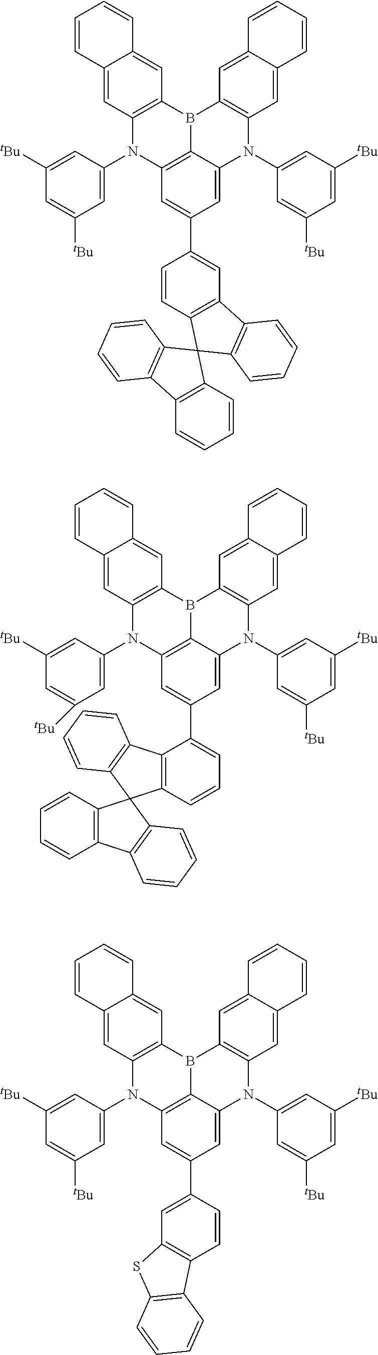 [SMILES: CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)-c5ccccc5C65c6ccccc6-c6ccccc65)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5cccc6c5-c5ccccc5C65c6ccccc6-c6ccccc65)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6c(c5)sc5ccccc56)cc2c43)cc(C(C)(C)C)c1]

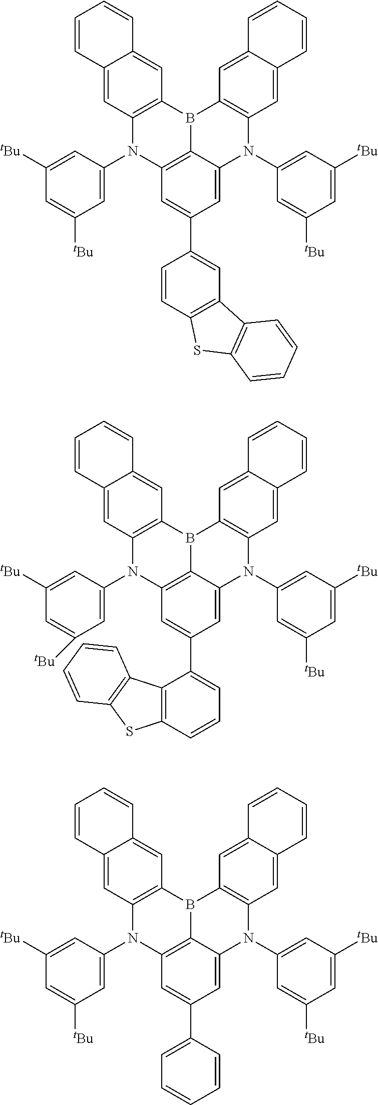

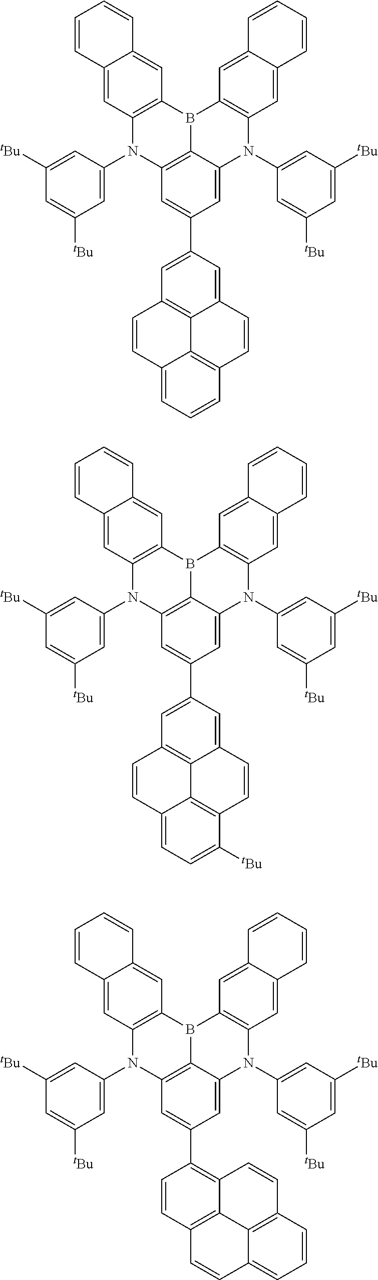 [SMILES: CC(C)(C)c1cc(N2c3cc4ccccc4cc3B3c4cc5ccccc5cc4N(c4cc(C(C)(C)C)cc(C(C)(C)C)c4)c4cc(-c5cc6ccc7cccc8ccc(c5)c6c78)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5cc6ccc7ccc(C(C)(C)C)c8ccc(c5)c6c78)cc2c43)cc(C(C)(C)C)c1 ; CC(C)(C)c1cc(N2c3cc4ccccc4cc3B3c4cc5ccccc5cc4N(c4cc(C(C)(C)C)cc(C(C)(C)C)c4)c4cc(-c5ccc6ccc7cccc8ccc5c6c78)cc2c43)cc(C(C)(C)C)c1]

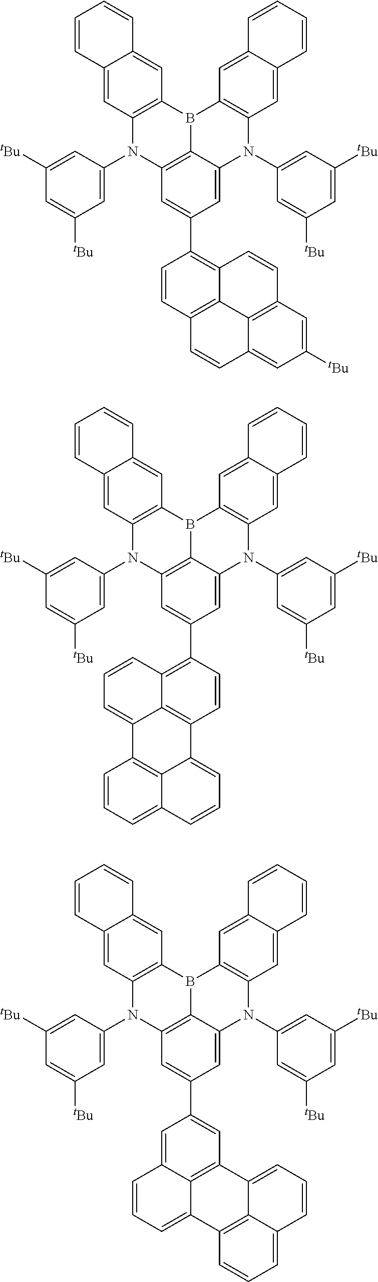

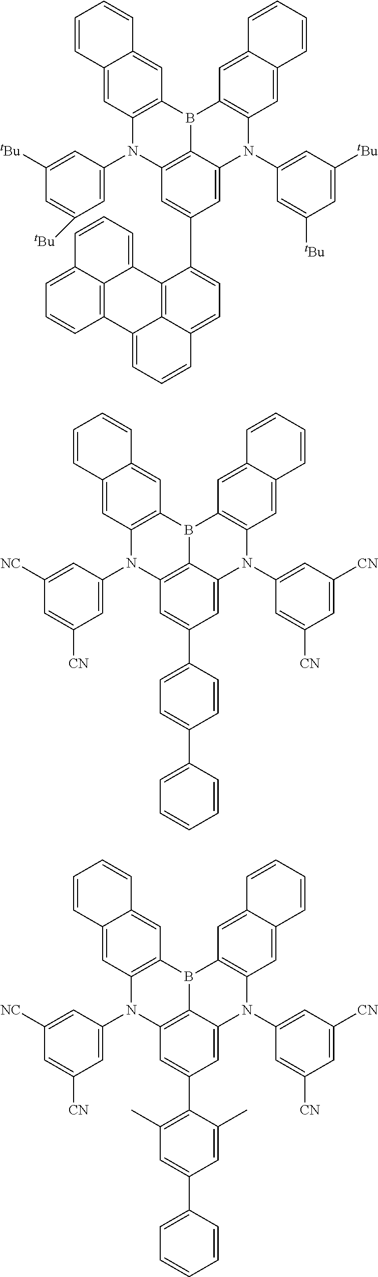 [SMILES: CC(C)(C)c1cc(N2c3cc4ccccc4cc3B3c4cc5ccccc5cc4N(c4cc(C(C)(C)C)cc(C(C)(C)C)c4)c4cc(-c5ccc6cccc7c8cccc9cccc(c5c67)c98)cc2c43)cc(C(C)(C)C)c1 ; N#Cc1cc(C#N)cc(N2c3cc4ccccc4cc3B3c4cc5ccccc5cc4N(c4cc(C#N)cc(C#N)c4)c4cc(-c5ccc(-c6ccccc6)cc5)cc2c43)c1 ; Cc1cc(-c2ccccc2)cc(C)c1-c1cc2c3c(c1)N(c1cc(C#N)cc(C#N)c1)c1cc4ccccc4cc1B3c1cc3ccccc3cc1N2c1cc(C#N)cc(C#N)c1]

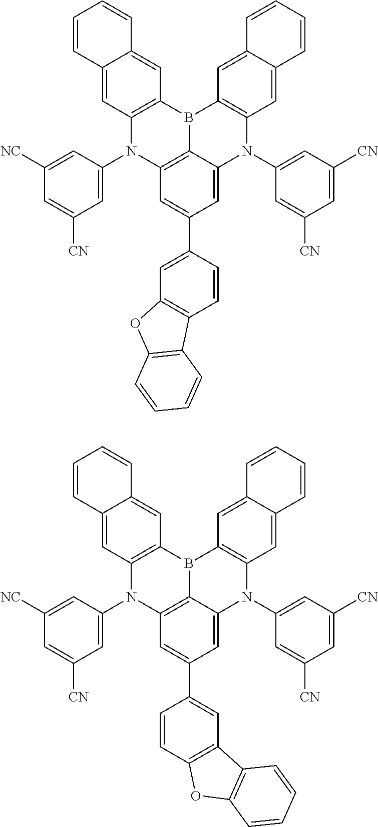 [SMILES: N#Cc1cc(C#N)cc(N2c3cc4ccccc4cc3B3c4cc5ccccc5cc4N(c4cc(C#N)cc(C#N)c4)c4cc(-c5ccc6c(c5)oc5ccccc56)cc2c43)c1 ; N#Cc1cc(C#N)cc(N2c3cc4ccccc4cc3B3c4cc5ccccc5cc4N(c4cc(C#N)cc(C#N)c4)c4cc(-c5ccc6oc7ccccc7c6c5)cc2c43)c1]

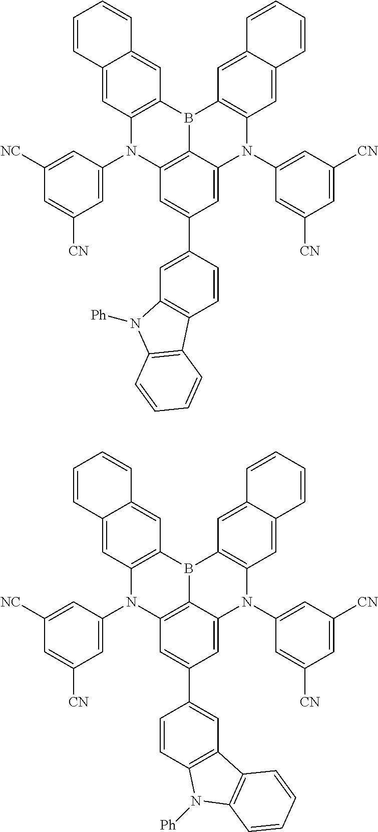 [SMILES: N#Cc1cc(C#N)cc(N2c3cc4ccccc4cc3B3c4cc5ccccc5cc4N(c4cc(C#N)cc(C#N)c4)c4cc(-c5ccc6c7ccccc7n(-c7ccccc7)c6c5)cc2c43)c1 ; N#Cc1cc(C#N)cc(N2c3cc4ccccc4cc3B3c4cc5ccccc5cc4N(c4cc(C#N)cc(C#N)c4)c4cc(-c5ccc6c(c5)c5ccccc5n6-c5ccccc5)cc2c43)c1]

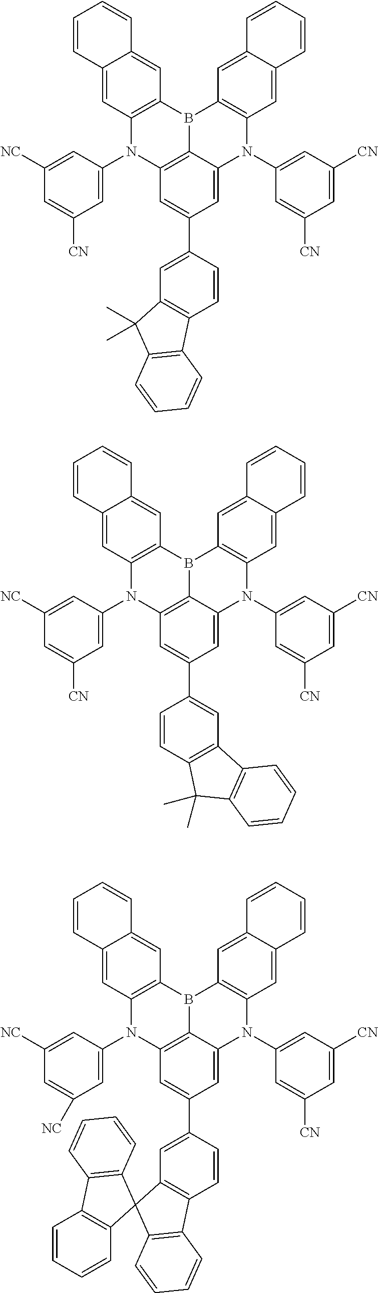 [SMILES: CC1(C)c2ccccc2-c2ccc(-c3cc4c5c(c3)N(c3cc(C#N)cc(C#N)c3)c3cc6ccccc6cc3B5c3cc5ccccc5cc3N4c3cc(C#N)cc(C#N)c3)cc21 ; CC1(C)c2ccccc2-c2cc(-c3cc4c5c(c3)N(c3cc(C#N)cc(C#N)c3)c3cc6ccccc6cc3B5c3cc5ccccc5cc3N4c3cc(C#N)cc(C#N)c3)ccc21 ; N#Cc1cc(C#N)cc(N2c3cc4ccccc4cc3B3c4cc5ccccc5cc4N(c4cc(C#N)cc(C#N)c4)c4cc(-c5ccc6c(c5)C5(c7ccccc7-c7ccccc75)c5ccccc5-6)cc2c43)c1]

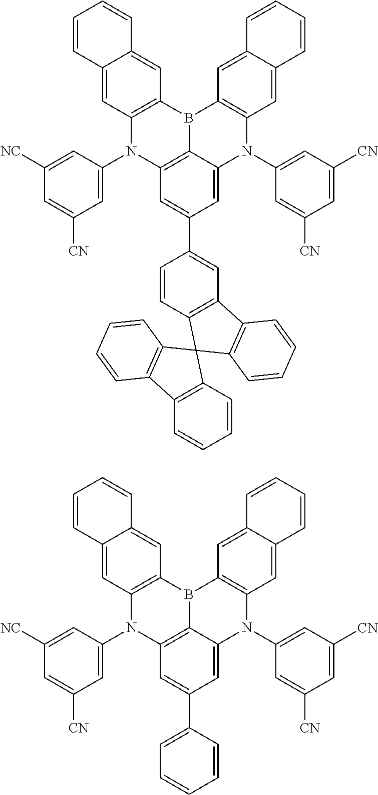 [SMILES: N#Cc1cc(C#N)cc(N2c3cc4ccccc4cc3B3c4cc5ccccc5cc4N(c4cc(C#N)cc(C#N)c4)c4cc(-c5ccc6c(c5)-c5ccccc5C65c6ccccc6-c6ccccc65)cc2c43)c1 ; N#Cc1cc(C#N)cc(N2c3cc4ccccc4cc3B3c4cc5ccccc5cc4N(c4cc(C#N)cc(C#N)c4)c4cc(-c5ccccc5)cc2c43)c1]

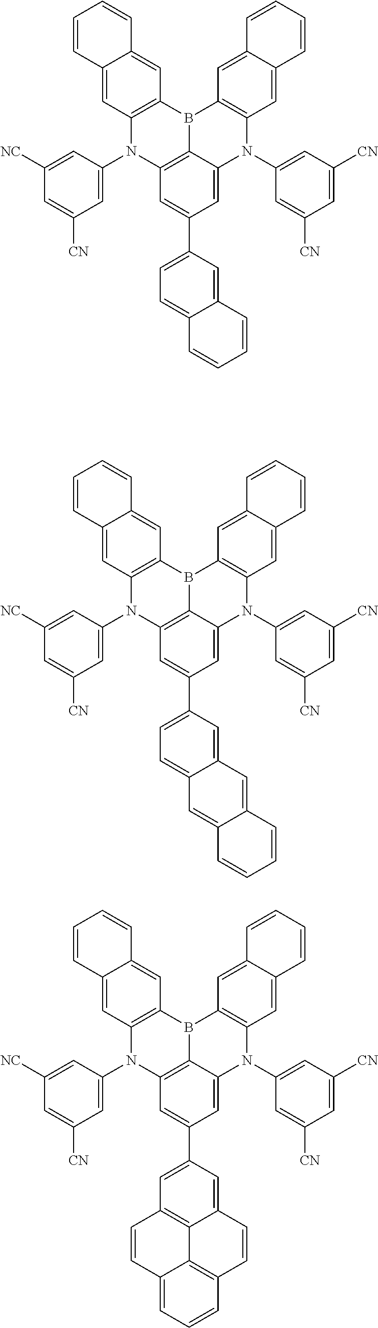

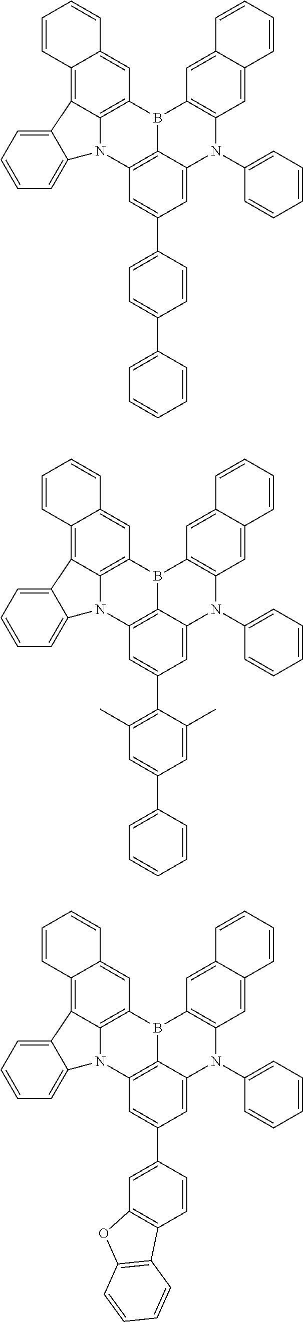 [SMILES: c1ccc(-c2ccc(-c3cc4c5c(c3)-n3c6ccccc6c6c7ccccc7cc(c63)B5c3cc5ccccc5cc3N4c3ccccc3)cc2)cc1 ; Cc1cc(-c2ccccc2)cc(C)c1-c1cc2c3c(c1)-n1c4ccccc4c4c5ccccc5cc(c41)B3c1cc3ccccc3cc1N2c1ccccc1 ; c1ccc(N2c3cc4ccccc4cc3B3c4c2cc(-c2ccc5c(c2)oc2ccccc25)cc4-n2c4ccccc4c4c5ccccc5cc3c42)cc1]

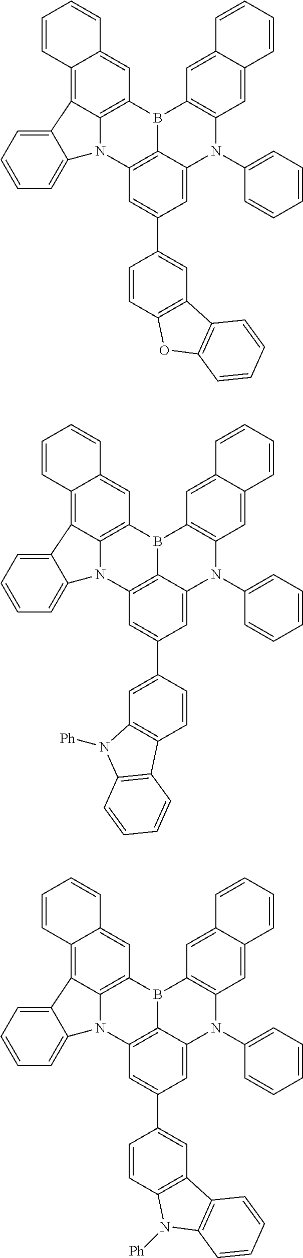 [SMILES: c1ccc(N2c3cc4ccccc4cc3B3c4c2cc(-c2ccc5oc6ccccc6c5c2)cc4-n2c4ccccc4c4c5ccccc5cc3c42)cc1 ; c1ccc(N2c3cc4ccccc4cc3B3c4c2cc(-c2ccc5c6ccccc6n(-c6ccccc6)c5c2)cc4-n2c4ccccc4c4c5ccccc5cc3c42)cc1 ; c1ccc(N2c3cc4ccccc4cc3B3c4c2cc(-c2ccc5c(c2)c2ccccc2n5-c2ccccc2)cc4-n2c4ccccc4c4c5ccccc5cc3c42)cc1]

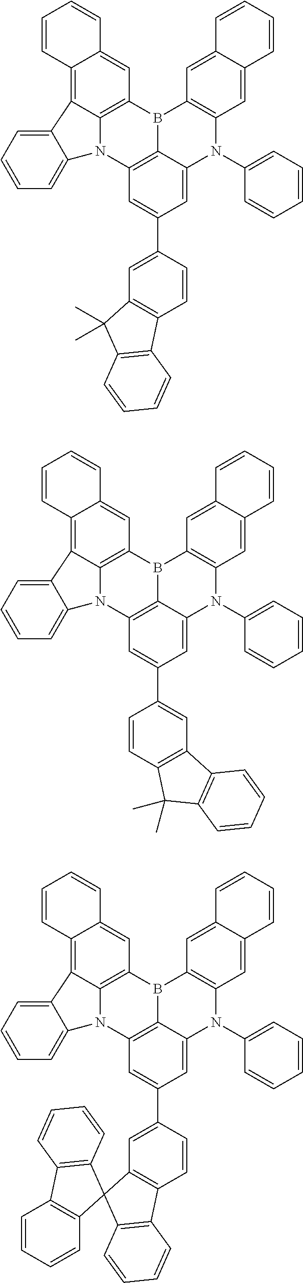

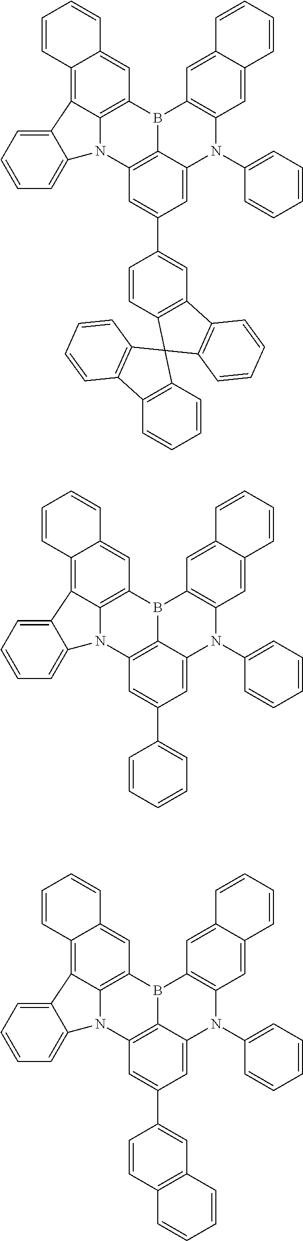 [SMILES: c1ccc(N2c3cc4ccccc4cc3B3c4c2cc(-c2ccc5c(c2)-c2ccccc2C52c5ccccc5-c5ccccc52)cc4-n2c4ccccc4c4c5ccccc5cc3c42)cc1 ; c1ccc(-c2cc3c4c(c2)-n2c5ccccc5c5c6ccccc6cc(c52)B4c2cc4ccccc4cc2N3c2ccccc2)cc1 ; c1ccc(N2c3cc4ccccc4cc3B3c4c2cc(-c2ccc5ccccc5c2)cc4-n2c4ccccc4c4c5ccccc5cc3c42)cc1]

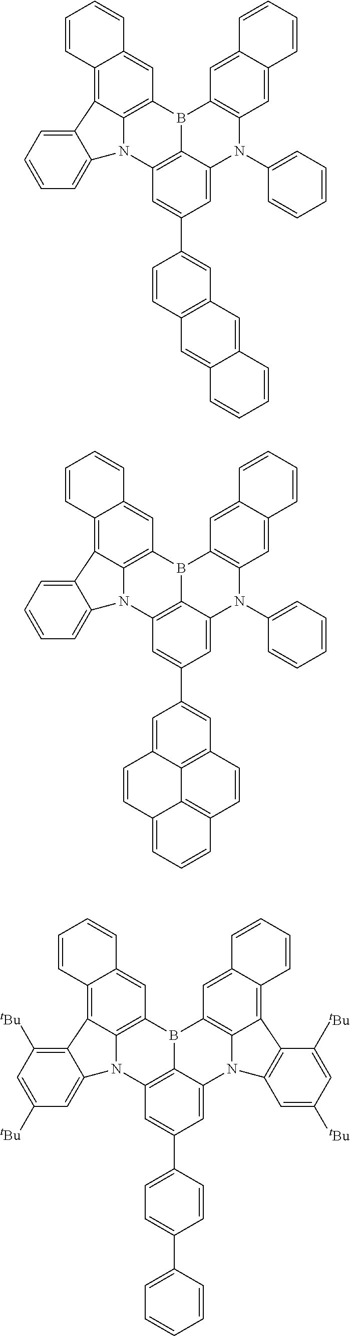

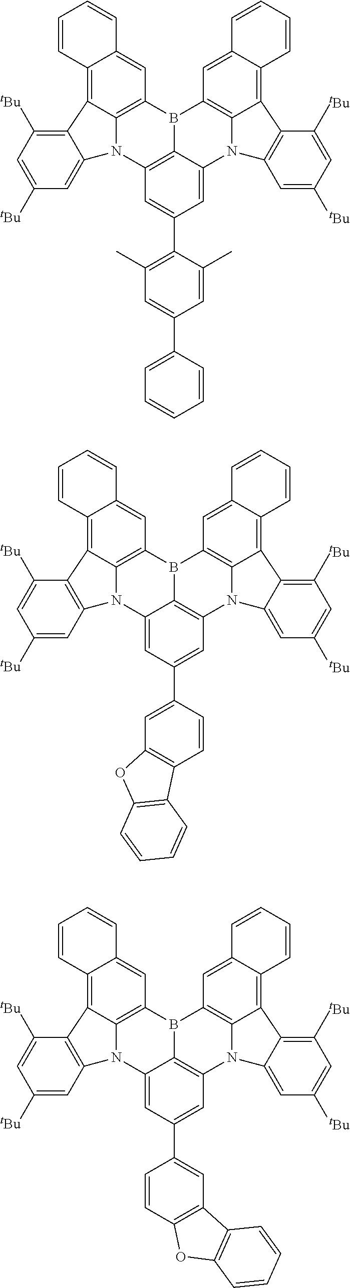 [SMILES: Cc1cc(-c2ccccc2)cc(C)c1-c1cc2c3c(c1)-n1c4cc(C(C)(C)C)cc(C(C)(C)C)c4c4c5ccccc5cc(c41)B3c1cc3ccccc3c3c4c(C(C)(C)C)cc(C(C)(C)C)cc4n-2c13 ; CC(C)(C)c1cc(C(C)(C)C)c2c3c4ccccc4cc4c3n(c2c1)-c1cc(-c2ccc3c(c2)oc2ccccc23)cc2c1B4c1cc3ccccc3c3c4c(C(C)(C)C)cc(C(C)(C)C)cc4n-2c13 ; CC(C)(C)c1cc(C(C)(C)C)c2c3c4ccccc4cc4c3n(c2c1)-c1cc(-c2ccc3oc5ccccc5c3c2)cc2c1B4c1cc3ccccc3c3c4c(C(C)(C)C)cc(C(C)(C)C)cc4n-2c13]

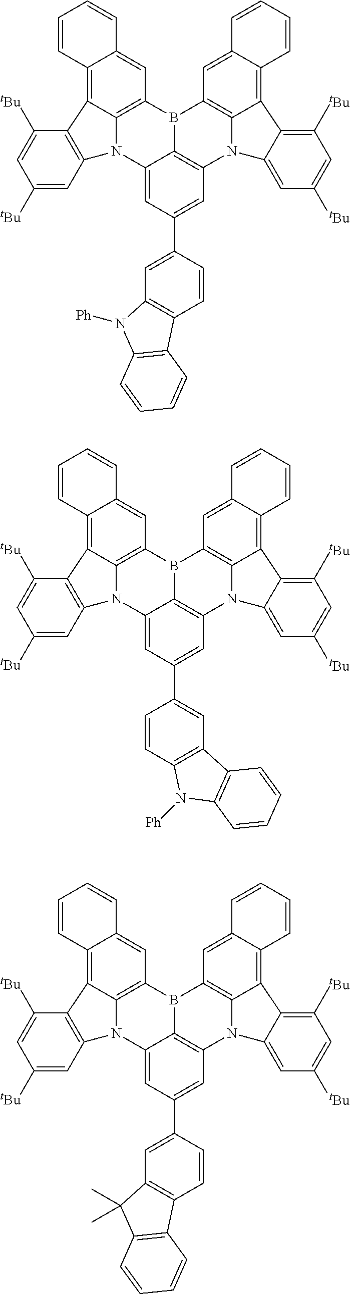 [SMILES: CC(C)(C)c1cc(C(C)(C)C)c2c3c4ccccc4cc4c3n(c2c1)-c1cc(-c2ccc3c5ccccc5n(-c5ccccc5)c3c2)cc2c1B4c1cc3ccccc3c3c4c(C(C)(C)C)cc(C(C)(C)C)cc4n-2c13 ; CC(C)(C)c1cc(C(C)(C)C)c2c3c4ccccc4cc4c3n(c2c1)-c1cc(-c2ccc3c(c2)c2ccccc2n3-c2ccccc2)cc2c1B4c1cc3ccccc3c3c4c(C(C)(C)C)cc(C(C)(C)C)cc4n-2c13 ; CC(C)(C)c1cc(C(C)(C)C)c2c3c4ccccc4cc4c3n(c2c1)-c1cc(-c2ccc3c(c2)C(C)(C)c2ccccc2-3)cc2c1B4c1cc3ccccc3c3c4c(C(C)(C)C)cc(C(C)(C)C)cc4n-2c13]

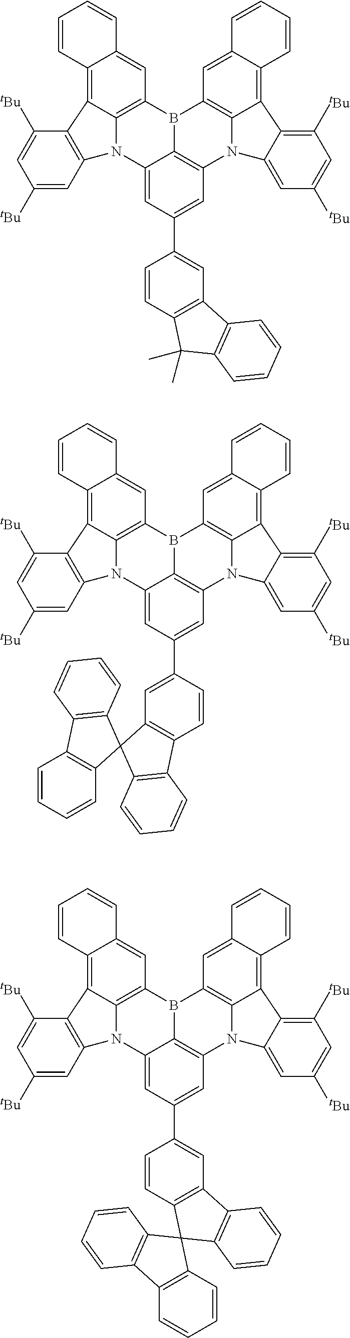

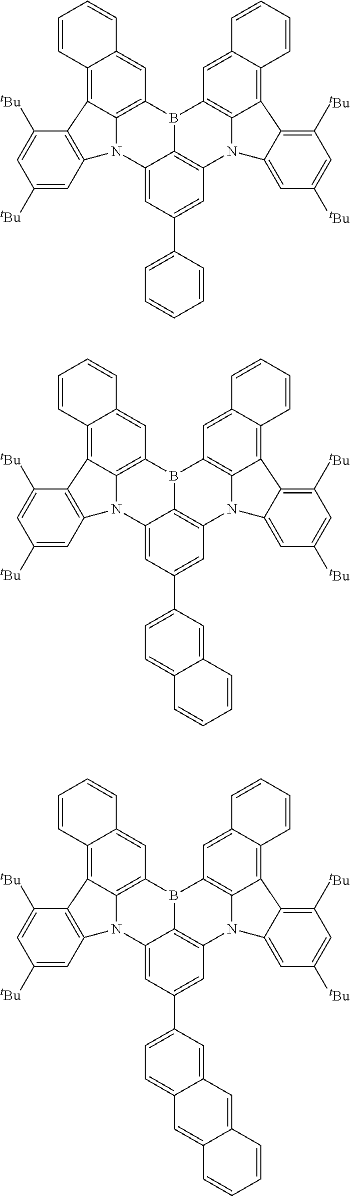 [SMILES: CC(C)(C)c1cc(C(C)(C)C)c2c3c4ccccc4cc4c3n(c2c1)-c1cc(-c2ccccc2)cc2c1B4c1cc3ccccc3c3c4c(C(C)(C)C)cc(C(C)(C)C)cc4n-2c13 ; CC(C)(C)c1cc(C(C)(C)C)c2c3c4ccccc4cc4c3n(c2c1)-c1cc(-c2ccc3ccccc3c2)cc2c1B4c1cc3ccccc3c3c4c(C(C)(C)C)cc(C(C)(C)C)cc4n-2c13 ; CC(C)(C)c1cc(C(C)(C)C)c2c3c4ccccc4cc4c3n(c2c1)-c1cc(-c2ccc3cc5ccccc5cc3c2)cc2c1B4c1cc3ccccc3c3c4c(C(C)(C)C)cc(C(C)(C)C)cc4n-2c13]

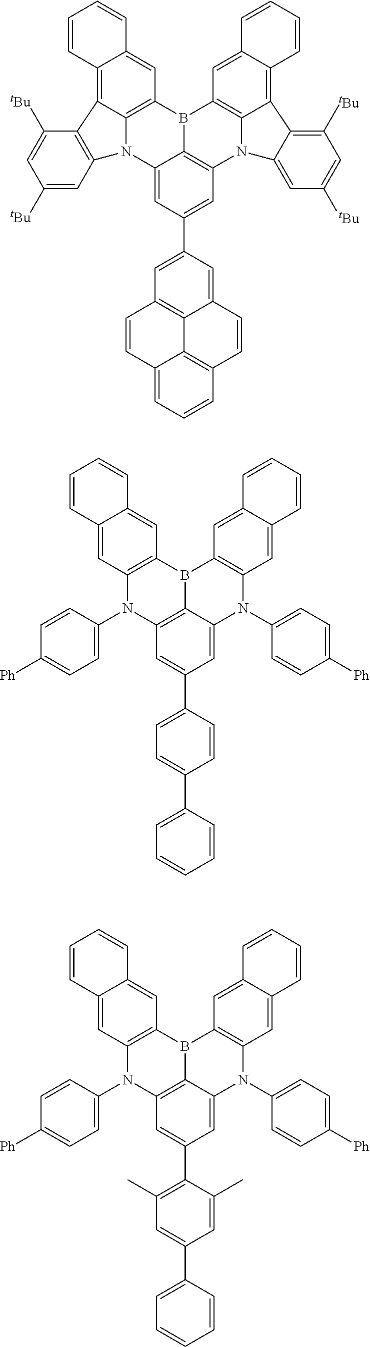 [SMILES: CC(C)(C)c1cc(C(C)(C)C)c2c3c4ccccc4cc4c3n(c2c1)-c1cc(-c2cc3ccc5cccc6ccc(c2)c3c56)cc2c1B4c1cc3ccccc3c3c4c(C(C)(C)C)cc(C(C)(C)C)cc4n-2c13 ; c1ccc(-c2ccc(-c3cc4c5c(c3)N(c3ccc(-c6ccccc6)cc3)c3cc6ccccc6cc3B5c3cc5ccccc5cc3N4c3ccc(-c4ccccc4)cc3)cc2)cc1 ; Cc1cc(-c2ccccc2)cc(C)c1-c1cc2c3c(c1)N(c1ccc(-c4ccccc4)cc1)c1cc4ccccc4cc1B3c1cc3ccccc3cc1N2c1ccc(-c2ccccc2)cc1]

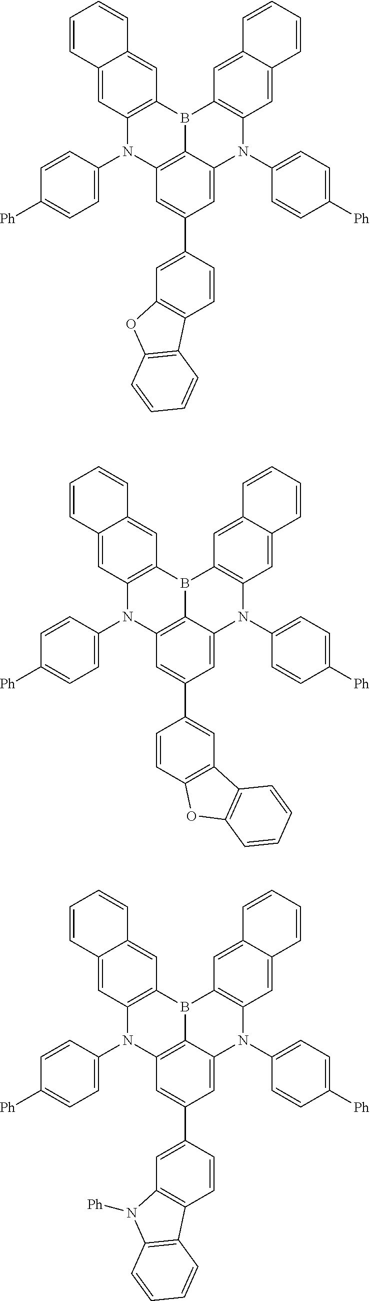 [SMILES: c1ccc(-c2ccc(N3c4cc5ccccc5cc4B4c5cc6ccccc6cc5N(c5ccc(-c6ccccc6)cc5)c5cc(-c6ccc7c(c6)oc6ccccc67)cc3c54)cc2)cc1 ; c1ccc(-c2ccc(N3c4cc5ccccc5cc4B4c5cc6ccccc6cc5N(c5ccc(-c6ccccc6)cc5)c5cc(-c6ccc7oc8ccccc8c7c6)cc3c54)cc2)cc1 ; c1ccc(-c2ccc(N3c4cc5ccccc5cc4B4c5cc6ccccc6cc5N(c5ccc(-c6ccccc6)cc5)c5cc(-c6ccc7c8ccccc8n(-c8ccccc8)c7c6)cc3c54)cc2)cc1]

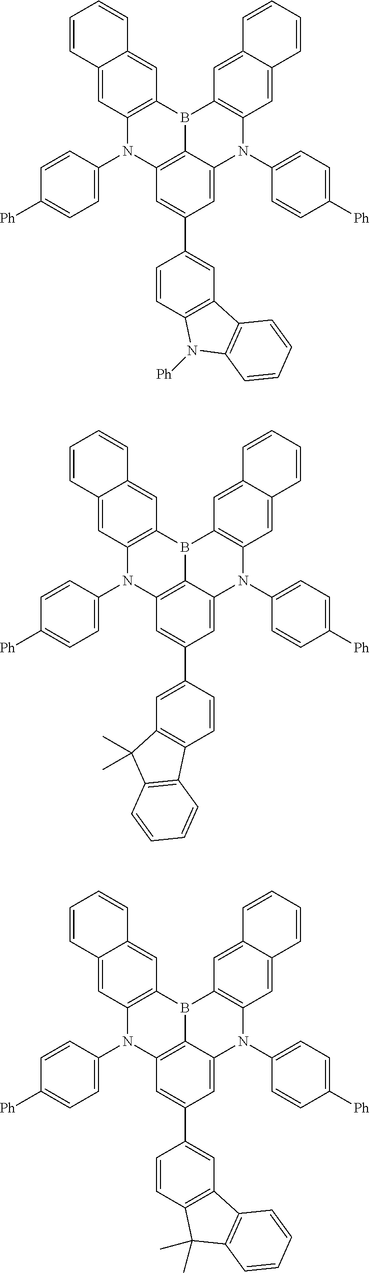 [SMILES: c1ccc(-c2ccc(N3c4cc5ccccc5cc4B4c5cc6ccccc6cc5N(c5ccc(-c6ccccc6)cc5)c5cc(-c6ccc7c(c6)c6ccccc6n7-c6ccccc6)cc3c54)cc2)cc1 ; CC1(C)c2ccccc2-c2ccc(-c3cc4c5c(c3)N(c3ccc(-c6ccccc6)cc3)c3cc6ccccc6cc3B5c3cc5ccccc5cc3N4c3ccc(-c4ccccc4)cc3)cc21 ; CC1(C)c2ccccc2-c2cc(-c3cc4c5c(c3)N(c3ccc(-c6ccccc6)cc3)c3cc6ccccc6cc3B5c3cc5ccccc5cc3N4c3ccc(-c4ccccc4)cc3)ccc21]

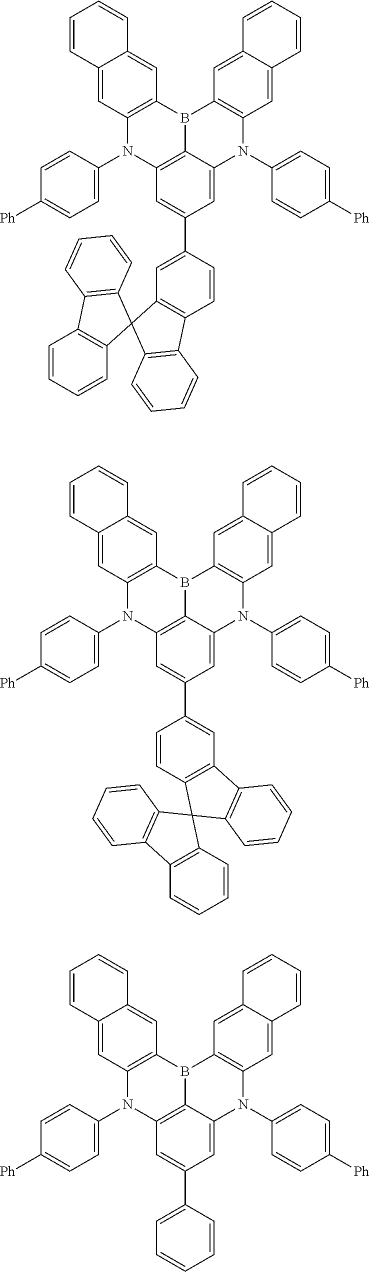 [SMILES: c1ccc(-c2ccc(N3c4cc5ccccc5cc4B4c5cc6ccccc6cc5N(c5ccc(-c6ccccc6)cc5)c5cc(-c6ccc7c(c6)C6(c8ccccc8-c8ccccc86)c6ccccc6-7)cc3c54)cc2)cc1 ; c1ccc(-c2ccc(N3c4cc5ccccc5cc4B4c5cc6ccccc6cc5N(c5ccc(-c6ccccc6)cc5)c5cc(-c6ccc7c(c6)-c6ccccc6C76c7ccccc7-c7ccccc76)cc3c54)cc2)cc1 ; c1ccc(-c2ccc(N3c4cc5ccccc5cc4B4c5cc6ccccc6cc5N(c5ccc(-c6ccccc6)cc5)c5cc(-c6ccccc6)cc3c54)cc2)cc1]

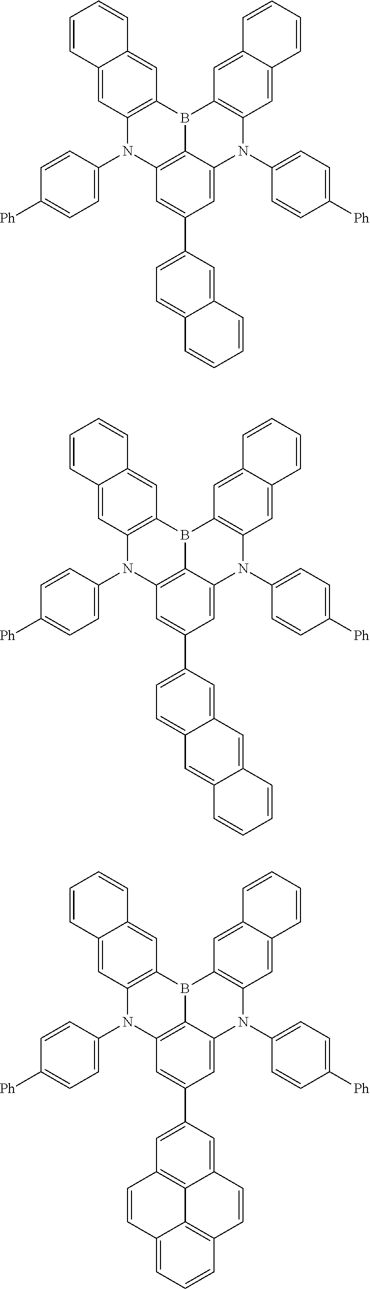

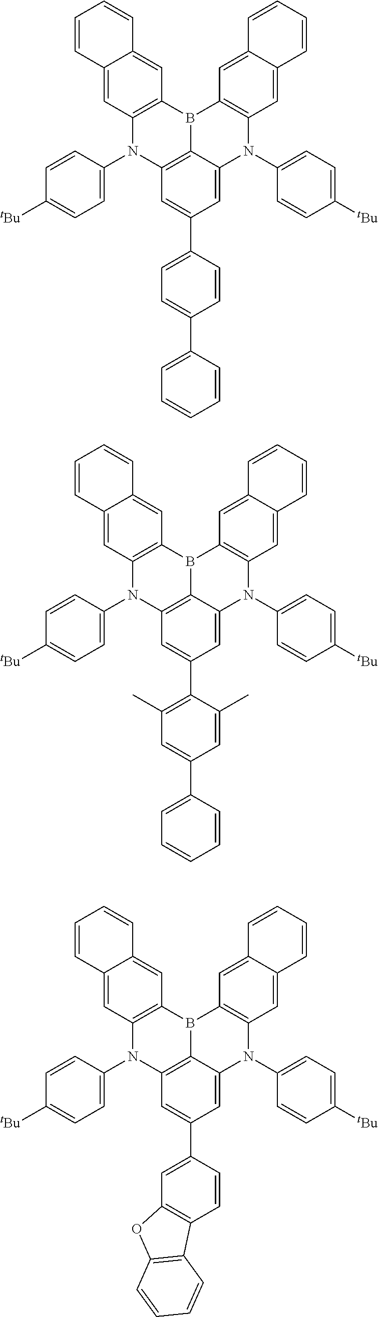 [SMILES: CC(C)(C)c1ccc(N2c3cc4ccccc4cc3B3c4cc5ccccc5cc4N(c4ccc(C(C)(C)C)cc4)c4cc(-c5ccc(-c6ccccc6)cc5)cc2c43)cc1 ; Cc1cc(-c2ccccc2)cc(C)c1-c1cc2c3c(c1)N(c1ccc(C(C)(C)C)cc1)c1cc4ccccc4cc1B3c1cc3ccccc3cc1N2c1ccc(C(C)(C)C)cc1 ; CC(C)(C)c1ccc(N2c3cc4ccccc4cc3B3c4cc5ccccc5cc4N(c4ccc(C(C)(C)C)cc4)c4cc(-c5ccc6c(c5)oc5ccccc56)cc2c43)cc1]

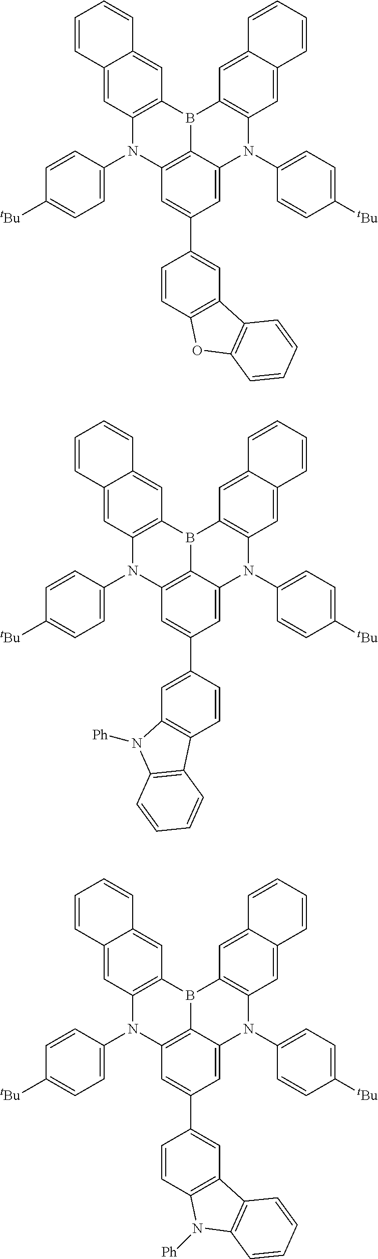

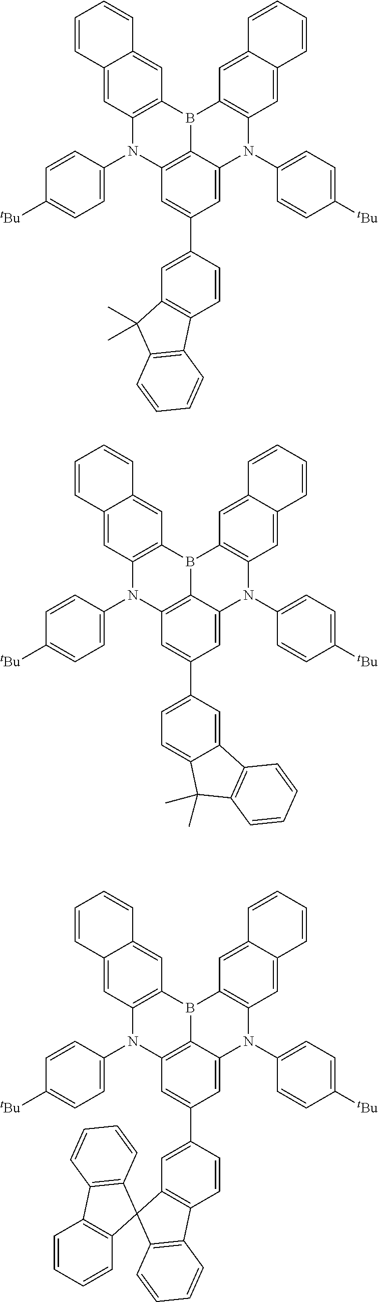 [SMILES: CC(C)(C)c1ccc(N2c3cc4ccccc4cc3B3c4cc5ccccc5cc4N(c4ccc(C(C)(C)C)cc4)c4cc(-c5ccc6c(c5)C(C)(C)c5ccccc5-6)cc2c43)cc1 ; CC(C)(C)c1ccc(N2c3cc4ccccc4cc3B3c4cc5ccccc5cc4N(c4ccc(C(C)(C)C)cc4)c4cc(-c5ccc6c(c5)-c5ccccc5C6(C)C)cc2c43)cc1 ; CC(C)(C)c1ccc(N2c3cc4ccccc4cc3B3c4cc5ccccc5cc4N(c4ccc(C(C)(C)C)cc4)c4cc(-c5ccc6c(c5)C5(c7ccccc7-c7ccccc75)c5ccccc5-6)cc2c43)cc1]

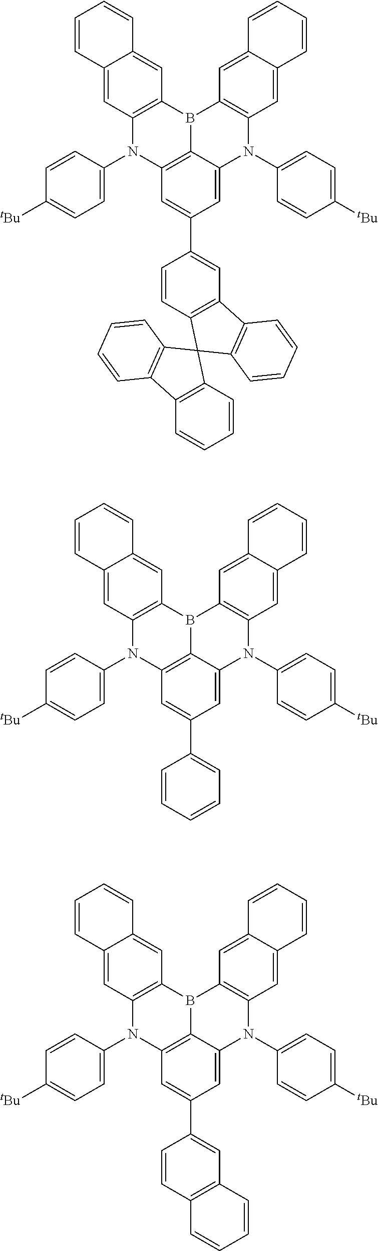 [SMILES: CC(C)(C)c1ccc(N2c3cc4ccccc4cc3B3c4cc5ccccc5cc4N(c4ccc(C(C)(C)C)cc4)c4cc(-c5ccc6c(c5)-c5ccccc5C65c6ccccc6-c6ccccc65)cc2c43)cc1 ; CC(C)(C)c1ccc(N2c3cc4ccccc4cc3B3c4cc5ccccc5cc4N(c4ccc(C(C)(C)C)cc4)c4cc(-c5ccccc5)cc2c43)cc1 ; CC(C)(C)c1ccc(N2c3cc4ccccc4cc3B3c4cc5ccccc5cc4N(c4ccc(C(C)(C)C)cc4)c4cc(-c5ccc6ccccc6c5)cc2c43)cc1]

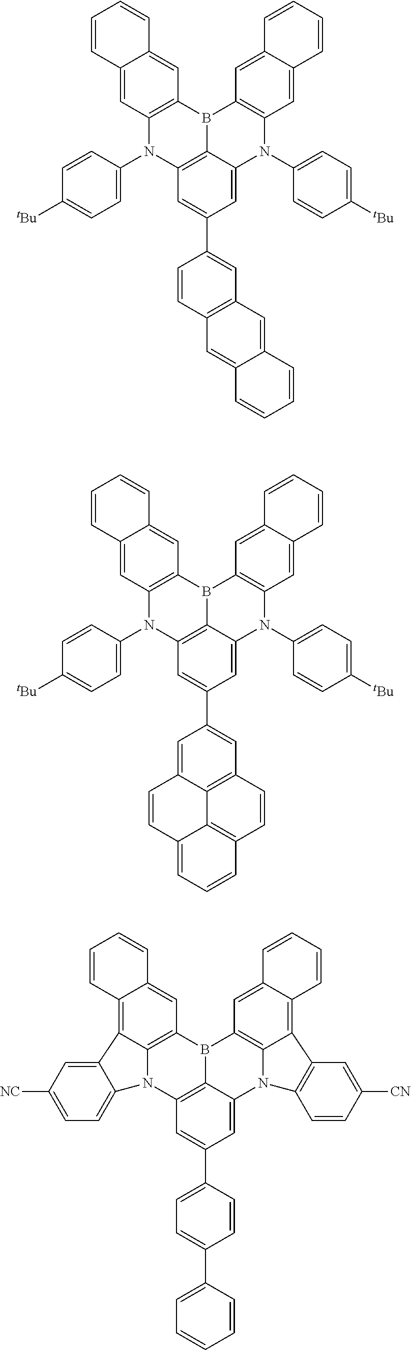 [SMILES: CC(C)(C)c1ccc(N2c3cc4ccccc4cc3B3c4cc5ccccc5cc4N(c4ccc(C(C)(C)C)cc4)c4cc(-c5ccc6cc7ccccc7cc6c5)cc2c43)cc1 ; CC(C)(C)c1ccc(N2c3cc4ccccc4cc3B3c4cc5ccccc5cc4N(c4ccc(C(C)(C)C)cc4)c4cc(-c5cc6ccc7cccc8ccc(c5)c6c78)cc2c43)cc1 ; N#Cc1ccc2c(c1)c1c3ccccc3cc3c1n2-c1cc(-c2ccc(-c4ccccc4)cc2)cc2c1B3c1cc3ccccc3c3c4cc(C#N)ccc4n-2c13]

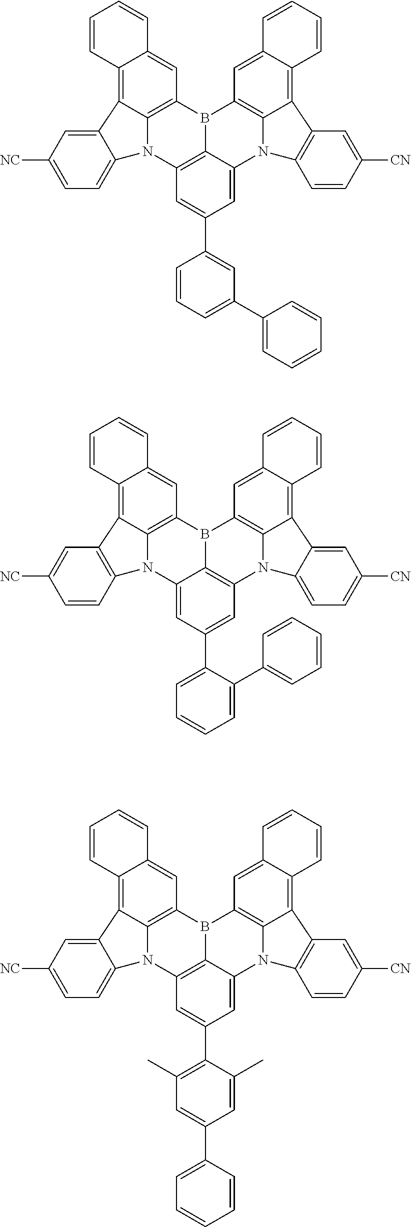 [SMILES: N#Cc1ccc2c(c1)c1c3ccccc3cc3c1n2-c1cc(-c2cccc(-c4ccccc4)c2)cc2c1B3c1cc3ccccc3c3c4cc(C#N)ccc4n-2c13 ; N#Cc1ccc2c(c1)c1c3ccccc3cc3c1n2-c1cc(-c2ccccc2-c2ccccc2)cc2c1B3c1cc3ccccc3c3c4cc(C#N)ccc4n-2c13 ; Cc1cc(-c2ccccc2)cc(C)c1-c1cc2c3c(c1)-n1c4ccc(C#N)cc4c4c5ccccc5cc(c41)B3c1cc3ccccc3c3c4cc(C#N)ccc4n-2c13]

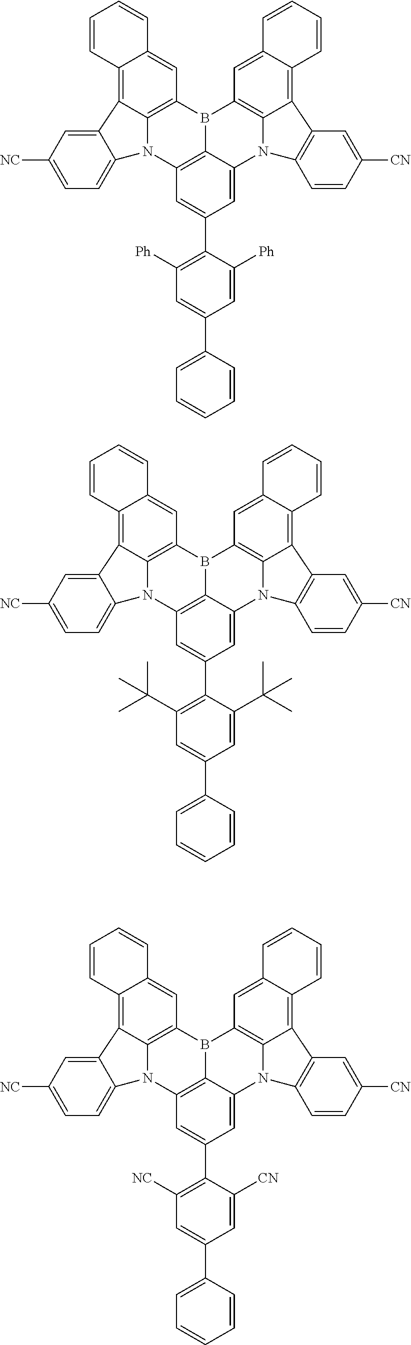 [SMILES: N#Cc1ccc2c(c1)c1c3ccccc3cc3c1n2-c1cc(-c2c(-c4ccccc4)cc(-c4ccccc4)cc2-c2ccccc2)cc2c1B3c1cc3ccccc3c3c4cc(C#N)ccc4n-2c13 ; CC(C)(C)c1cc(-c2ccccc2)cc(C(C)(C)C)c1-c1cc2c3c(c1)-n1c4ccc(C#N)cc4c4c5ccccc5cc(c41)B3c1cc3ccccc3c3c4cc(C#N)ccc4n-2c13 ; N#Cc1ccc2c(c1)c1c3ccccc3cc3c1n2-c1cc(-c2c(C#N)cc(-c4ccccc4)cc2C#N)cc2c1B3c1cc3ccccc3c3c4cc(C#N)ccc4n-2c13]

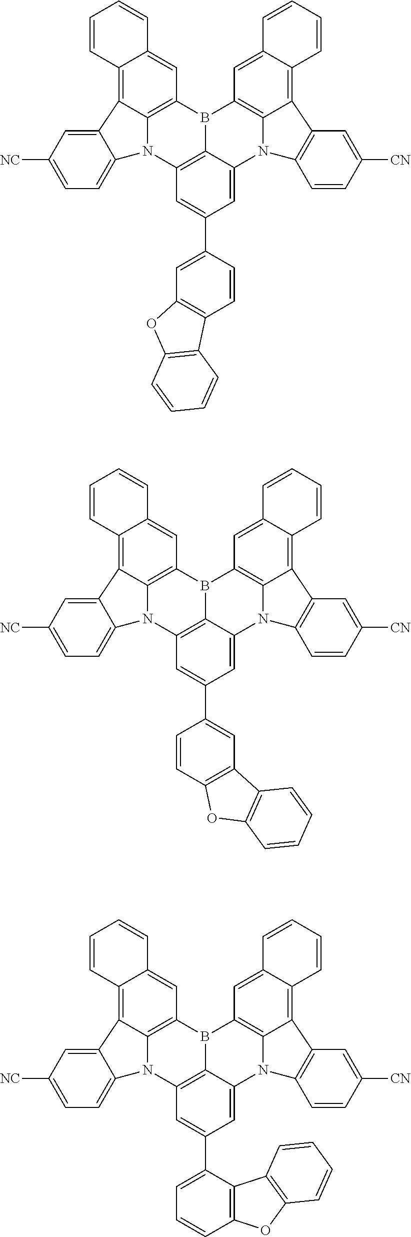 [SMILES: N#Cc1ccc2c(c1)c1c3ccccc3cc3c1n2-c1cc(-c2ccc4c(c2)oc2ccccc24)cc2c1B3c1cc3ccccc3c3c4cc(C#N)ccc4n-2c13 ; N#Cc1ccc2c(c1)c1c3ccccc3cc3c1n2-c1cc(-c2ccc4oc5ccccc5c4c2)cc2c1B3c1cc3ccccc3c3c4cc(C#N)ccc4n-2c13 ; N#Cc1ccc2c(c1)c1c3ccccc3cc3c1n2-c1cc(-c2cccc4oc5ccccc5c24)cc2c1B3c1cc3ccccc3c3c4cc(C#N)ccc4n-2c13]

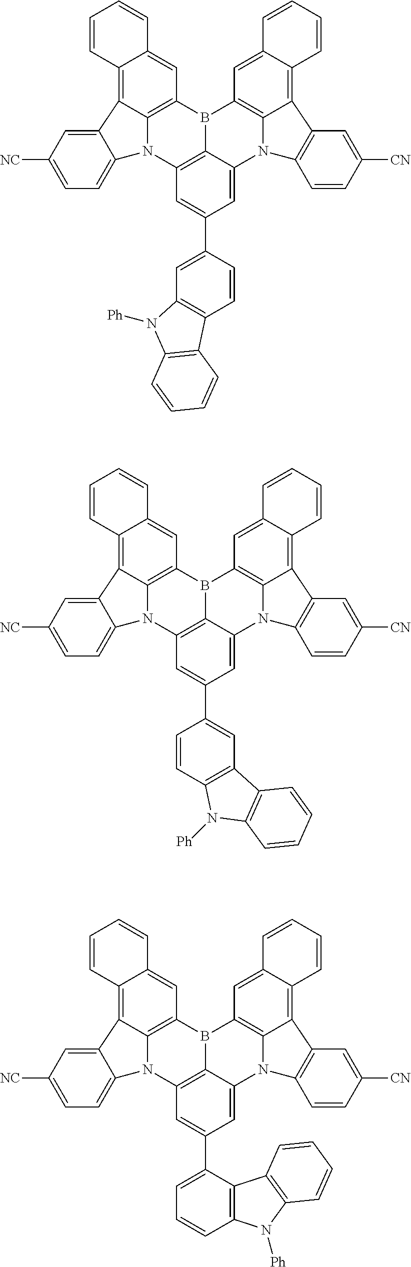 [SMILES: N#Cc1ccc2c(c1)c1c3ccccc3cc3c1n2-c1cc(-c2ccc4c5ccccc5n(-c5ccccc5)c4c2)cc2c1B3c1cc3ccccc3c3c4cc(C#N)ccc4n-2c13 ; N#Cc1ccc2c(c1)c1c3ccccc3cc3c1n2-c1cc(-c2ccc4c(c2)c2ccccc2n4-c2ccccc2)cc2c1B3c1cc3ccccc3c3c4cc(C#N)ccc4n-2c13 ; N#Cc1ccc2c(c1)c1c3ccccc3cc3c1n2-c1cc(-c2cccc4c2c2ccccc2n4-c2ccccc2)cc2c1B3c1cc3ccccc3c3c4cc(C#N)ccc4n-2c13]

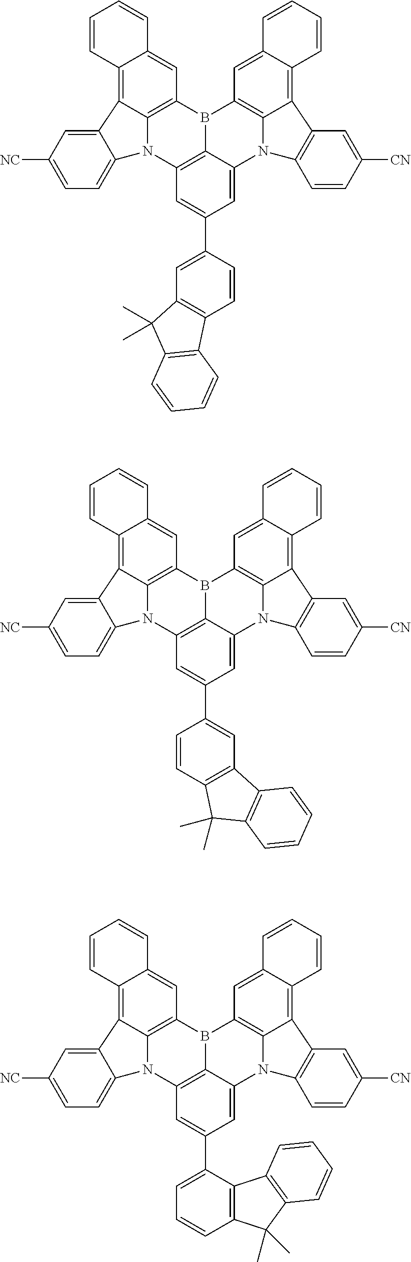 [SMILES: CC1(C)c2ccccc2-c2ccc(-c3cc4c5c(c3)-n3c6ccc(C#N)cc6c6c7ccccc7cc(c63)B5c3cc5ccccc5c5c6cc(C#N)ccc6n-4c35)cc21 ; CC1(C)c2ccccc2-c2cc(-c3cc4c5c(c3)-n3c6ccc(C#N)cc6c6c7ccccc7cc(c63)B5c3cc5ccccc5c5c6cc(C#N)ccc6n-4c35)ccc21 ; CC1(C)c2ccccc2-c2c(-c3cc4c5c(c3)-n3c6ccc(C#N)cc6c6c7ccccc7cc(c63)B5c3cc5ccccc5c5c6cc(C#N)ccc6n-4c35)cccc21]

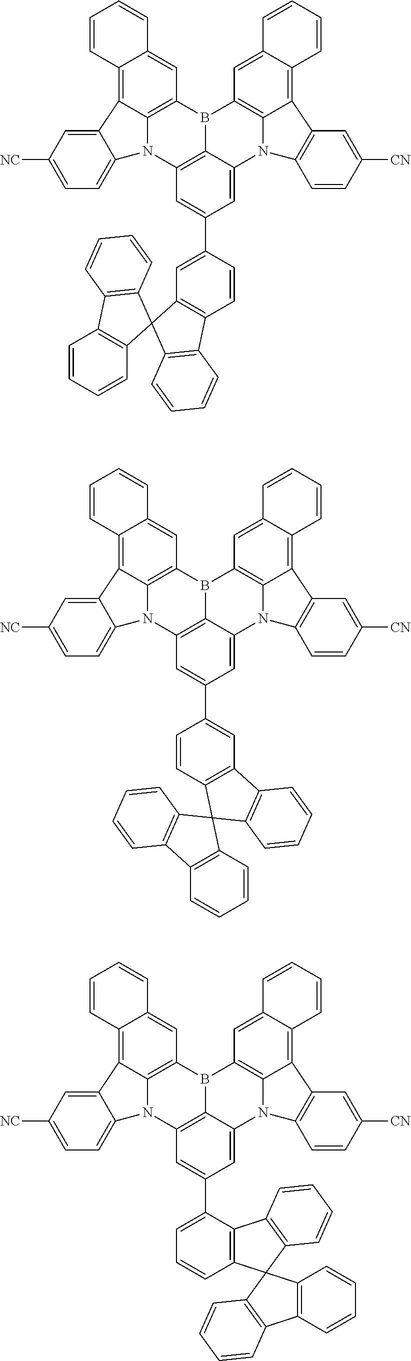 [SMILES: N#Cc1ccc2c(c1)c1c3ccccc3cc3c1n2-c1cc(-c2ccc4c(c2)C2(c5ccccc5-c5ccccc52)c2ccccc2-4)cc2c1B3c1cc3ccccc3c3c4cc(C#N)ccc4n-2c13 ; N#Cc1ccc2c(c1)c1c3ccccc3cc3c1n2-c1cc(-c2ccc4c(c2)-c2ccccc2C42c4ccccc4-c4ccccc42)cc2c1B3c1cc3ccccc3c3c4cc(C#N)ccc4n-2c13 ; N#Cc1ccc2c(c1)c1c3ccccc3cc3c1n2-c1cc(-c2cccc4c2-c2ccccc2C42c4ccccc4-c4ccccc42)cc2c1B3c1cc3ccccc3c3c4cc(C#N)ccc4n-2c13]

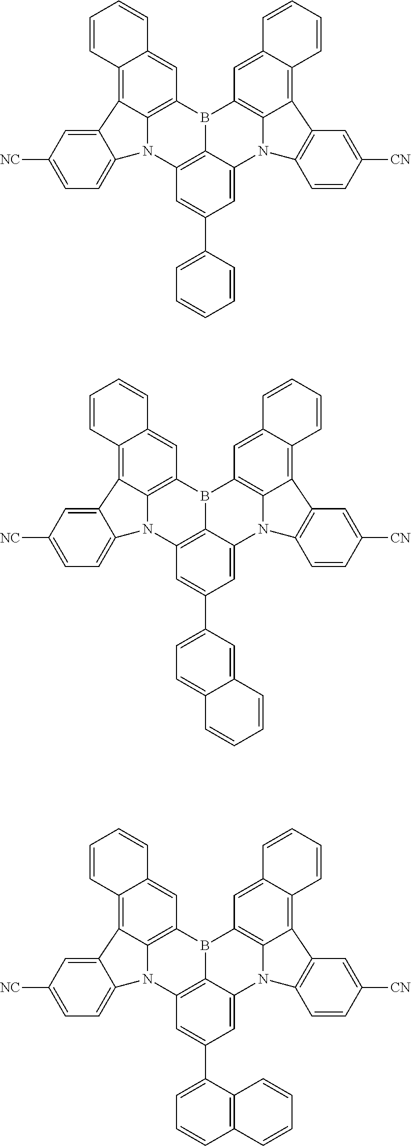 [SMILES: N#Cc1ccc2c(c1)c1c3ccccc3cc3c1n2-c1cc(-c2ccccc2)cc2c1B3c1cc3ccccc3c3c4cc(C#N)ccc4n-2c13 ; N#Cc1ccc2c(c1)c1c3ccccc3cc3c1n2-c1cc(-c2ccc4ccccc4c2)cc2c1B3c1cc3ccccc3c3c4cc(C#N)ccc4n-2c13 ; N#Cc1ccc2c(c1)c1c3ccccc3cc3c1n2-c1cc(-c2cccc4ccccc24)cc2c1B3c1cc3ccccc3c3c4cc(C#N)ccc4n-2c13]

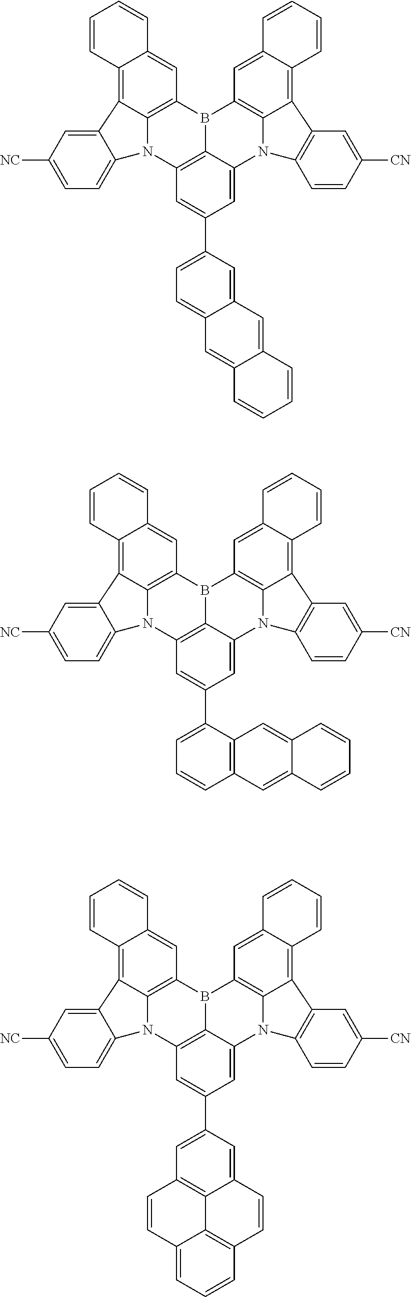 [SMILES: N#Cc1ccc2c(c1)c1c3ccccc3cc3c1n2-c1cc(-c2ccc4cc5ccccc5cc4c2)cc2c1B3c1cc3ccccc3c3c4cc(C#N)ccc4n-2c13 ; N#Cc1ccc2c(c1)c1c3ccccc3cc3c1n2-c1cc(-c2cccc4cc5ccccc5cc24)cc2c1B3c1cc3ccccc3c3c4cc(C#N)ccc4n-2c13 ; N#Cc1ccc2c(c1)c1c3ccccc3cc3c1n2-c1cc(-c2cc4ccc5cccc6ccc(c2)c4c56)cc2c1B3c1cc3ccccc3c3c4cc(C#N)ccc4n-2c13]

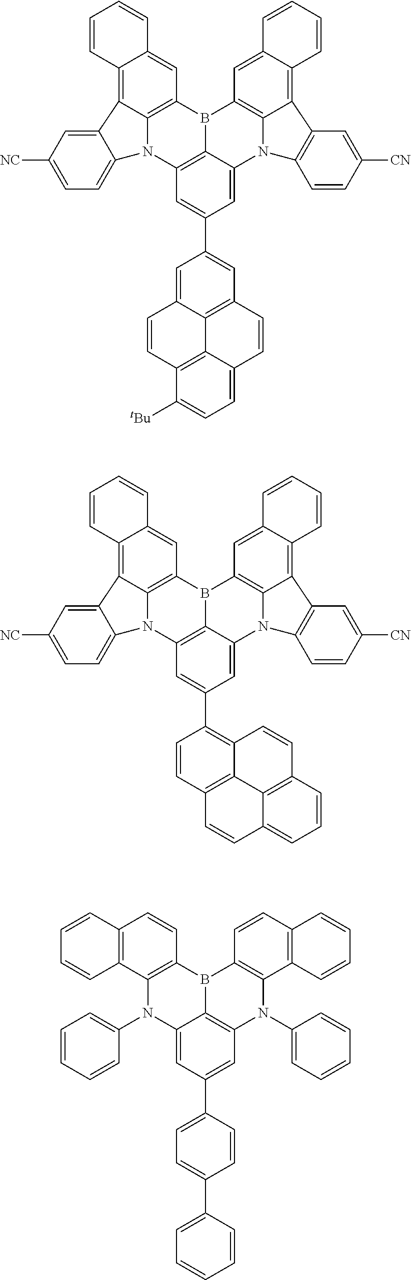 [SMILES: CC(C)(C)c1ccc2ccc3cc(-c4cc5c6c(c4)-n4c7ccc(C#N)cc7c7c8ccccc8cc(c74)B6c4cc6ccccc6c6c7cc(C#N)ccc7n-5c46)cc4ccc1c2c34 ; N#Cc1ccc2c(c1)c1c3ccccc3cc3c1n2-c1cc(-c2ccc4ccc5cccc6ccc2c4c56)cc2c1B3c1cc3ccccc3c3c4cc(C#N)ccc4n-2c13 ; c1ccc(-c2ccc(-c3cc4c5c(c3)N(c3ccccc3)c3c(ccc6ccccc36)B5c3ccc5ccccc5c3N4c3ccccc3)cc2)cc1]

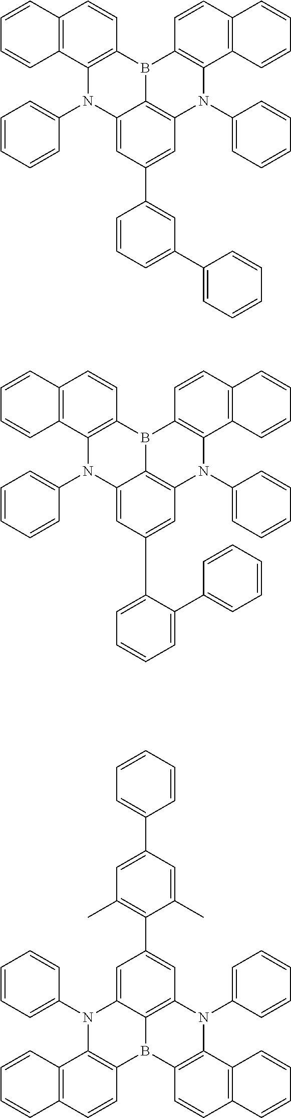 [SMILES: c1ccc(-c2cccc(-c3cc4c5c(c3)N(c3ccccc3)c3c(ccc6ccccc36)B5c3ccc5ccccc5c3N4c3ccccc3)c2)cc1 ; c1ccc(-c2ccccc2-c2cc3c4c(c2)N(c2ccccc2)c2c(ccc5ccccc25)B4c2ccc4ccccc4c2N3c2ccccc2)cc1 ; Cc1cc(-c2ccccc2)cc(C)c1-c1cc2c3c(c1)N(c1ccccc1)c1c(ccc4ccccc14)B3c1ccc3ccccc3c1N2c1ccccc1]

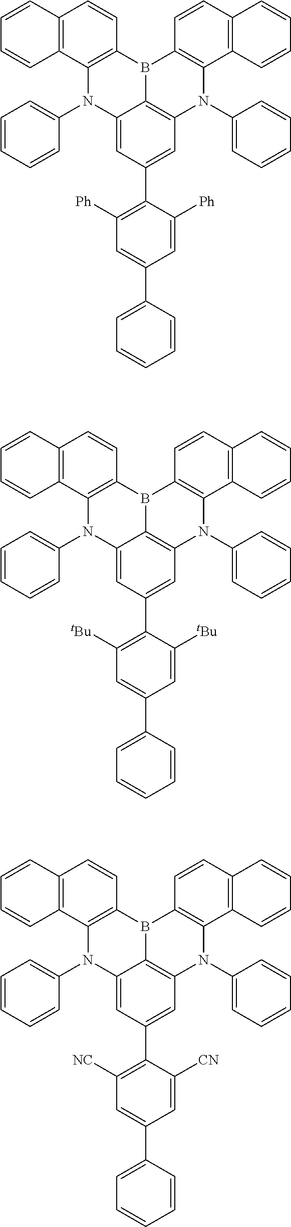 [SMILES: c1ccc(-c2cc(-c3ccccc3)c(-c3cc4c5c(c3)N(c3ccccc3)c3c(ccc6ccccc36)B5c3ccc5ccccc5c3N4c3ccccc3)c(-c3ccccc3)c2)cc1 ; CC(C)(C)c1cc(-c2ccccc2)cc(C(C)(C)C)c1-c1cc2c3c(c1)N(c1ccccc1)c1c(ccc4ccccc14)B3c1ccc3ccccc3c1N2c1ccccc1 ; N#Cc1cc(-c2ccccc2)cc(C#N)c1-c1cc2c3c(c1)N(c1ccccc1)c1c(ccc4ccccc14)B3c1ccc3ccccc3c1N2c1ccccc1]

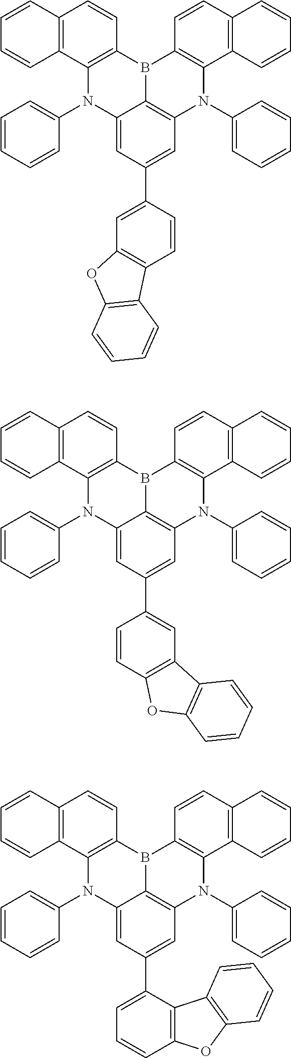 [SMILES: c1ccc(N2c3cc(-c4ccc5c(c4)oc4ccccc45)cc4c3B(c3ccc5ccccc5c32)c2ccc3ccccc3c2N4c2ccccc2)cc1 ; c1ccc(N2c3cc(-c4ccc5oc6ccccc6c5c4)cc4c3B(c3ccc5ccccc5c32)c2ccc3ccccc3c2N4c2ccccc2)cc1 ; c1ccc(N2c3cc(-c4cccc5oc6ccccc6c45)cc4c3B(c3ccc5ccccc5c32)c2ccc3ccccc3c2N4c2ccccc2)cc1]

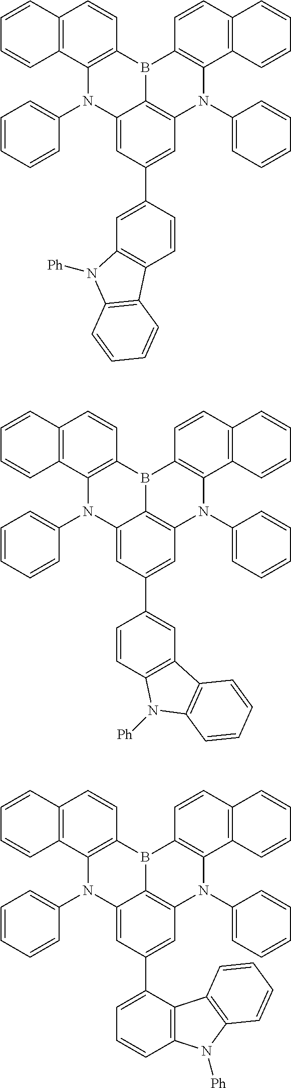 [SMILES: c1ccc(N2c3cc(-c4ccc5c6ccccc6n(-c6ccccc6)c5c4)cc4c3B(c3ccc5ccccc5c32)c2ccc3ccccc3c2N4c2ccccc2)cc1 ; c1ccc(N2c3cc(-c4ccc5c(c4)c4ccccc4n5-c4ccccc4)cc4c3B(c3ccc5ccccc5c32)c2ccc3ccccc3c2N4c2ccccc2)cc1 ; c1ccc(N2c3cc(-c4cccc5c4c4ccccc4n5-c4ccccc4)cc4c3B(c3ccc5ccccc5c32)c2ccc3ccccc3c2N4c2ccccc2)cc1]

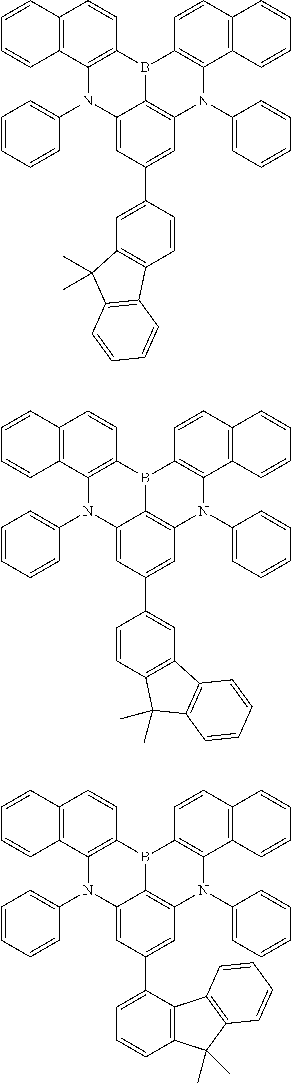 [SMILES: CC1(C)c2ccccc2-c2ccc(-c3cc4c5c(c3)N(c3ccccc3)c3c(ccc6ccccc36)B5c3ccc5ccccc5c3N4c3ccccc3)cc21 ; CC1(C)c2ccccc2-c2cc(-c3cc4c5c(c3)N(c3ccccc3)c3c(ccc6ccccc36)B5c3ccc5ccccc5c3N4c3ccccc3)ccc21 ; CC1(C)c2ccccc2-c2c(-c3cc4c5c(c3)N(c3ccccc3)c3c(ccc6ccccc36)B5c3ccc5ccccc5c3N4c3ccccc3)cccc21]

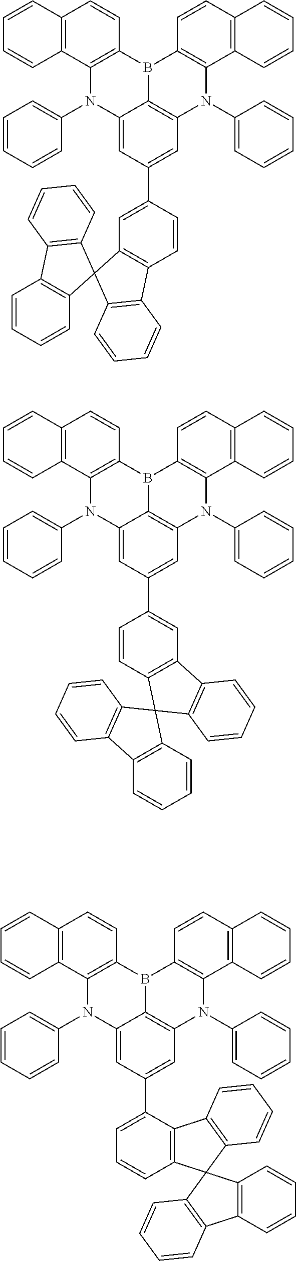 [SMILES: c1ccc(N2c3cc(-c4ccc5c(c4)C4(c6ccccc6-c6ccccc64)c4ccccc4-5)cc4c3B(c3ccc5ccccc5c32)c2ccc3ccccc3c2N4c2ccccc2)cc1 ; c1ccc(N2c3cc(-c4ccc5c(c4)-c4ccccc4C54c5ccccc5-c5ccccc54)cc4c3B(c3ccc5ccccc5c32)c2ccc3ccccc3c2N4c2ccccc2)cc1 ; c1ccc(N2c3cc(-c4cccc5c4-c4ccccc4C54c5ccccc5-c5ccccc54)cc4c3B(c3ccc5ccccc5c32)c2ccc3ccccc3c2N4c2ccccc2)cc1]

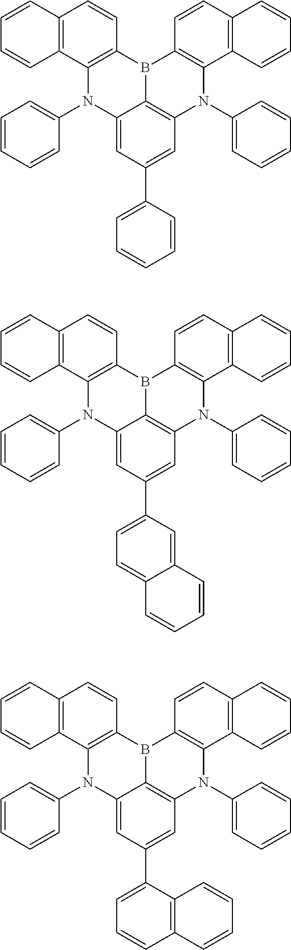 [SMILES: c1ccc(-c2cc3c4c(c2)N(c2ccccc2)c2c(ccc5ccccc25)B4c2ccc4ccccc4c2N3c2ccccc2)cc1 ; c1ccc(N2c3cc(-c4ccc5ccccc5c4)cc4c3B(c3ccc5ccccc5c32)c2ccc3ccccc3c2N4c2ccccc2)cc1 ; c1ccc(N2c3cc(-c4cccc5ccccc45)cc4c3B(c3ccc5ccccc5c32)c2ccc3ccccc3c2N4c2ccccc2)cc1]

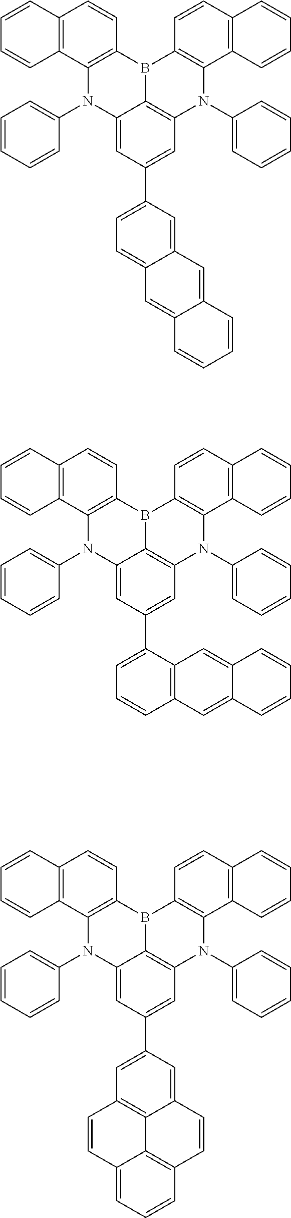 [SMILES: c1ccc(N2c3cc(-c4ccc5cc6ccccc6cc5c4)cc4c3B(c3ccc5ccccc5c32)c2ccc3ccccc3c2N4c2ccccc2)cc1 ; c1ccc(N2c3cc(-c4cccc5cc6ccccc6cc45)cc4c3B(c3ccc5ccccc5c32)c2ccc3ccccc3c2N4c2ccccc2)cc1 ; c1ccc(N2c3cc(-c4cc5ccc6cccc7ccc(c4)c5c67)cc4c3B(c3ccc5ccccc5c32)c2ccc3ccccc3c2N4c2ccccc2)cc1]

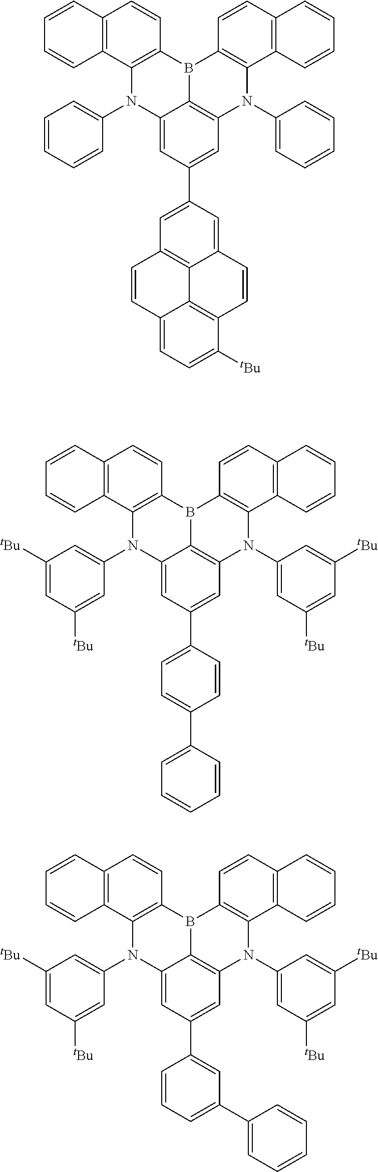 [SMILES: CC(C)(C)c1ccc2ccc3cc(-c4cc5c6c(c4)N(c4ccccc4)c4c(ccc7ccccc47)B6c4ccc6ccccc6c4N5c4ccccc4)cc4ccc1c2c34 ; CC(C)(C)c1cc(N2c3cc(-c4ccc(-c5ccccc5)cc4)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4cccc(-c5ccccc5)c4)cc4c3B(c3ccc5ccccc5c32)c2ccc3ccccc3c2N4c2cc(C(C)(C)C)cc(C(C)(C)C)c2)cc(C(C)(C)C)c1]

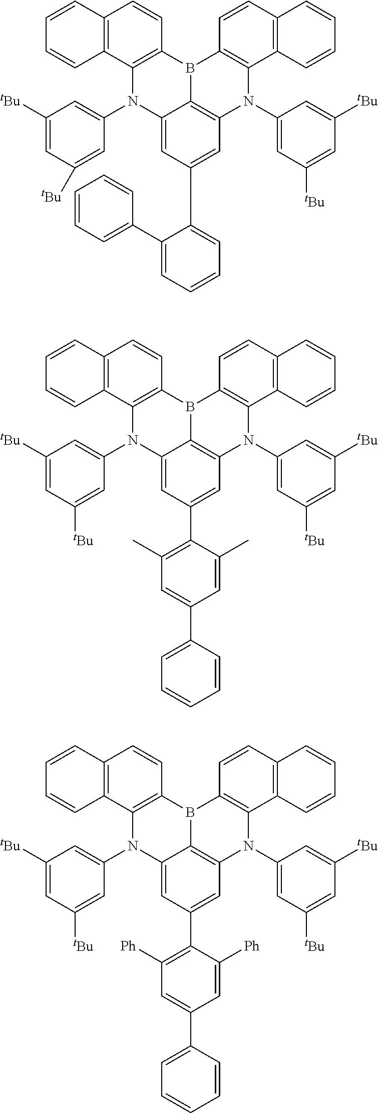 [SMILES: CC(C)(C)c1cc(N2c3cc(-c4ccccc4-c4ccccc4)cc4c3B(c3ccc5ccccc5c32)c2ccc3ccccc3c2N4c2cc(C(C)(C)C)cc(C(C)(C)C)c2)cc(C(C)(C)C)c1 ; Cc1cc(-c2ccccc2)cc(C)c1-c1cc2c3c(c1)N(c1cc(C(C)(C)C)cc(C(C)(C)C)c1)c1c(ccc4ccccc14)B3c1ccc3ccccc3c1N2c1cc(C(C)(C)C)cc(C(C)(C)C)c1 ; CC(C)(C)c1cc(N2c3cc(-c4c(-c5ccccc5)cc(-c5ccccc5)cc4-c4ccccc4)cc4c3B(c3ccc5ccccc5c32)c2ccc3ccccc3c2N4c2cc(C(C)(C)C)cc(C(C)(C)C)c2)cc(C(C)(C)C)c1]

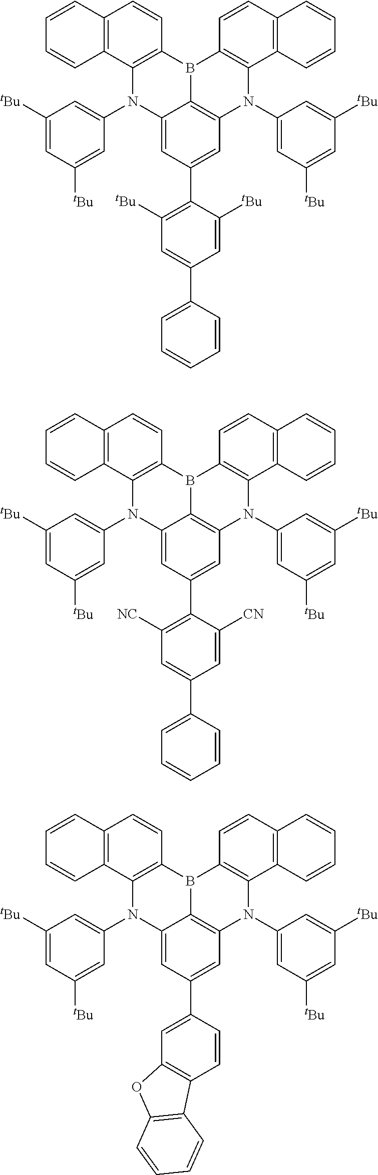 [SMILES: CC(C)(C)c1cc(N2c3cc(-c4c(C(C)(C)C)cc(-c5ccccc5)cc4C(C)(C)C)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4c(C#N)cc(-c5ccccc5)cc4C#N)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c(c4)oc4ccccc45)cc4c3B(c3ccc5ccccc5c32)c2ccc3ccccc3c2N4c2cc(C(C)(C)C)cc(C(C)(C)C)c2)cc(C(C)(C)C)c1]

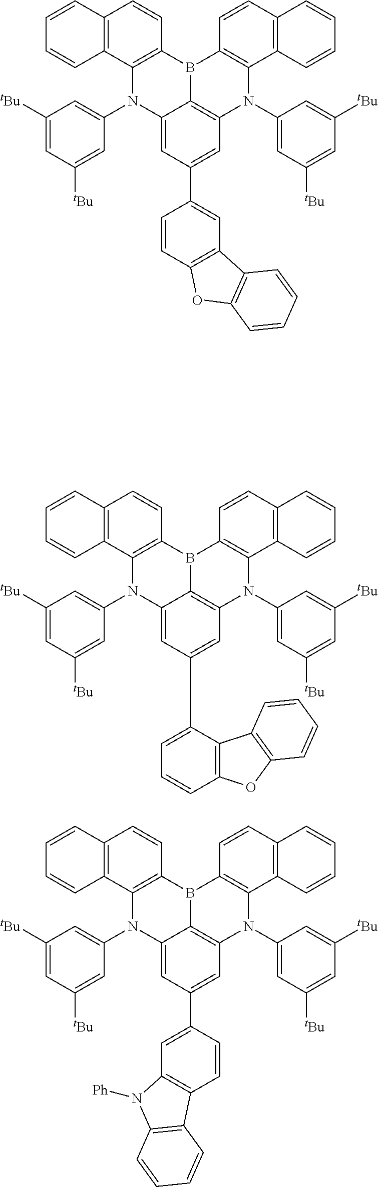

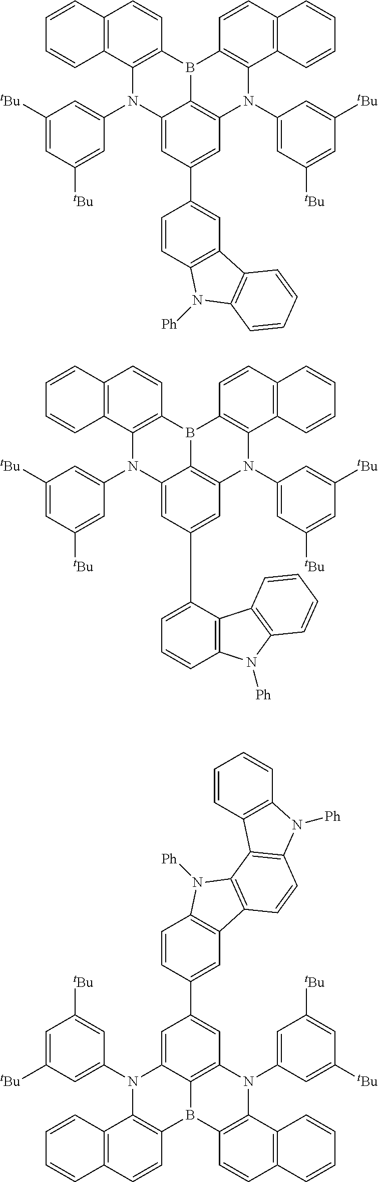

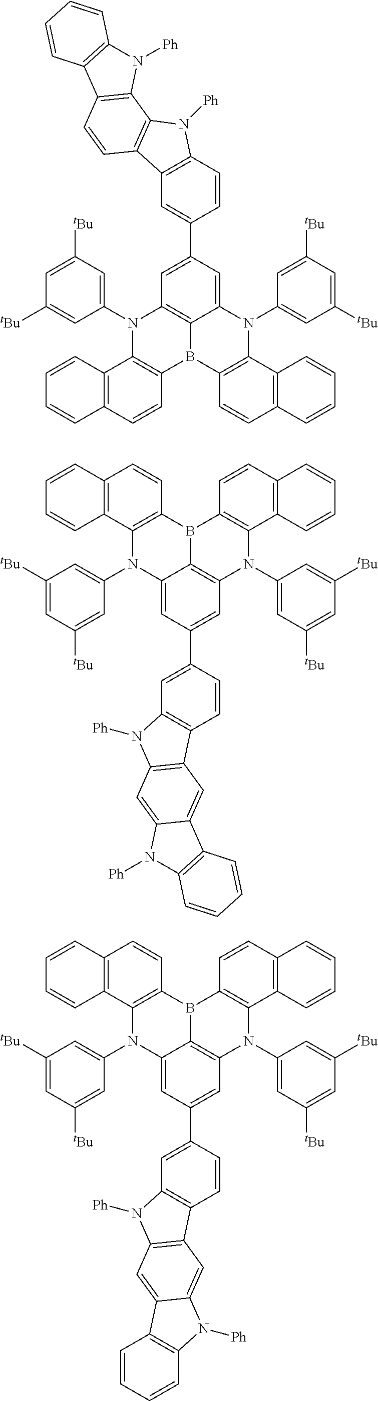

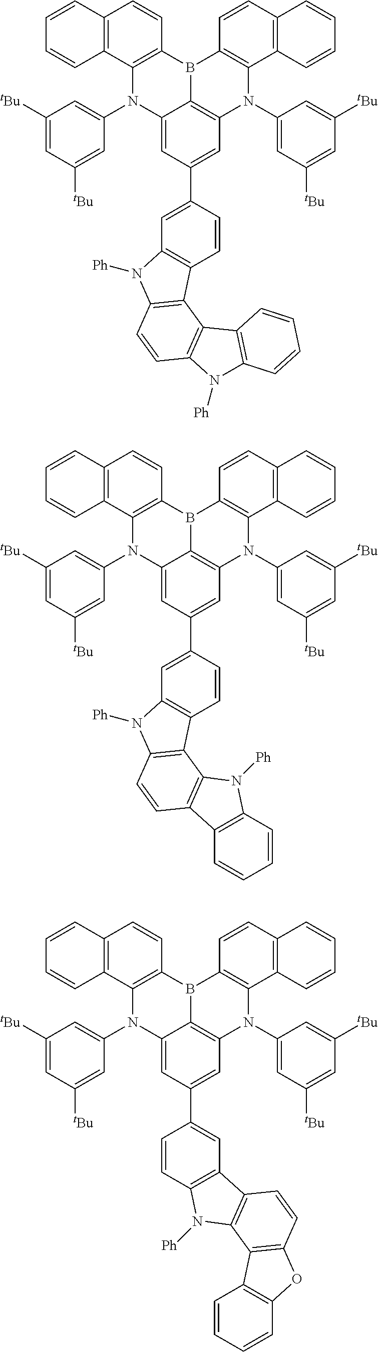

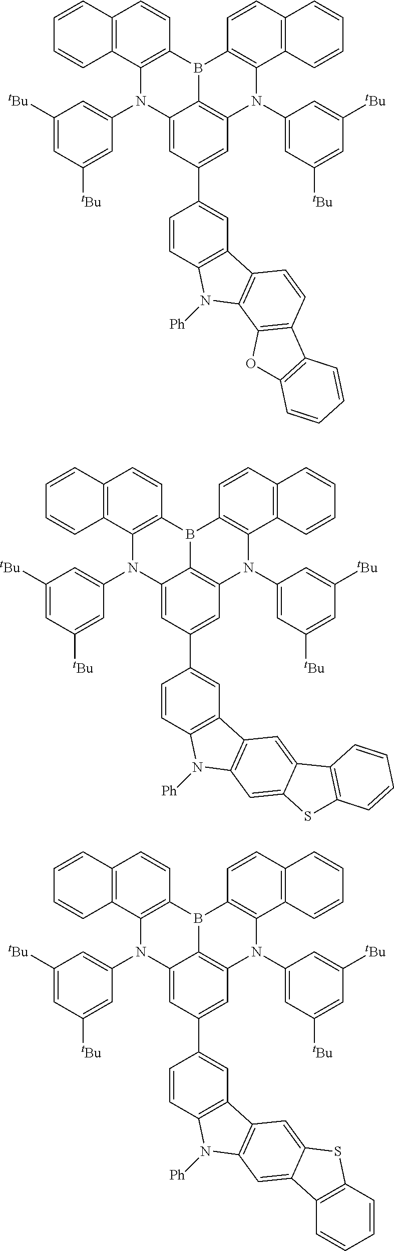

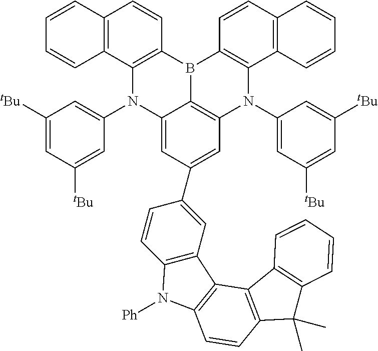 [SMILES: CC(C)(C)c1cc(N2c3cc(-c4ccc5c(c4)c4c6c(ccc4n5-c4ccccc4)C(C)(C)c4ccccc4-6)cc4c3B(c3ccc5ccccc5c32)c2ccc3ccccc3c2N4c2cc(C(C)(C)C)cc(C(C)(C)C)c2)cc(C(C)(C)C)c1]

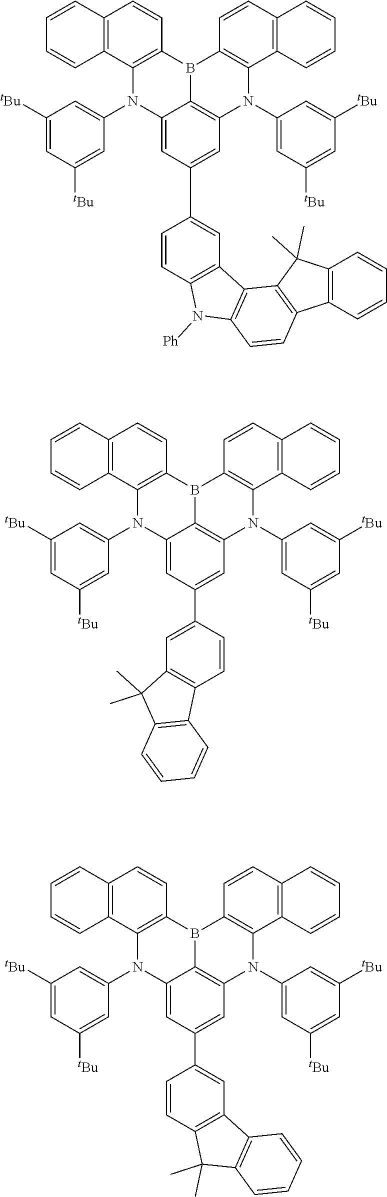 [SMILES: CC(C)(C)c1cc(N2c3cc(-c4ccc5c(c4)c4c6c(ccc4n5-c4ccccc4)-c4ccccc4C6(C)C)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c(c4)C(C)(C)c4ccccc4-5)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c(c4)-c4ccccc4C5(C)C)cc4c3B(c3ccc5ccccc5c32)c2ccc3ccccc3c2N4c2cc(C(C)(C)C)cc(C(C)(C)C)c2)cc(C(C)(C)C)c1]

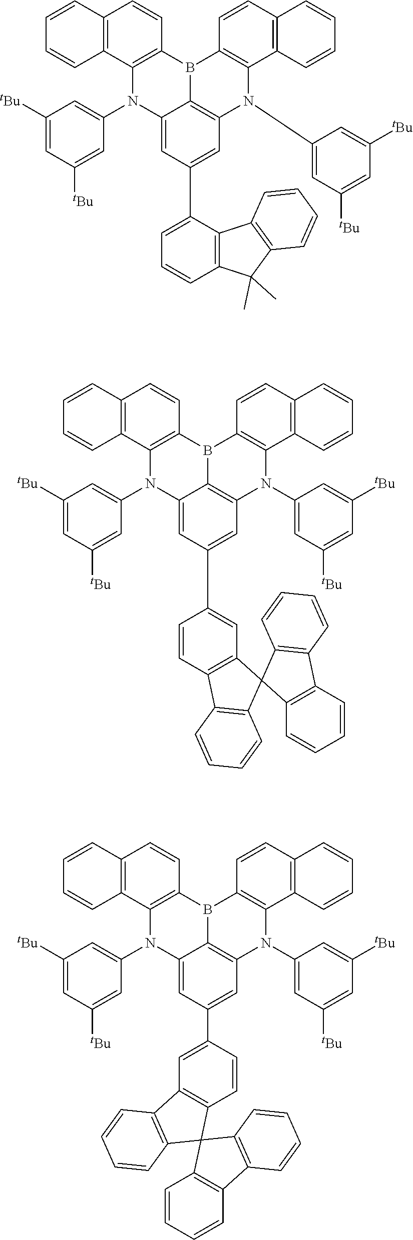 [SMILES: CC(C)(C)c1cc(N2c3cc(-c4cccc5c4-c4ccccc4C5(C)C)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c(c4)C4(c6ccccc6-c6ccccc64)c4ccccc4-5)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c(c4)-c4ccccc4C54c5ccccc5-c5ccccc54)cc4c3B(c3ccc5ccccc5c32)c2ccc3ccccc3c2N4c2cc(C(C)(C)C)cc(C(C)(C)C)c2)cc(C(C)(C)C)c1]

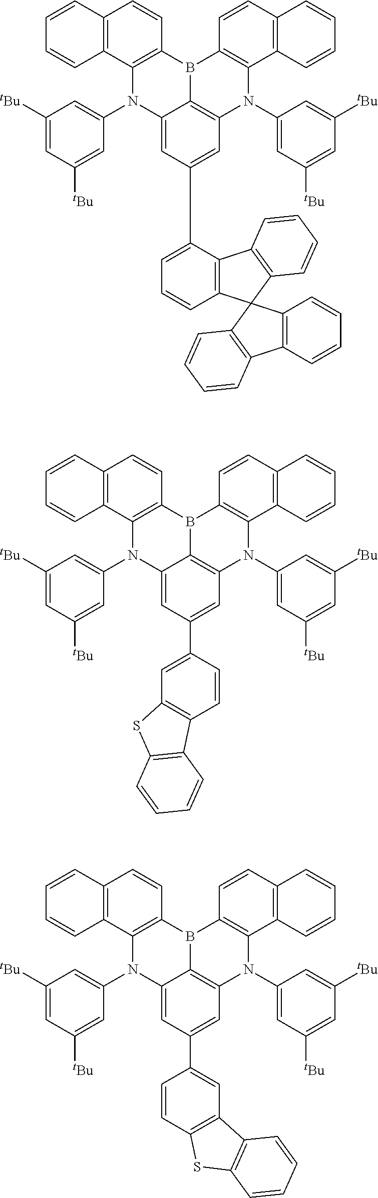 [SMILES: CC(C)(C)c1cc(N2c3cc(-c4cccc5c4-c4ccccc4C54c5ccccc5-c5ccccc54)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c(c4)sc4ccccc45)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5sc6ccccc6c5c4)cc4c3B(c3ccc5ccccc5c32)c2ccc3ccccc3c2N4c2cc(C(C)(C)C)cc(C(C)(C)C)c2)cc(C(C)(C)C)c1]

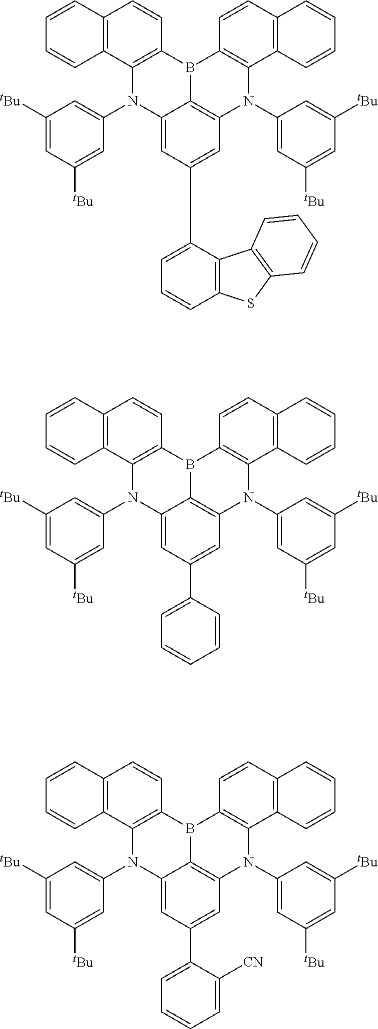 [SMILES: CC(C)(C)c1cc(N2c3cc(-c4cccc5sc6ccccc6c45)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccccc4)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccccc4C#N)cc4c3B(c3ccc5ccccc5c32)c2ccc3ccccc3c2N4c2cc(C(C)(C)C)cc(C(C)(C)C)c2)cc(C(C)(C)C)c1]

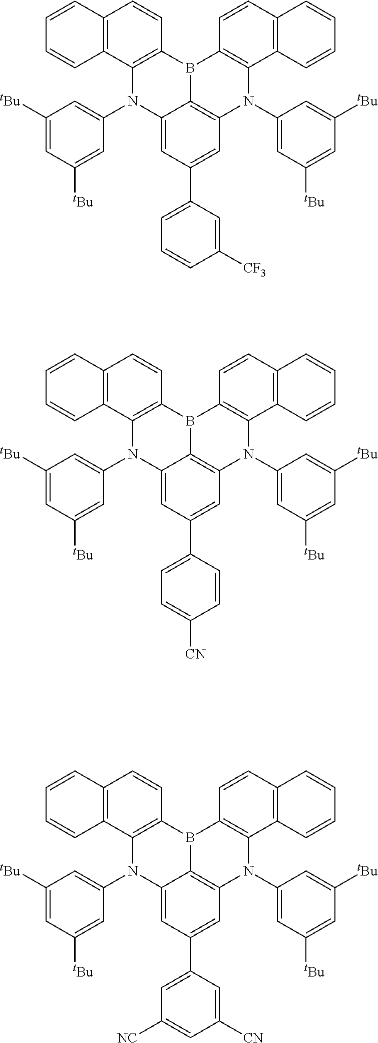 [SMILES: CC(C)(C)c1cc(N2c3cc(-c4cccc(C(F)(F)F)c4)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc(C#N)cc4)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4cc(C#N)cc(C#N)c4)cc4c3B(c3ccc5ccccc5c32)c2ccc3ccccc3c2N4c2cc(C(C)(C)C)cc(C(C)(C)C)c2)cc(C(C)(C)C)c1]

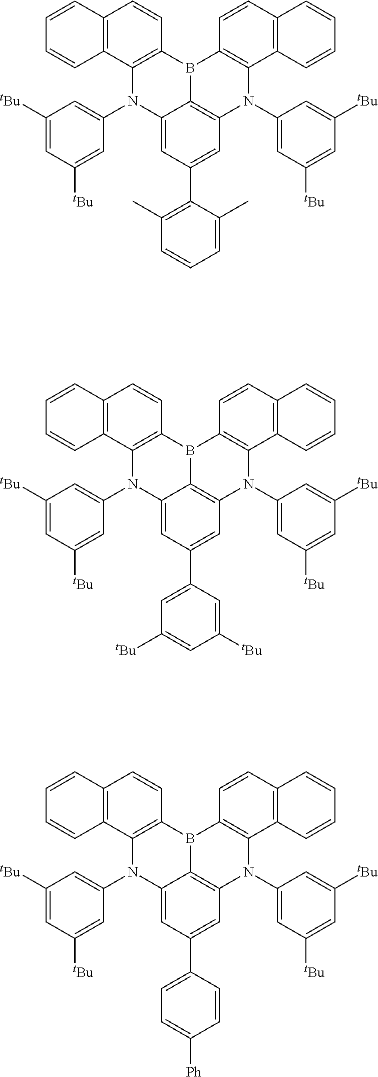 [SMILES: Cc1cccc(C)c1-c1cc2c3c(c1)N(c1cc(C(C)(C)C)cc(C(C)(C)C)c1)c1c(ccc4ccccc14)B3c1ccc3ccccc3c1N2c1cc(C(C)(C)C)cc(C(C)(C)C)c1 ; CC(C)(C)c1cc(-c2cc3c4c(c2)N(c2cc(C(C)(C)C)cc(C(C)(C)C)c2)c2c(ccc5ccccc25)B4c2ccc4ccccc4c2N3c2cc(C(C)(C)C)cc(C(C)(C)C)c2)cc(C(C)(C)C)c1 ; CC(C)(C)c1cc(N2c3cc(-c4ccc(-c5ccccc5)cc4)cc4c3B(c3ccc5ccccc5c32)c2ccc3ccccc3c2N4c2cc(C(C)(C)C)cc(C(C)(C)C)c2)cc(C(C)(C)C)c1]

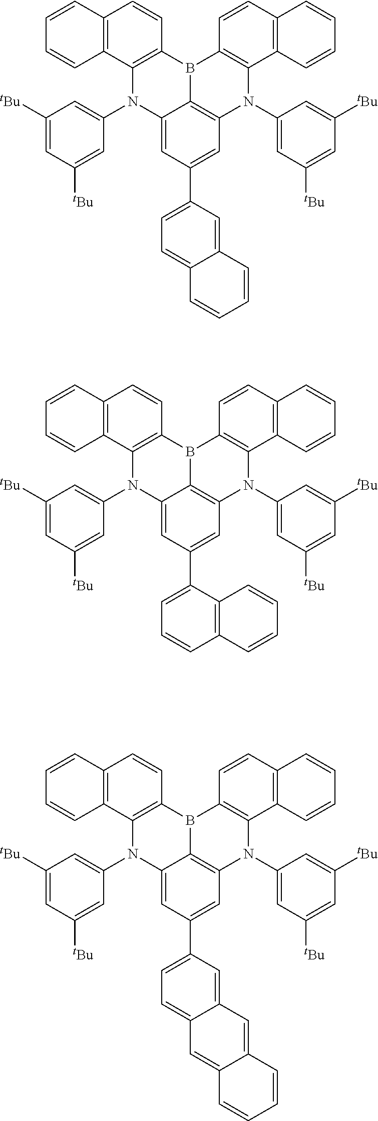 [SMILES: CC(C)(C)c1cc(N2c3cc(-c4ccc5ccccc5c4)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4cccc5ccccc45)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5cc6ccccc6cc5c4)cc4c3B(c3ccc5ccccc5c32)c2ccc3ccccc3c2N4c2cc(C(C)(C)C)cc(C(C)(C)C)c2)cc(C(C)(C)C)c1]

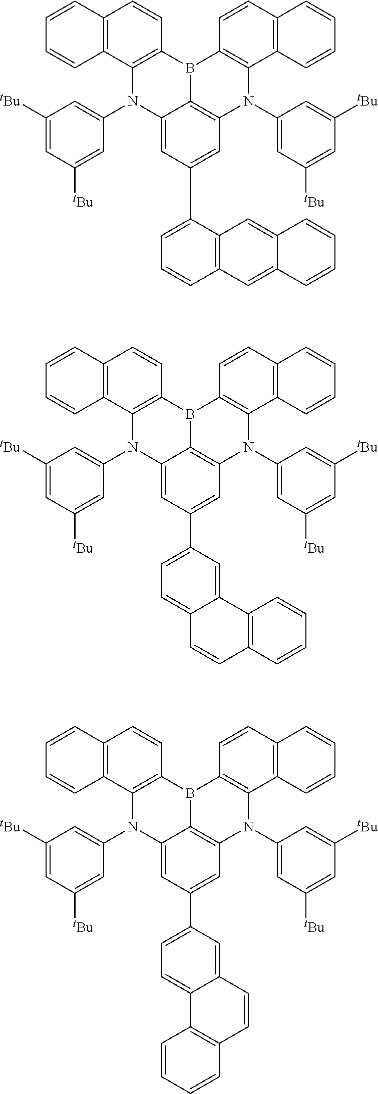 [SMILES: CC(C)(C)c1cc(N2c3cc(-c4cccc5cc6ccccc6cc45)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5ccc6ccccc6c5c4)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c(ccc6ccccc65)c4)cc4c3B(c3ccc5ccccc5c32)c2ccc3ccccc3c2N4c2cc(C(C)(C)C)cc(C(C)(C)C)c2)cc(C(C)(C)C)c1]

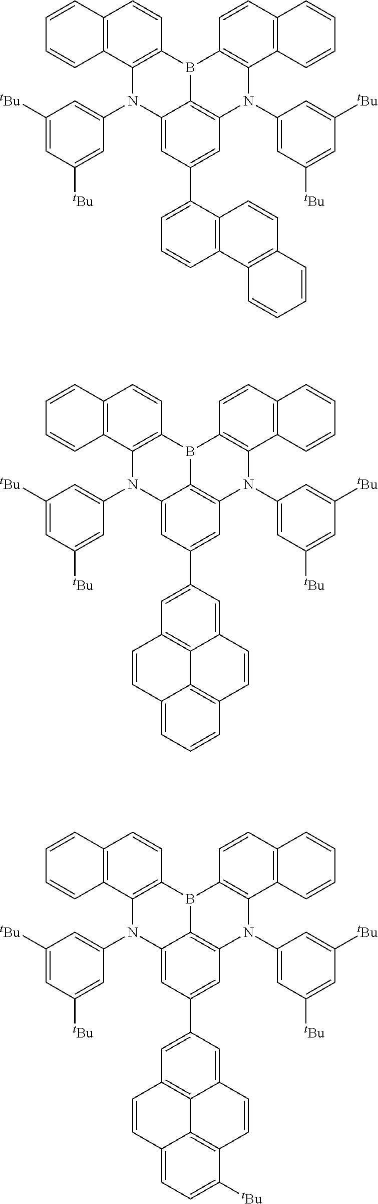 [SMILES: CC(C)(C)c1cc(N2c3cc(-c4cccc5c4ccc4ccccc45)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4cc5ccc6cccc7ccc(c4)c5c67)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4cc5ccc6ccc(C(C)(C)C)c7ccc(c4)c5c67)cc4c3B(c3ccc5ccccc5c32)c2ccc3ccccc3c2N4c2cc(C(C)(C)C)cc(C(C)(C)C)c2)cc(C(C)(C)C)c1]

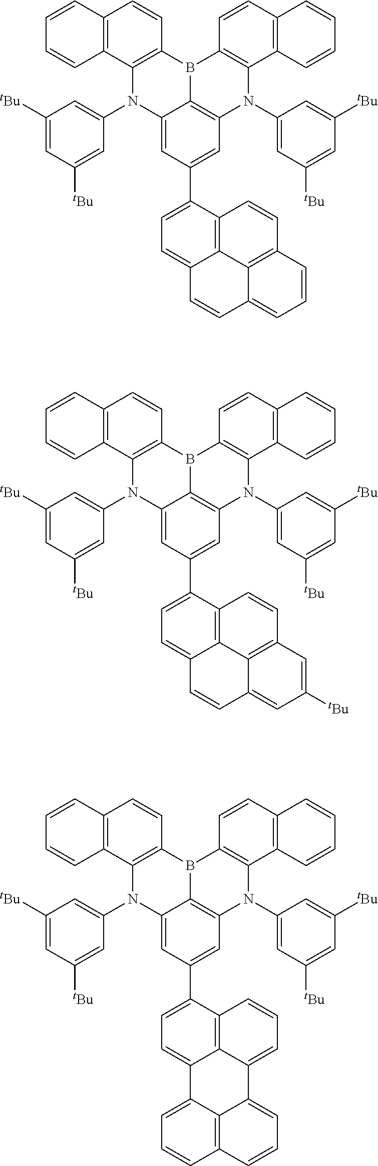 [SMILES: CC(C)(C)c1cc(N2c3cc(-c4ccc5ccc6cccc7ccc4c5c67)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5ccc6cc(C(C)(C)C)cc7ccc4c5c67)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5c6cccc7cccc(c8cccc4c85)c76)cc4c3B(c3ccc5ccccc5c32)c2ccc3ccccc3c2N4c2cc(C(C)(C)C)cc(C(C)(C)C)c2)cc(C(C)(C)C)c1]

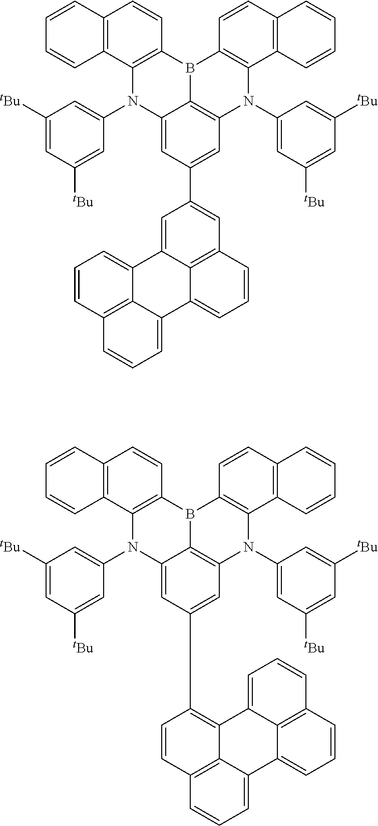 [SMILES: CC(C)(C)c1cc(N2c3cc(-c4cc5cccc6c7cccc8cccc(c(c4)c56)c87)cc4c3B(c3ccc5ccccc5c32)c2ccc3ccccc3c2N4c2cc(C(C)(C)C)cc(C(C)(C)C)c2)cc(C(C)(C)C)c1 ; CC(C)(C)c1cc(N2c3cc(-c4ccc5cccc6c7cccc8cccc(c4c56)c87)cc4c3B(c3ccc5ccccc5c32)c2ccc3ccccc3c2N4c2cc(C(C)(C)C)cc(C(C)(C)C)c2)cc(C(C)(C)C)c1]

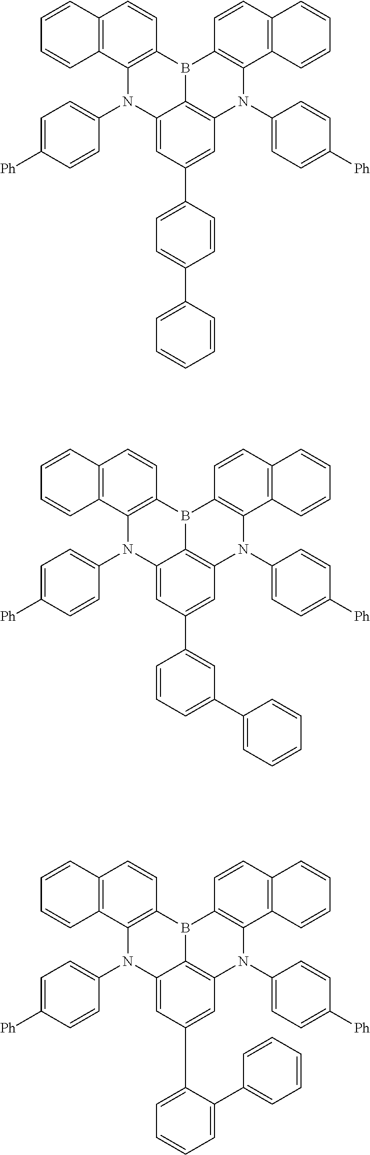 [SMILES: c1ccc(-c2ccc(-c3cc4c5c(c3)N(c3ccc(-c6ccccc6)cc3)c3c(ccc6ccccc36)B5c3ccc5ccccc5c3N4c3ccc(-c4ccccc4)cc3)cc2)cc1 ; c1ccc(-c2ccc(N3c4cc(-c5cccc(-c6ccccc6)c5)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccccc5-c5ccccc5)cc5c4B(c4ccc6ccccc6c43)c3ccc4ccccc4c3N5c3ccc(-c4ccccc4)cc3)cc2)cc1]

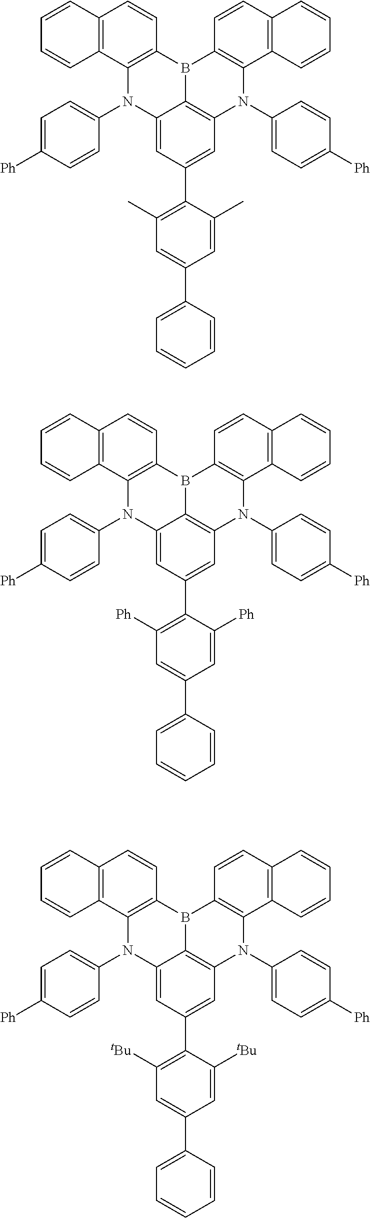 [SMILES: Cc1cc(-c2ccccc2)cc(C)c1-c1cc2c3c(c1)N(c1ccc(-c4ccccc4)cc1)c1c(ccc4ccccc14)B3c1ccc3ccccc3c1N2c1ccc(-c2ccccc2)cc1 ; c1ccc(-c2ccc(N3c4cc(-c5c(-c6ccccc6)cc(-c6ccccc6)cc5-c5ccccc5)cc5c4B(c4ccc6ccccc6c43)c3ccc4ccccc4c3N5c3ccc(-c4ccccc4)cc3)cc2)cc1 ; CC(C)(C)c1cc(-c2ccccc2)cc(C(C)(C)C)c1-c1cc2c3c(c1)N(c1ccc(-c4ccccc4)cc1)c1c(ccc4ccccc14)B3c1ccc3ccccc3c1N2c1ccc(-c2ccccc2)cc1]

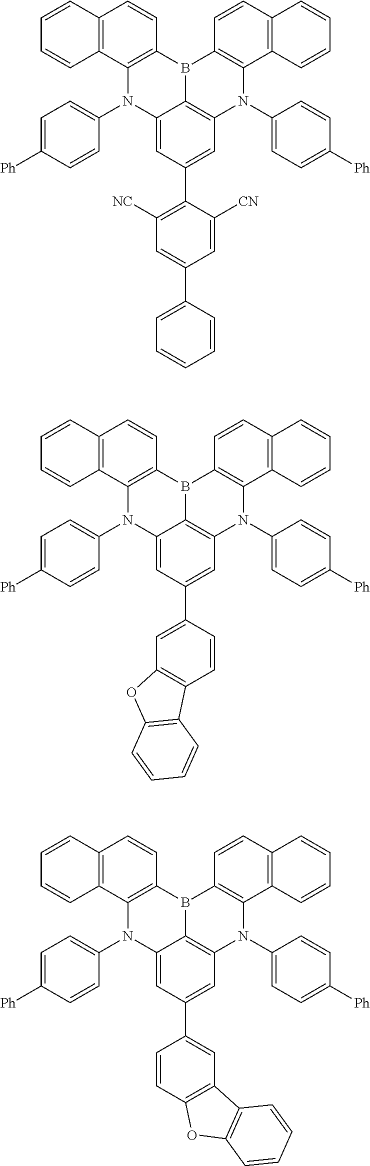 [SMILES: N#Cc1cc(-c2ccccc2)cc(C#N)c1-c1cc2c3c(c1)N(c1ccc(-c4ccccc4)cc1)c1c(ccc4ccccc14)B3c1ccc3ccccc3c1N2c1ccc(-c2ccccc2)cc1 ; c1ccc(-c2ccc(N3c4cc(-c5ccc6c(c5)oc5ccccc56)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccc6oc7ccccc7c6c5)cc5c4B(c4ccc6ccccc6c43)c3ccc4ccccc4c3N5c3ccc(-c4ccccc4)cc3)cc2)cc1]

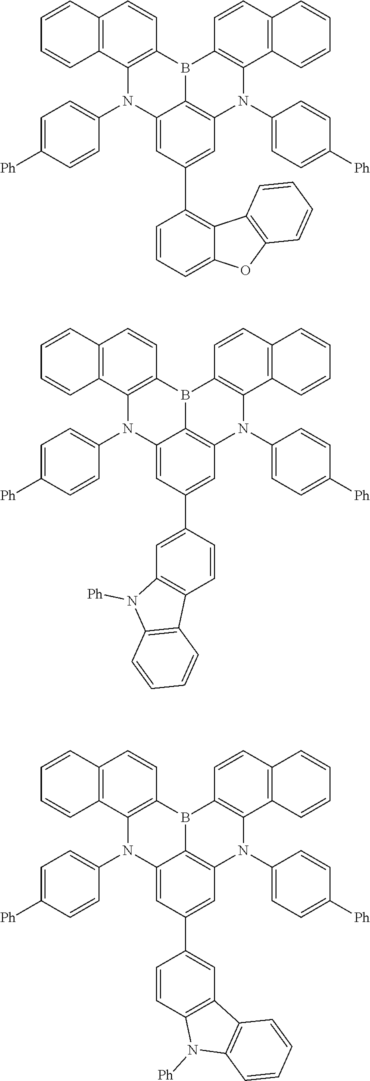 [SMILES: c1ccc(-c2ccc(N3c4cc(-c5cccc6oc7ccccc7c56)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccc6c7ccccc7n(-c7ccccc7)c6c5)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccc6c(c5)c5ccccc5n6-c5ccccc5)cc5c4B(c4ccc6ccccc6c43)c3ccc4ccccc4c3N5c3ccc(-c4ccccc4)cc3)cc2)cc1]

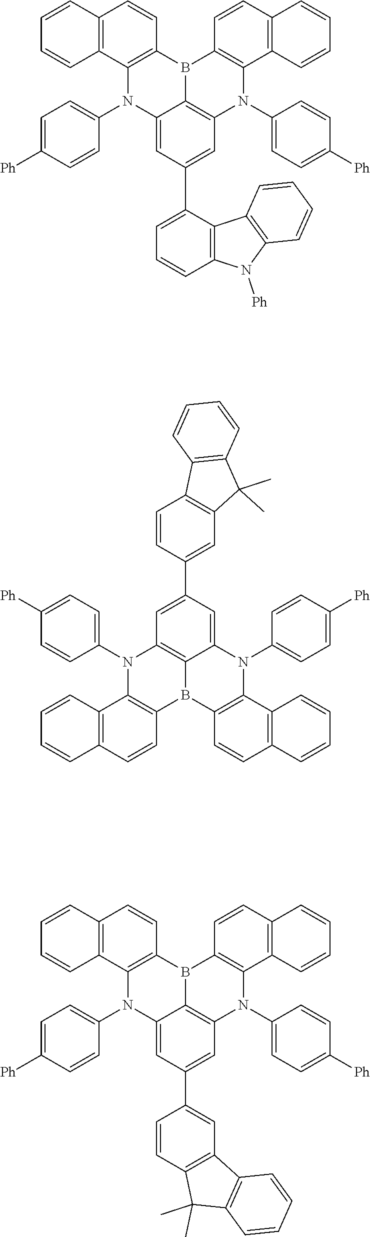 [SMILES: c1ccc(-c2ccc(N3c4cc(-c5cccc6c5c5ccccc5n6-c5ccccc5)cc5c4B(c4ccc6ccccc6c43)c3ccc4ccccc4c3N5c3ccc(-c4ccccc4)cc3)cc2)cc1 ; CC1(C)c2ccccc2-c2ccc(-c3cc4c5c(c3)N(c3ccc(-c6ccccc6)cc3)c3c(ccc6ccccc36)B5c3ccc5ccccc5c3N4c3ccc(-c4ccccc4)cc3)cc21 ; CC1(C)c2ccccc2-c2cc(-c3cc4c5c(c3)N(c3ccc(-c6ccccc6)cc3)c3c(ccc6ccccc36)B5c3ccc5ccccc5c3N4c3ccc(-c4ccccc4)cc3)ccc21]

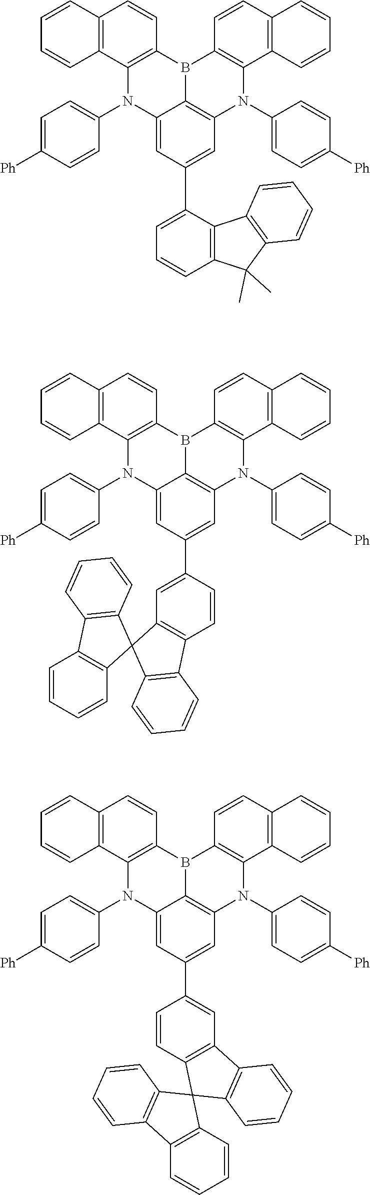 [SMILES: CC1(C)c2ccccc2-c2c(-c3cc4c5c(c3)N(c3ccc(-c6ccccc6)cc3)c3c(ccc6ccccc36)B5c3ccc5ccccc5c3N4c3ccc(-c4ccccc4)cc3)cccc21 ; c1ccc(-c2ccc(N3c4cc(-c5ccc6c(c5)C5(c7ccccc7-c7ccccc75)c5ccccc5-6)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccc6c(c5)-c5ccccc5C65c6ccccc6-c6ccccc65)cc5c4B(c4ccc6ccccc6c43)c3ccc4ccccc4c3N5c3ccc(-c4ccccc4)cc3)cc2)cc1]

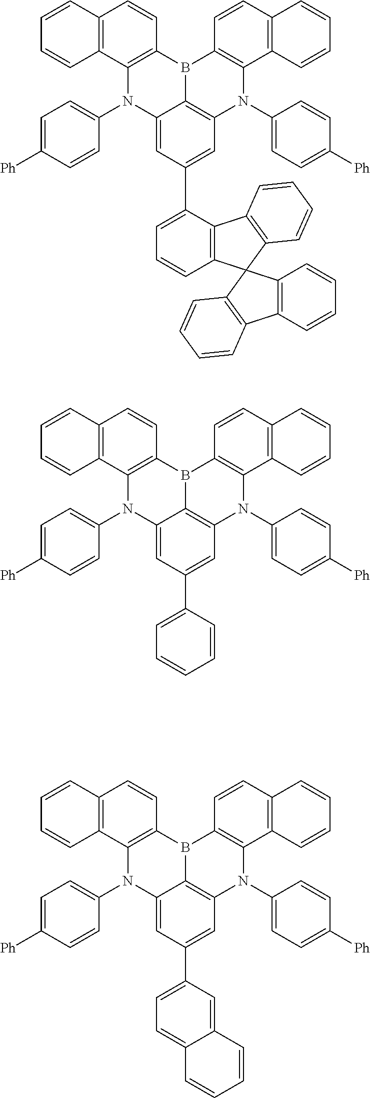 [SMILES: c1ccc(-c2ccc(N3c4cc(-c5cccc6c5-c5ccccc5C65c6ccccc6-c6ccccc65)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccccc5)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccc6ccccc6c5)cc5c4B(c4ccc6ccccc6c43)c3ccc4ccccc4c3N5c3ccc(-c4ccccc4)cc3)cc2)cc1]

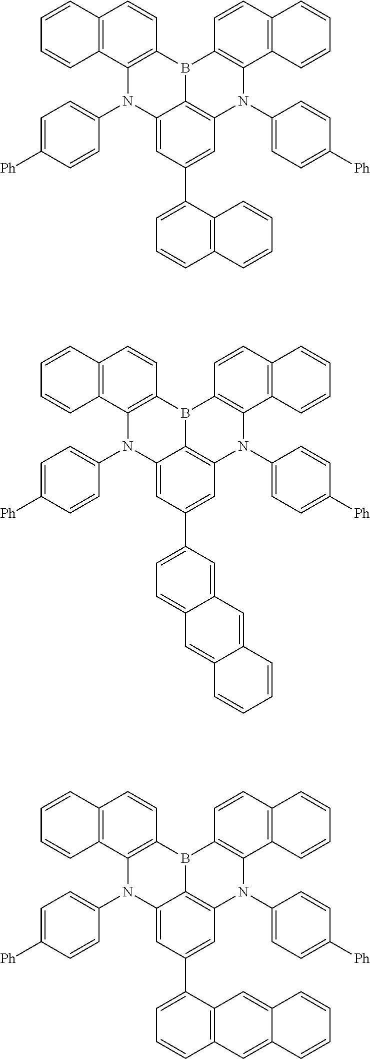 [SMILES: c1ccc(-c2ccc(N3c4cc(-c5cccc6ccccc56)cc5c4B(c4ccc6ccccc6c43)c3ccc4ccccc4c3N5c3ccc(-c4ccccc4)cc3)cc2)cc1 ; c1ccc(-c2ccc(N3c4cc(-c5ccc6cc7ccccc7cc6c5)cc5c4B(c4ccc6ccccc6c43)c3ccc4ccccc4c3N5c3ccc(-c4ccccc4)cc3)cc2)cc1 ; c1ccc(-c2ccc(N3c4cc(-c5cccc6cc7ccccc7cc56)cc5c4B(c4ccc6ccccc6c43)c3ccc4ccccc4c3N5c3ccc(-c4ccccc4)cc3)cc2)cc1]

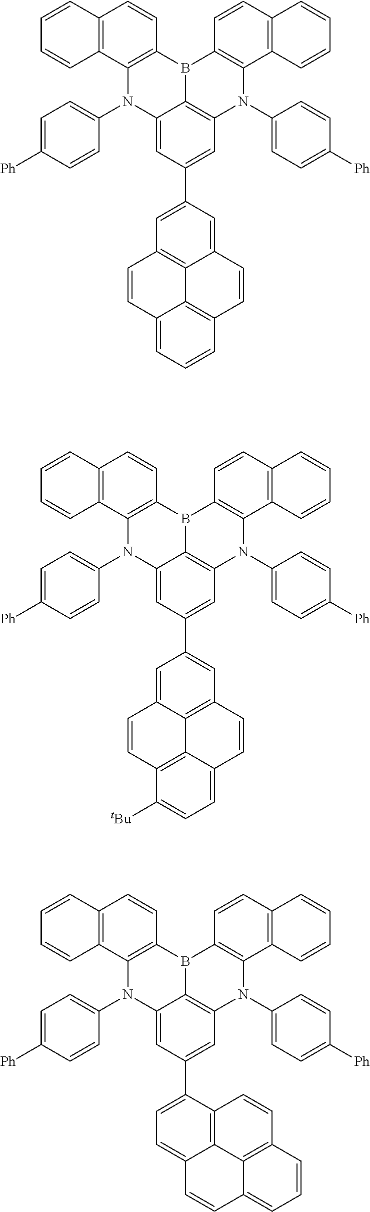 [SMILES: c1ccc(-c2ccc(N3c4cc(-c5cc6ccc7cccc8ccc(c5)c6c78)cc5c4B(c4ccc6ccccc6c43)c3ccc4ccccc4c3N5c3ccc(-c4ccccc4)cc3)cc2)cc1 ; CC(C)(C)c1ccc2ccc3cc(-c4cc5c6c(c4)N(c4ccc(-c7ccccc7)cc4)c4c(ccc7ccccc47)B6c4ccc6ccccc6c4N5c4ccc(-c5ccccc5)cc4)cc4ccc1c2c34 ; c1ccc(-c2ccc(N3c4cc(-c5ccc6ccc7cccc8ccc5c6c78)cc5c4B(c4ccc6ccccc6c43)c3ccc4ccccc4c3N5c3ccc(-c4ccccc4)cc3)cc2)cc1]

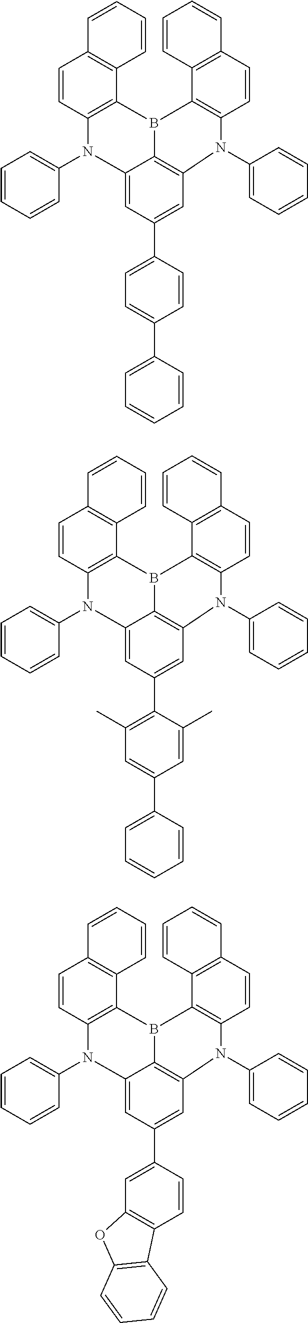 [SMILES: c1ccc(-c2ccc(-c3cc4c5c(c3)N(c3ccccc3)c3ccc6ccccc6c3B5c3c(ccc5ccccc35)N4c3ccccc3)cc2)cc1 ; Cc1cc(-c2ccccc2)cc(C)c1-c1cc2c3c(c1)N(c1ccccc1)c1ccc4ccccc4c1B3c1c(ccc3ccccc13)N2c1ccccc1 ; c1ccc(N2c3cc(-c4ccc5c(c4)oc4ccccc45)cc4c3B(c3c2ccc2ccccc32)c2c(ccc3ccccc23)N4c2ccccc2)cc1]

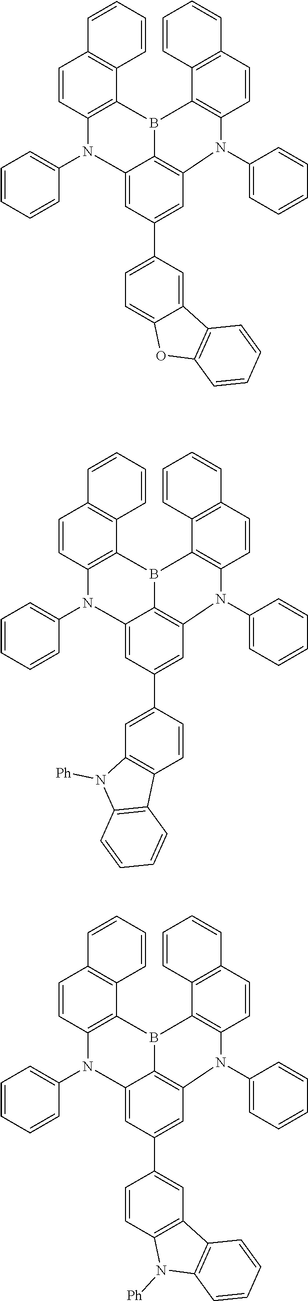 [SMILES: c1ccc(N2c3cc(-c4ccc5oc6ccccc6c5c4)cc4c3B(c3c2ccc2ccccc32)c2c(ccc3ccccc23)N4c2ccccc2)cc1 ; c1ccc(N2c3cc(-c4ccc5c6ccccc6n(-c6ccccc6)c5c4)cc4c3B(c3c2ccc2ccccc32)c2c(ccc3ccccc23)N4c2ccccc2)cc1 ; c1ccc(N2c3cc(-c4ccc5c(c4)c4ccccc4n5-c4ccccc4)cc4c3B(c3c2ccc2ccccc32)c2c(ccc3ccccc23)N4c2ccccc2)cc1]

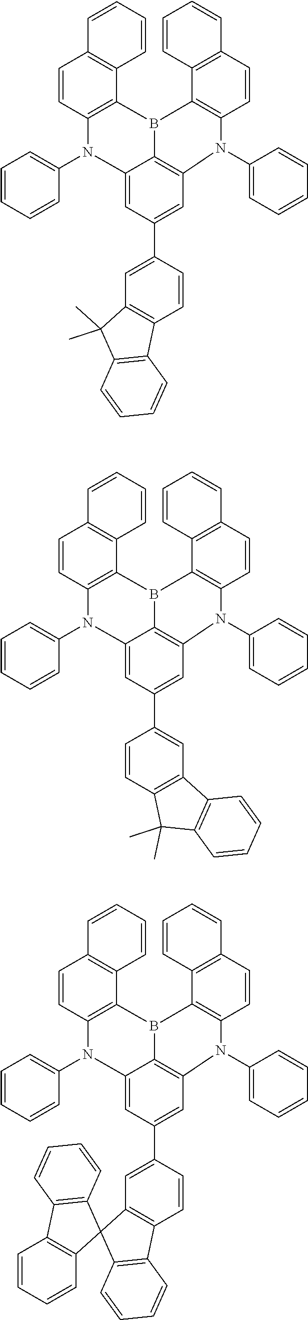 [SMILES: CC1(C)c2ccccc2-c2ccc(-c3cc4c5c(c3)N(c3ccccc3)c3ccc6ccccc6c3B5c3c(ccc5ccccc35)N4c3ccccc3)cc21 ; CC1(C)c2ccccc2-c2cc(-c3cc4c5c(c3)N(c3ccccc3)c3ccc6ccccc6c3B5c3c(ccc5ccccc35)N4c3ccccc3)ccc21 ; c1ccc(N2c3cc(-c4ccc5c(c4)C4(c6ccccc6-c6ccccc64)c4ccccc4-5)cc4c3B(c3c2ccc2ccccc32)c2c(ccc3ccccc23)N4c2ccccc2)cc1]

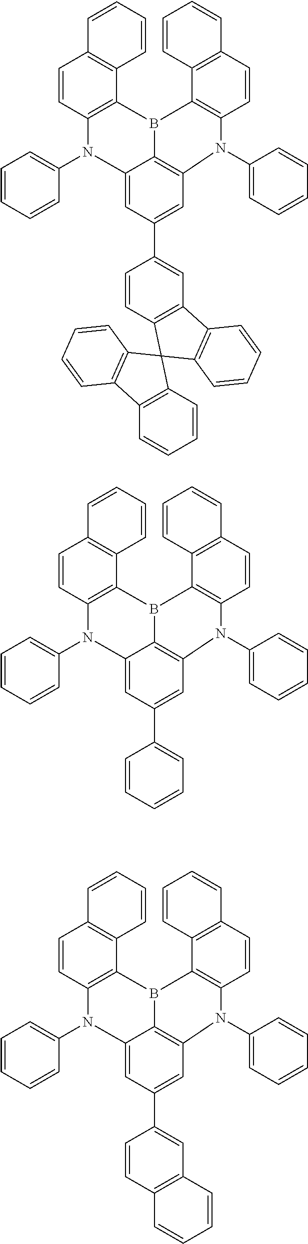

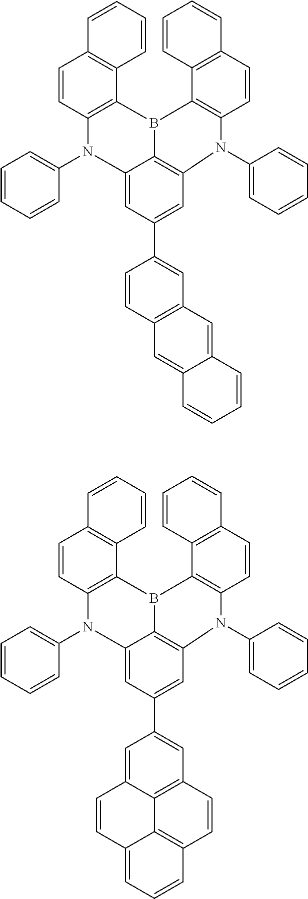 [SMILES: c1ccc(N2c3cc(-c4ccc5cc6ccccc6cc5c4)cc4c3B(c3c2ccc2ccccc32)c2c(ccc3ccccc23)N4c2ccccc2)cc1 ; c1ccc(N2c3cc(-c4cc5ccc6cccc7ccc(c4)c5c67)cc4c3B(c3c2ccc2ccccc32)c2c(ccc3ccccc23)N4c2ccccc2)cc1]

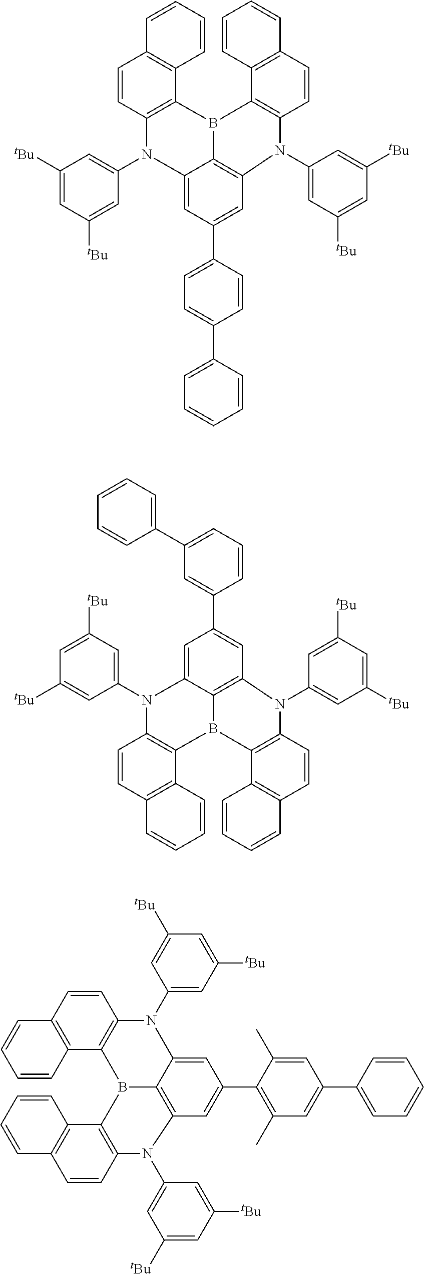 [SMILES: CC(C)(C)c1cc(N2c3cc(-c4ccc(-c5ccccc5)cc4)cc4c3B(c3c2ccc2ccccc32)c2c(ccc3ccccc23)N4c2cc(C(C)(C)C)cc(C(C)(C)C)c2)cc(C(C)(C)C)c1 ; CC(C)(C)c1cc(N2c3cc(-c4cccc(-c5ccccc5)c4)cc4c3B(c3c2ccc2ccccc32)c2c(ccc3ccccc23)N4c2cc(C(C)(C)C)cc(C(C)(C)C)c2)cc(C(C)(C)C)c1 ; Cc1cc(-c2ccccc2)cc(C)c1-c1cc2c3c(c1)N(c1cc(C(C)(C)C)cc(C(C)(C)C)c1)c1ccc4ccccc4c1B3c1c(ccc3ccccc13)N2c1cc(C(C)(C)C)cc(C(C)(C)C)c1]

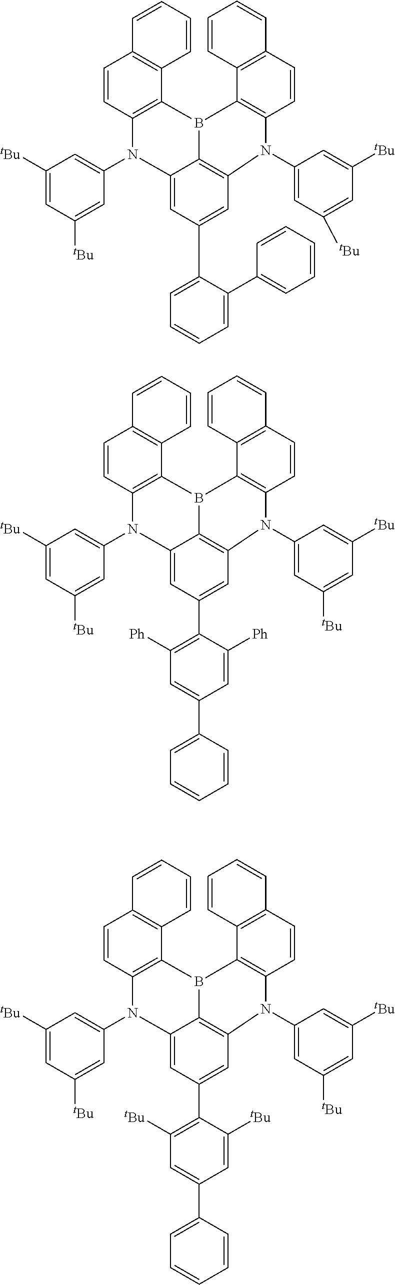 [SMILES: CC(C)(C)c1cc(N2c3cc(-c4ccccc4-c4ccccc4)cc4c3B(c3c2ccc2ccccc32)c2c(ccc3ccccc23)N4c2cc(C(C)(C)C)cc(C(C)(C)C)c2)cc(C(C)(C)C)c1 ; CC(C)(C)c1cc(N2c3cc(-c4c(-c5ccccc5)cc(-c5ccccc5)cc4-c4ccccc4)cc4c3B(c3c2ccc2ccccc32)c2c(ccc3ccccc23)N4c2cc(C(C)(C)C)cc(C(C)(C)C)c2)cc(C(C)(C)C)c1 ; CC(C)(C)c1cc(N2c3cc(-c4c(C(C)(C)C)cc(-c5ccccc5)cc4C(C)(C)C)cc4c3B(c3c2ccc2ccccc32)c2c(ccc3ccccc23)N4c2cc(C(C)(C)C)cc(C(C)(C)C)c2)cc(C(C)(C)C)c1]

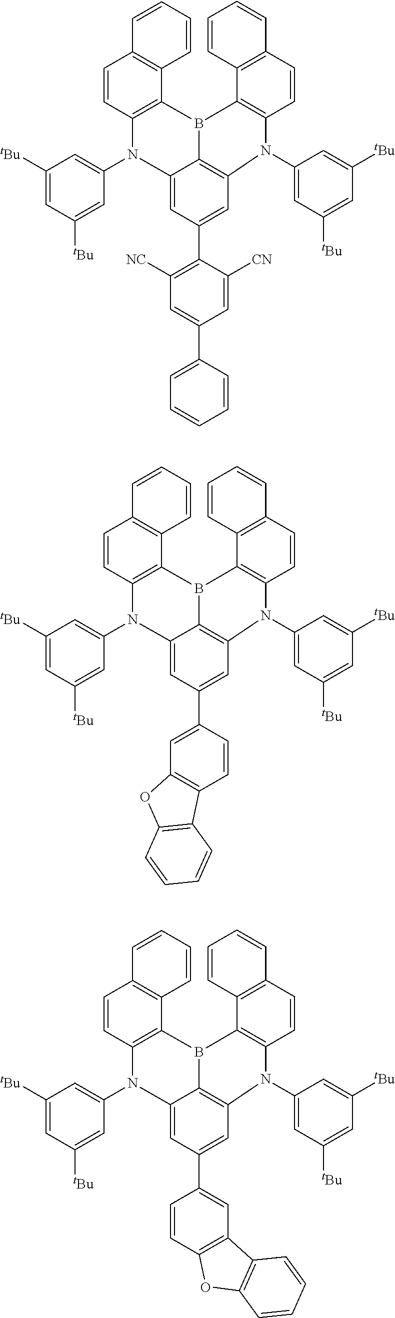

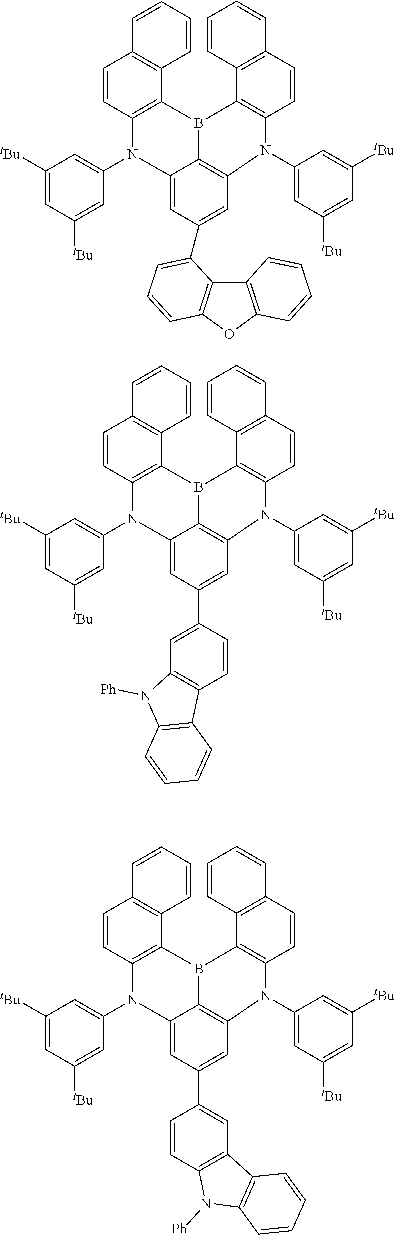

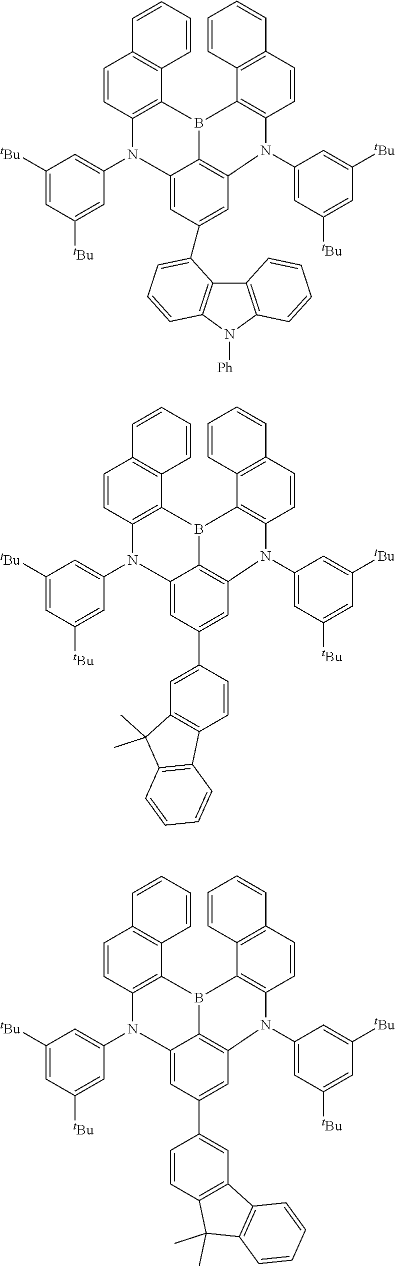

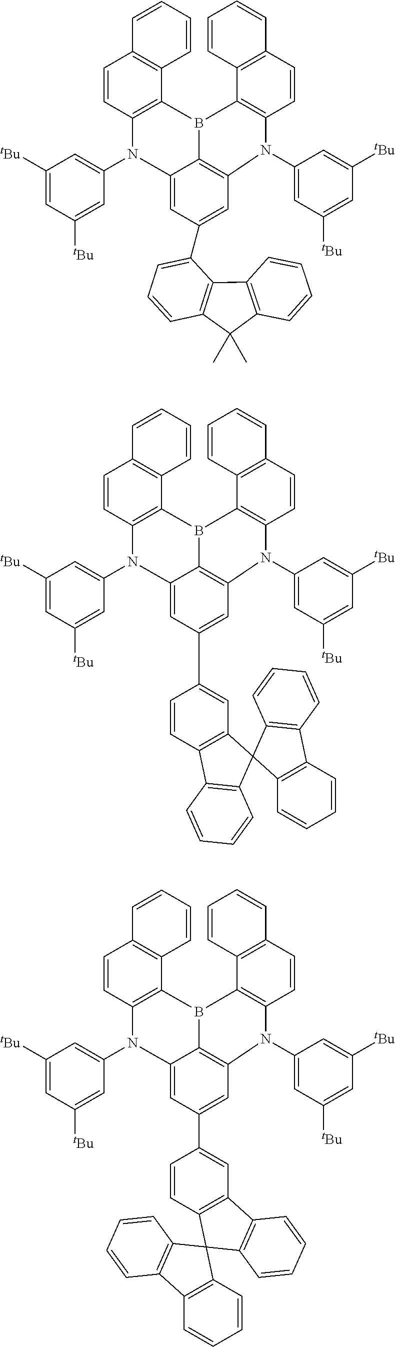

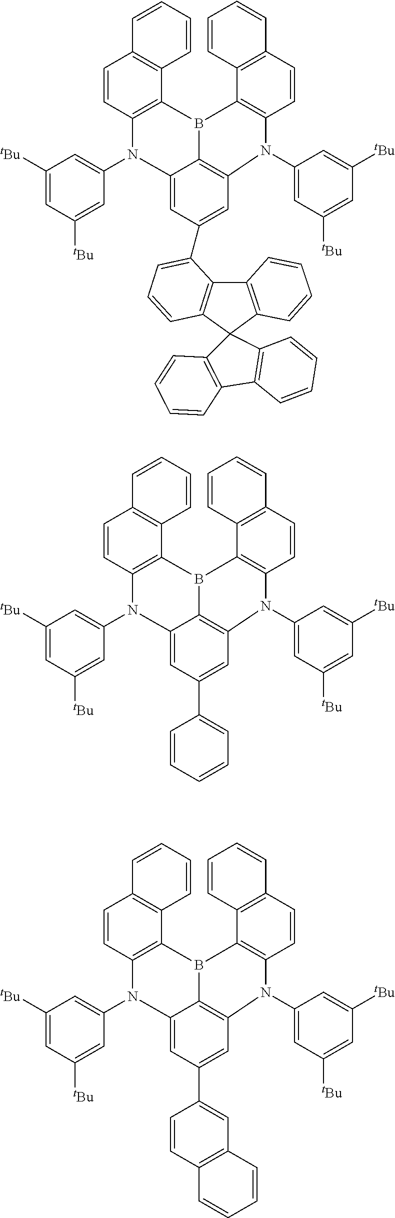

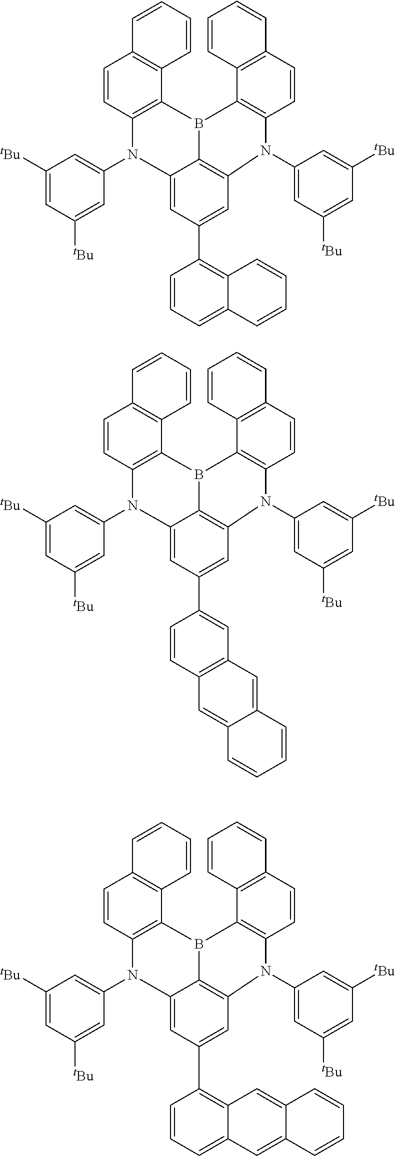

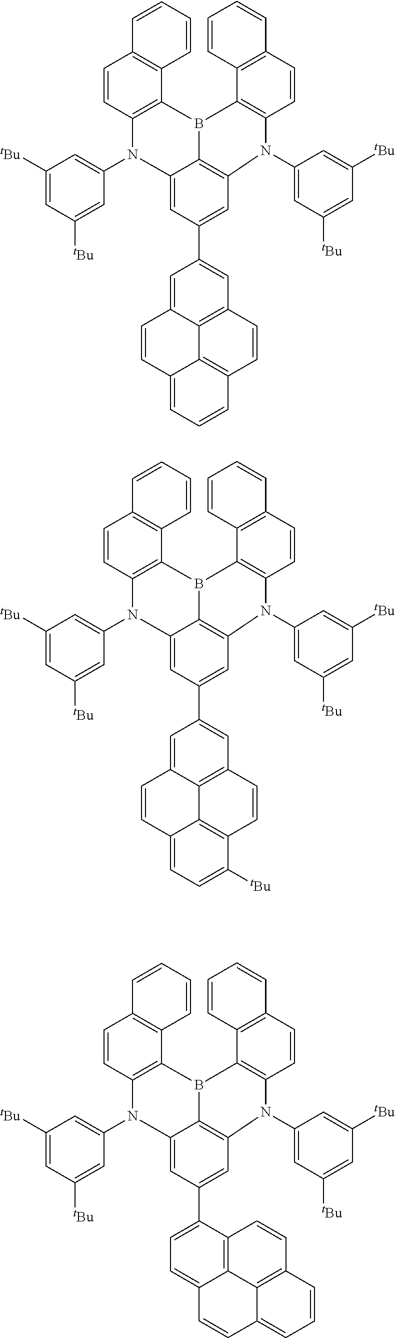 [SMILES: CC(C)(C)c1cc(N2c3cc(-c4cc5ccc6cccc7ccc(c4)c5c67)cc4c3B(c3c2ccc2ccccc32)c2c(ccc3ccccc23)N4c2cc(C(C)(C)C)cc(C(C)(C)C)c2)cc(C(C)(C)C)c1 ; CC(C)(C)c1cc(N2c3cc(-c4cc5ccc6ccc(C(C)(C)C)c7ccc(c4)c5c67)cc4c3B(c3c2ccc2ccccc32)c2c(ccc3ccccc23)N4c2cc(C(C)(C)C)cc(C(C)(C)C)c2)cc(C(C)(C)C)c1 ; CC(C)(C)c1cc(N2c3cc(-c4ccc5ccc6cccc7ccc4c5c67)cc4c3B(c3c2ccc2ccccc32)c2c(ccc3ccccc23)N4c2cc(C(C)(C)C)cc(C(C)(C)C)c2)cc(C(C)(C)C)c1]

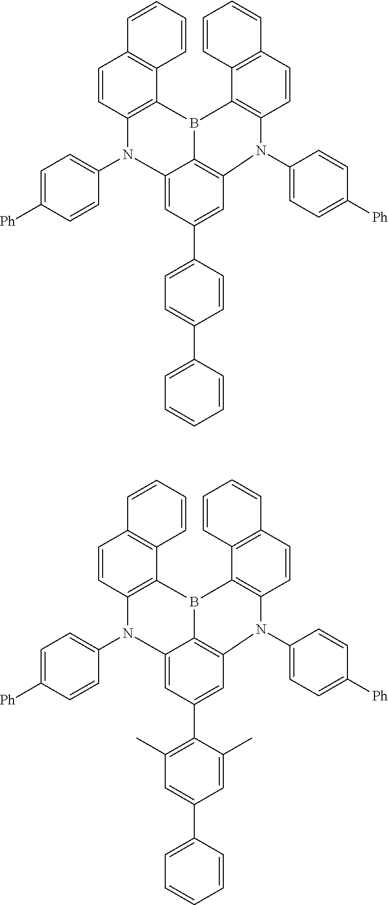 [SMILES: c1ccc(-c2ccc(-c3cc4c5c(c3)N(c3ccc(-c6ccccc6)cc3)c3ccc6ccccc6c3B5c3c(ccc5ccccc35)N4c3ccc(-c4ccccc4)cc3)cc2)cc1 ; Cc1cc(-c2ccccc2)cc(C)c1-c1cc2c3c(c1)N(c1ccc(-c4ccccc4)cc1)c1ccc4ccccc4c1B3c1c(ccc3ccccc13)N2c1ccc(-c2ccccc2)cc1]

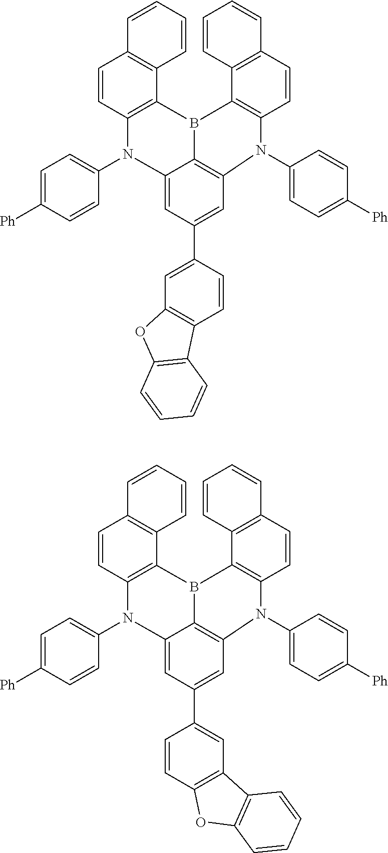

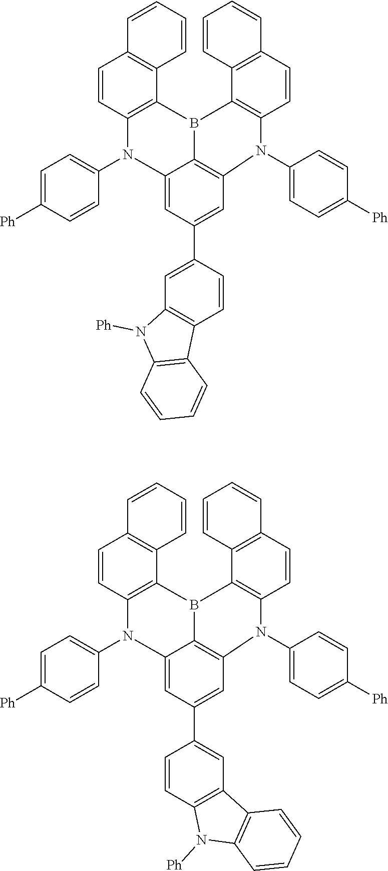 [SMILES: c1ccc(-c2ccc(N3c4cc(-c5ccc6c7ccccc7n(-c7ccccc7)c6c5)cc5c4B(c4c3ccc3ccccc43)c3c(ccc4ccccc34)N5c3ccc(-c4ccccc4)cc3)cc2)cc1 ; c1ccc(-c2ccc(N3c4cc(-c5ccc6c(c5)c5ccccc5n6-c5ccccc5)cc5c4B(c4c3ccc3ccccc43)c3c(ccc4ccccc34)N5c3ccc(-c4ccccc4)cc3)cc2)cc1]

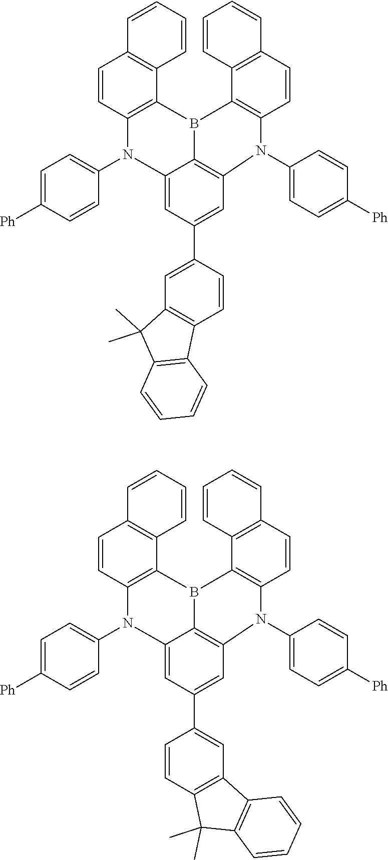 [SMILES: CC1(C)c2ccccc2-c2ccc(-c3cc4c5c(c3)N(c3ccc(-c6ccccc6)cc3)c3ccc6ccccc6c3B5c3c(ccc5ccccc35)N4c3ccc(-c4ccccc4)cc3)cc21 ; CC1(C)c2ccccc2-c2cc(-c3cc4c5c(c3)N(c3ccc(-c6ccccc6)cc3)c3ccc6ccccc6c3B5c3c(ccc5ccccc35)N4c3ccc(-c4ccccc4)cc3)ccc21]

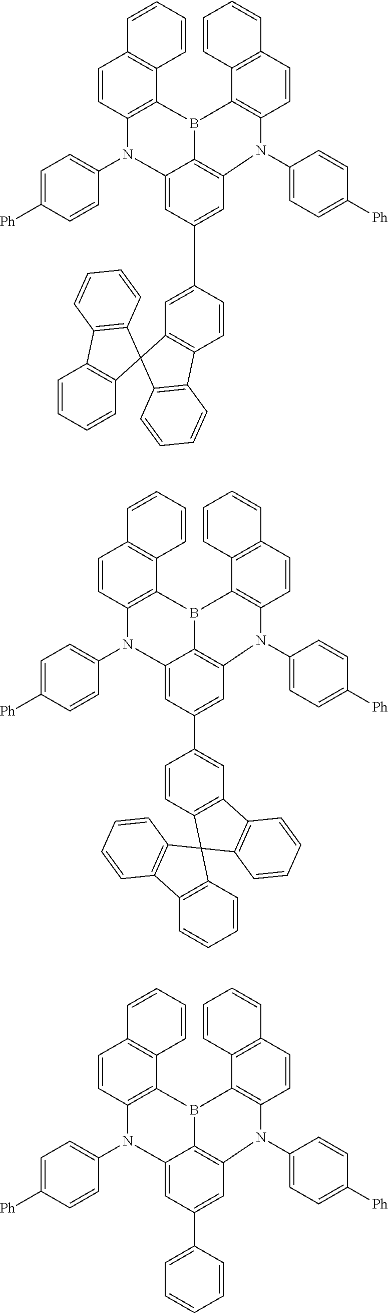

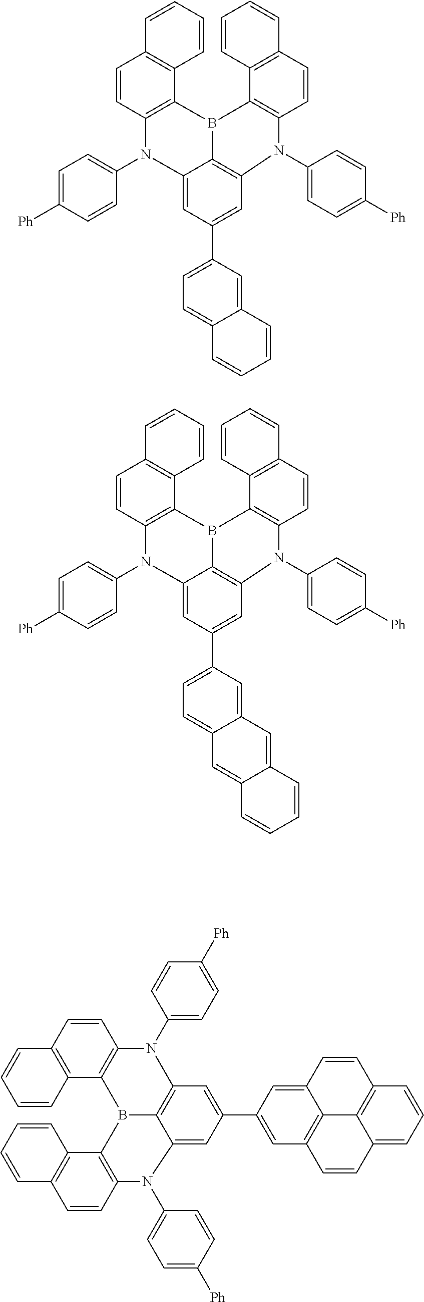

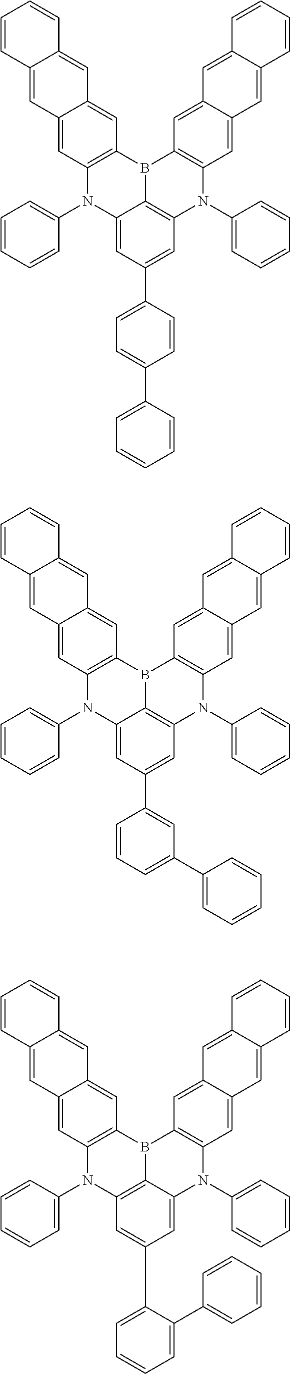 [SMILES: c1ccc(-c2ccc(-c3cc4c5c(c3)N(c3ccccc3)c3cc6cc7ccccc7cc6cc3B5c3cc5cc6ccccc6cc5cc3N4c3ccccc3)cc2)cc1 ; c1ccc(-c2cccc(-c3cc4c5c(c3)N(c3ccccc3)c3cc6cc7ccccc7cc6cc3B5c3cc5cc6ccccc6cc5cc3N4c3ccccc3)c2)cc1 ; c1ccc(-c2ccccc2-c2cc3c4c(c2)N(c2ccccc2)c2cc5cc6ccccc6cc5cc2B4c2cc4cc5ccccc5cc4cc2N3c2ccccc2)cc1]

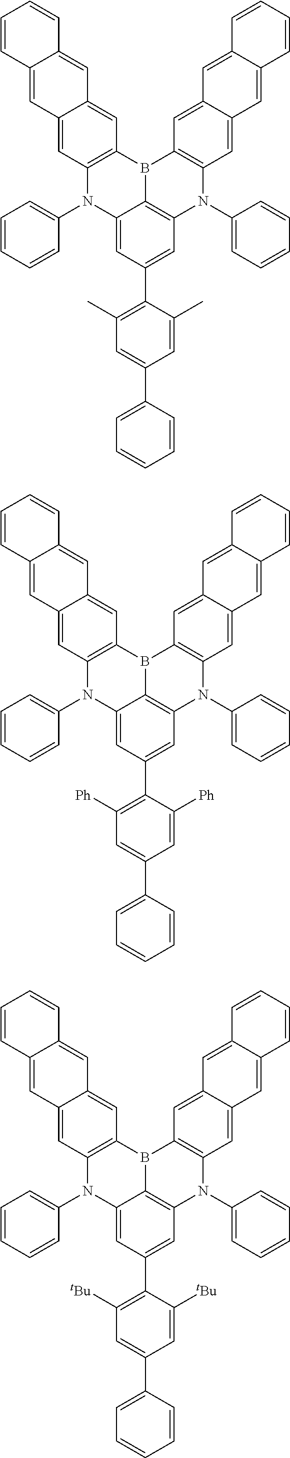 [SMILES: Cc1cc(-c2ccccc2)cc(C)c1-c1cc2c3c(c1)N(c1ccccc1)c1cc4cc5ccccc5cc4cc1B3c1cc3cc4ccccc4cc3cc1N2c1ccccc1 ; c1ccc(-c2cc(-c3ccccc3)c(-c3cc4c5c(c3)N(c3ccccc3)c3cc6cc7ccccc7cc6cc3B5c3cc5cc6ccccc6cc5cc3N4c3ccccc3)c(-c3ccccc3)c2)cc1 ; CC(C)(C)c1cc(-c2ccccc2)cc(C(C)(C)C)c1-c1cc2c3c(c1)N(c1ccccc1)c1cc4cc5ccccc5cc4cc1B3c1cc3cc4ccccc4cc3cc1N2c1ccccc1]

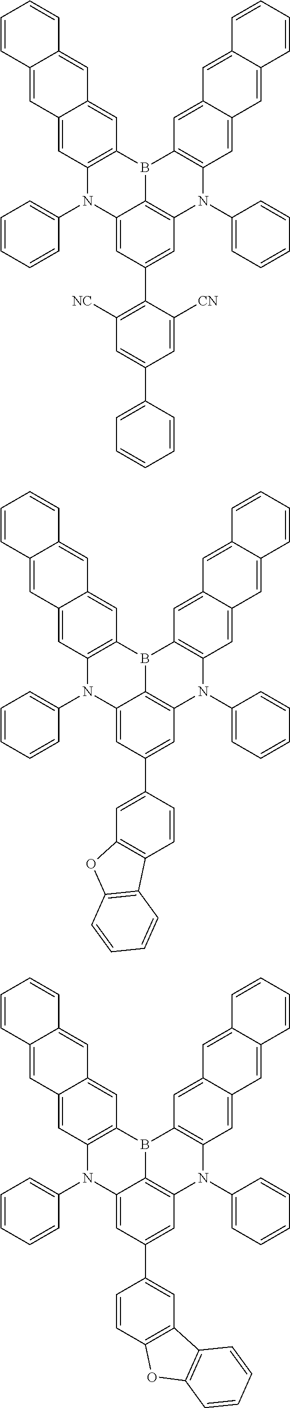 [SMILES: N#Cc1cc(-c2ccccc2)cc(C#N)c1-c1cc2c3c(c1)N(c1ccccc1)c1cc4cc5ccccc5cc4cc1B3c1cc3cc4ccccc4cc3cc1N2c1ccccc1 ; c1ccc(N2c3cc4cc5ccccc5cc4cc3B3c4cc5cc6ccccc6cc5cc4N(c4ccccc4)c4cc(-c5ccc6c(c5)oc5ccccc56)cc2c43)cc1 ; c1ccc(N2c3cc4cc5ccccc5cc4cc3B3c4cc5cc6ccccc6cc5cc4N(c4ccccc4)c4cc(-c5ccc6oc7ccccc7c6c5)cc2c43)cc1]

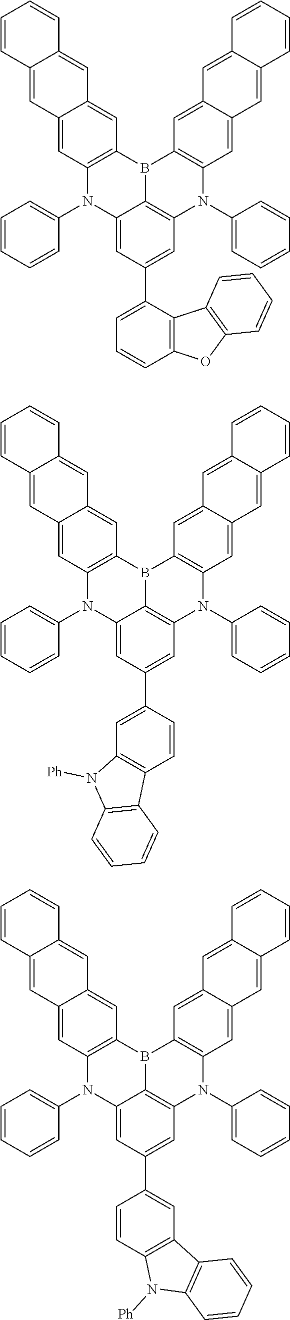 [SMILES: c1ccc(N2c3cc4cc5ccccc5cc4cc3B3c4cc5cc6ccccc6cc5cc4N(c4ccccc4)c4cc(-c5cccc6oc7ccccc7c56)cc2c43)cc1 ; c1ccc(N2c3cc4cc5ccccc5cc4cc3B3c4cc5cc6ccccc6cc5cc4N(c4ccccc4)c4cc(-c5ccc6c7ccccc7n(-c7ccccc7)c6c5)cc2c43)cc1 ; c1ccc(N2c3cc4cc5ccccc5cc4cc3B3c4cc5cc6ccccc6cc5cc4N(c4ccccc4)c4cc(-c5ccc6c(c5)c5ccccc5n6-c5ccccc5)cc2c43)cc1]

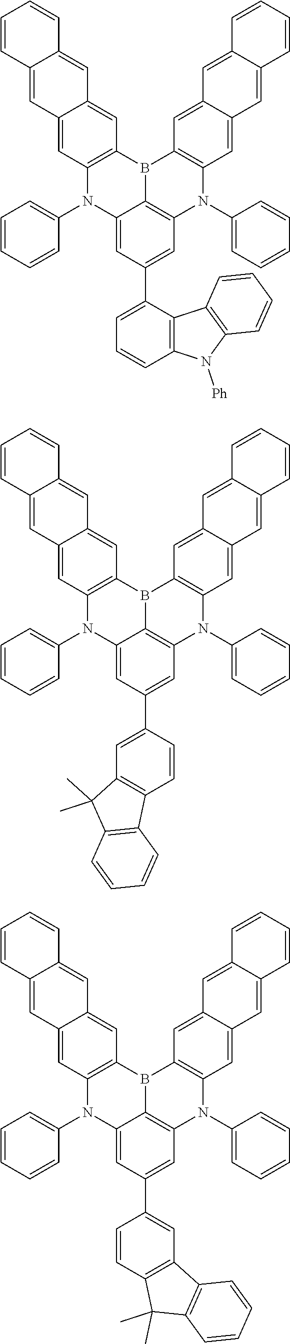 [SMILES: c1ccc(N2c3cc4cc5ccccc5cc4cc3B3c4cc5cc6ccccc6cc5cc4N(c4ccccc4)c4cc(-c5cccc6c5c5ccccc5n6-c5ccccc5)cc2c43)cc1 ; CC1(C)c2ccccc2-c2ccc(-c3cc4c5c(c3)N(c3ccccc3)c3cc6cc7ccccc7cc6cc3B5c3cc5cc6ccccc6cc5cc3N4c3ccccc3)cc21 ; CC1(C)c2ccccc2-c2cc(-c3cc4c5c(c3)N(c3ccccc3)c3cc6cc7ccccc7cc6cc3B5c3cc5cc6ccccc6cc5cc3N4c3ccccc3)ccc21]

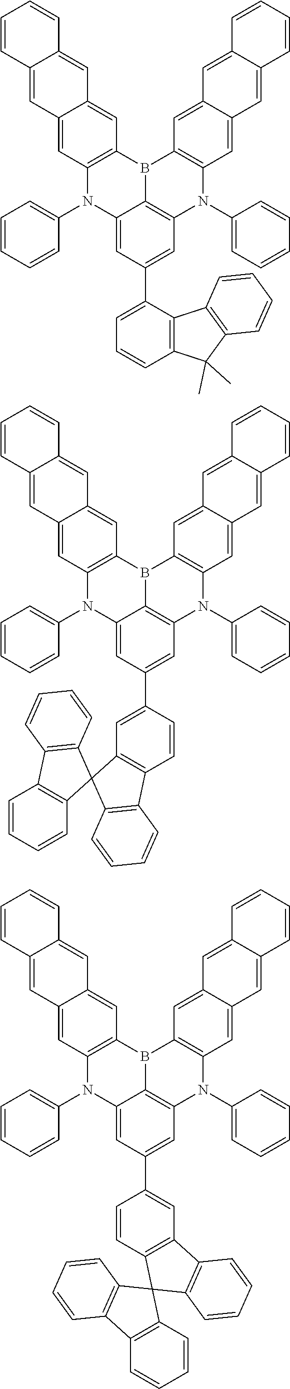

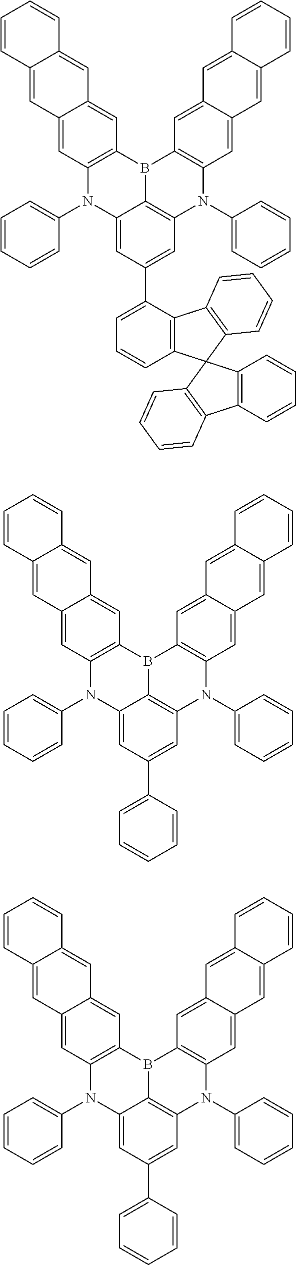 [SMILES: c1ccc(N2c3cc4cc5ccccc5cc4cc3B3c4cc5cc6ccccc6cc5cc4N(c4ccccc4)c4cc(-c5cccc6c5-c5ccccc5C65c6ccccc6-c6ccccc65)cc2c43)cc1 ; c1ccc(-c2cc3c4c(c2)N(c2ccccc2)c2cc5cc6ccccc6cc5cc2B4c2cc4cc5ccccc5cc4cc2N3c2ccccc2)cc1 ; c1ccc(-c2cc3c4c(c2)N(c2ccccc2)c2cc5cc6ccccc6cc5cc2B4c2cc4cc5ccccc5cc4cc2N3c2ccccc2)cc1]

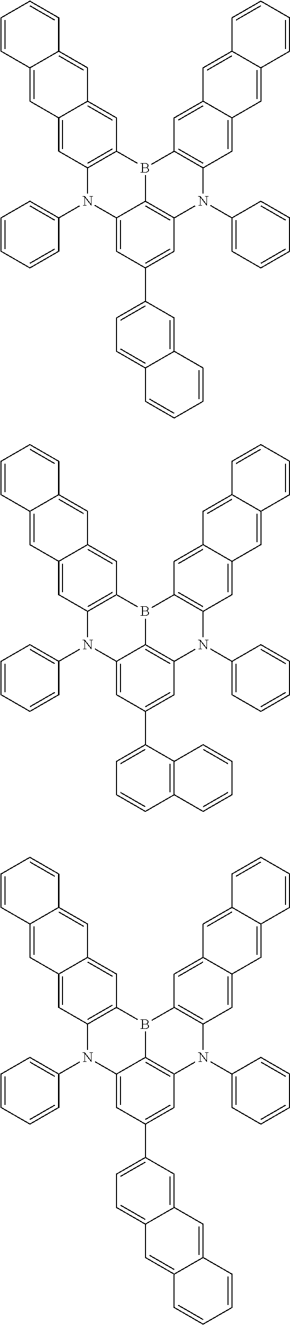 [SMILES: c1ccc(N2c3cc4cc5ccccc5cc4cc3B3c4cc5cc6ccccc6cc5cc4N(c4ccccc4)c4cc(-c5ccc6ccccc6c5)cc2c43)cc1 ; c1ccc(N2c3cc4cc5ccccc5cc4cc3B3c4cc5cc6ccccc6cc5cc4N(c4ccccc4)c4cc(-c5cccc6ccccc56)cc2c43)cc1 ; c1ccc(N2c3cc4cc5ccccc5cc4cc3B3c4cc5cc6ccccc6cc5cc4N(c4ccccc4)c4cc(-c5ccc6cc7ccccc7cc6c5)cc2c43)cc1]

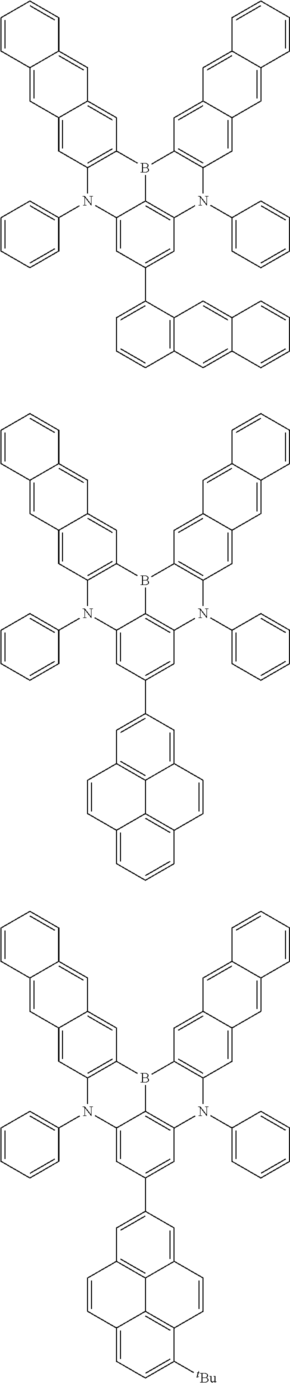

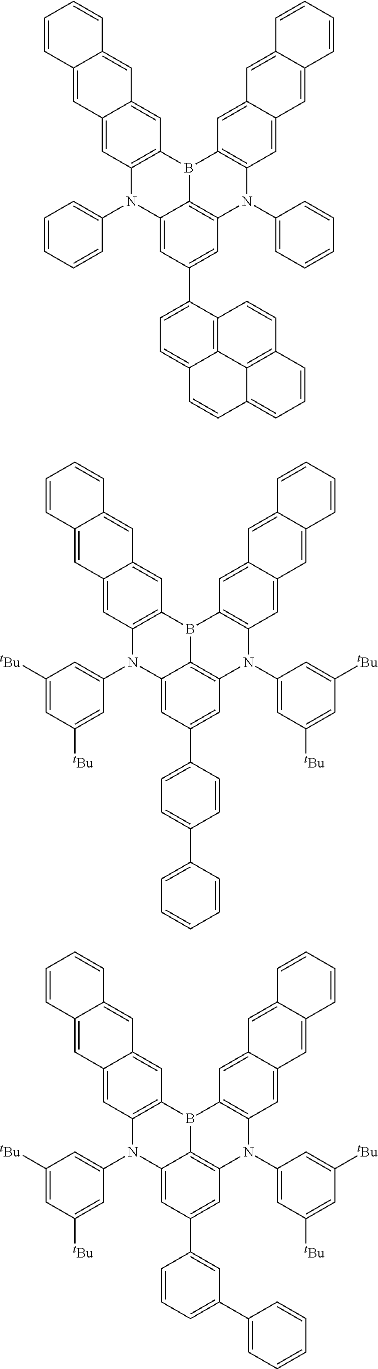 [SMILES: c1ccc(N2c3cc4cc5ccccc5cc4cc3B3c4cc5cc6ccccc6cc5cc4N(c4ccccc4)c4cc(-c5ccc6ccc7cccc8ccc5c6c78)cc2c43)cc1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc(-c6ccccc6)cc5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cccc(-c6ccccc6)c5)cc2c43)cc(C(C)(C)C)c1]

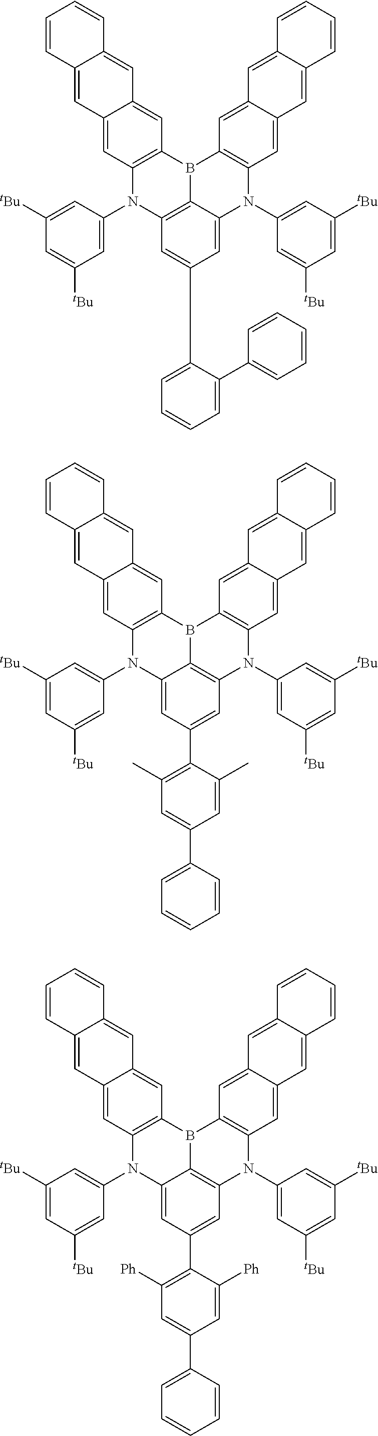 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccccc5-c5ccccc5)cc2c43)cc(C(C)(C)C)c1 ; Cc1cc(-c2ccccc2)cc(C)c1-c1cc2c3c(c1)N(c1cc(C(C)(C)C)cc(C(C)(C)C)c1)c1cc4cc5ccccc5cc4cc1B3c1cc3cc4ccccc4cc3cc1N2c1cc(C(C)(C)C)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5c(-c6ccccc6)cc(-c6ccccc6)cc5-c5ccccc5)cc2c43)cc(C(C)(C)C)c1]

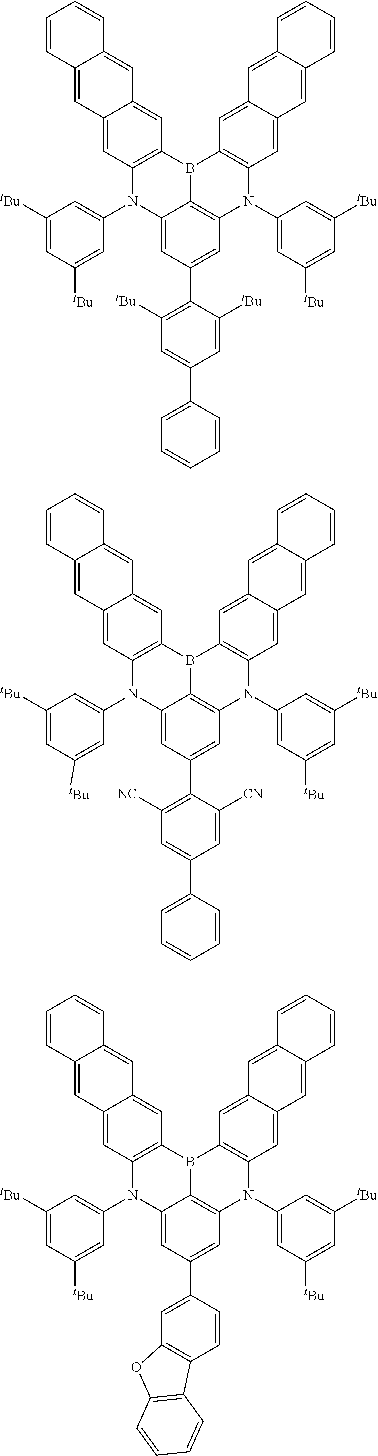 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5c(C(C)(C)C)cc(-c6ccccc6)cc5C(C)(C)C)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5c(C#N)cc(-c6ccccc6)cc5C#N)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)oc5ccccc56)cc2c43)cc(C(C)(C)C)c1]

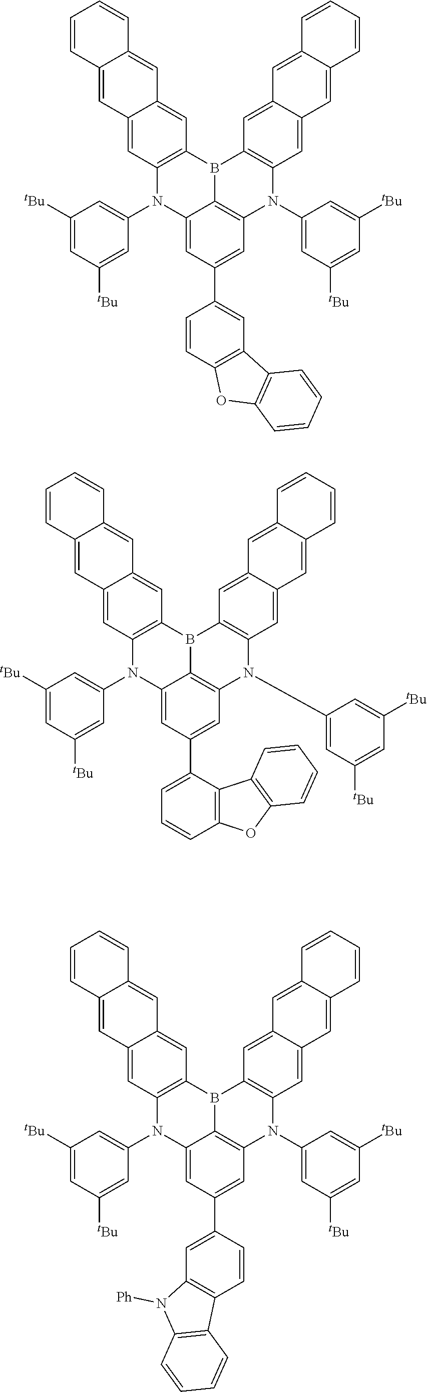

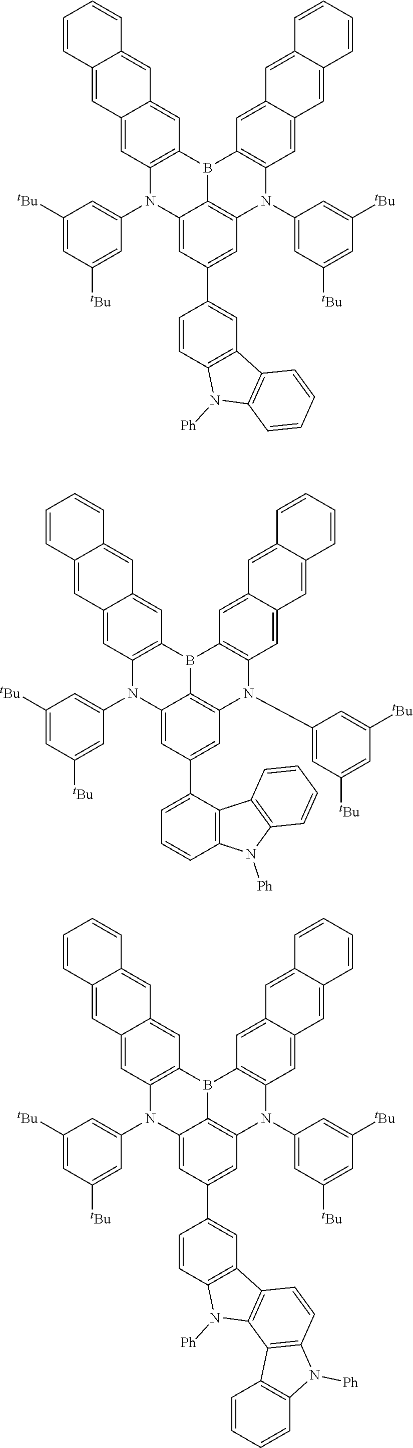 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)c5ccccc5n6-c5ccccc5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cccc6c5c5ccccc5n6-c5ccccc5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)c5ccc7c(c8ccccc8n7-c7ccccc7)c5n6-c5ccccc5)cc2c43)cc(C(C)(C)C)c1]

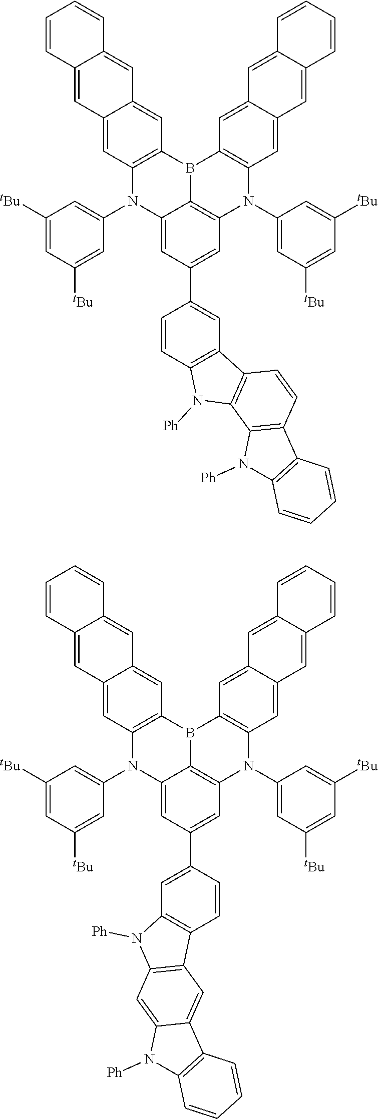

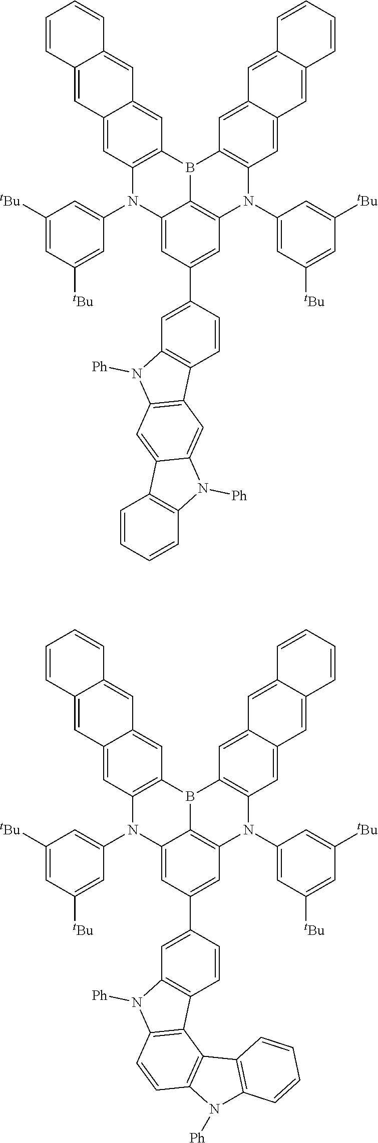 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c7cc8c(cc7n(-c7ccccc7)c6c5)c5ccccc5n8-c5ccccc5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c7c8c9ccccc9n(-c9ccccc9)c8ccc7n(-c7ccccc7)c6c5)cc2c43)cc(C(C)(C)C)c1]

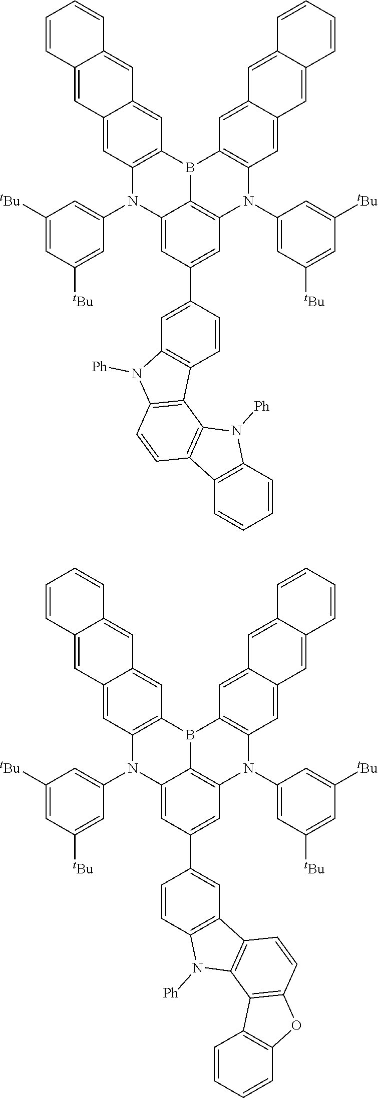 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c7c(ccc8c9ccccc9n(-c9ccccc9)c87)n(-c7ccccc7)c6c5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)c5ccc7oc8ccccc8c7c5n6-c5ccccc5)cc2c43)cc(C(C)(C)C)c1]

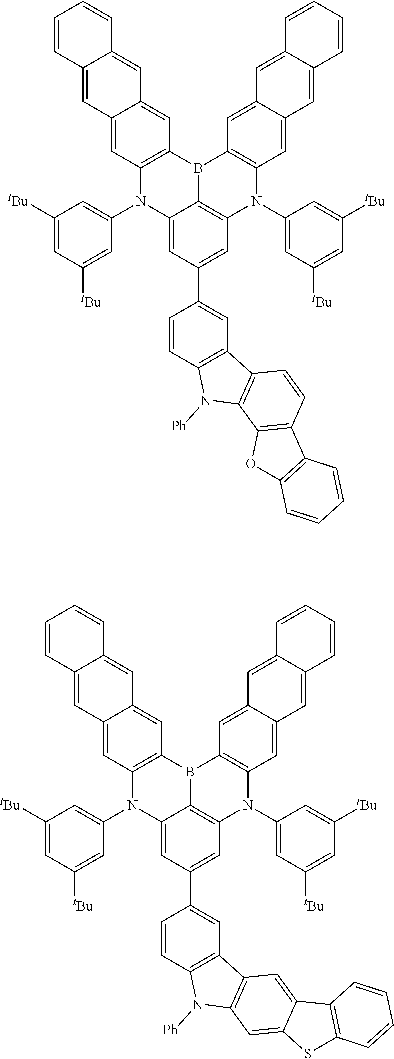 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)c5ccc7c8ccccc8oc7c5n6-c5ccccc5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)c5cc7c(cc5n6-c5ccccc5)sc5ccccc57)cc2c43)cc(C(C)(C)C)c1]

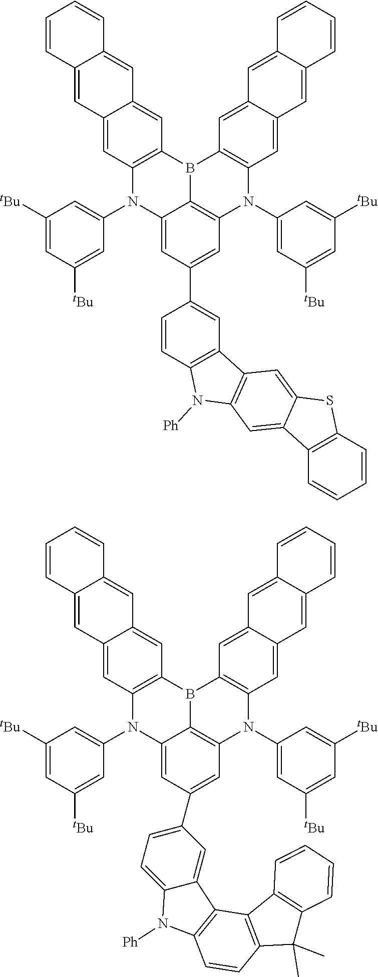

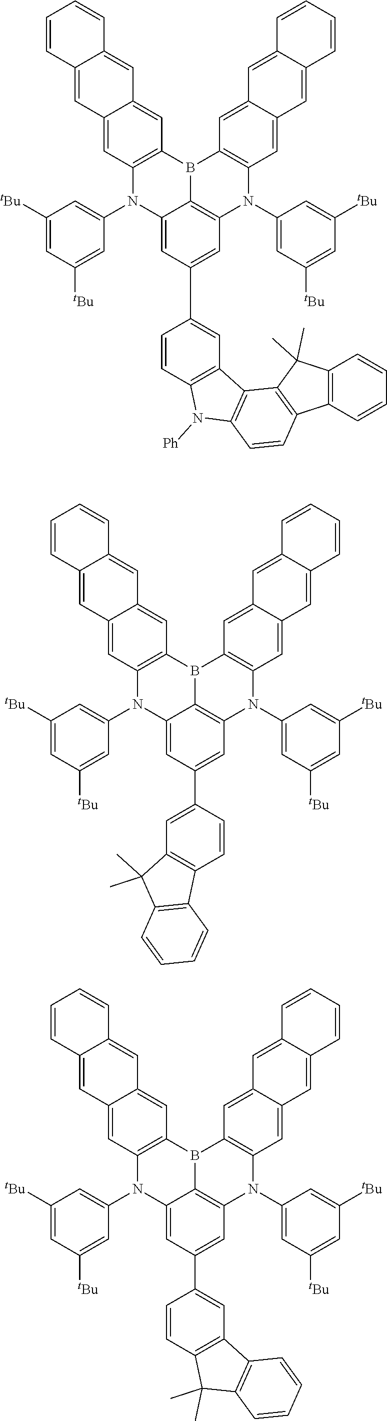 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)c5c7c(ccc5n6-c5ccccc5)-c5ccccc5C7(C)C)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)C(C)(C)c5ccccc5-6)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)-c5ccccc5C6(C)C)cc2c43)cc(C(C)(C)C)c1]

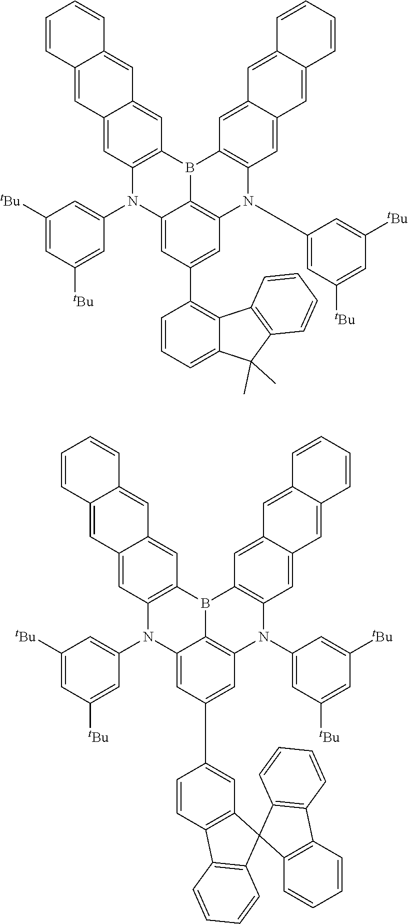 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cccc6c5-c5ccccc5C6(C)C)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)C5(c7ccccc7-c7ccccc75)c5ccccc5-6)cc2c43)cc(C(C)(C)C)c1]

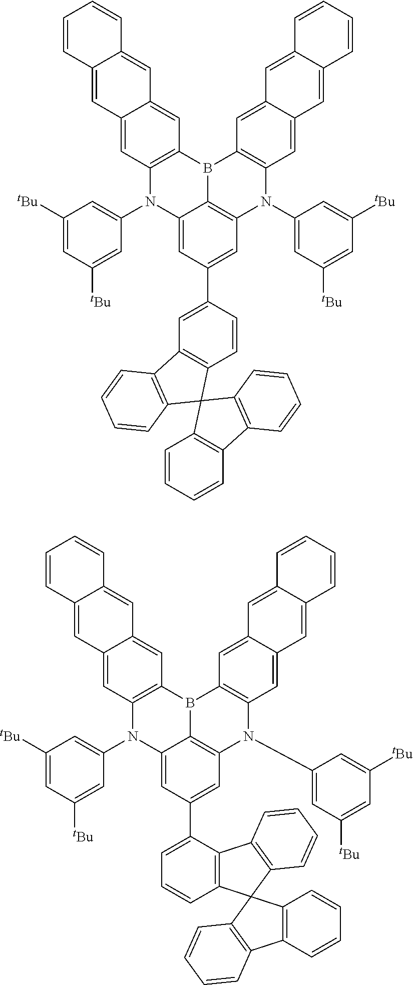 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)-c5ccccc5C65c6ccccc6-c6ccccc65)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cccc6c5-c5ccccc5C65c6ccccc6-c6ccccc65)cc2c43)cc(C(C)(C)C)c1]

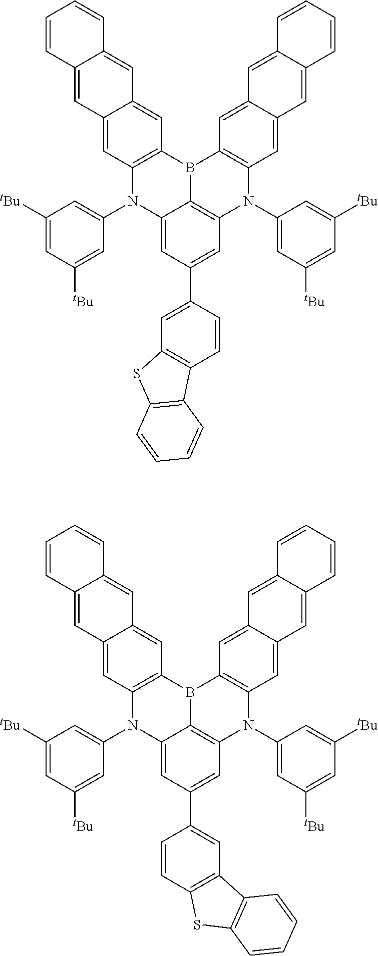 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6c(c5)sc5ccccc56)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6sc7ccccc7c6c5)cc2c43)cc(C(C)(C)C)c1]

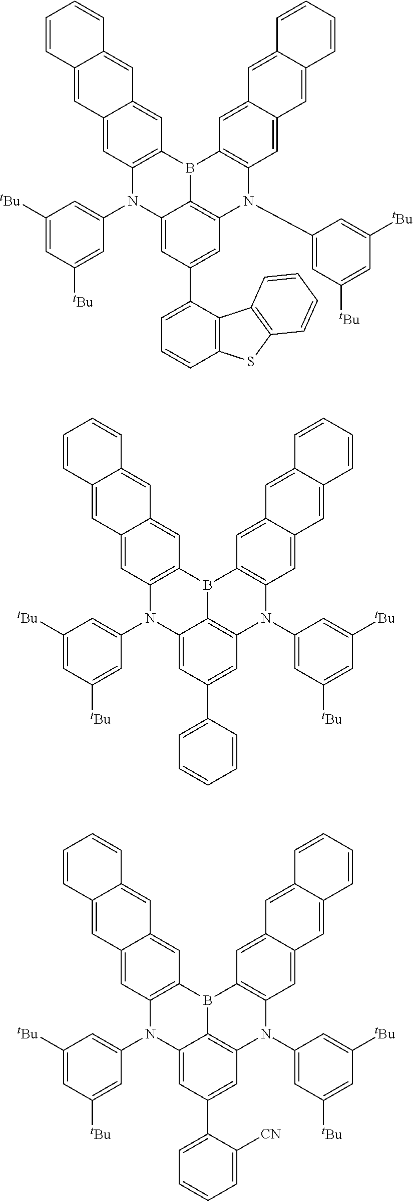 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cccc6sc7ccccc7c56)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccccc5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccccc5C#N)cc2c43)cc(C(C)(C)C)c1]

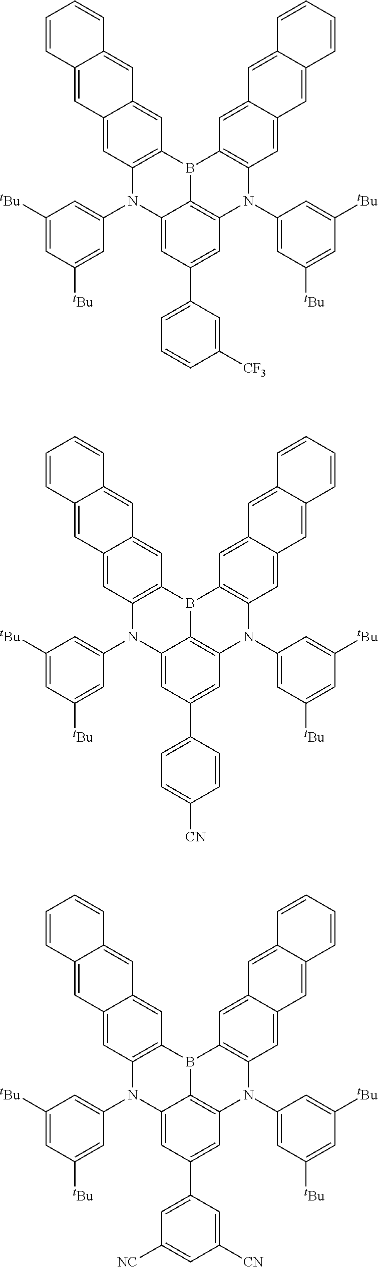 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cccc(C(F)(F)F)c5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc(C#N)cc5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cc(C#N)cc(C#N)c5)cc2c43)cc(C(C)(C)C)c1]

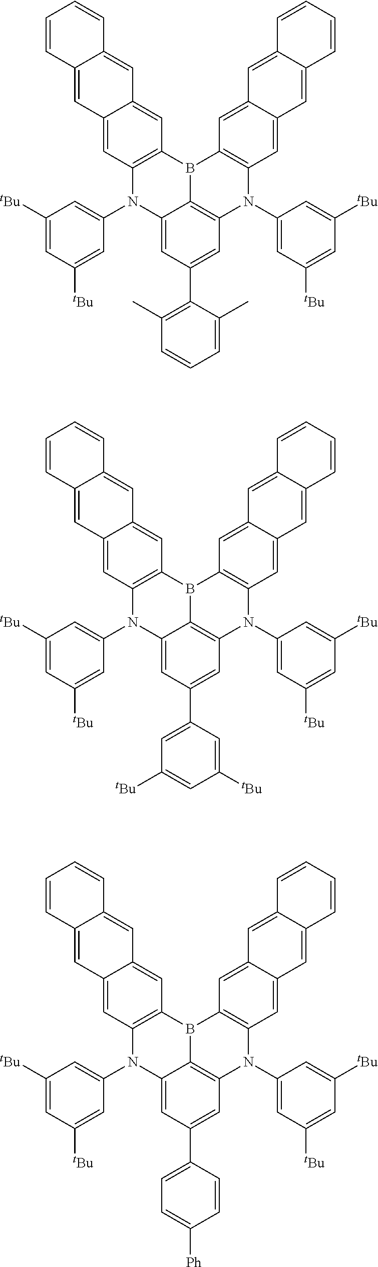 [SMILES: Cc1cccc(C)c1-c1cc2c3c(c1)N(c1cc(C(C)(C)C)cc(C(C)(C)C)c1)c1cc4cc5ccccc5cc4cc1B3c1cc3cc4ccccc4cc3cc1N2c1cc(C(C)(C)C)cc(C(C)(C)C)c1 ; CC(C)(C)c1cc(-c2cc3c4c(c2)N(c2cc(C(C)(C)C)cc(C(C)(C)C)c2)c2cc5cc6ccccc6cc5cc2B4c2cc4cc5ccccc5cc4cc2N3c2cc(C(C)(C)C)cc(C(C)(C)C)c2)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc(-c6ccccc6)cc5)cc2c43)cc(C(C)(C)C)c1]

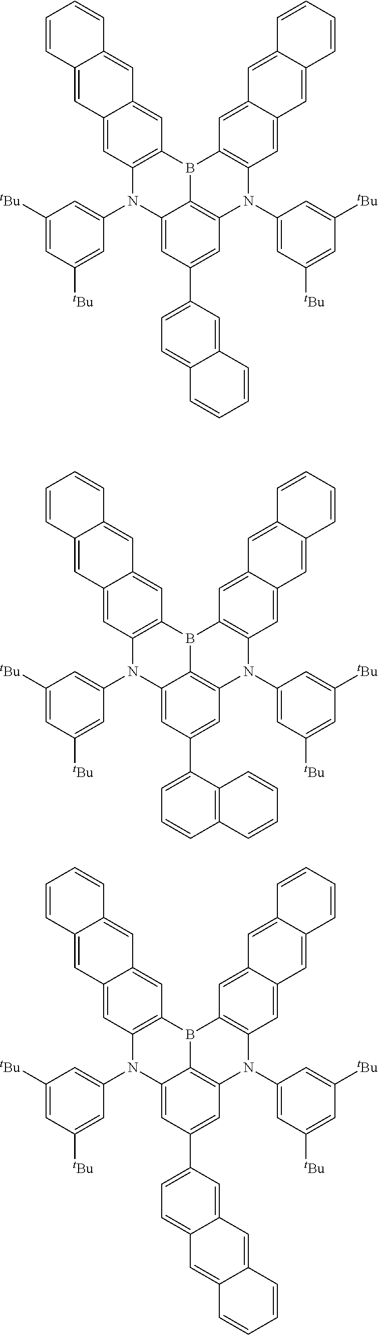 [SMILES: CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6ccccc6c5)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5cccc6ccccc56)cc2c43)cc(C(C)(C)C)c1 ; CC(C)(C)c1cc(N2c3cc4cc5ccccc5cc4cc3B3c4cc5cc6ccccc6cc5cc4N(c4cc(C(C)(C)C)cc(C(C)(C)C)c4)c4cc(-c5ccc6cc7ccccc7cc6c5)cc2c43)cc(C(C)(C)C)c1]

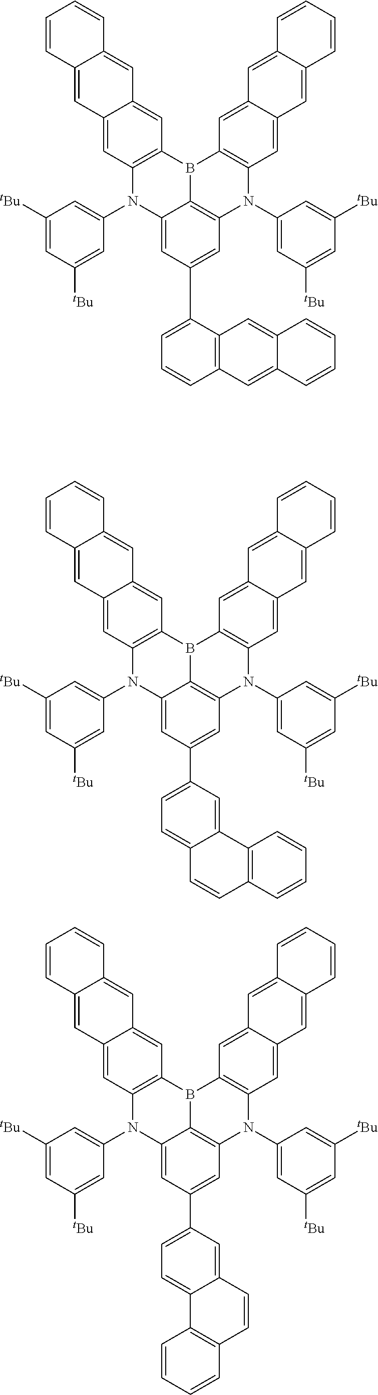

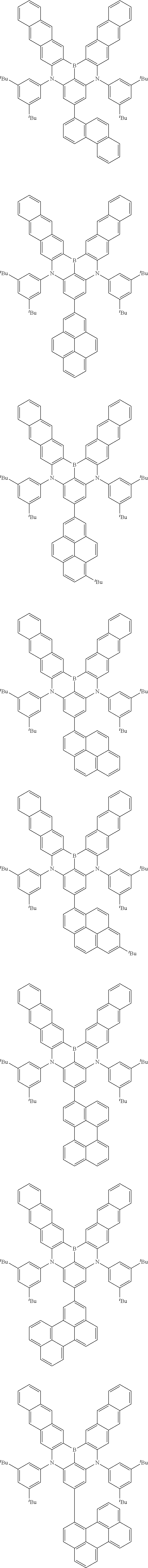

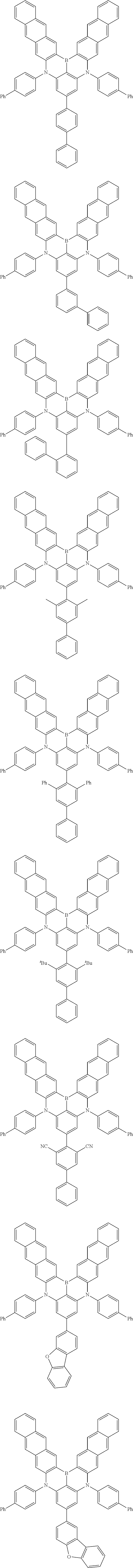

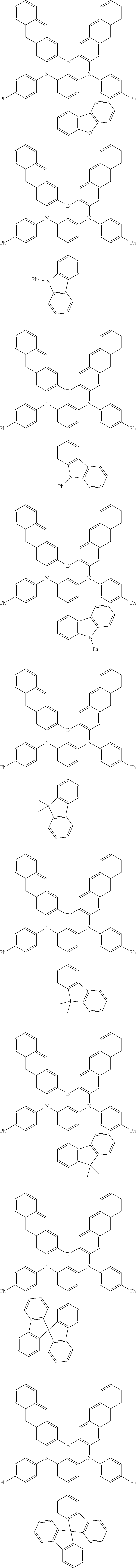

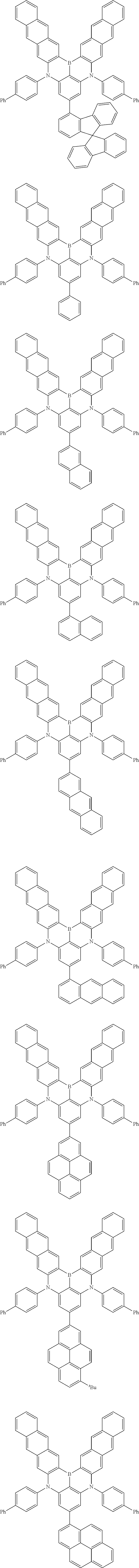

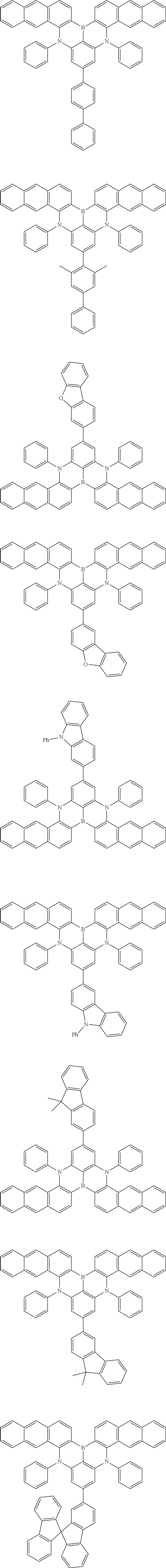

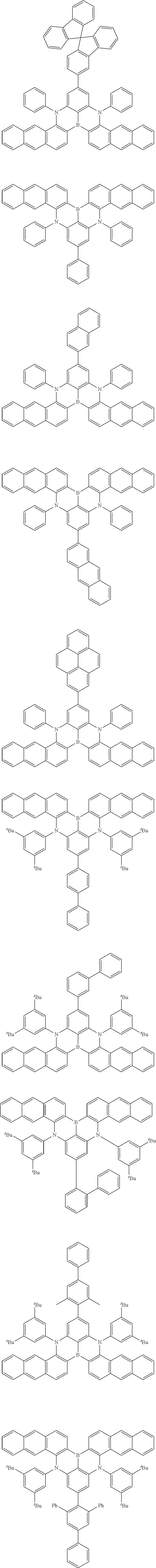

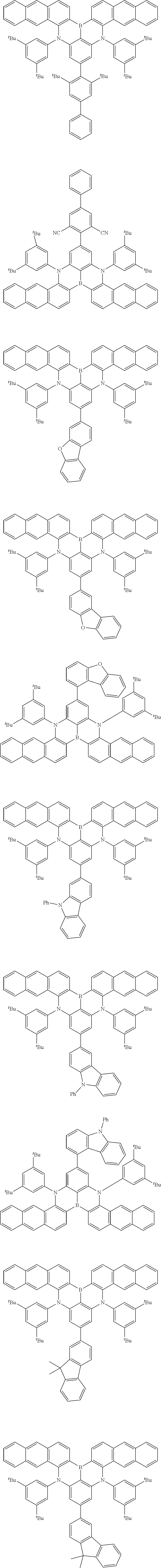

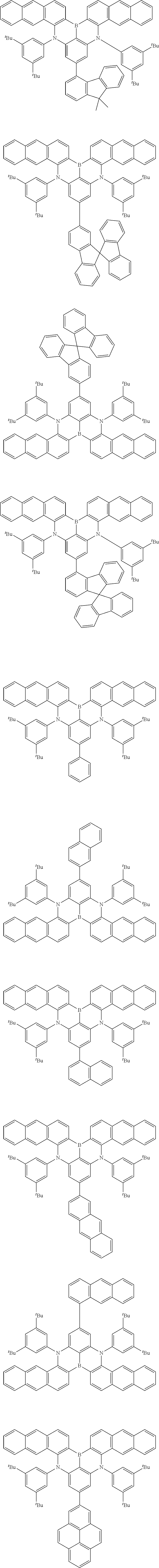

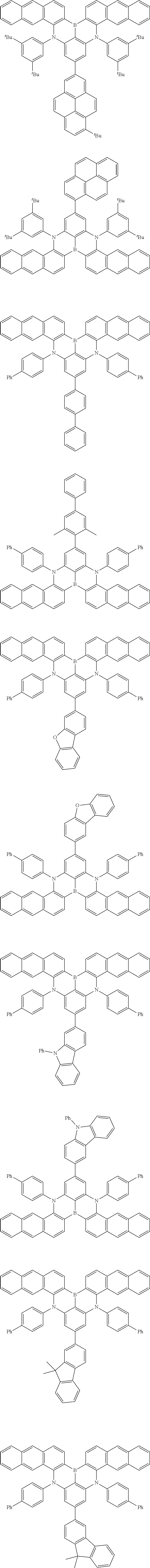

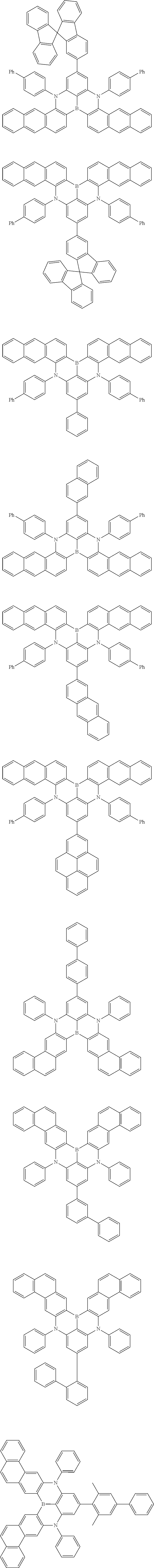

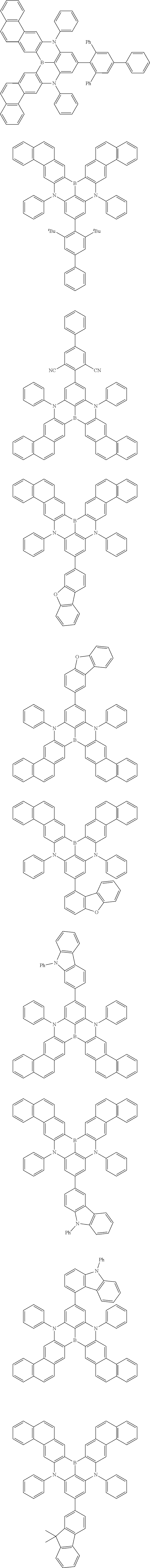

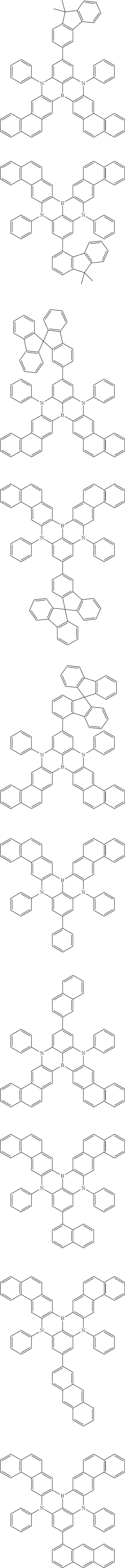

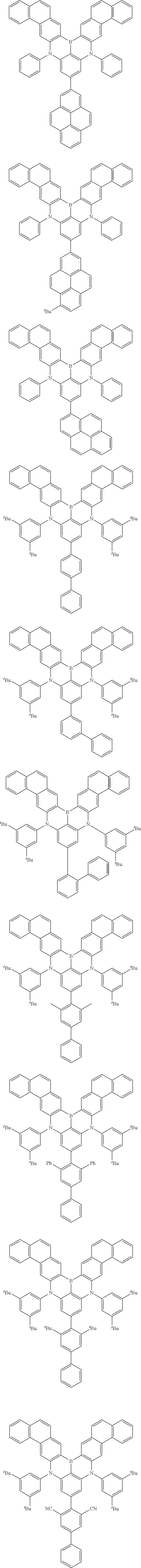

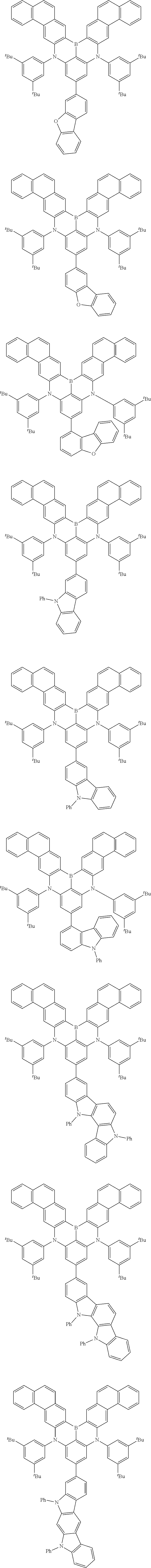

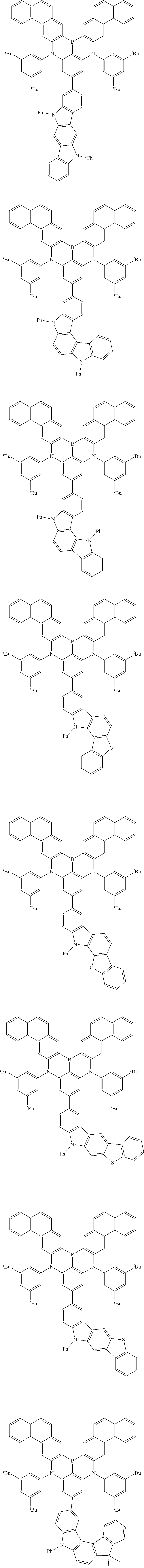

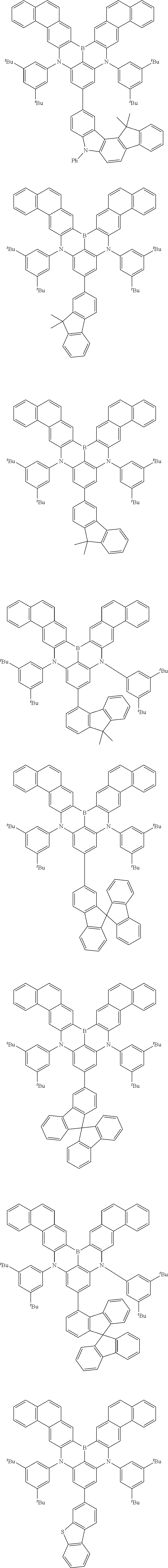

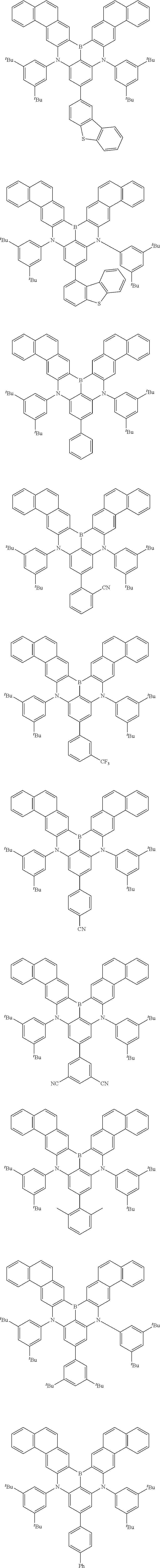

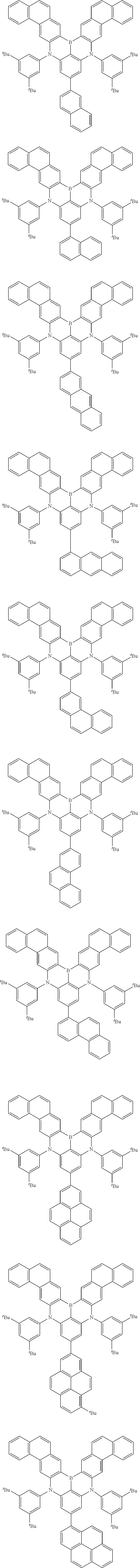

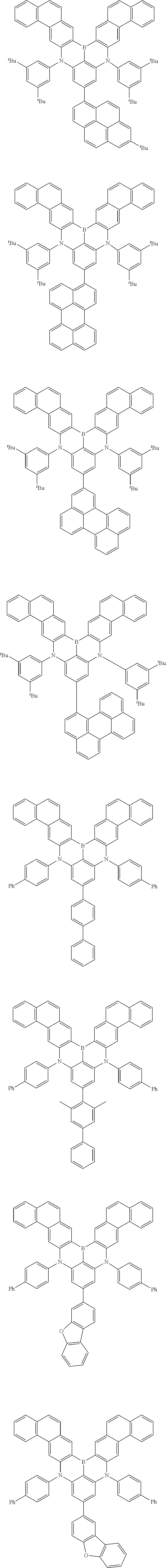

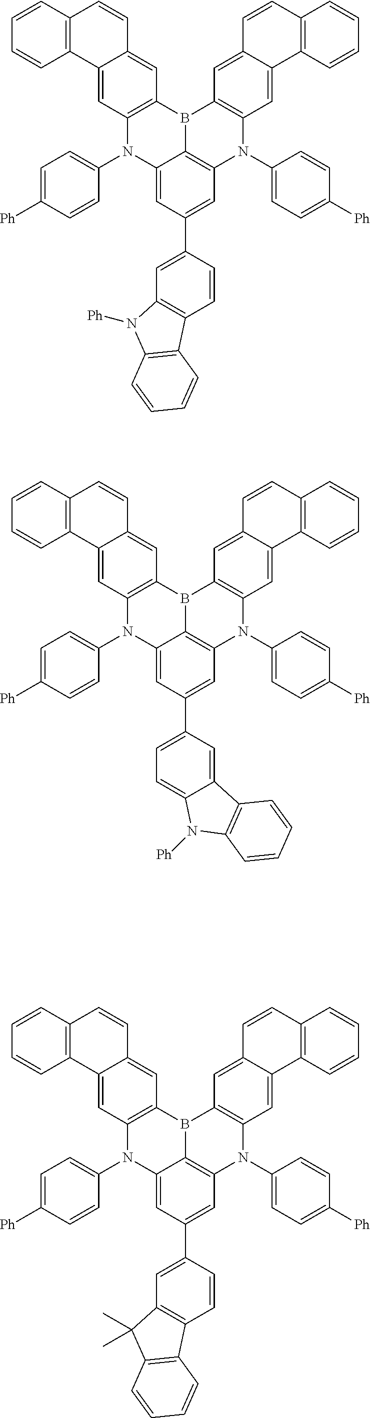 [SMILES: c1ccc(-c2ccc(N3c4cc5c(ccc6ccccc65)cc4B4c5cc6ccc7ccccc7c6cc5N(c5ccc(-c6ccccc6)cc5)c5cc(-c6ccc7c8ccccc8n(-c8ccccc8)c7c6)cc3c54)cc2)cc1 ; c1ccc(-c2ccc(N3c4cc5c(ccc6ccccc65)cc4B4c5cc6ccc7ccccc7c6cc5N(c5ccc(-c6ccccc6)cc5)c5cc(-c6ccc7c(c6)c6ccccc6n7-c6ccccc6)cc3c54)cc2)cc1 ; CC1(C)c2ccccc2-c2ccc(-c3cc4c5c(c3)N(c3ccc(-c6ccccc6)cc3)c3cc6c(ccc7ccccc76)cc3B5c3cc5ccc6ccccc6c5cc3N4c3ccc(-c4ccccc4)cc3)cc21]

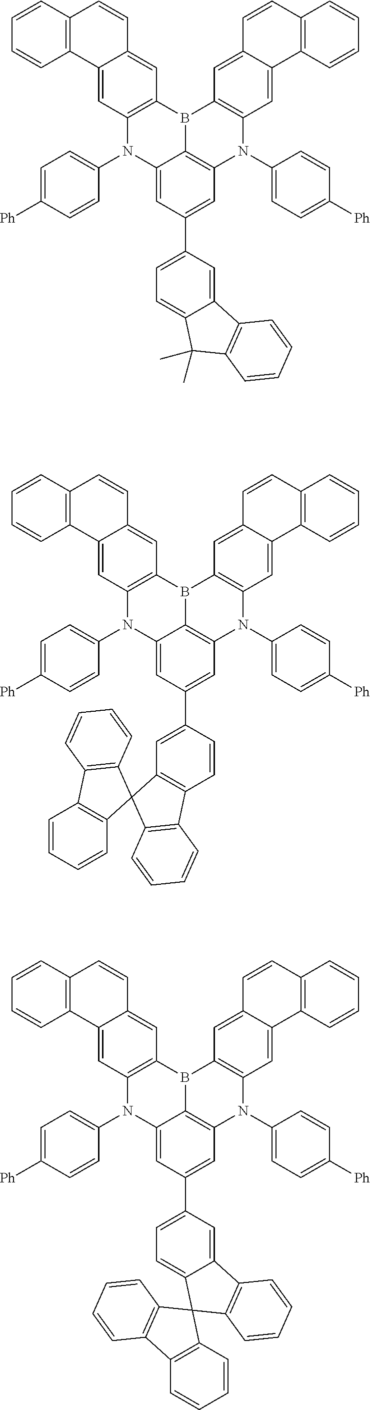 [SMILES: CC1(C)c2ccccc2-c2cc(-c3cc4c5c(c3)N(c3ccc(-c6ccccc6)cc3)c3cc6c(ccc7ccccc76)cc3B5c3cc5ccc6ccccc6c5cc3N4c3ccc(-c4ccccc4)cc3)ccc21 ; c1ccc(-c2ccc(N3c4cc5c(ccc6ccccc65)cc4B4c5cc6ccc7ccccc7c6cc5N(c5ccc(-c6ccccc6)cc5)c5cc(-c6ccc7c(c6)C6(c8ccccc8-c8ccccc86)c6ccccc6-7)cc3c54)cc2)cc1 ; c1ccc(-c2ccc(N3c4cc5c(ccc6ccccc65)cc4B4c5cc6ccc7ccccc7c6cc5N(c5ccc(-c6ccccc6)cc5)c5cc(-c6ccc7c(c6)-c6ccccc6C76c7ccccc7-c7ccccc76)cc3c54)cc2)cc1]

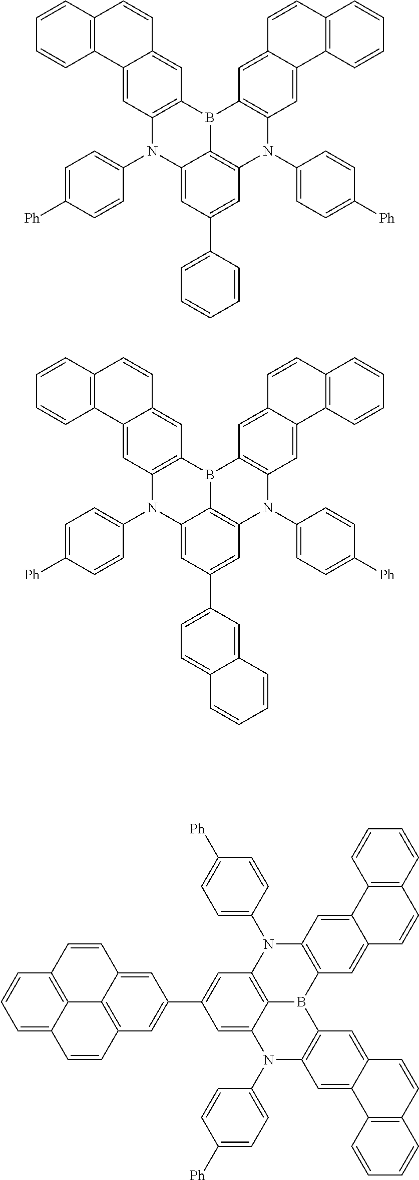 [SMILES: c1ccc(-c2ccc(N3c4cc5c(ccc6ccccc65)cc4B4c5cc6ccc7ccccc7c6cc5N(c5ccc(-c6ccccc6)cc5)c5cc(-c6ccccc6)cc3c54)cc2)cc1 ; c1ccc(-c2ccc(N3c4cc5c(ccc6ccccc65)cc4B4c5cc6ccc7ccccc7c6cc5N(c5ccc(-c6ccccc6)cc5)c5cc(-c6ccc7ccccc7c6)cc3c54)cc2)cc1 ; c1ccc(-c2ccc(N3c4cc5c(ccc6ccccc65)cc4B4c5cc6ccc7ccccc7c6cc5N(c5ccc(-c6ccccc6)cc5)c5cc(-c6cc7ccc8cccc9ccc(c6)c7c89)cc3c54)cc2)cc1]

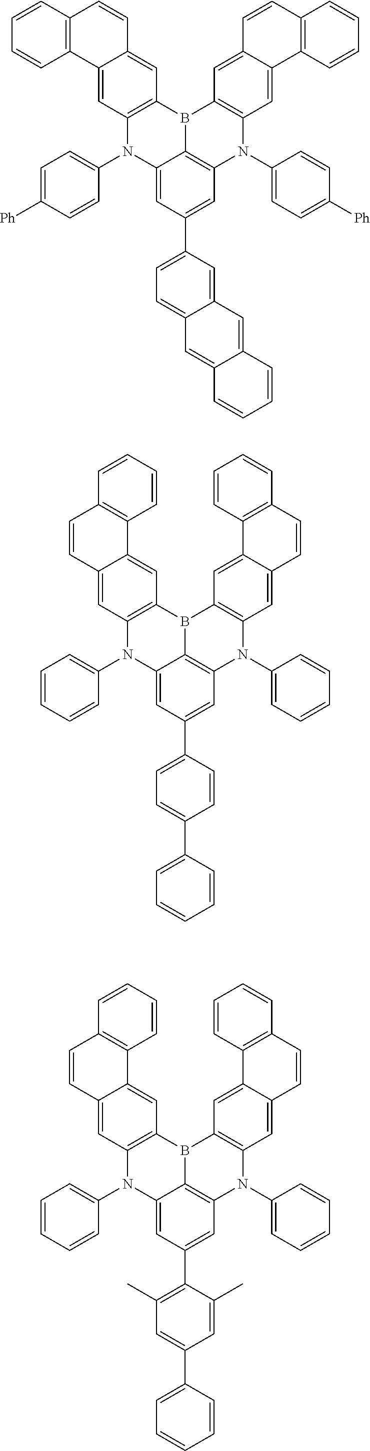

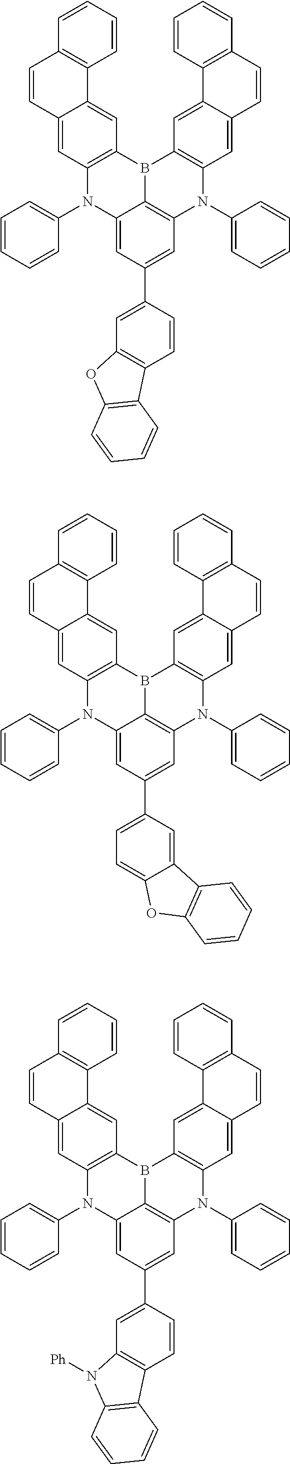 [SMILES: c1ccc(N2c3cc4ccc5ccccc5c4cc3B3c4cc5c(ccc6ccccc65)cc4N(c4ccccc4)c4cc(-c5ccc6c(c5)oc5ccccc56)cc2c43)cc1 ; c1ccc(N2c3cc4ccc5ccccc5c4cc3B3c4cc5c(ccc6ccccc65)cc4N(c4ccccc4)c4cc(-c5ccc6oc7ccccc7c6c5)cc2c43)cc1 ; c1ccc(N2c3cc4ccc5ccccc5c4cc3B3c4cc5c(ccc6ccccc65)cc4N(c4ccccc4)c4cc(-c5ccc6c7ccccc7n(-c7ccccc7)c6c5)cc2c43)cc1]

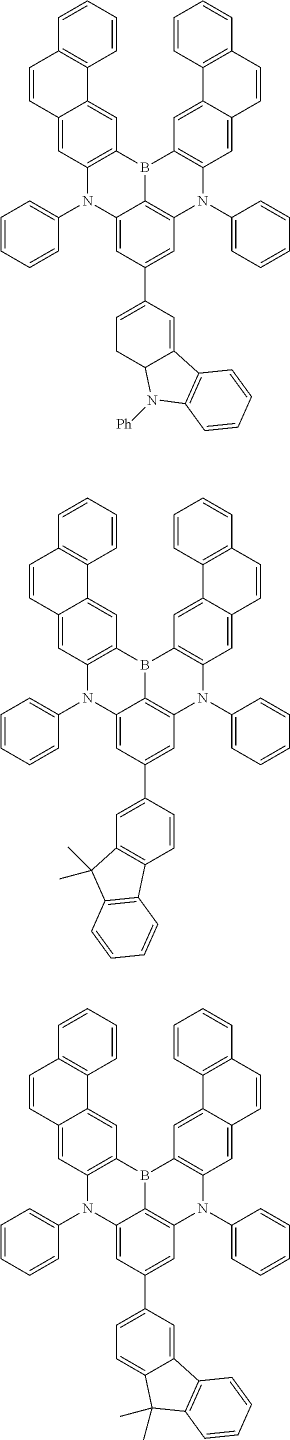 [SMILES: C1=C(c2cc3c4c(c2)N(c2ccccc2)c2cc5ccc6ccccc6c5cc2B4c2cc4c(ccc5ccccc54)cc2N3c2ccccc2)C=C2c3ccccc3N(c3ccccc3)C2C1 ; CC1(C)c2ccccc2-c2ccc(-c3cc4c5c(c3)N(c3ccccc3)c3cc6ccc7ccccc7c6cc3B5c3cc5c(ccc6ccccc65)cc3N4c3ccccc3)cc21 ; CC1(C)c2ccccc2-c2cc(-c3cc4c5c(c3)N(c3ccccc3)c3cc6ccc7ccccc7c6cc3B5c3cc5c(ccc6ccccc65)cc3N4c3ccccc3)ccc21]

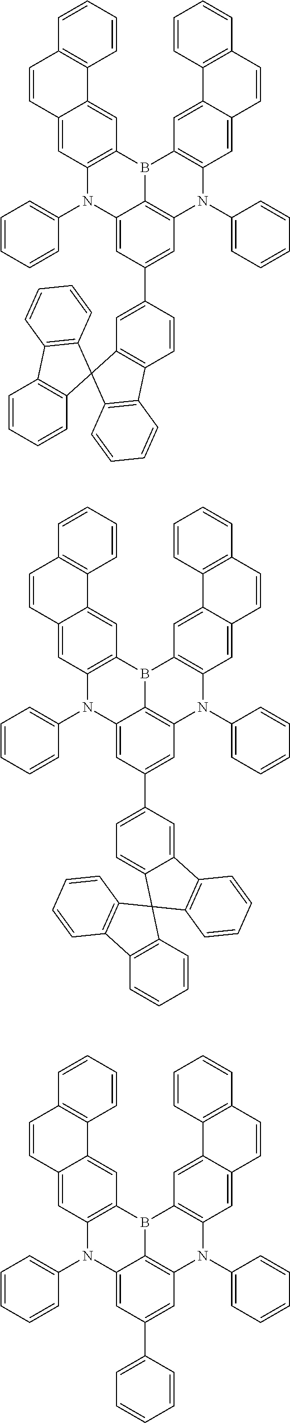 [SMILES: c1ccc(N2c3cc4ccc5ccccc5c4cc3B3c4cc5c(ccc6ccccc65)cc4N(c4ccccc4)c4cc(-c5ccc6c(c5)C5(c7ccccc7-c7ccccc75)c5ccccc5-6)cc2c43)cc1 ; c1ccc(N2c3cc4ccc5ccccc5c4cc3B3c4cc5c(ccc6ccccc65)cc4N(c4ccccc4)c4cc(-c5ccc6c(c5)-c5ccccc5C65c6ccccc6-c6ccccc65)cc2c43)cc1 ; c1ccc(-c2cc3c4c(c2)N(c2ccccc2)c2cc5ccc6ccccc6c5cc2B4c2cc4c(ccc5ccccc54)cc2N3c2ccccc2)cc1]

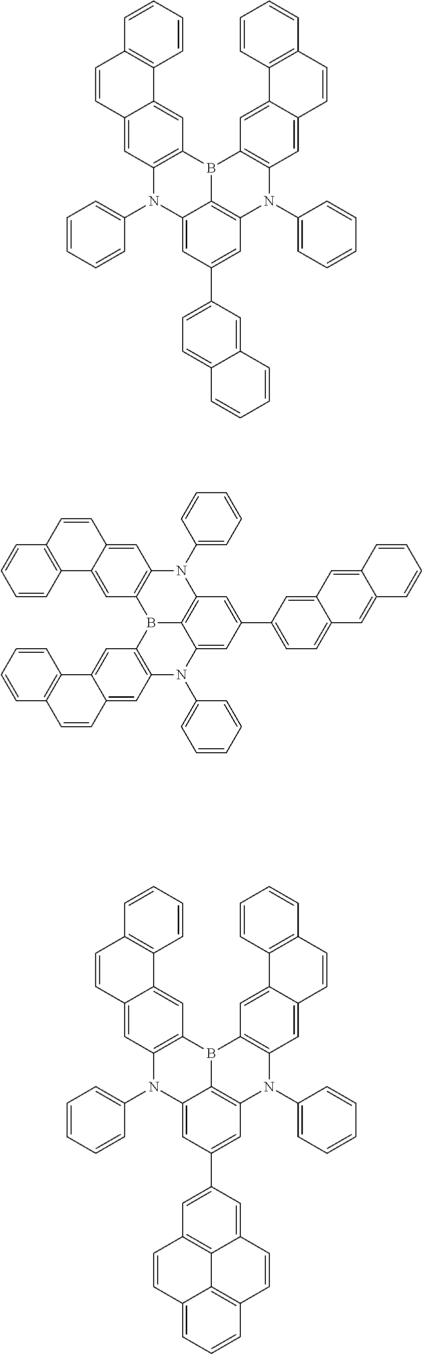 [SMILES: c1ccc(N2c3cc4ccc5ccccc5c4cc3B3c4cc5c(ccc6ccccc65)cc4N(c4ccccc4)c4cc(-c5ccc6ccccc6c5)cc2c43)cc1 ; c1ccc(N2c3cc4ccc5ccccc5c4cc3B3c4cc5c(ccc6ccccc65)cc4N(c4ccccc4)c4cc(-c5ccc6cc7ccccc7cc6c5)cc2c43)cc1 ; c1ccc(N2c3cc4ccc5ccccc5c4cc3B3c4cc5c(ccc6ccccc65)cc4N(c4ccccc4)c4cc(-c5cc6ccc7cccc8ccc(c5)c6c78)cc2c43)cc1]

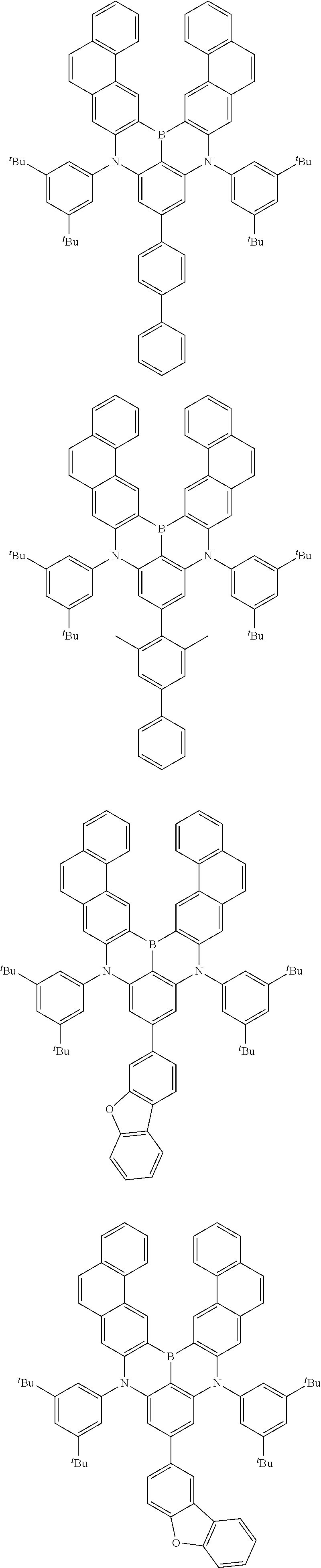

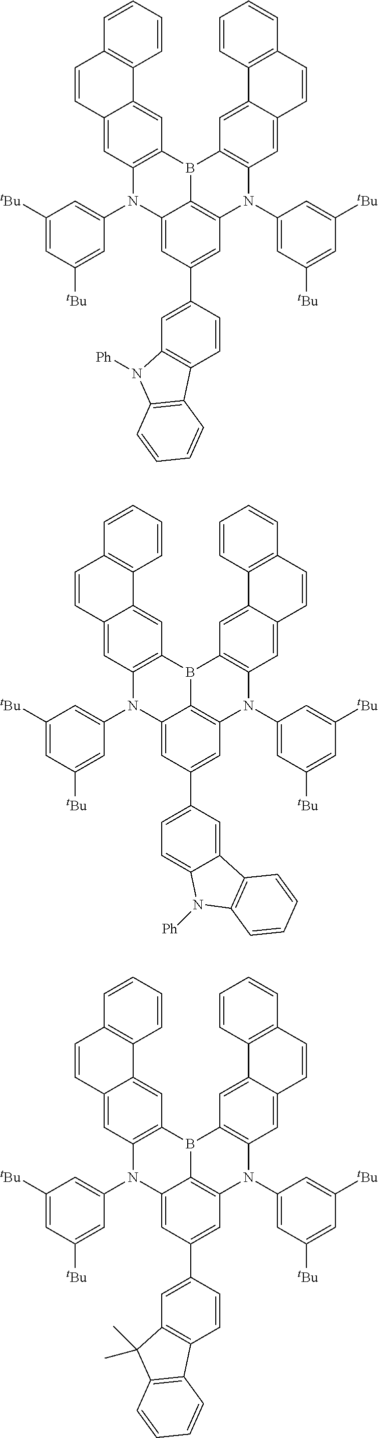

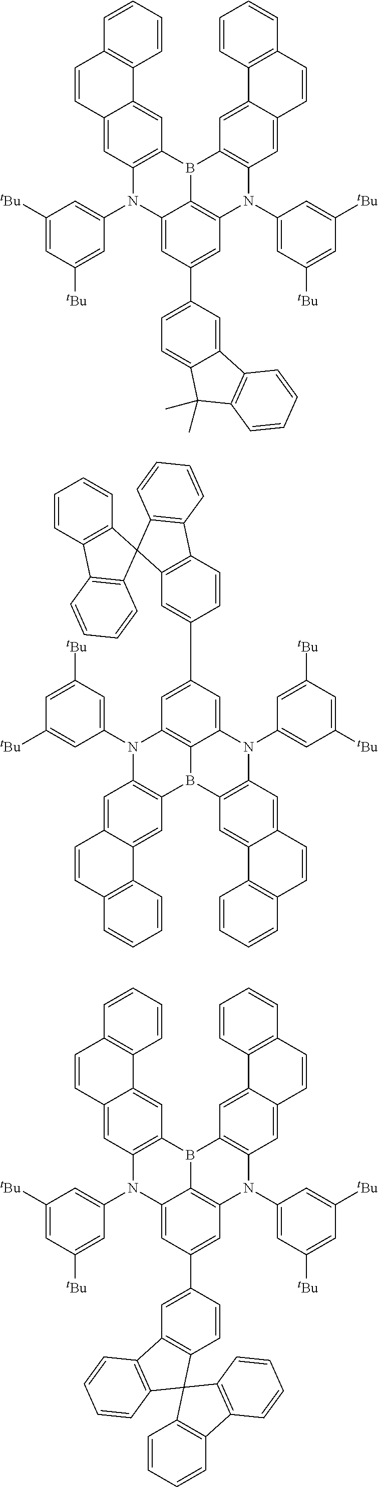

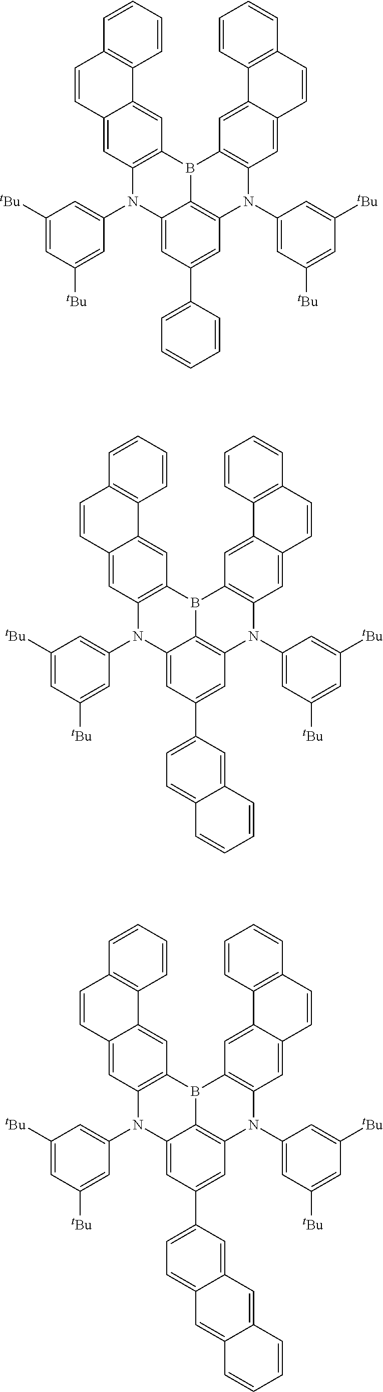 [SMILES: CC(C)(C)c1cc(N2c3cc4ccc5ccccc5c4cc3B3c4cc5c(ccc6ccccc65)cc4N(c4cc(C(C)(C)C)cc(C(C)(C)C)c4)c4cc(-c5ccccc5)cc2c43)cc(C(C)(C)C)c1 ; CC(C)(C)c1cc(N2c3cc4ccc5ccccc5c4cc3B3c4cc5c(ccc6ccccc65)cc4N(c4cc(C(C)(C)C)cc(C(C)(C)C)c4)c4cc(-c5ccc6ccccc6c5)cc2c43)cc(C(C)(C)C)c1 ; CC(C)(C)c1cc(N2c3cc4ccc5ccccc5c4cc3B3c4cc5c(ccc6ccccc65)cc4N(c4cc(C(C)(C)C)cc(C(C)(C)C)c4)c4cc(-c5ccc6cc7ccccc7cc6c5)cc2c43)cc(C(C)(C)C)c1]

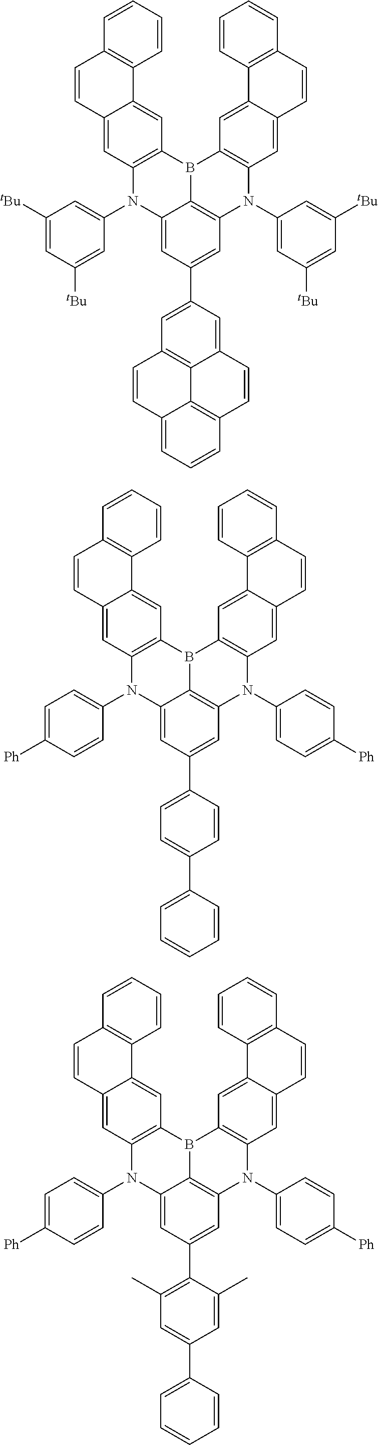 [SMILES: CC(C)(C)c1cc(N2c3cc4ccc5ccccc5c4cc3B3c4cc5c(ccc6ccccc65)cc4N(c4cc(C(C)(C)C)cc(C(C)(C)C)c4)c4cc(-c5cc6ccc7cccc8ccc(c5)c6c78)cc2c43)cc(C(C)(C)C)c1 ; c1ccc(-c2ccc(-c3cc4c5c(c3)N(c3ccc(-c6ccccc6)cc3)c3cc6ccc7ccccc7c6cc3B5c3cc5c(ccc6ccccc65)cc3N4c3ccc(-c4ccccc4)cc3)cc2)cc1 ; Cc1cc(-c2ccccc2)cc(C)c1-c1cc2c3c(c1)N(c1ccc(-c4ccccc4)cc1)c1cc4ccc5ccccc5c4cc1B3c1cc3c(ccc4ccccc43)cc1N2c1ccc(-c2ccccc2)cc1]

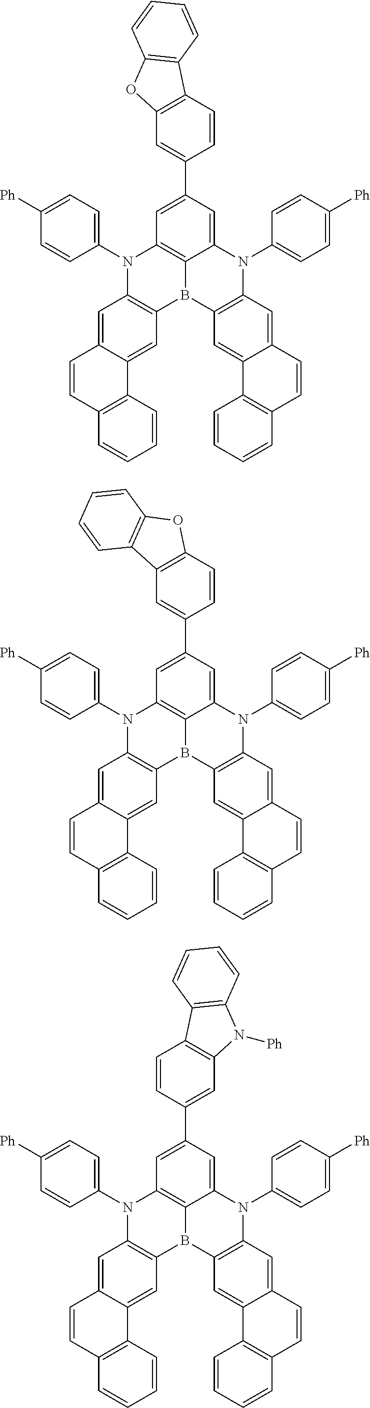

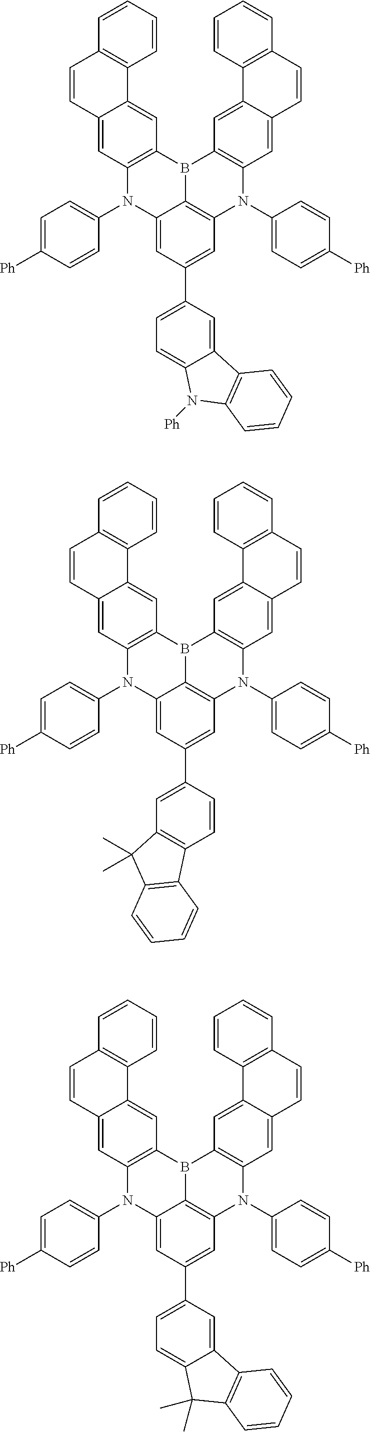 [SMILES: c1ccc(-c2ccc(N3c4cc5ccc6ccccc6c5cc4B4c5cc6c(ccc7ccccc76)cc5N(c5ccc(-c6ccccc6)cc5)c5cc(-c6ccc7c(c6)c6ccccc6n7-c6ccccc6)cc3c54)cc2)cc1 ; CC1(C)c2ccccc2-c2ccc(-c3cc4c5c(c3)N(c3ccc(-c6ccccc6)cc3)c3cc6ccc7ccccc7c6cc3B5c3cc5c(ccc6ccccc65)cc3N4c3ccc(-c4ccccc4)cc3)cc21 ; CC1(C)c2ccccc2-c2cc(-c3cc4c5c(c3)N(c3ccc(-c6ccccc6)cc3)c3cc6ccc7ccccc7c6cc3B5c3cc5c(ccc6ccccc65)cc3N4c3ccc(-c4ccccc4)cc3)ccc21]

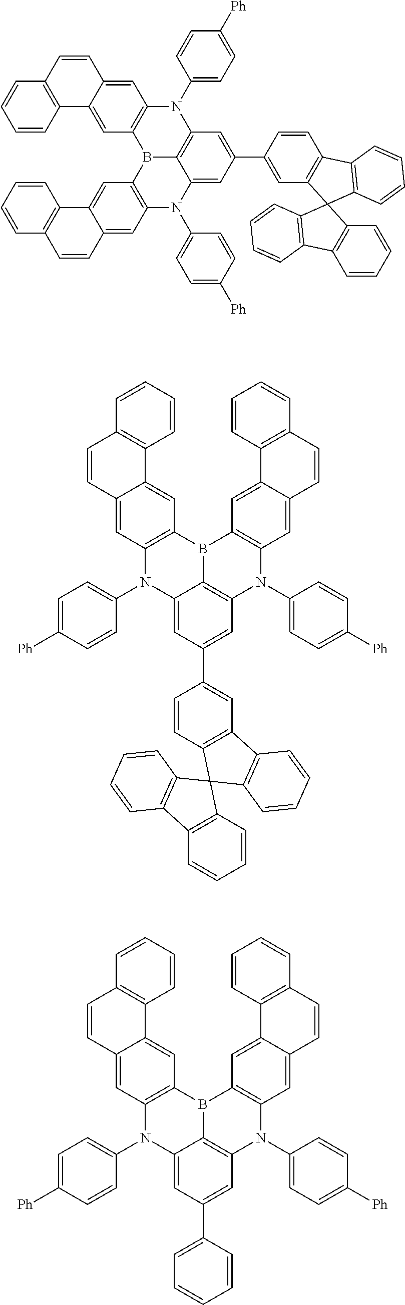 [SMILES: c1ccc(-c2ccc(N3c4cc5ccc6ccccc6c5cc4B4c5cc6c(ccc7ccccc76)cc5N(c5ccc(-c6ccccc6)cc5)c5cc(-c6ccc7c(c6)C6(c8ccccc8-c8ccccc86)c6ccccc6-7)cc3c54)cc2)cc1 ; c1ccc(-c2ccc(N3c4cc5ccc6ccccc6c5cc4B4c5cc6c(ccc7ccccc76)cc5N(c5ccc(-c6ccccc6)cc5)c5cc(-c6ccc7c(c6)-c6ccccc6C76c7ccccc7-c7ccccc76)cc3c54)cc2)cc1 ; c1ccc(-c2ccc(N3c4cc5ccc6ccccc6c5cc4B4c5cc6c(ccc7ccccc76)cc5N(c5ccc(-c6ccccc6)cc5)c5cc(-c6ccccc6)cc3c54)cc2)cc1]

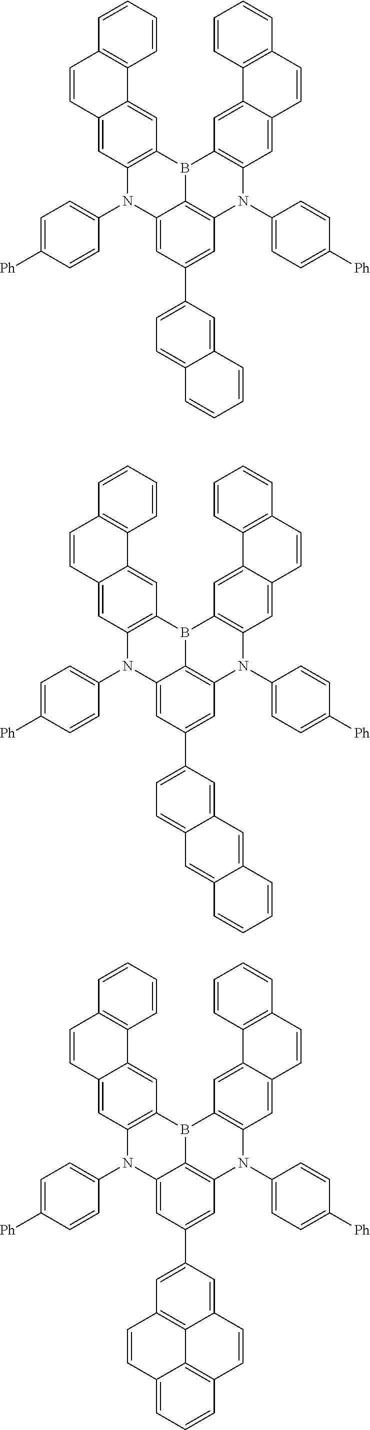

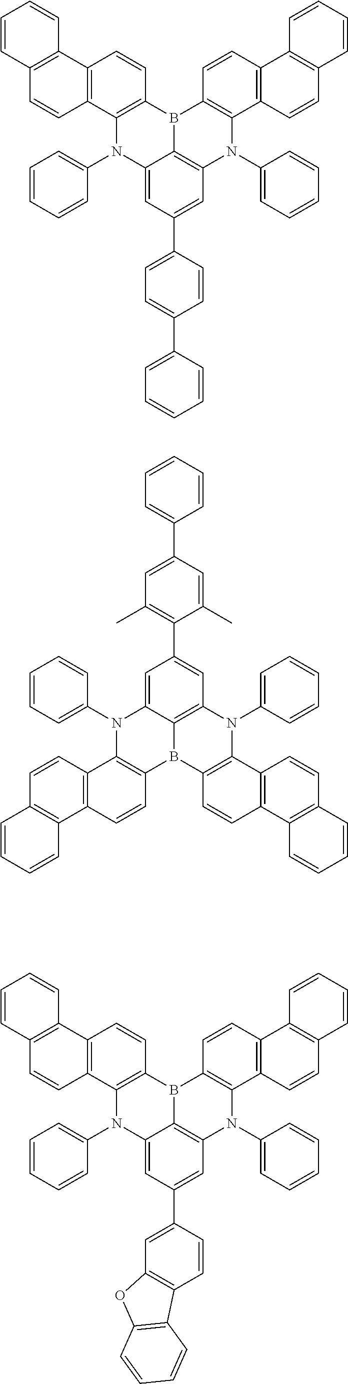

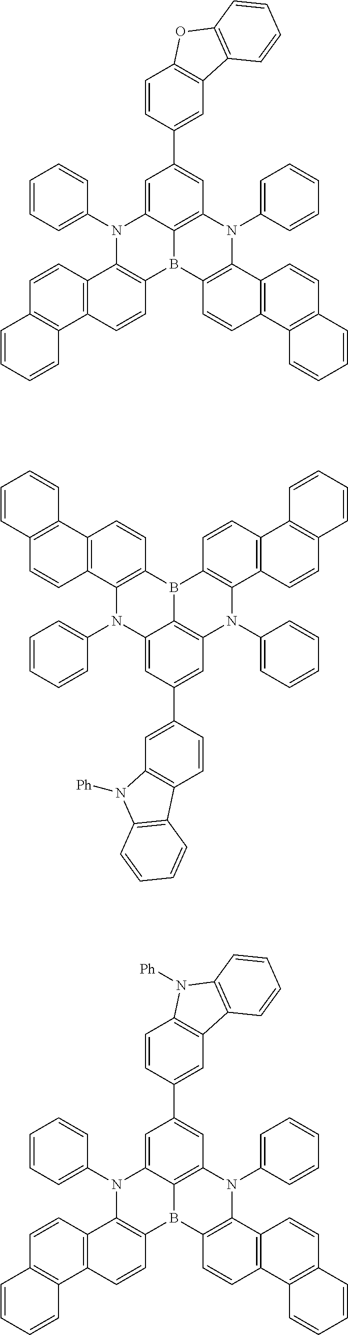 [SMILES: c1ccc(N2c3cc(-c4ccc5oc6ccccc6c5c4)cc4c3B(c3ccc5c(ccc6ccccc65)c32)c2ccc3c(ccc5ccccc53)c2N4c2ccccc2)cc1 ; c1ccc(N2c3cc(-c4ccc5c6ccccc6n(-c6ccccc6)c5c4)cc4c3B(c3ccc5c(ccc6ccccc65)c32)c2ccc3c(ccc5ccccc53)c2N4c2ccccc2)cc1 ; c1ccc(N2c3cc(-c4ccc5c(c4)c4ccccc4n5-c4ccccc4)cc4c3B(c3ccc5c(ccc6ccccc65)c32)c2ccc3c(ccc5ccccc53)c2N4c2ccccc2)cc1]

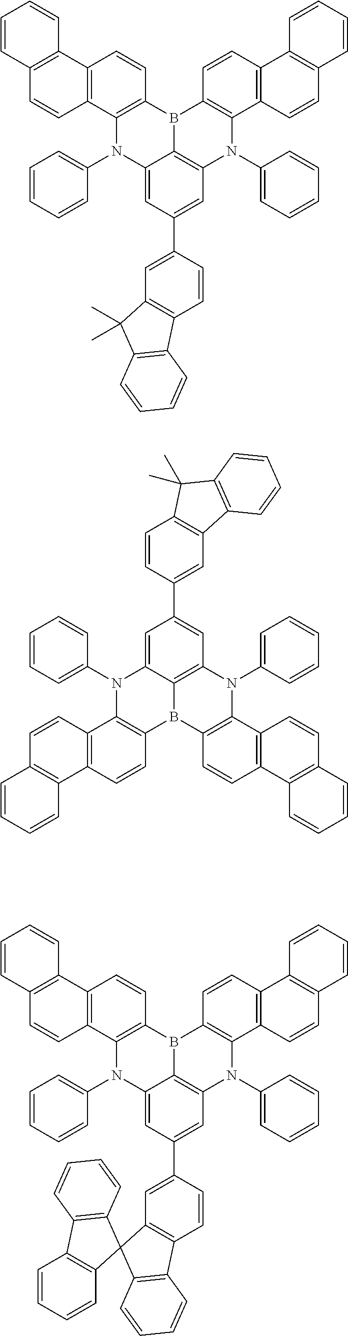 [SMILES: CC1(C)c2ccccc2-c2ccc(-c3cc4c5c(c3)N(c3ccccc3)c3c(ccc6c3ccc3ccccc36)B5c3ccc5c(ccc6ccccc65)c3N4c3ccccc3)cc21 ; CC1(C)c2ccccc2-c2cc(-c3cc4c5c(c3)N(c3ccccc3)c3c(ccc6c3ccc3ccccc36)B5c3ccc5c(ccc6ccccc65)c3N4c3ccccc3)ccc21 ; c1ccc(N2c3cc(-c4ccc5c(c4)C4(c6ccccc6-c6ccccc64)c4ccccc4-5)cc4c3B(c3ccc5c(ccc6ccccc65)c32)c2ccc3c(ccc5ccccc53)c2N4c2ccccc2)cc1]

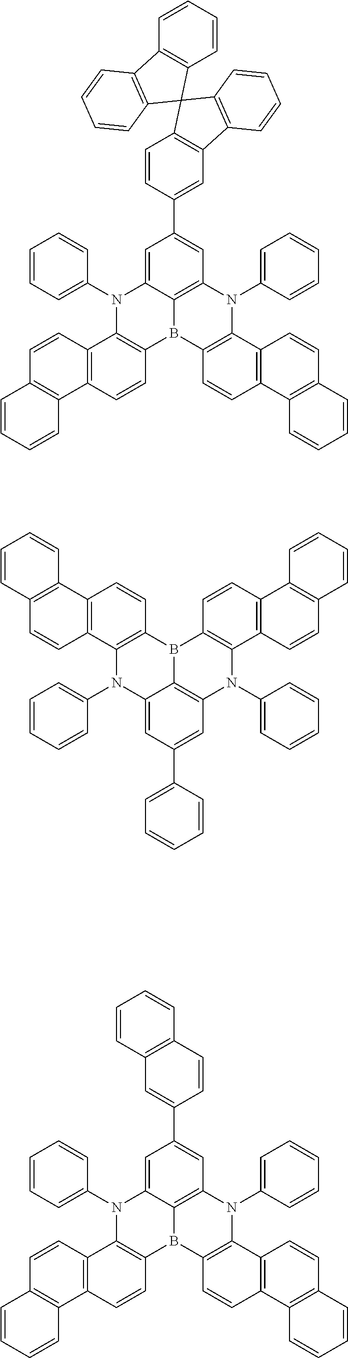 [SMILES: c1ccc(N2c3cc(-c4ccc5c(c4)-c4ccccc4C54c5ccccc5-c5ccccc54)cc4c3B(c3ccc5c(ccc6ccccc65)c32)c2ccc3c(ccc5ccccc53)c2N4c2ccccc2)cc1 ; c1ccc(-c2cc3c4c(c2)N(c2ccccc2)c2c(ccc5c2ccc2ccccc25)B4c2ccc4c(ccc5ccccc54)c2N3c2ccccc2)cc1 ; c1ccc(N2c3cc(-c4ccc5ccccc5c4)cc4c3B(c3ccc5c(ccc6ccccc65)c32)c2ccc3c(ccc5ccccc53)c2N4c2ccccc2)cc1]

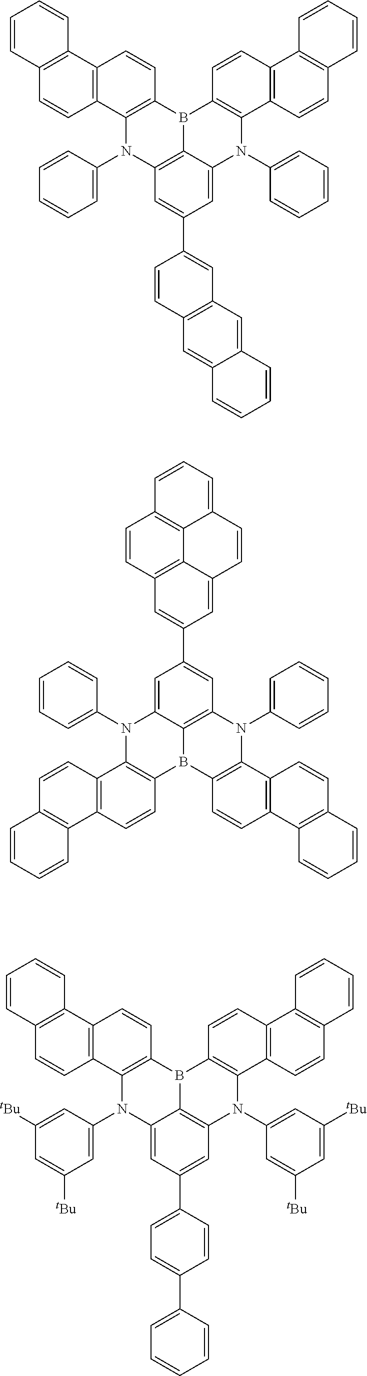 [SMILES: c1ccc(N2c3cc(-c4ccc5cc6ccccc6cc5c4)cc4c3B(c3ccc5c(ccc6ccccc65)c32)c2ccc3c(ccc5ccccc53)c2N4c2ccccc2)cc1 ; c1ccc(N2c3cc(-c4cc5ccc6cccc7ccc(c4)c5c67)cc4c3B(c3ccc5c(ccc6ccccc65)c32)c2ccc3c(ccc5ccccc53)c2N4c2ccccc2)cc1 ; CC(C)(C)c1cc(N2c3cc(-c4ccc(-c5ccccc5)cc4)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1]

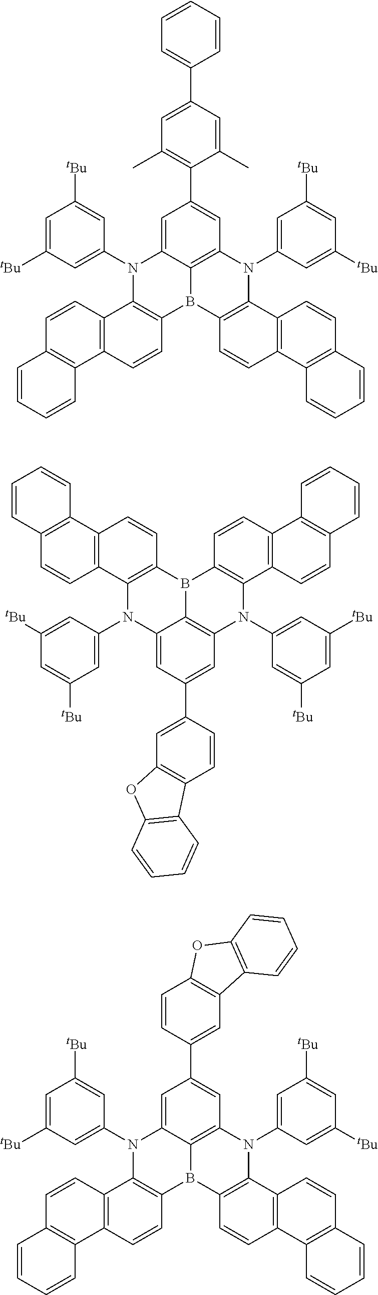 [SMILES: Cc1cc(-c2ccccc2)cc(C)c1-c1cc2c3c(c1)N(c1cc(C(C)(C)C)cc(C(C)(C)C)c1)c1c(ccc4c1ccc1ccccc14)B3c1ccc3c(ccc4ccccc43)c1N2c1cc(C(C)(C)C)cc(C(C)(C)C)c1 ; CC(C)(C)c1cc(N2c3cc(-c4ccc5c(c4)oc4ccccc45)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; CC(C)(C)c1cc(N2c3cc(-c4ccc5oc6ccccc6c5c4)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1]

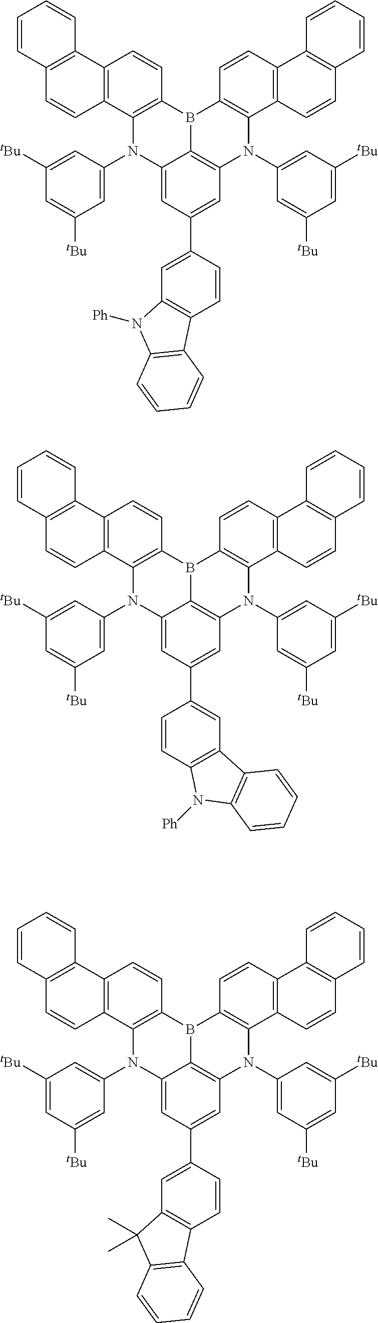 [SMILES: CC(C)(C)c1cc(N2c3cc(-c4ccc5c6ccccc6n(-c6ccccc6)c5c4)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; CC(C)(C)c1cc(N2c3cc(-c4ccc5c(c4)c4ccccc4n5-c4ccccc4)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; CC(C)(C)c1cc(N2c3cc(-c4ccc5c(c4)C(C)(C)c4ccccc4-5)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1]

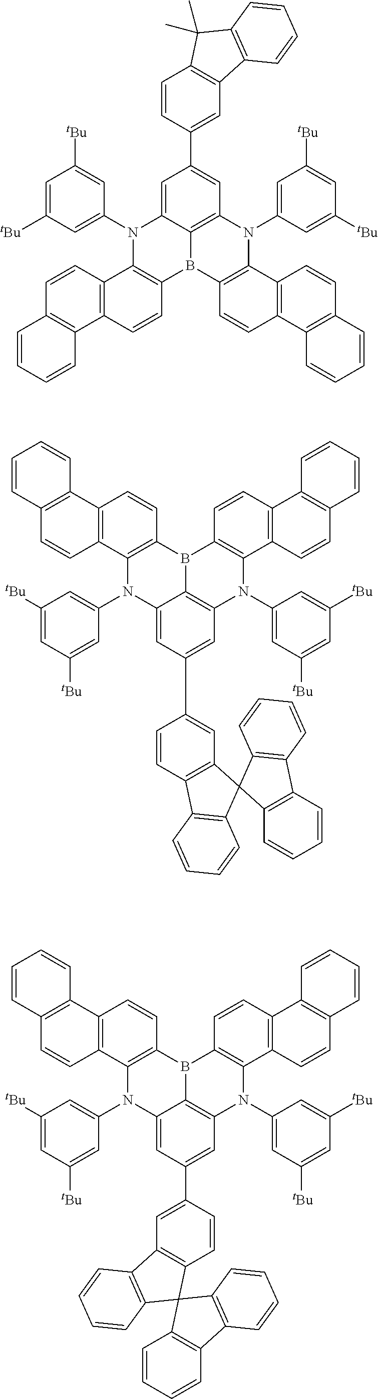 [SMILES: CC(C)(C)c1cc(N2c3cc(-c4ccc5c(c4)-c4ccccc4C5(C)C)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; CC(C)(C)c1cc(N2c3cc(-c4ccc5c(c4)C4(c6ccccc6-c6ccccc64)c4ccccc4-5)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; CC(C)(C)c1cc(N2c3cc(-c4ccc5c(c4)-c4ccccc4C54c5ccccc5-c5ccccc54)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1]

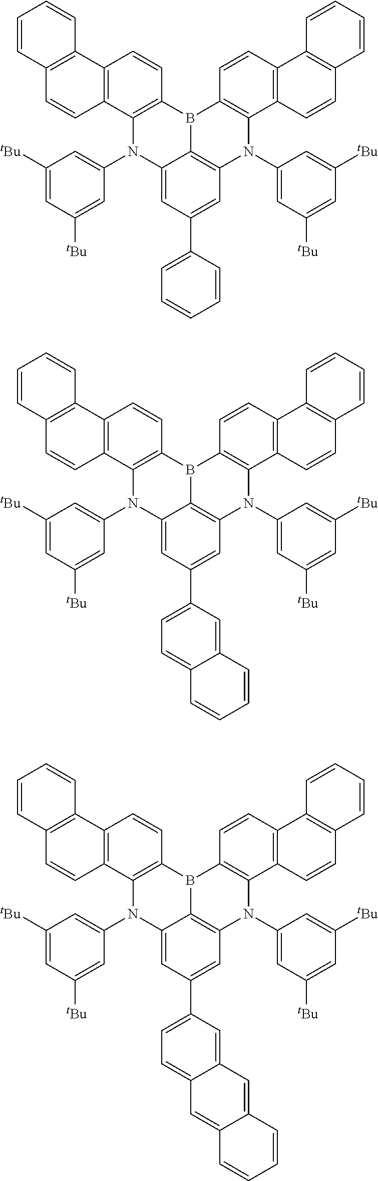 [SMILES: CC(C)(C)c1cc(N2c3cc(-c4ccccc4)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; CC(C)(C)c1cc(N2c3cc(-c4ccc5ccccc5c4)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; CC(C)(C)c1cc(N2c3cc(-c4ccc5cc6ccccc6cc5c4)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1]

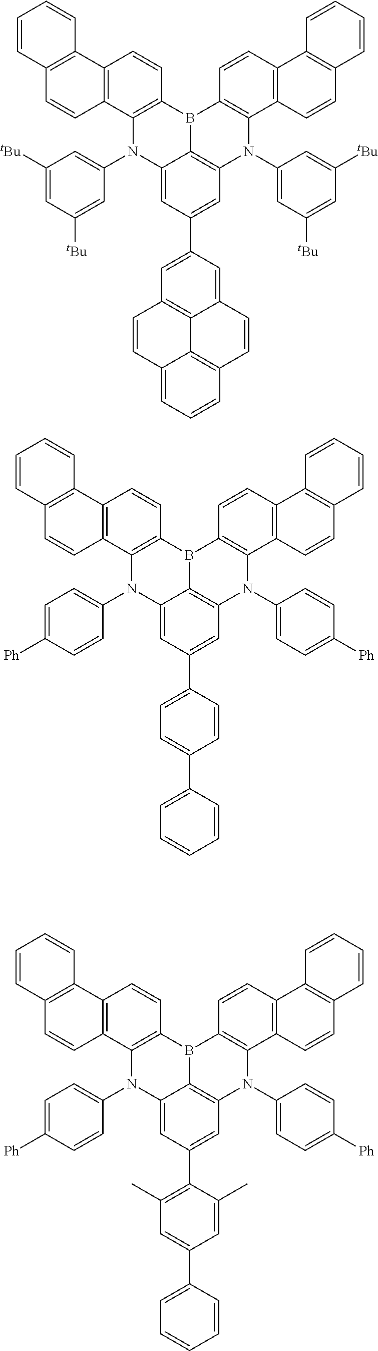 [SMILES: CC(C)(C)c1cc(N2c3cc(-c4cc5ccc6cccc7ccc(c4)c5c67)cc4c3B(c3ccc5c(ccc6ccccc65)c32)c2ccc3c(ccc5ccccc53)c2N4c2cc(C(C)(C)C)cc(C(C)(C)C)c2)cc(C(C)(C)C)c1 ; c1ccc(-c2ccc(-c3cc4c5c(c3)N(c3ccc(-c6ccccc6)cc3)c3c(ccc6c3ccc3ccccc36)B5c3ccc5c(ccc6ccccc65)c3N4c3ccc(-c4ccccc4)cc3)cc2)cc1 ; Cc1cc(-c2ccccc2)cc(C)c1-c1cc2c3c(c1)N(c1ccc(-c4ccccc4)cc1)c1c(ccc4c1ccc1ccccc14)B3c1ccc3c(ccc4ccccc43)c1N2c1ccc(-c2ccccc2)cc1]

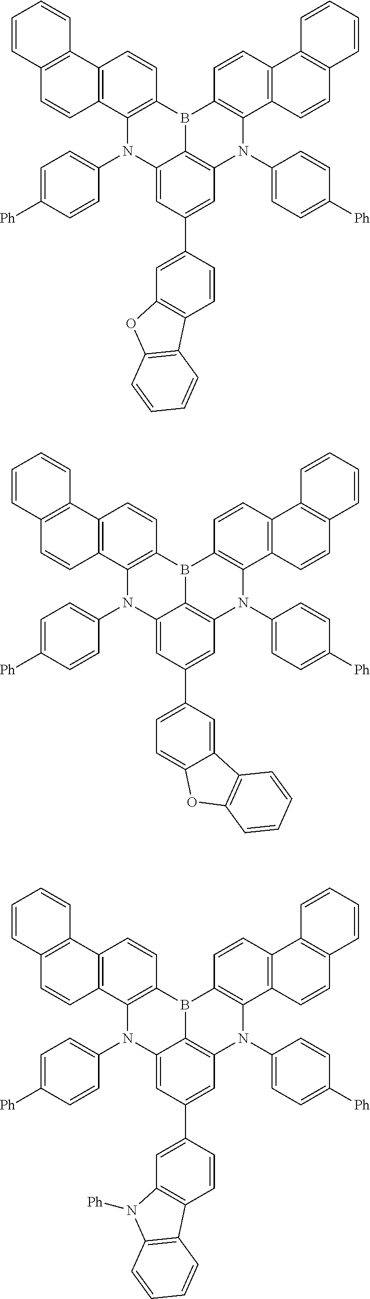 [SMILES: c1ccc(-c2ccc(N3c4cc(-c5ccc6c(c5)oc5ccccc56)cc5c4B(c4ccc6c(ccc7ccccc76)c43)c3ccc4c(ccc6ccccc64)c3N5c3ccc(-c4ccccc4)cc3)cc2)cc1 ; c1ccc(-c2ccc(N3c4cc(-c5ccc6oc7ccccc7c6c5)cc5c4B(c4ccc6c(ccc7ccccc76)c43)c3ccc4c(ccc6ccccc64)c3N5c3ccc(-c4ccccc4)cc3)cc2)cc1 ; c1ccc(-c2ccc(N3c4cc(-c5ccc6c7ccccc7n(-c7ccccc7)c6c5)cc5c4B(c4ccc6c(ccc7ccccc76)c43)c3ccc4c(ccc6ccccc64)c3N5c3ccc(-c4ccccc4)cc3)cc2)cc1]

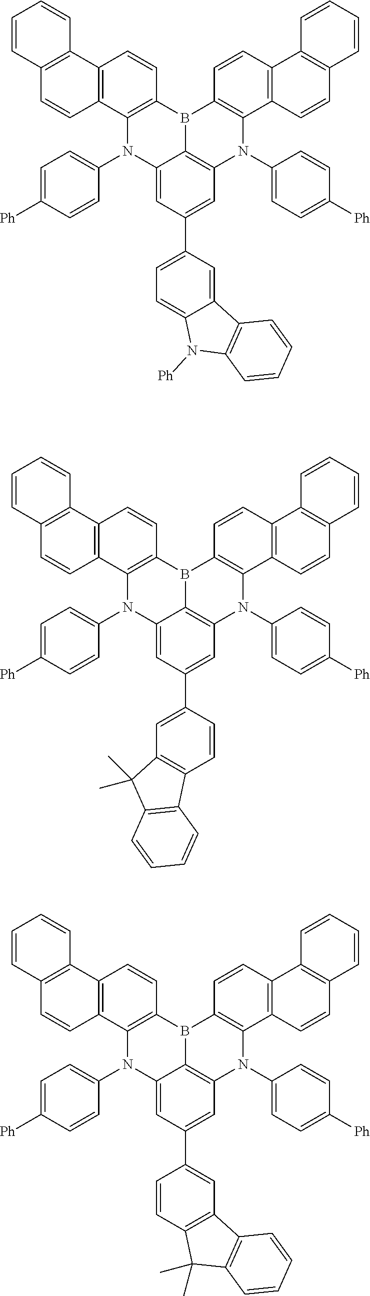 [SMILES: c1ccc(-c2ccc(N3c4cc(-c5ccc6c(c5)c5ccccc5n6-c5ccccc5)cc5c4B(c4ccc6c(ccc7ccccc76)c43)c3ccc4c(ccc6ccccc64)c3N5c3ccc(-c4ccccc4)cc3)cc2)cc1 ; CC1(C)c2ccccc2-c2ccc(-c3cc4c5c(c3)N(c3ccc(-c6ccccc6)cc3)c3c(ccc6c3ccc3ccccc36)B5c3ccc5c(ccc6ccccc65)c3N4c3ccc(-c4ccccc4)cc3)cc21 ; CC1(C)c2ccccc2-c2cc(-c3cc4c5c(c3)N(c3ccc(-c6ccccc6)cc3)c3c(ccc6c3ccc3ccccc36)B5c3ccc5c(ccc6ccccc65)c3N4c3ccc(-c4ccccc4)cc3)ccc21]

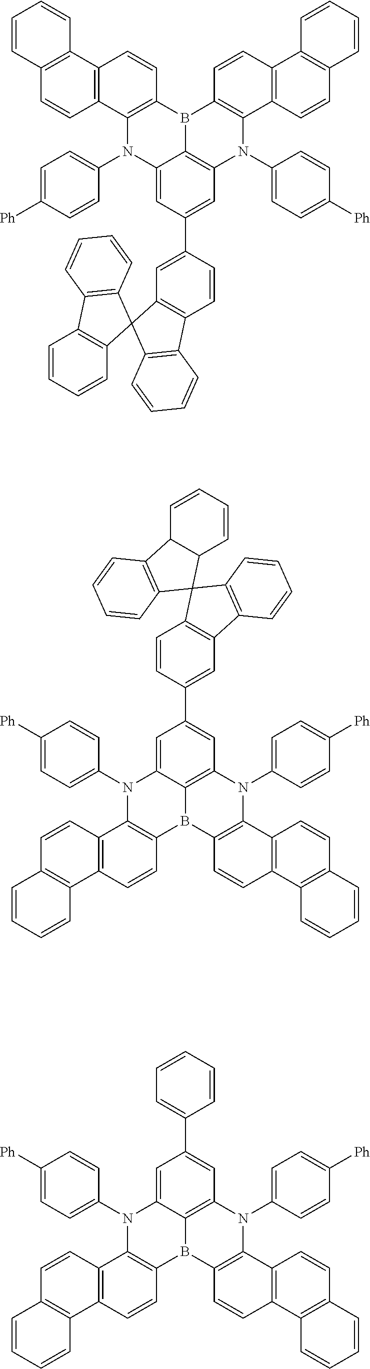 [SMILES: c1ccc(-c2ccc(N3c4cc(-c5ccc6c(c5)C5(c7ccccc7-c7ccccc75)c5ccccc5-6)cc5c4B(c4ccc6c(ccc7ccccc76)c43)c3ccc4c(ccc6ccccc64)c3N5c3ccc(-c4ccccc4)cc3)cc2)cc1 ; C1=CC2c3ccccc3C3(c4ccccc4-c4cc(-c5cc6c7c(c5)N(c5ccc(-c8ccccc8)cc5)c5c(ccc8c5ccc5ccccc58)B7c5ccc7c(ccc8ccccc87)c5N6c5ccc(-c6ccccc6)cc5)ccc43)C2C=C1 ; c1ccc(-c2ccc(N3c4cc(-c5ccccc5)cc5c4B(c4ccc6c(ccc7ccccc76)c43)c3ccc4c(ccc6ccccc64)c3N5c3ccc(-c4ccccc4)cc3)cc2)cc1]

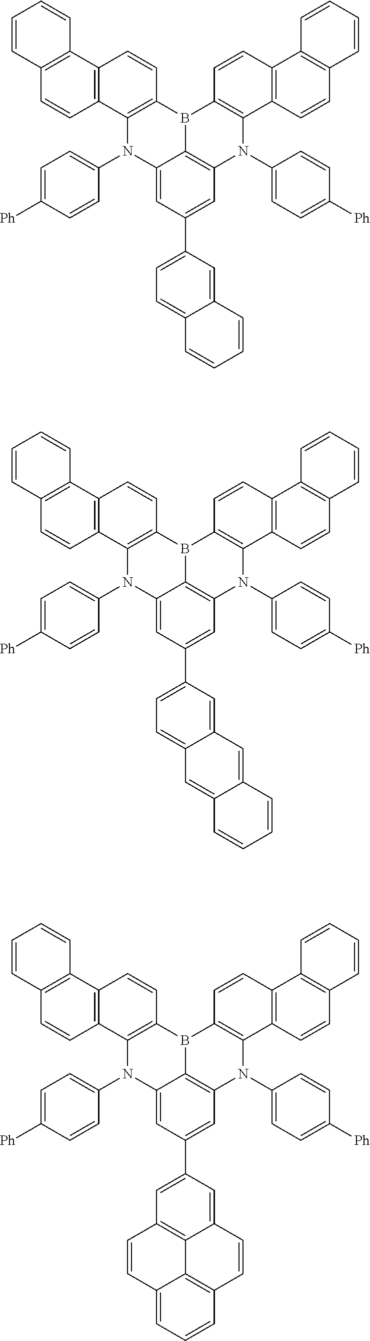 [SMILES: c1ccc(-c2ccc(N3c4cc(-c5ccc6ccccc6c5)cc5c4B(c4ccc6c(ccc7ccccc76)c43)c3ccc4c(ccc6ccccc64)c3N5c3ccc(-c4ccccc4)cc3)cc2)cc1 ; c1ccc(-c2ccc(N3c4cc(-c5ccc6cc7ccccc7cc6c5)cc5c4B(c4ccc6c(ccc7ccccc76)c43)c3ccc4c(ccc6ccccc64)c3N5c3ccc(-c4ccccc4)cc3)cc2)cc1 ; c1ccc(-c2ccc(N3c4cc(-c5cc6ccc7cccc8ccc(c5)c6c78)cc5c4B(c4ccc6c(ccc7ccccc76)c43)c3ccc4c(ccc6ccccc64)c3N5c3ccc(-c4ccccc4)cc3)cc2)cc1]

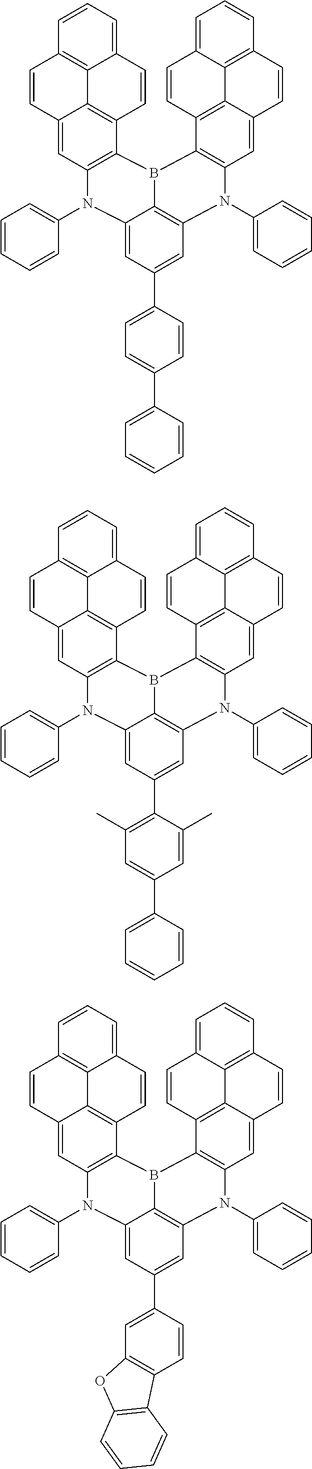 [SMILES: c1ccc(-c2ccc(-c3cc4c5c(c3)N(c3ccccc3)c3cc6ccc7cccc8ccc(c3B5c3c(cc5ccc9cccc%10ccc3c5c9%10)N4c3ccccc3)c6c78)cc2)cc1 ; Cc1cc(-c2ccccc2)cc(C)c1-c1cc2c3c(c1)N(c1ccccc1)c1cc4ccc5cccc6ccc(c1B3c1c(cc3ccc7cccc8ccc1c3c78)N2c1ccccc1)c4c56 ; c1ccc(N2c3cc(-c4ccc5c(c4)oc4ccccc45)cc4c3B(c3c2cc2ccc5cccc6ccc3c2c56)c2c(cc3ccc5cccc6ccc2c3c56)N4c2ccccc2)cc1]

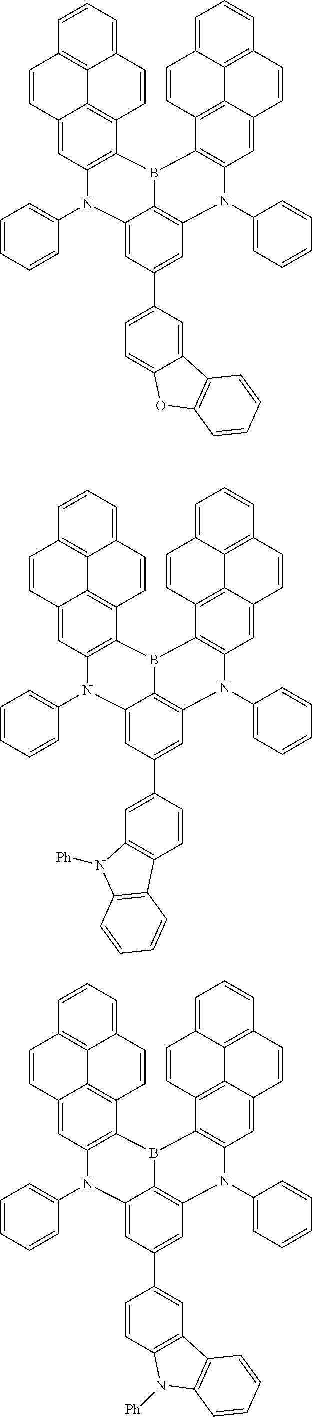

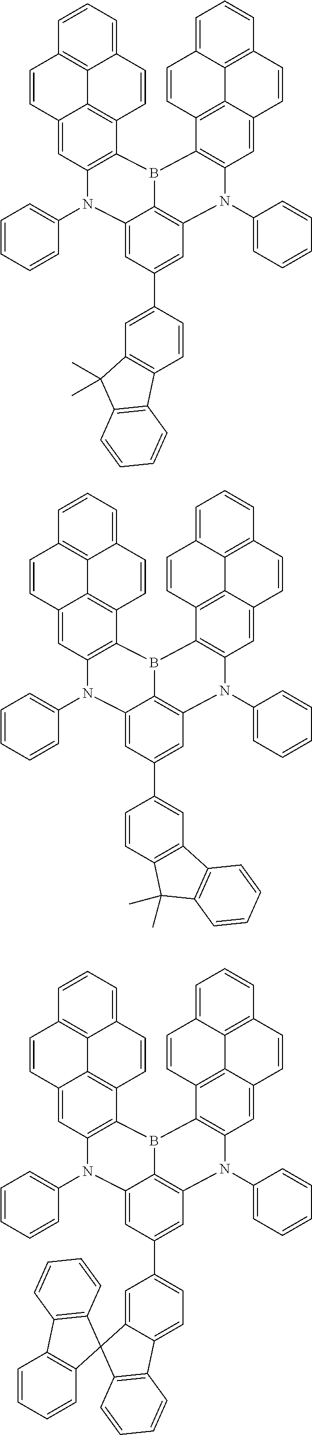

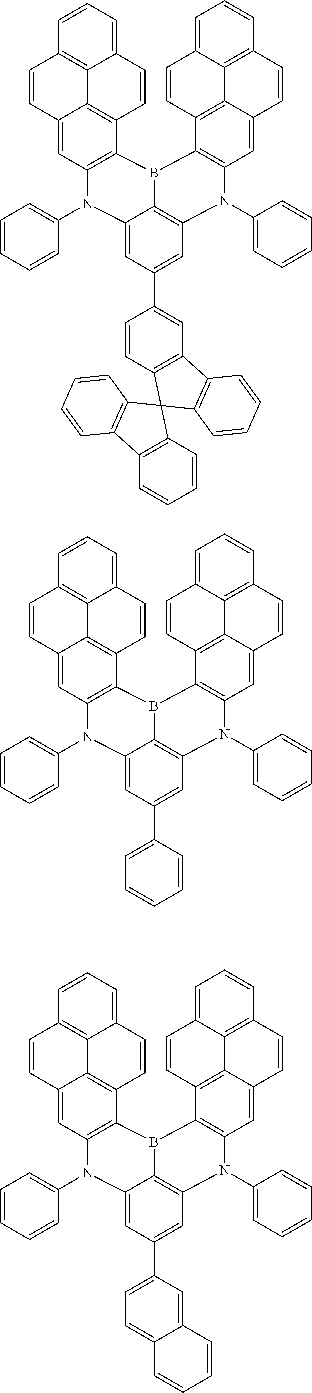 [SMILES: c1ccc(N2c3cc(-c4ccc5c(c4)-c4ccccc4C54c5ccccc5-c5ccccc54)cc4c3B(c3c2cc2ccc5cccc6ccc3c2c56)c2c(cc3ccc5cccc6ccc2c3c56)N4c2ccccc2)cc1 ; c1ccc(-c2cc3c4c(c2)N(c2ccccc2)c2cc5ccc6cccc7ccc(c2B4c2c(cc4ccc8cccc9ccc2c4c89)N3c2ccccc2)c5c67)cc1 ; c1ccc(N2c3cc(-c4ccc5ccccc5c4)cc4c3B(c3c2cc2ccc5cccc6ccc3c2c56)c2c(cc3ccc5cccc6ccc2c3c56)N4c2ccccc2)cc1]

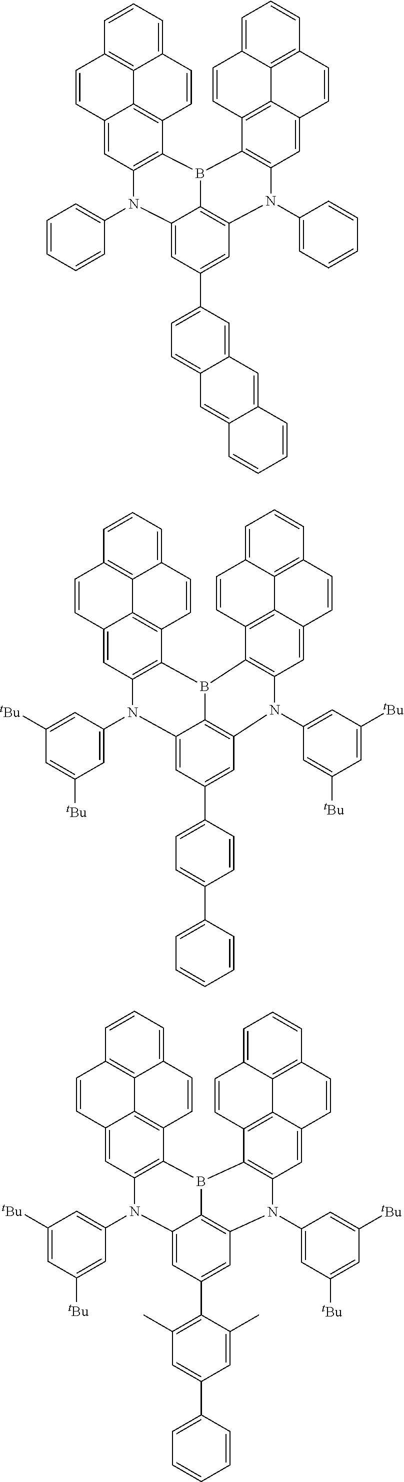

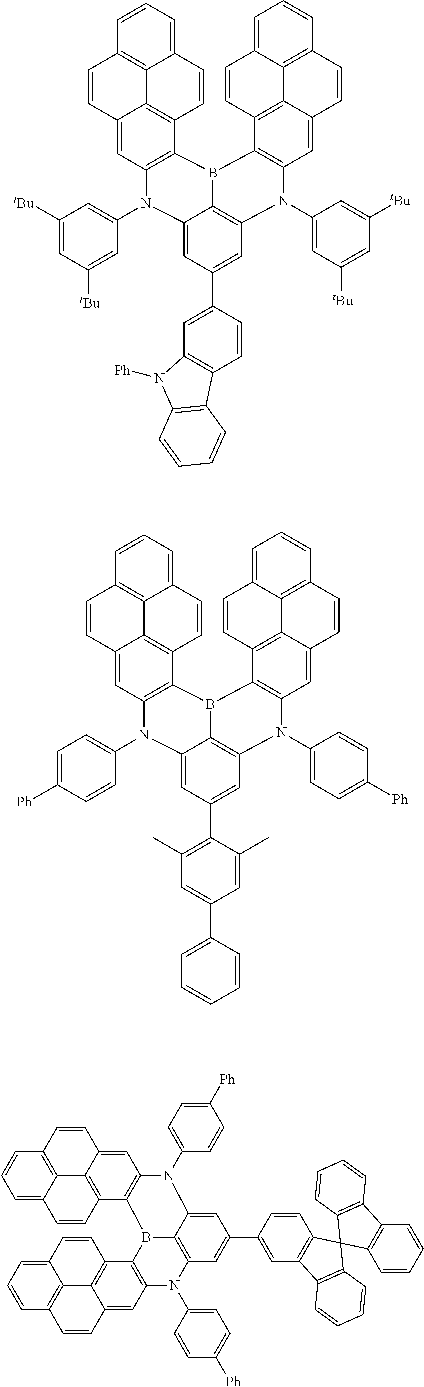 [SMILES: CC(C)(C)c1cc(N2c3cc(-c4ccc5c6ccccc6n(-c6ccccc6)c5c4)cc4c3B(c3c2cc2ccc5cccc6ccc3c2c56)c2c(cc3ccc5cccc6ccc2c3c56)N4c2cc(C(C)(C)C)cc(C(C)(C)C)c2)cc(C(C)(C)C)c1 ; Cc1cc(-c2ccccc2)cc(C)c1-c1cc2c3c(c1)N(c1ccc(-c4ccccc4)cc1)c1cc4ccc5cccc6ccc(c1B3c1c(cc3ccc7cccc8ccc1c3c78)N2c1ccc(-c2ccccc2)cc1)c4c56 ; c1ccc(-c2ccc(N3c4cc(-c5ccc6c(c5)-c5ccccc5C65c6ccccc6-c6ccccc65)cc5c4B(c4c3cc3ccc6cccc7ccc4c3c67)c3c(cc4ccc6cccc7ccc3c4c67)N5c3ccc(-c4ccccc4)cc3)cc2)cc1]

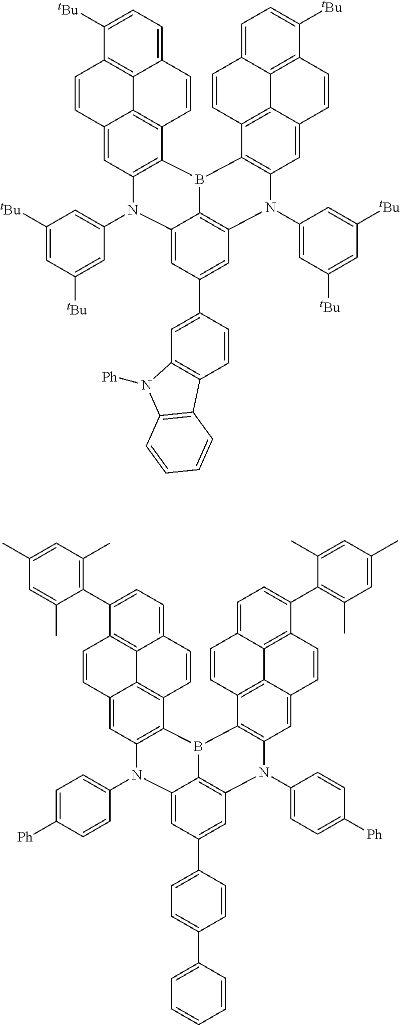

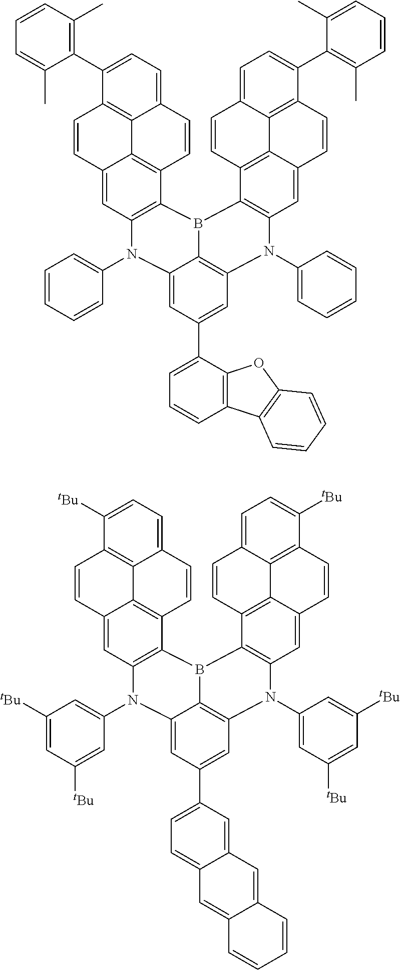 [SMILES: Cc1cccc(C)c1-c1ccc2ccc3c4c(cc5ccc1c2c53)N(c1ccccc1)c1cc(-c2cccc3c2oc2ccccc23)cc2c1B4c1c(cc3ccc4c(-c5c(C)cccc5C)ccc5ccc1c3c54)N2c1ccccc1 ; CC(C)(C)c1cc(N2c3cc(-c4ccc5cc6ccccc6cc5c4)cc4c3B(c3c2cc2ccc5c(C(C)(C)C)ccc6ccc3c2c65)c2c(cc3ccc5c(C(C)(C)C)ccc6ccc2c3c65)N4c2cc(C(C)(C)C)cc(C(C)(C)C)c2)cc(C(C)(C)C)c1]

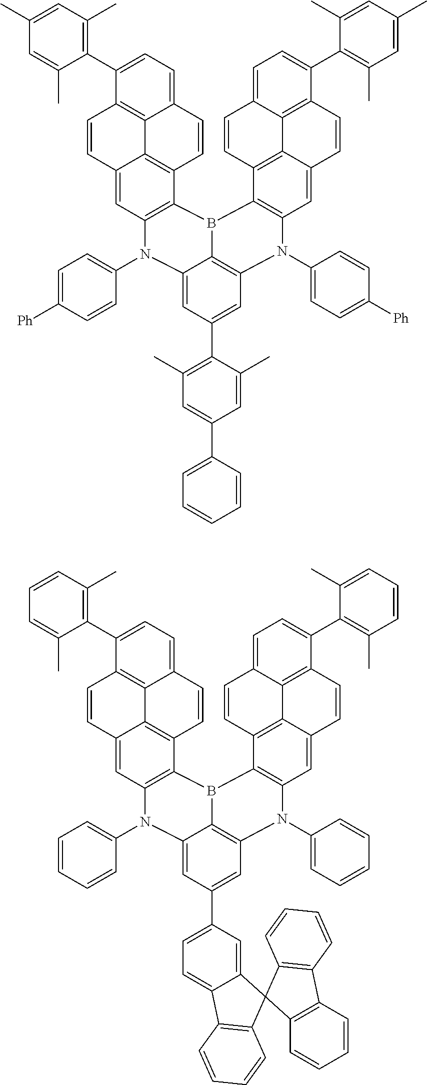

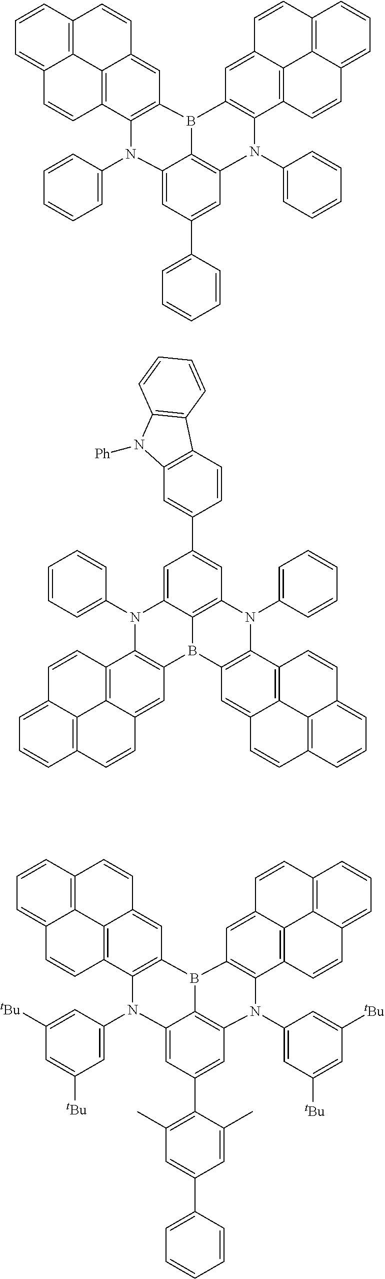

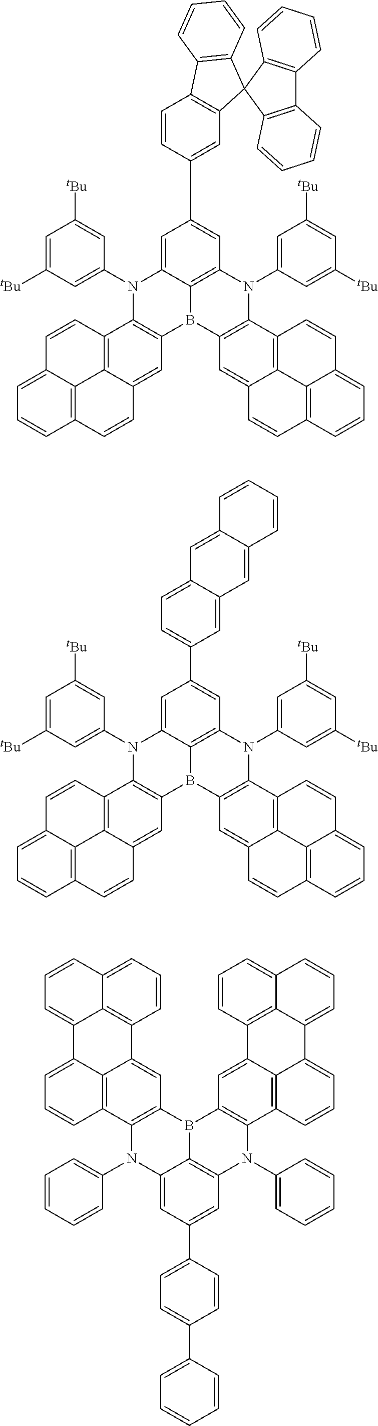 [SMILES: CC(C)(C)c1cc(N2c3cc(-c4ccc5c(c4)C4(c6ccccc6-c6ccccc64)c4ccccc4-5)cc4c3B(c3cc5ccc6cccc7ccc(c32)c5c67)c2cc3ccc5cccc6ccc(c2N4c2cc(C(C)(C)C)cc(C(C)(C)C)c2)c3c56)cc(C(C)(C)C)c1 ; CC(C)(C)c1cc(N2c3cc(-c4ccc5cc6ccccc6cc5c4)cc4c3B(c3cc5ccc6cccc7ccc(c32)c5c67)c2cc3ccc5cccc6ccc(c2N4c2cc(C(C)(C)C)cc(C(C)(C)C)c2)c3c56)cc(C(C)(C)C)c1 ; c1ccc(-c2ccc(-c3cc4c5c(c3)N(c3ccccc3)c3c(cc6c7cccc8cccc(c9cccc3c96)c87)B5c3cc5c6cccc7cccc(c8cccc(c3N4c3ccccc3)c85)c76)cc2)cc1]

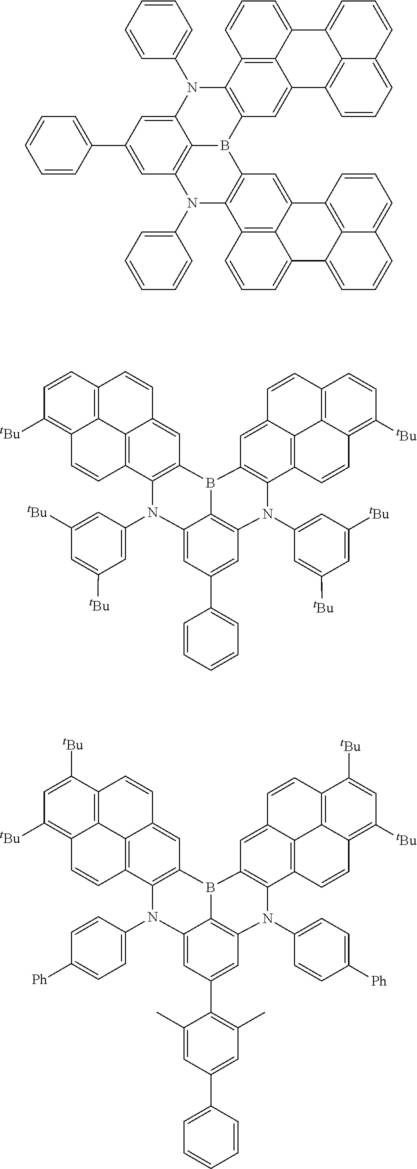 [SMILES: c1ccc(-c2cc3c4c(c2)N(c2ccccc2)c2c(cc5c6cccc7cccc(c8cccc2c85)c76)B4c2cc4c5cccc6cccc(c7cccc(c2N3c2ccccc2)c74)c65)cc1 ; CC(C)(C)c1cc(N2c3cc(-c4ccccc4)cc4c3B(c3cc5ccc6ccc(C(C)(C)C)c7ccc(c32)c5c67)c2cc3ccc5ccc(C(C)(C)C)c6ccc(c2N4c2cc(C(C)(C)C)cc(C(C)(C)C)c2)c3c56)cc(C(C)(C)C)c1 ; Cc1cc(-c2ccccc2)cc(C)c1-c1cc2c3c(c1)N(c1ccc(-c4ccccc4)cc1)c1c(cc4ccc5c(C(C)(C)C)cc(C(C)(C)C)c6ccc1c4c56)B3c1cc3ccc4c(C(C)(C)C)cc(C(C)(C)C)c5ccc(c1N2c1ccc(-c2ccccc2)cc1)c3c45]

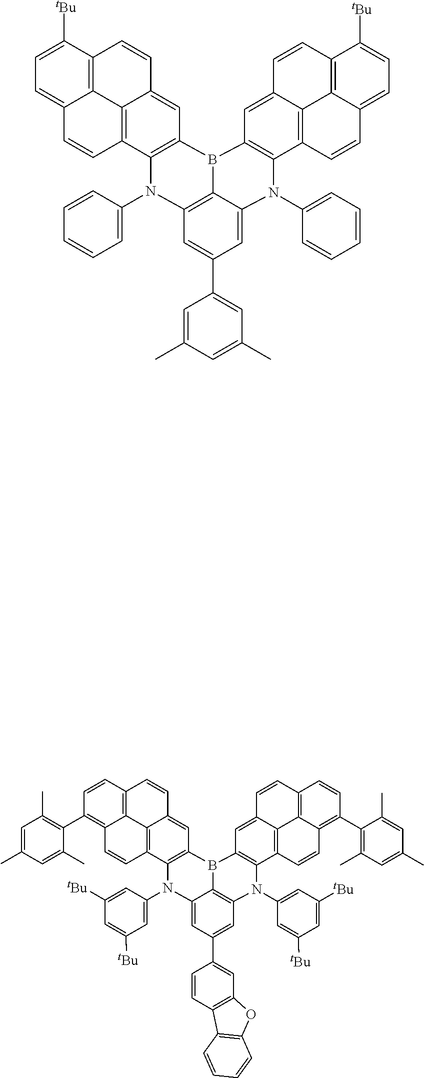

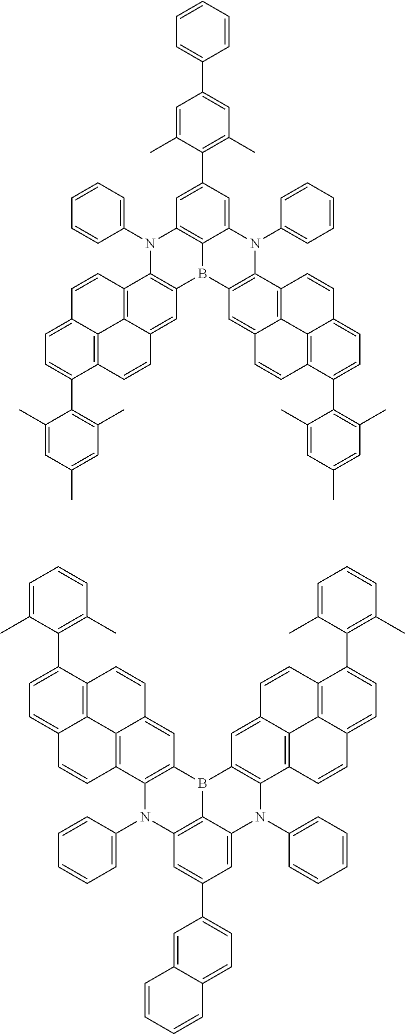

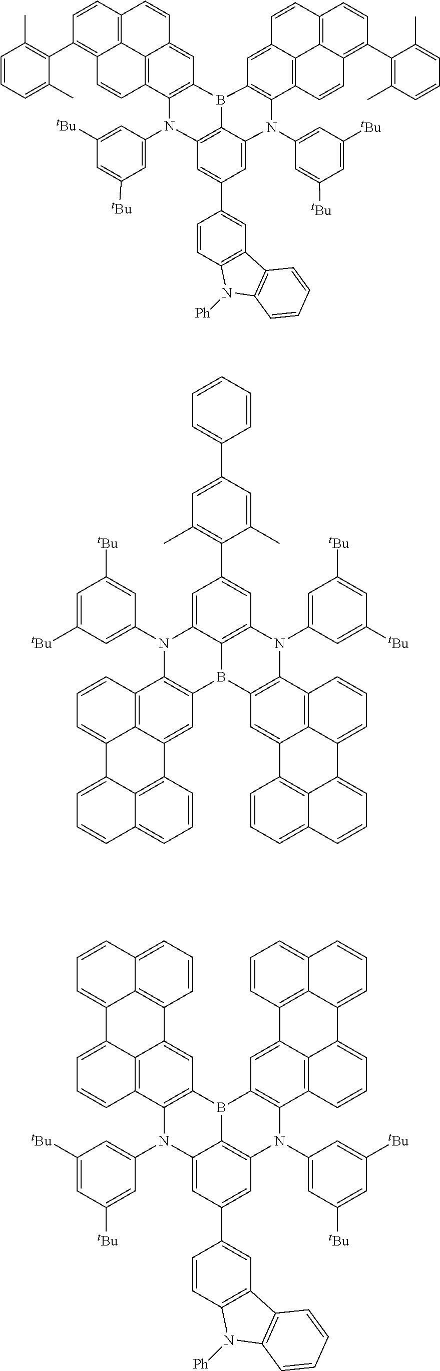

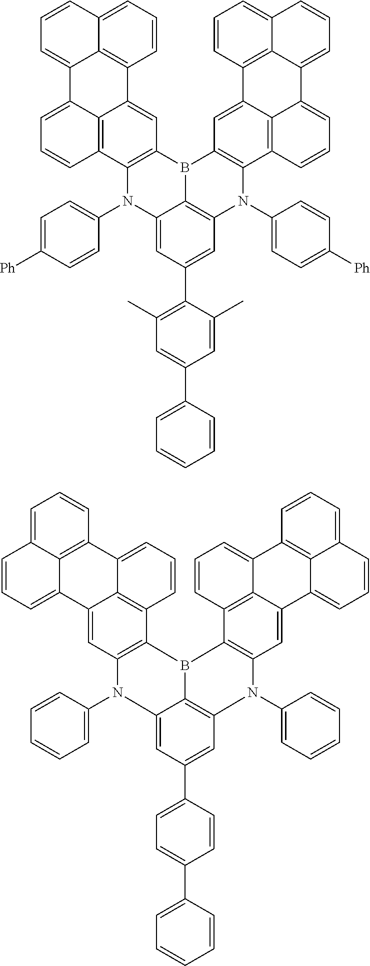 [SMILES: Cc1cc(-c2ccccc2)cc(C)c1-c1cc2c3c(c1)N(c1ccc(-c4ccccc4)cc1)c1c(cc4c5cccc6cccc(c7cccc1c74)c65)B3c1cc3c4cccc5cccc(c6cccc(c1N2c1ccc(-c2ccccc2)cc1)c63)c54 ; c1ccc(-c2ccc(-c3cc4c5c(c3)N(c3ccccc3)c3cc6c7cccc8cccc(c9cccc(c3B5c3c(cc5c%10cccc%11cccc(c%12cccc3c%125)c%11%10)N4c3ccccc3)c96)c87)cc2)cc1]

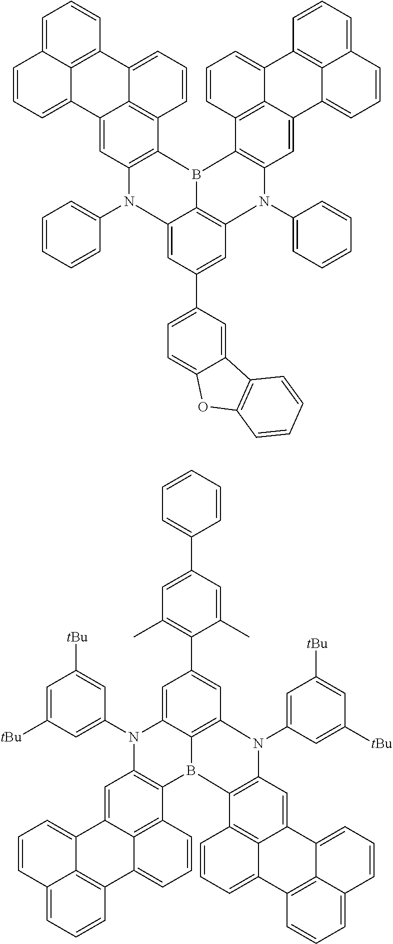 [SMILES: c1ccc(N2c3cc(-c4ccc5oc6ccccc6c5c4)cc4c3B(c3c2cc2c5cccc6cccc(c7cccc3c72)c65)c2c(cc3c5cccc6cccc(c7cccc2c73)c65)N4c2ccccc2)cc1 ; Cc1cc(-c2ccccc2)cc(C)c1-c1cc2c3c(c1)N(c1cc(C(C)(C)C)cc(C(C)(C)C)c1)c1cc4c5cccc6cccc(c7cccc(c1B3c1c(cc3c8cccc9cccc(c%10cccc1c%103)c98)N2c1cc(C(C)(C)C)cc(C(C)(C)C)c1)c74)c65]

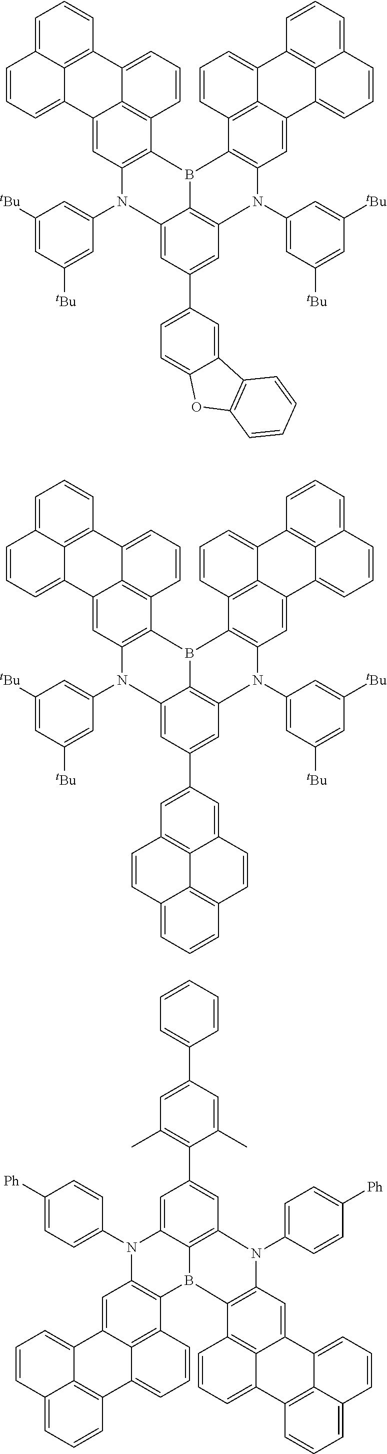

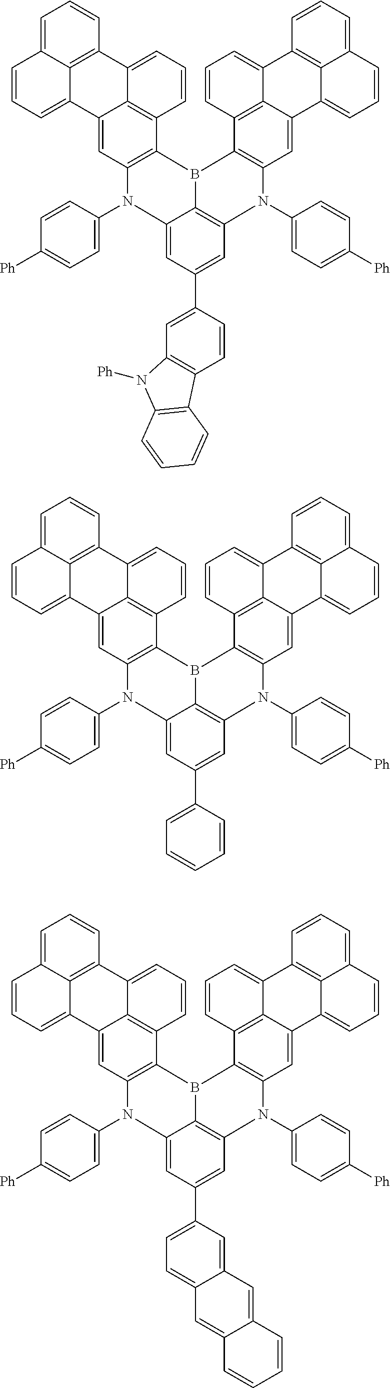 [SMILES: c1ccc(-c2ccc(N3c4cc(-c5ccc6c7ccccc7n(-c7ccccc7)c6c5)cc5c4B(c4c3cc3c6cccc7cccc(c8cccc4c83)c76)c3c(cc4c6cccc7cccc(c8cccc3c84)c76)N5c3ccc(-c4ccccc4)cc3)cc2)cc1 ; c1ccc(-c2ccc(N3c4cc(-c5ccccc5)cc5c4B(c4c3cc3c6cccc7cccc(c8cccc4c83)c76)c3c(cc4c6cccc7cccc(c8cccc3c84)c76)N5c3ccc(-c4ccccc4)cc3)cc2)cc1 ; c1ccc(-c2ccc(N3c4cc(-c5ccc6cc7ccccc7cc6c5)cc5c4B(c4c3cc3c6cccc7cccc(c8cccc4c83)c76)c3c(cc4c6cccc7cccc(c8cccc3c84)c76)N5c3ccc(-c4ccccc4)cc3)cc2)cc1]

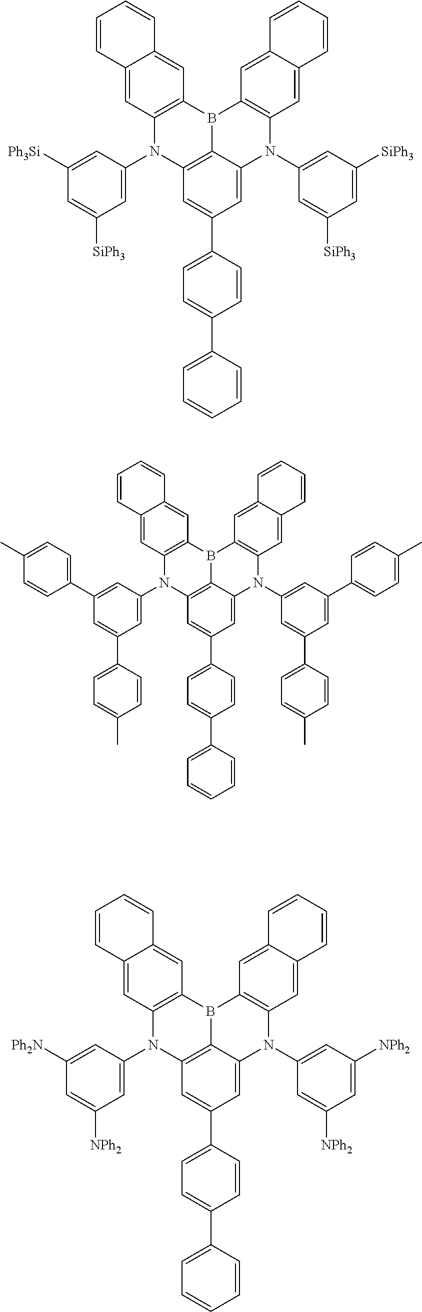

### FIGURES

FIG. 1 Emission spectrum of example 1 (2% by weight) in PMMA.

FIG. 2 Emission spectrum of example 2 (2% by weight) in PMMA.

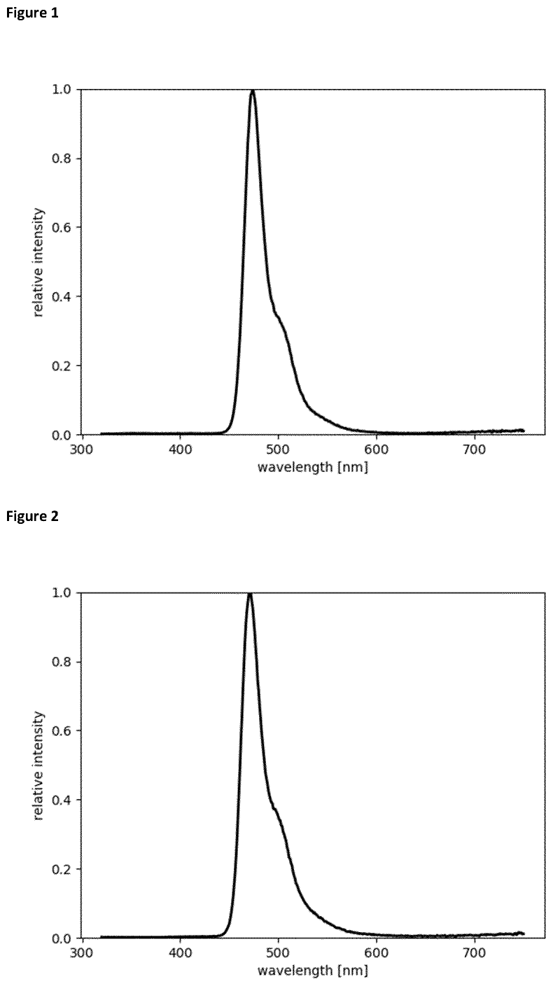

1.-15. (canceled)

16. An organic molecule, comprising:
a first chemical moiety represented by Formula I, 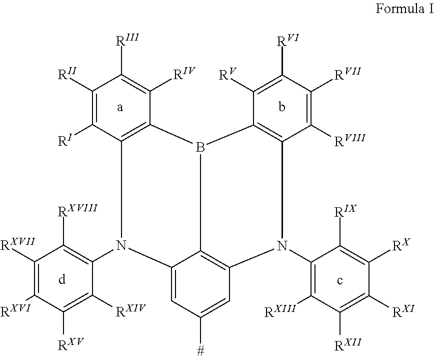
and
a second chemical moiety represented by Formula II, 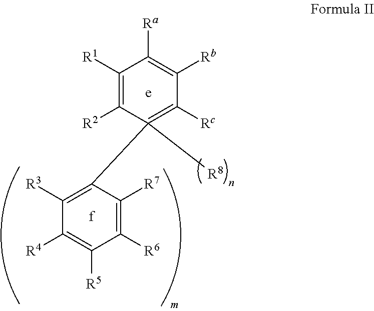
wherein the first chemical moiety is linked to the second chemical moiety via a single bond;
# is a binding site of the first chemical moiety to the second chemical moiety;
m is 0 or 1, n is 0 or 1, and
m+n=1;
R^{a} is a binding site of the single bond linking the second chemical moiety to the first chemical moiety, or is R^{A};
R^{b} is the binding site of the single bond linking the second chemical moiety to the first chemical moiety, or is R^{B};
R^{c} is the binding site of the single bond linking the second chemical moiety to the first chemical moiety, or is R^{X};
R^{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, and R^{XVIII} are each independently selected from the group consisting of:
hydrogen;
deuterium;
N(R⁹)₂;
OR⁹;
SR⁹;
Si(R⁹)₃;
B(OR⁹)₂;
OSO₂R⁹;
CF₃;
CN;
F;
Cl;
Br;
I;
C₁-C₄₀-alkyl,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₁-C₄₀-alkoxy,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₁-C₄₀-thioalkoxy,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₂-C₄₀-alkenyl,
which is optionally substituted with one or more substituents R⁹ and
wherein one or more non-adjacent CH₂-groups are optionally substituted by R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₂-C₄₀-alkynyl,
which is optionally substituted with one or more substituents R⁹ and
wherein one or more non-adjacent CH₂-groups are optionally substituted by
R⁹C═CR⁹, C≡C, Si(R⁹)₂, Ge(R⁹)₂, Sn(R⁹)₂, C═O, C═S, C═Se, C═NR⁹, P(═O)(R⁹), SO, SO₂, NR⁹, O, S or CONR⁹;
C₆-C₆₀-aryl,
which is optionally substituted with one or more substituents R⁹; and
C₃-C₅₇-heteroaryl,
which is optionally substituted with one or more substituents R⁹;
wherein at least one pair of adjacent groups selected from the group of pairs consisting of R^{I} and R^{II}, R^{II} and R^{III}, R^{III} and R^{IV}, R^{V} and R^{VI}, R^{VI} and R^{VII}, R^{VII} and R^{VIII}, R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} forms an aromatic ring system which is fused to a corresponding adjacent benzene ring a, b, c or d, and which is optionally substituted with one or more substituents R⁹; and
wherein adjacent groups R^{I} and R^{XVIII} and/or adjacent groups R^{VIII} and R^{IX} optionally form a group Z¹, which is at each occurrence independently selected from the group consisting of: a direct bond, CR⁹R¹⁰, C═CR⁹R¹⁰, C═O, C═NR⁹, NR⁹, O, SiR⁹R¹⁰, S, S(O), and S(O)₂;
R^{A}, R^{B}, R^{X}, and R¹ to R⁸ are independently selected from the group consisting of:
hydrogen;
deuterium;
N(R¹¹)₂;
OR¹¹;
SR¹¹;
Si(R¹¹)₃;
B(OR¹¹)₂;
OSO₂R¹¹;
CF₃;
CN;
F;
Cl;
Br;
I;
C₁-C₄₀-alkyl,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₁-C₄₀-alkoxy,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₁-C₄₀-thioalkoxy,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R₁₁)₂, C═O, C═S, C═Se, C═NR¹¹, P(═O)(R¹¹), SO, SO₂, NR¹¹, O, S or CONR¹¹;
C₂-C₄₀-alkenyl,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₂-C₄₀-alkynyl,
which is optionally substituted with one or more substituents R¹¹ and
wherein one or more non-adjacent CH₂-groups are optionally substituted by R¹¹C═CR¹¹, C≡C, Si(R¹¹)₂, Ge(R¹¹)₂, Sn(R¹¹)₂, C═O, C═S, C═Se, C═NR¹¹, P(═O)(R¹¹), SO, SO₂, NR¹¹, O, S or CONR¹¹;
C₆-C₆₀-aryl,
which is optionally substituted with one or more substituents R¹¹; and
C₃-C₅₇-heteroaryl,
which is optionally substituted with one or more substituents R¹¹;
wherein adjacent groups R² and R³ and/or adjacent groups R^{X} and R⁷ optionally form a group Z², which is at each occurrence independently selected from the group consisting of: CR¹²R¹³, C═CR¹²R¹³, C═O, C═NR¹², NR¹², O, SiR¹²R¹³, S, S(O) and S(O)₂;
wherein, optionally, one or more pairs of adjacent groups selected from the group of pairs consisting of R¹ and R², R³ and R⁴, R⁴ and R⁵, R⁵ and R⁶, R⁶ and R⁷, R⁷ and R⁸, R⁸ and R^{X}, R^{X} and R^{B}, R^{B} and R^{A}, and R^{A} and R¹ form an aromatic or aliphatic, carbo- or heterocyclic ring system which is fused to a corresponding adjacent benzene ring e or f, which is optionally substituted with one or more substituents R¹¹;
R¹² and R¹³ are at each occurrence independently selected from the group consisting of:
hydrogen;
deuterium;
N(R¹⁴)₂;
OR¹⁴;
SR¹⁴;
Si(R¹⁴)₃;
B(OR¹¹)₂;
OSO₂R¹⁴;
CF₃;
CN;
F;
Cl;
Br;
I;
C₁-C₄₀-alkyl,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₁-C₄₀-alkoxy,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₁-C₄₀-thioalkoxy,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₂-C₄₀-alkenyl,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₂-C₄₀-alkynyl,
which is optionally substituted with one or more substituents R¹⁴ and
wherein one or more non-adjacent CH₂-groups are optionally substituted by R¹⁴C═CR¹⁴, C≡C, Si(R¹⁴)₂, Ge(R¹⁴)₂, Sn(R¹⁴)₂, C═O, C═S, C═Se, C═NR¹⁴, P(═O)(R¹⁴), SO, SO₂, NR¹⁴, O, S or CONR¹⁴;
C₆-C₆₀-aryl,
which is optionally substituted with one or more substituents R¹⁴; and
C₃-C₅₇-heteroaryl,
which is optionally substituted with one or more substituents R¹⁴;
wherein, optionally, R¹² and R¹³ form an aliphatic or aromatic carbo- or heterocyclic ring system with 5 to 30 ring atoms, of which 1 to 3 atoms optionally are a heteroatom independently selected from the group consisting of N, O, and S;
R⁹, R¹⁰, R¹¹, and R¹⁴ are at each occurrence independently selected from the group consisting of:
hydrogen;
deuterium;
OPh;
SPh;
CF₃;
CN;
F;
Si(C₁-C₅-alkyl)₃;
Si(Ph)₃;
C₁-C₅-alkyl,
wherein optionally one or more hydrogen atoms are independently substituted by deuterium, CN, CF₃, or F;
C₁-C₅-alkoxy,
wherein optionally one or more hydrogen atoms are independently substituted by deuterium, CN, CF₃, or F;
C₁-C₅-thioalkoxy,
wherein optionally one or more hydrogen atoms are independently substituted by deuterium, CN, CF₃, or F;
C₂-C₅-alkenyl,
wherein optionally one or more hydrogen atoms are independently substituted by deuterium, CN, CF₃, or F;
C₂-C₅-alkynyl,
wherein optionally one or more hydrogen atoms are independently substituted by deuterium, CN, CF₃, or F;
C₆-C₁₈-aryl,
which is optionally substituted with one or more C₁-C₅-alkyl substituents;
C₃-C₁₇-heteroaryl,
which is optionally substituted with one or more C₁-C₅-alkyl substituents;
N(C₆-C₁₈-aryl)₂;
N(C₃-C₁₇-heteroaryl)₂; and
N(C₃-C₁₇-heteroaryl)(C₆-C₁₈-aryl); and
wherein exactly one group selected from the group consisting of R^{a}, R^{b}, and R^{c} is the binding site of the single bond linking the second chemical moiety to the first chemical moiety.

17. The organic molecule according to claim 16, wherein R^{I}, R^{II}, R^{III}, R^{IV}, R^{V}, R^{VI}, R^{VII}, R^{VIII}, R^{IX}, R^{X}, R^{XI}, R^{XII}, R^{XIII}, R^{XIV}, R^{XV}, R^{XVI}, R^{XVII}, and R^{XVIII} are each independently selected from the group consisting of:
hydrogen;
deuterium;
Me;
ⁱPr;
Bu;
CN;
CF₃;
SiMe₃;
SiPh₃;
Ph, which is optionally substituted with one or more substituents independently selected from the group consisting of deuterium, Me, ⁱPr, ^{t}Bu, CN, CF₃, and Ph, and
N(Ph)₂;
wherein at least one pair of adjacent groups selected from the group of pairs consisting of R^{I} and R^{II}, R^{II} and R^{III}, R^{III} and R^{IV}, R^{V} and R^{VI}, R^{VI} and R^{VII}, and R^{VII} and R^{VIII} forms an aromatic ring system which is fused to a respective adjacent benzene ring a or b to form a fused ring system, and which is optionally substituted with one or more substituents independently selected from the group consisting of:
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph; and
wherein a total number of ring-forming atoms in the fused ring system is 9 to 30;
wherein each pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} do not form an aromatic ring system which is fused to the adjacent benzene ring c or d; and
wherein adjacent groups R^{I} and R^{XVIII} and/or adjacent groups R^{VIII} and R^{IX} optionally form a group Z¹, which is at each occurrence a direct bond.

18. The organic molecule according to claim 16, wherein:
at least one pair of adjacent groups selected from the group of pairs consisting of R^{I} and R^{II}, R^{II} and R^{III}, and R^{III} and R^{IV} forms a first aromatic ring system which is fused to the adjacent benzene ring a to form a first fused ring system; and
at least one pair of adjacent groups selected from the group of pairs consisting of R^{V} and R^{VI}, R^{VI} and R^{VII}, and R^{VII} and R^{VIII} forms a second aromatic ring system which is fused to the adjacent benzene ring b to form a second fused ring system;
wherein the first and second aromatic ring systems are identical and optionally substituted with one or more substituents independently selected from the group consisting of:
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph;
wherein a total number of ring-forming atoms in each of the first and second fused ring systems is 9 to 30;
wherein each pair of adjacent groups R^{IX} and R^{X}, R^{X} and R^{XI}, R^{XI} and R^{XII}, R^{XII} and R^{XIII}, R^{XIV} and R^{XV}, R^{XV} and R^{XVI}, R^{XVI} and R^{XVII}, and R^{XVII} and R^{XVIII} do not form an aromatic ring system which is fused to the adjacent benzene ring c or d; and
wherein adjacent groups R^{I} and R^{XVIII} and/or adjacent groups R^{VIII} and R^{IX} optionally form a group Z¹, which is at each occurrence a direct bond.

19. The organic molecule according to claim 16, wherein R^{A}, R^{B}, R^{X}, and R¹ to R⁸ are each independently selected from the group consisting of:
hydrogen;
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph;
wherein adjacent groups R² and R³ and/or adjacent groups R^{X} and R⁷ optionally form a group Z², which is at each occurrence independently selected from the group consisting of: CR¹²R¹³, NR¹², O, and S;
wherein, optionally, one or more pair of adjacent groups selected from the group of pairs consisting of R¹ and R², R³ and R⁴, R⁴ and R⁵, R⁵ and R⁶, R⁶ and R⁷, R² and R⁸, R⁸ and R^{X}, R^{X} and R^{B}, R^{B} and R^{A}, and R^{A} and R¹ form an additional aliphatic or aromatic, carbocyclic or heterocyclic ring system which is fused to the adjacent benzene ring e or f to form a fused ring system, and optionally substituted with one or more substituents independently selected from the group consisting of:
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, and CF₃; and
wherein a total number of ring-forming atoms in the fused ring system is 9 to 30 ring atoms, of which 1 to 3 atoms optionally are heteroatoms independently selected from the group consisting of N, O, and S.

20. The organic molecule according to claim 16, wherein adjacent groups R² and R³ and/or adjacent groups R^{X} and R⁷ form the group Z², and
R¹² and R¹³ are at each occurrence independently selected from the group consisting of:
hydrogen;
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph, and
wherein, optionally, R¹² and R¹³ form an aliphatic or aromatic, carbocyclic ring system with 5 to 30 carbon atoms.

21. The organic molecule according to claim 16, wherein the first chemical moiety is represented by any of Formula I-a, I-b, I-c, I-d, I-e, I-f, I-g, I-h, I-i, I-j, I-k, I-m, I-n, I-o, I-p, I-q, I-r, I-s, I-t, I-u, I-v, I-w, I-x, or I-y: 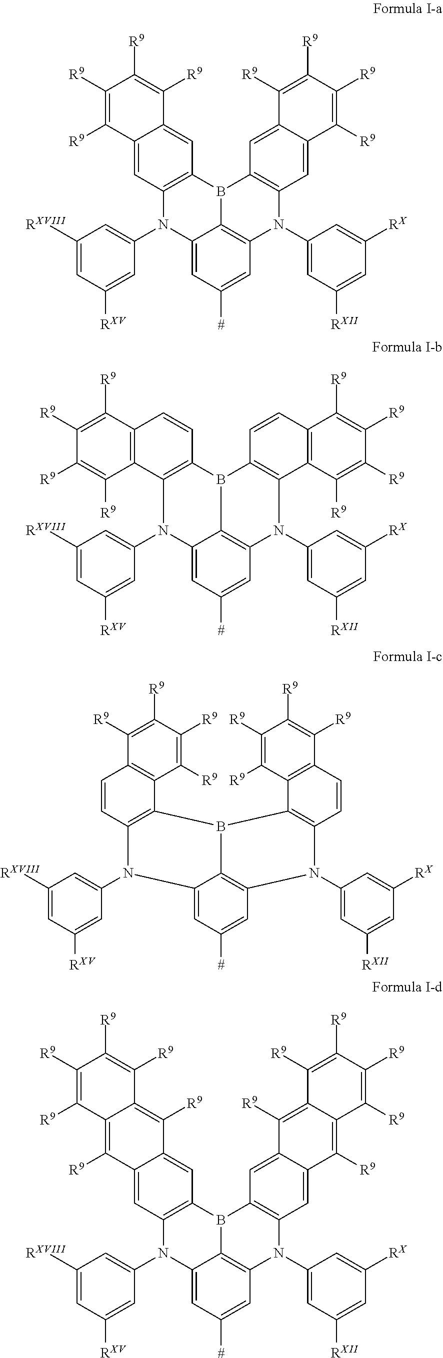 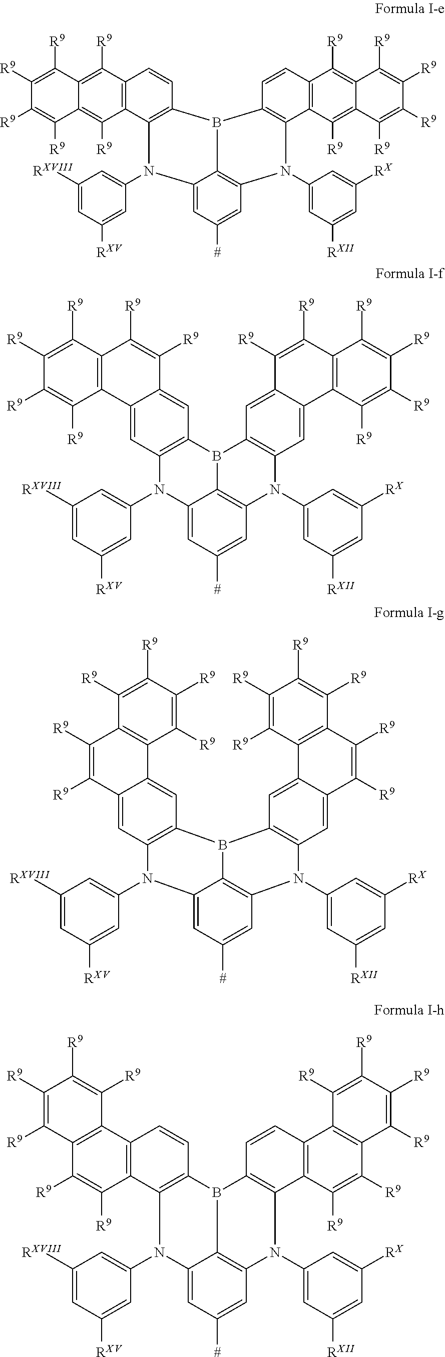 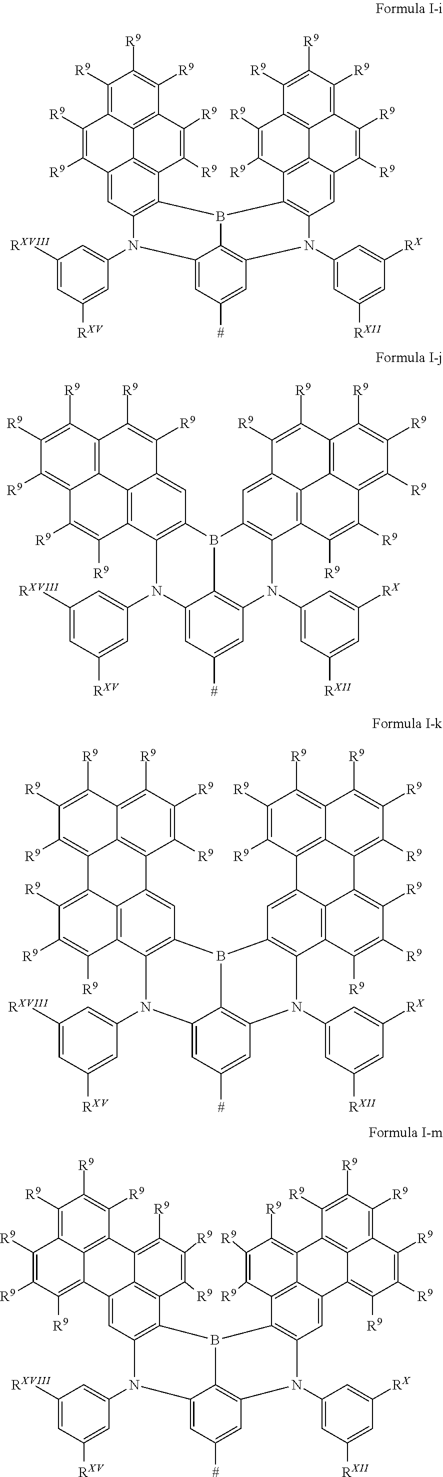 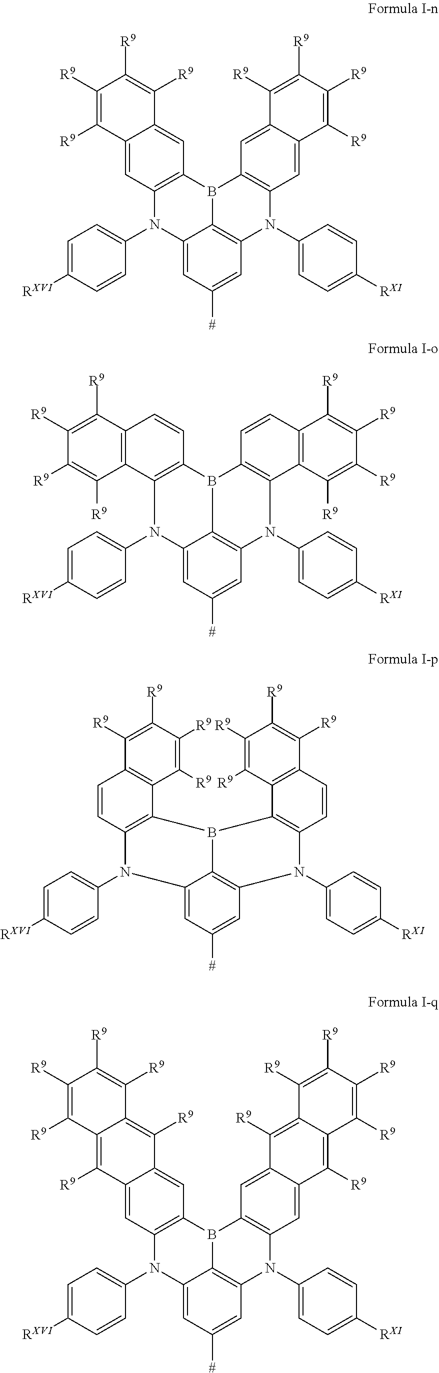 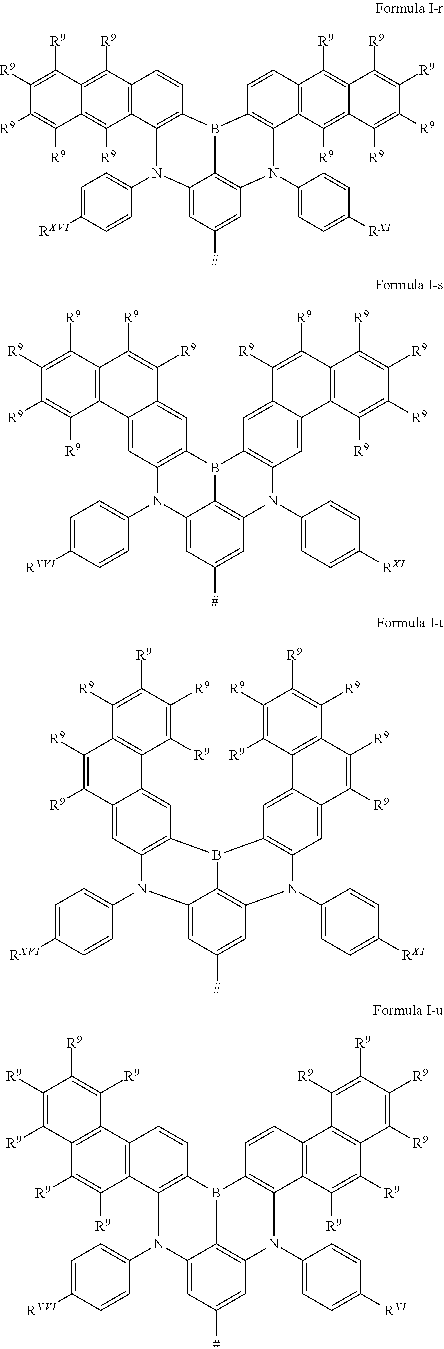 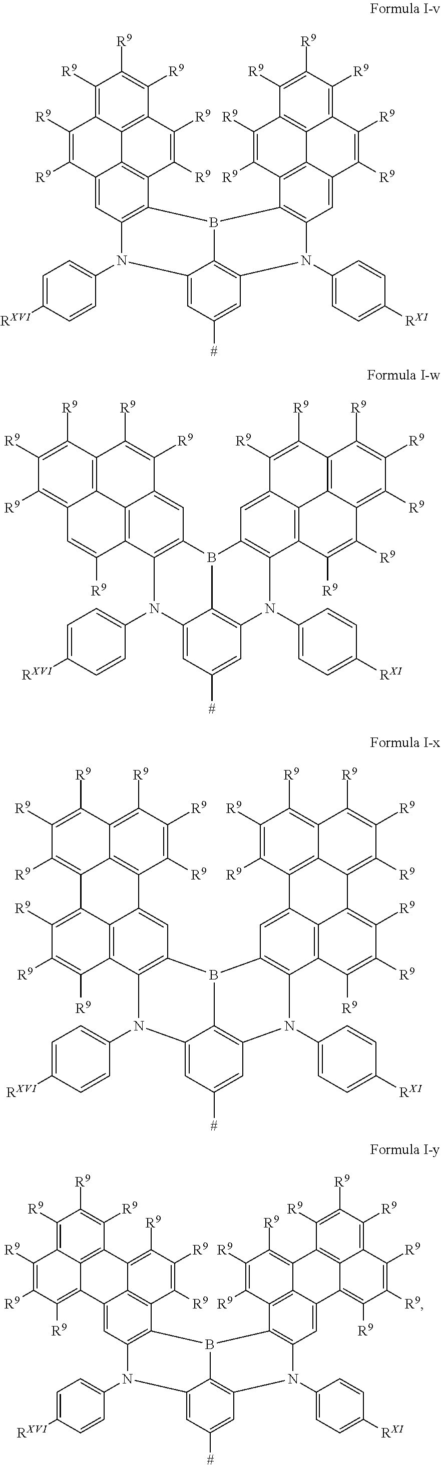
wherein R⁹ is at each occurrence independently selected from the group consisting of:
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph.

22. The organic molecule according to claim 21, wherein the first chemical moiety is represented by any of Formula I-a, I-d, I-f, I-n, I-q, or I-s, and wherein R⁹ is at each occurrence hydrogen or deuterium.

23. The organic molecule according to claim 16, wherein the second chemical moiety is represented by any of Formula II-a-1, II-a-2, II-a-3, II-a-4, II-a-5, II-a-6, II-a-7, II-b-1, II-b-2, II-b-3, II-b-4, II-b-5, II-b-6, II-b-7, II-b-8, II-b-9, II-b-10, II-b-11, II-b-12, or II-b-13: 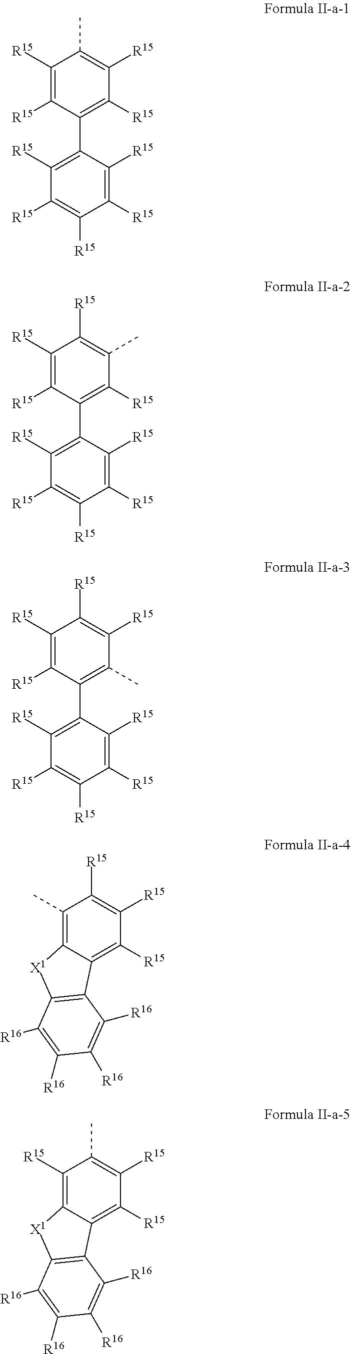 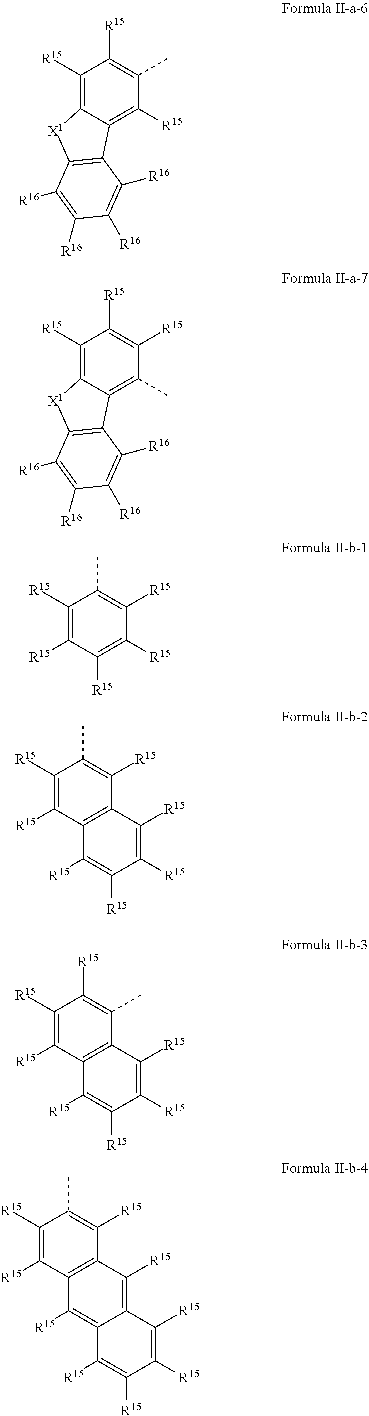 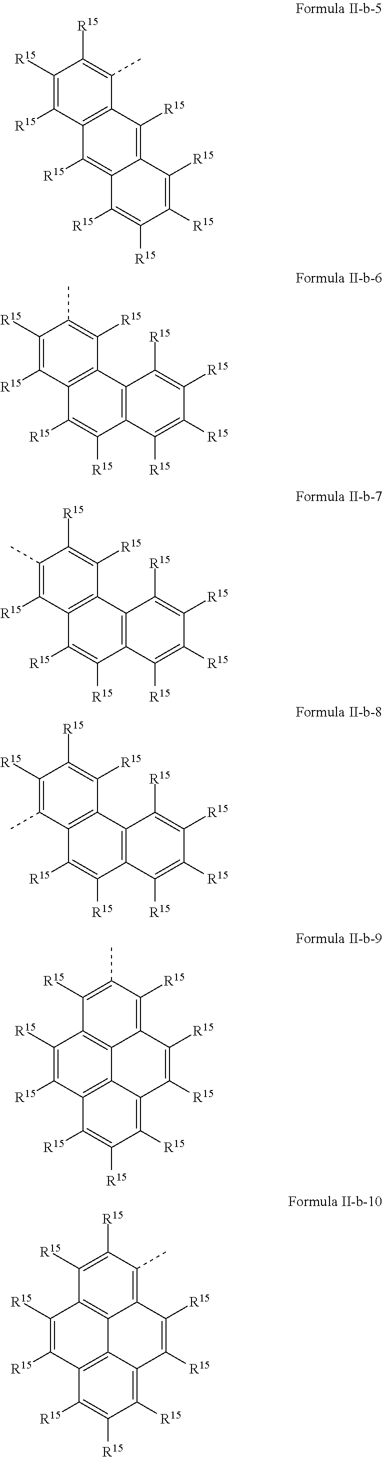 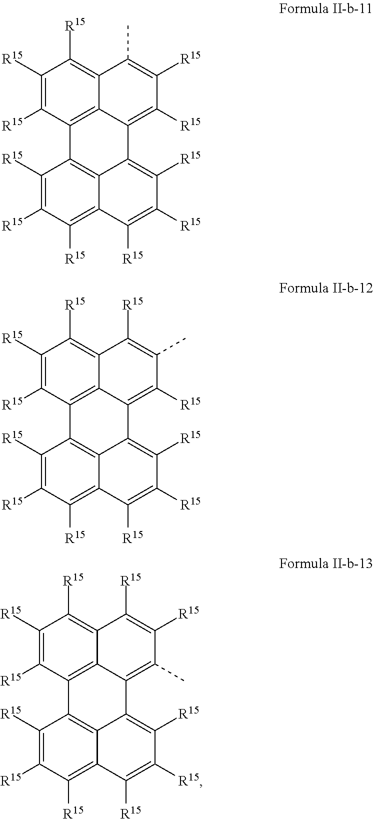
wherein,
the dashed line indicates the single bond linking the second chemical moiety to the first chemical moiety;
X¹ is selected from the group consisting of C(R¹⁷)₂, NR¹⁵, O, and S;
R¹⁵, R¹⁶, and R¹⁷ are at each occurrence independently selected from the group consisting of:
hydrogen;
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph;
wherein two or more adjacent groups R¹⁶ optionally form an additional aliphatic or aromatic, carbocyclic or heterocyclic ring system which is fused to the structure according to any of Formulas II-a-4, II-a-5, II-a-6 and II-a-7 to form a fused ring system;
wherein, a total number of ring-forming atoms in the fused ring system of the second chemical moiety represented by Formula II-a-4, II-a-5, II-a-6, or II-a-7 is 16 to 30, of which 1 to 3 atoms optionally are heteroatoms independently selected from the group consisting of N, O, and S;
wherein the optionally formed additional ring system is optionally substituted with one or more substituents independently selected from the group consisting of:
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph; and
wherein, optionally, two substituents R¹⁷ form an aliphatic or aromatic, carbocyclic ring system with 5 to 30 carbon atoms, which optionally are substituted with one or more substituents independently selected from the group consisting of:
deuterium;
Me;
ⁱPr;
^{t}Bu;
CN;
CF₃; and
Ph, which is optionally substituted with one or more substituents independently selected from the group consisting of deuterium, Me, ⁱPr, ^{t}Bu, CN, CF₃, and Ph.

24. An optoelectronic device, comprising the organic molecule according to claim 16 as a luminescent emitter.

25. The optoelectronic device according to claim 24, wherein the optoelectronic device is at least one selected from the group consisting of:
organic light-emitting diodes (OLEDs), light-emitting electrochemical cells, OLED-sensors, organic diodes, organic solar cells, organic transistors, organic field-effect transistors, organic lasers, and down-conversion elements.

26. A composition, comprising:
(a) the organic molecule according to claim 16, in the form of an emitter and/or a host, and
(b) an emitter and/or host material, which differs from the organic molecule, and
(c) optionally, a dye and/or a solvent.

27. An optoelectronic device, comprising the composition according to claim 26.

28. The optoelectronic device according to claim 27,
wherein the device is at least one selected from the group consisting of organic light-emitting diodes (OLEDs), light-emitting electrochemical cells, OLED-sensors, organic diodes, organic solar cells, organic transistors, organic field-effect transistors, organic lasers, and down-conversion elements.

29. The optoelectronic device according to claim 24, comprising:
a substrate,
an anode, and
a cathode, wherein the anode or the cathode is on the substrate, and
a light-emitting layer between the anode and the cathode and comprising the organic molecule.

30. A method for producing an optoelectronic device, the method comprising depositing the organic molecule according to claim 16 by a vacuum evaporation method and/or from a solution.

31. The optoelectronic device according to claim 27, comprising:
a substrate,
an anode, and
a cathode, wherein the anode or the cathode is on the substrate, and
a light-emitting layer between the anode and the cathode and comprising the composition.

32. A method for producing an optoelectronic device, the method comprising depositing the composition according to claim 26 by a vacuum evaporation method and/or from a solution.
